(19) United States
(12) Patent Application Publication
(10) Pub. No.: US 2020/0264461 A1
(43) Pub. Date: Aug. 20, 2020

(54) LIGHT CONVERSION FILM AND IMAGE DISPLAY DEVICE

(71) Applicant: DIC CORPORATION, Tokyo (JP)

(72) Inventors: Yasuhiro Kuwana, Kita-adachi-gun (JP); Hidetoshi Nakata, Kita-adachi-gun (JP); Hidehiko Yamaguchi, Kita-adachi-gun (JP); Takayuki Miki, Sakura-shi (JP); Hirotomo Sasaki, Sakura-shi (JP); Shunki Sakai, Sakura-shi (JP)

(73) Assignee: DIC CORPORATION, Tokyo (JP)

(21) Appl. No.: 16/648,056

(22) PCT Filed: Sep. 20, 2018
(86) PCT No.: PCT/JP2018/034906

§ 371 Date: Mar. 17, 2020

(30) Foreign Application Priority Data
Sep. 22, 2017 (JP) 2017-182481

(51) Int. Cl. G02F 1/13357; C09K 11/70; C09K 11/08; G02F 1/1335; F21V 8/00; G02F 1/1368; H01L 27/32

(52) U.S. Cl. CPC G02F 1/1336; C09K 11/703; C09K 11/0883; G02F 1/133514; G02B 6/0068; G02F 2001/133614; G02B 6/0073; G02F 1/1368; G02F 1/133512; H01L 27/322; G02B 6/0091

(57) ABSTRACT

An aspect of the present invention provides a light conversion film including light-emitting nanocrystalline particles configured to convert light having a predetermined wavelength into light of any of red, green, and blue and to emit the light, and a wavelength-selective transmission layer disposed on at least one side of the light conversion layer and configured to transmit light in a specific wavelength range.

### TECHNICAL FIELD

The present invention relates to a light conversion film and an image display device including the light conversion film.

### BACKGROUND ART

As image display devices for displaying two-dimensional images or three-dimensional images, there are various devices, such as liquid crystal display devices and inorganic and organic electroluminescent (EL) devices. Liquid crystal display devices are not self-luminous and thus require light sources. Liquid crystal display devices are flat, thin image display devices that display images with liquid crystal materials serving as shutters for light passing through pixels by voltage control. Inorganic or organic electroluminescent (EL) devices are self-luminous display devices in which the emission intensity can be adjusted by controlling the amount of electric current, and are image display devices including light-emitting diodes (LEDs) that include light-emitting layers composed of inorganic or organic compounds. In each case, one pixel is composed of three colors of red, green, and blue. Currently, mainstream image display devices include thin-film transistors (TFTs) that have a switch function to allow the transmission of light and that are connected to the respective color portions.

Active-matrix liquid crystal display devices have been placed on markets for, for example, mobile terminals, liquid crystal television sets, projectors, and computers because of their good display qualities. In active-matrix display systems, for example, thin-film transistors (TFTs) or metal-insulator-metal (NIM) structures are used for respective pixels. For example, twisted nematic (TN), vertical alignment (VA), in-plane switching (IPS), and fringe field switching (FFS) modes are used in combination with liquid crystal compositions having high voltage holding ratios. In particular, because liquid crystal display devices include color filters in addition to liquid crystal elements to achieve color display, even if light source units are improved, it is difficult to improve color reproducibility. To improve color reproducibility, it is thus necessary to increase pigment concentrations in color filters or to increase color purity by increasing colored film thickness.

Electroluminescent devices, typified by organic electroluminescent devices, are self-luminous, requires no backlight, can be reduced in thickness and weight, have a small number of members, and are easily designed to be foldable. Electroluminescent devices, however, have problems, such as display failure due to the deterioration of light-emitting members. Specifically, there is a need to solve problems, such as high costs due to poor yield in the production of devices, the image-sticking of devices due to lifetime, and display nonuniformity. To produce full-color organic electroluminescent devices, light beams of red, green, and blue colors need to be independently emitted. In particular, the foregoing problems tend to occur in high-energy, short-wavelength blue light. There is also a problem that devices turn yellow because blue fades for long-term use.

As a technique for addressing both of the color reproducibility and the luminous efficiency of an image display device, quantum dot technology (see Patent Literature 1), which is an example of light-emitting nanocrystalline particles, have been receiving attention. The use of quantum dots seemingly enables the production of light sources of the three primary colors each having a narrow full width at half maximum to lead to a wide color gamut display; a liquid crystal display device having improved color reproducibility is disclosed (see Patent Literature 2 and Non-Patent Literature 1). It is reported that instead of conventional color filters, quantum dots of three colors are used by means of near-ultraviolet light or short-wavelength visible light, such as blue, as a light source (see Patent Literature 3). In principle, these display devices can achieve both high luminous efficiency and high color reproducibility.

### CITATION LIST

### Patent Literature

PTL 1: Japanese Unexamined Patent Application Publication (Translation of PCT Application) No. 2001-523758
PTL 2: International Publication No. 2004/074739
PTL 3: U.S. Pat. No. 8,648,524

### Non Patent Literature

NPL 1: SID 2012 DIGEST, pp 895-896

### SUMMARY OF INVENTION

### Technical Problem

However, in the case where quantum dots, which are an example of light-emitting nanocrystalline particles, are used as color filters of an image display device as described in PTLs 2 and 3 and NPL 1, an increase in quantum dot content causes adjacent quantum dots to absorb and extinguish emitted light; thus, the external quantum efficiency is not increased. A reduction in quantum dot content disadvantageously causes blue light used for emission from the quantum dots to pass therethrough, thereby decreasing color purity.

Additionally, there are problems of the deactivation of quantum dots by the external environment surrounding the quantum dots and a decrease in external quantum efficiency due to a ligand used, a cured resin, and so forth to a value lower than that of the quantum dots alone.

Accordingly, a technical object to be solved by the present invention is to provide a light conversion film that can achieve high luminous efficiency and high color purity and an image display device including the light conversion film.

### Solution to Problem

The inventors have conducted intensive studies to solve the foregoing problems and have found that the problems can be solved. The findings have led to the completion of the present invention.

According to one aspect of the present invention, a light conversion film includes a light conversion layer containing light-emitting nanocrystalline particles configured to convert light having one or more predetermined wavelengths into light of any of red, green, and blue and to emit the light, and a wavelength-selective transmission layer disposed on at least one side of the light conversion layer and configured to transmit light in one or more specific wavelength ranges.

The light conversion film includes the wavelength-selective transmission layer in accordance with the wavelength of incident light and the wavelength of light emitted from the light-emitting nanocrystalline particles. Thus, part of the light emitted from the light conversion layer can be reflected from the wavelength-selective transmission layer, so that light emitted from the light conversion layer can be amplified and emitted from the one surface side.

According to another aspect of the present invention, an image display device includes a light source section, a light conversion layer containing light-emitting nanocrystalline particles configured to convert light having one or more predetermined wavelengths into light of any of red, green, and blue and to emit the light, and a wavelength-selective transmission layer disposed on at least one side of the light conversion layer and configured to transmit light in one or more specific wavelength ranges.

The image display device includes the light conversion layer and the wavelength-selective transmission layer. Thus, part of the light emitted from the light conversion layer can be reflected from the wavelength-selective transmission layer, so that light emitted from the light conversion layer can be amplified and emitted from on the display side.

### Advantageous Effects of Invention

The image display device of the present invention has good luminous efficiency and good color purity. The image display device of the present invention has good transmittance and maintains the color gamut over an extended period of time. The light conversion film of the present invention has good luminous efficiency and good color purity. The light conversion film of the present invention has good transmittance and maintains the color gamut over an extended period of time.

### BRIEF DESCRIPTION OF DRAWINGS

FIG. 1 is a perspective view of an image display device (liquid crystal display device) according to an embodiment.

FIG. 2 is a perspective view of an image display device (liquid crystal display device) according to another embodiment.

FIG. 3 is a cross-sectional view illustrating the structure of a liquid crystal panel according to an embodiment.

FIG. 4 is a cross-sectional view illustrating a light conversion film according to an embodiment.

FIG. 5 is a graph illustrating an example of the transmission characteristics of a wavelength-selective transmission layer.

FIG. 6 is a cross-sectional view illustrating the structure of a liquid crystal panel according to another embodiment.

FIG. 7 is a cross-sectional view illustrating the structure of a liquid crystal panel according to another embodiment.

FIG. 8 is a cross-sectional view illustrating the structure of a liquid crystal panel according to another embodiment.

FIG. 9 is a cross-sectional view of a light conversion film according to another embodiment.

FIG. 10 is a cross-sectional view illustrating the structure of a liquid crystal panel according to another embodiment.

FIG. 11 is a cross-sectional view illustrating the structure of a liquid crystal panel according to another embodiment.

FIG. 12 is a perspective view of a light conversion film according to another embodiment.

FIG. 13 is a schematic diagram of an equivalent circuit of pixel portions of a liquid crystal display device.

FIG. 14 is a schematic view of an example of the shape of pixel electrodes.

FIG. 15 is a schematic view of an example of the shape of pixel electrodes.

FIG. 16 is a schematic view of the electrode structure of an IPS-mode liquid crystal display device.

FIG. 17 is an example of a cross-sectional view of a liquid crystal display device taken along line of FIG. 14 or 15.

FIG. 18 is a cross-sectional view of an IPS-mode liquid crystal panel taken along line of FIG. 16.

FIG. 19 is an enlarged plan view of a region of an electrode layer 3 surrounded by line XIV, the region including thin-film transistor disposed on a substrate of FIG. 2.

FIG. 20 is a cross-sectional view of the liquid crystal display device illustrated in FIG. 2 taken along line of FIG. 18.

FIG. 21 is a schematic view of an image display device (OLED) according to an embodiment.

FIG. 22 is a graph illustrating a comparison of an example and a comparative example.

### DESCRIPTION OF EMBODIMENTS

Embodiments of the present invention will be described in detail below with reference to the drawings as appropriate.

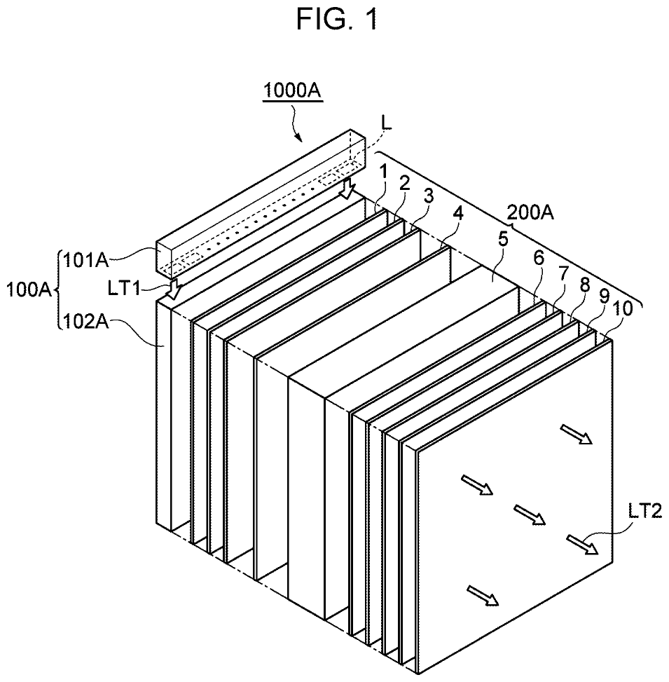

An embodiment of an image display device will first be described. The image display device may be, for example, a liquid crystal display device or an organic electroluminescent display device. FIG. 1 is a perspective view of an image display device (liquid crystal display device) according to an embodiment. In FIG. 1, for explanatory convenience, components are illustrated separately.

As illustrated in FIG. 1, a liquid crystal display device 1000A according to an embodiment includes a backlight unit 100A and a liquid crystal panel 200A. The backlight unit 100A includes a light source section 101A including multiple light-emitting devices L and a light guide section 102A serving as a light guide plate or a light diffusion plate.

As illustrated in FIG. 1, in an embodiment of the backlight unit 100A, the light source section 101A including multiple light-emitting devices L is disposed on one side of the light guide section 102A. The light source section 101A including multiple light-emitting devices L may also be disposed on another side of the light guide section 102A (both sides opposite each other) in addition to on one side of the liquid crystal panel 200A (the one side of the light guide section 102A), as needed. The light source section 101A including multiple light-emitting devices L may be disposed on the three sides of the light guide section 102A, i.e., so as to surround the light guide section 102A, or on the four sides of the light guide section 102A, i.e., so as to surround the entire circumference of the light guide section 102A. The light guide section 102A may include a light diffusion plate in place of the light guide plate, as needed.

Each of the light-emitting devices L is a light-emitting device that emits light LT1, which is ultraviolet light or visible light. The wavelength range of each light-emitting device L is not particularly limited. The light-emitting device L preferably has a main emission peak in a blue region. For example, a light-emitting diode (blue light-emitting diode) having a main emission peak in the wavelength range of 420 nm to 480 nm can be preferably used. As such a light-emitting device L, a known light-emitting device can be used. An example thereof is a light-emitting device at least including a seed layer composed of AlN on a sapphire substrate, an underlying layer on the seed layer, and a stacked semiconductor layer mainly containing GaN. The stacked semiconductor layer may have a structure in which an underlying layer, an n-type semiconductor layer, a light-emitting layer, and a p-type semiconductor layer are stacked in this order from the substrate side.

Examples of the light-emitting device L that emits ultraviolet light may include low-pressure mercury lamps, medium-pressure mercury lamps, high-pressure mercury lamps, ultrahigh-pressure mercury lamps, carbon-arc lamps, electrodeless lamps, metal halide lamps, xenon arc lamps, and LEDs. LEDs are preferred.

In this specification, light in the wavelength range of 420 nm to 480 nm (in particular, light having an emission center wavelength in the wavelength range) is referred to as blue light. Light in the wavelength range of 500 nm to 560 nm (in particular, light having an emission center wavelength in the wavelength range) is referred to as green light. Light in the wavelength range of 605 nm to 665 nm (in particular, light having an emission center wavelength in the wavelength range) is referred to as red light. Ultraviolet light used in this specification refers to light in the wavelength range of 300 nm or more and less than 420 nm (in particular, light having an emission center wavelength in the wavelength range). In this specification, the term “full width at half maximum” refers to the wavelength width of a peak at ½ of the peak maximum.

As illustrated in FIG. 1, the liquid crystal panel 200A according to an embodiment includes a first polarizing layer a first substrate 2, an electrode layer 3, a first alignment layer 4, a liquid crystal layer 5, a second alignment layer 6, a second polarizing layer 7, a wavelength-selective transmission layer 8, a light conversion layer 9, and a second substrate 10, stacked in this order from the side close to the backlight unit 100A.

In other words, the first polarizing layer 1 is disposed on one surface of the first substrate 2, and the electrode layer 3 and the first alignment layer 4 covering the electrode layer 3 are disposed on the other surface. The second substrate 10 is disposed opposite the first substrate 2 with the liquid crystal layer 5 provided therebetween. The light conversion layer 9A (9), the wavelength-selective transmission layer 8A (8), the second polarizing layer 7, and the second alignment layer 6 are disposed in this order on a surface of the second substrate 10 adjacent to the first substrate 2 from the side close to the second substrate 10.

The first polarizing layer 1 and the second polarizing layer 7 are not particularly limited. Known polarizing plates (polarizing layers) can be used. Examples of the polarizing plates (polarizing layers) include dichroic organic dye polarizers, coating-type polarizing layers, wire grid-type polarizers, and cholesteric liquid crystal polarizers. For example, a wire grid-type polarizer is preferably formed by one of a nanoimprint method, a block copolymer method, an E beam lithography method, and a glancing angle deposition method. In the case where the polarizing layer is a coating-type polarizing layer, an alignment layer described below may further be disposed. That is, in an embodiment, both of the coating-type polarizing layer and the alignment layer are preferably disposed.

Each of the first substrate 2 and the second substrate 10 is a transparent insulating substrate that is composed of, for example, glass or a flexible material, such as a plastic material, and that is transparent and insulative.

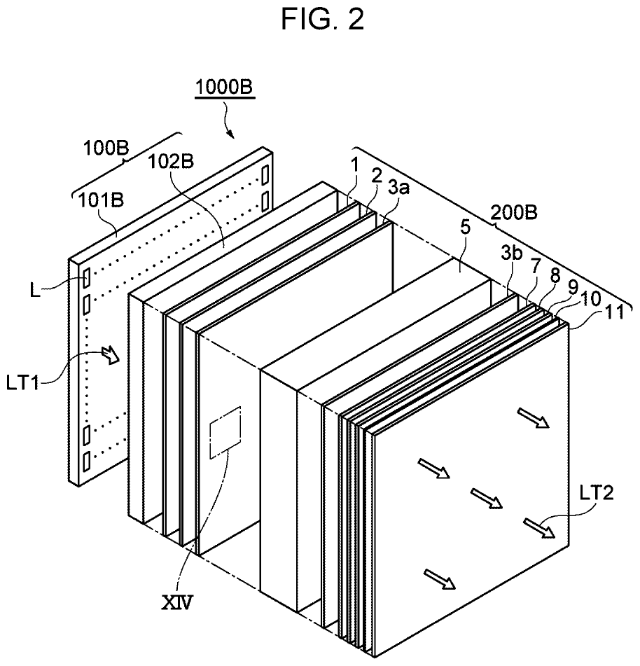

The electrode layer 3 is composed of a transparent material, such as ITO. The liquid crystal panel 200A illustrated in FIG. 1 has a structure in which a pixel electrode (not illustrated) and a common electrode (not illustrated) are disposed as the electrode layer 3 on the first substrate 2 side. In another embodiment, like a liquid crystal panel 200B illustrated in FIG. 2 described below, a pixel electrode (first electrode layer) 3a may be disposed on the first substrate 2, and a common electrode (second electrode layer) 3b may be disposed on the second substrate 10.

Because the first alignment layer 4 is disposed, liquid crystal molecules in the liquid crystal layer 5 can be aligned in a predetermined direction with respect to the substrates 2 and 7 when no voltage is applied. FIG. 1 illustrates a structure in which the liquid crystal layer 5 is held between the pair of the alignment layers 4 and 6. In another embodiment, an alignment layer may be disposed only on the side of the first substrate 2 or the second substrate 10. In another embodiment, no alignment layer may be disposed on the first substrate 2 or the second substrate 10. That is, a liquid crystal panel according to another embodiment may have a structure in which the first polarizing layer 1, the first substrate 2, the electrode layer 3, the liquid crystal layer 5, the second polarizing layer 7, the wavelength-selective transmission layer 8, the light conversion layer 9, and the second substrate 10 are stacked in this order from the side close to the backlight unit 100A.

In the liquid crystal display device 1000A illustrated in FIG. 1, light LT1 emitted from the light source section 101A (light-emitting devices L) passes through the light guide section 102A (for example, through a light guide plate or light diffusion plate) and enters the liquid crystal panel 200A. The light incident on the liquid crystal panel 200A is polarized in a specific direction by the first polarizing layer 1 and then incident on the liquid crystal layer 5. In the liquid crystal layer 5, the alignment direction of the liquid crystal molecules is controlled by driving the electrode layer 3. Thus, the liquid crystal layer 5 serves as an optical shutter. The light whose polarization direction has been changed by the liquid crystal layer 5 is blocked or polarized by the second polarizing layer 7 in a specific direction, passes through the wavelength-selective transmission layer 8, and then enters the light conversion layer 9. In the light conversion layer 9, the color of the incident light is converted (details will be described below). The converted light LT2 is emitted to the outside of the liquid crystal panel 200A.

The shape of the light guide section 102A (in particular, a light guide plate) is preferably a flat plate having side surfaces whose thickness decreases gradually from a side surface on which light emitted from the light-emitting devices L is incident to the opposite surface (a rectangular plate having tapered- or wedge-shaped side surfaces) because linear light can be converted into planar light and thus light is easily incident on the liquid crystal panel 200A.

FIG. 2 is a perspective view of a liquid crystal display device according to another embodiment. The same description as that of the liquid crystal display device illustrated in FIG. 1 is not redundantly repeated below. As illustrated in FIG. 2, in a liquid crystal display device 1000B according to another embodiment 1000B, a backlight unit 100B may have what is called a direct backlight structure in which multiple light-emitting devices L in a light source section 101B are arranged in a plane and substantially parallel to a flat-plate-shaped light guide section 102B. In the case of the direct backlight structure, unlike the embodiment illustrated in FIG. 1, light LT1 from the light-emitting devices L is planar light; thus, the shape of the light guide section 102B need not be a tapered shape.

As illustrated in FIG. 2, the first electrode layer (thin-film transistor layer or pixel electrode) 3a may be disposed on a surface of the first substrate 2 adjacent to the liquid crystal layer 5, and the second electrode layer (common electrode) 3b may be disposed on a surface of the second substrate 10 adjacent to the liquid crystal layer 5. A second wavelength-selective transmission layer 11 may be further disposed on the side of the liquid crystal layer 5 adjacent to the second substrate 10 in addition to the first wavelength-selective transmission layer 8. The second wavelength-selective transmission layer 11 may be disposed on the opposite side of the second substrate 10 from the liquid crystal layer 5.

Specifically, in the embodiment illustrated in FIG. 2, a liquid crystal panel 200B has a structure in which the first polarizing layer 1, the first substrate 2, the first electrode layer 3a, the liquid crystal layer 5, the second electrode layer 3b, the second polarizing layer 7, the first wavelength-selective transmission layer 8, the light conversion layer 9, the second substrate 10, and the second wavelength-selective transmission layer 11 are stacked in this order from the side close to the backlight unit 100B.

In another embodiment, the liquid crystal panel 200B illustrated in FIG. 2 may further include alignment layers. Specifically, the liquid crystal panel 200B according to a modified embodiment as illustrated in FIG. 2 may have a structure in which the first polarizing layer 1, the first substrate 2, the first electrode layer 3a, the alignment layer 4, the liquid crystal layer 5, the alignment layer 4, the second electrode layer 3b, the second polarizing layer 7, the first wavelength-selective transmission layer 8, the light conversion layer 9, the second substrate 10, and the second wavelength-selective transmission layer 11 are stacked in this order from the side close to the backlight unit 100B.

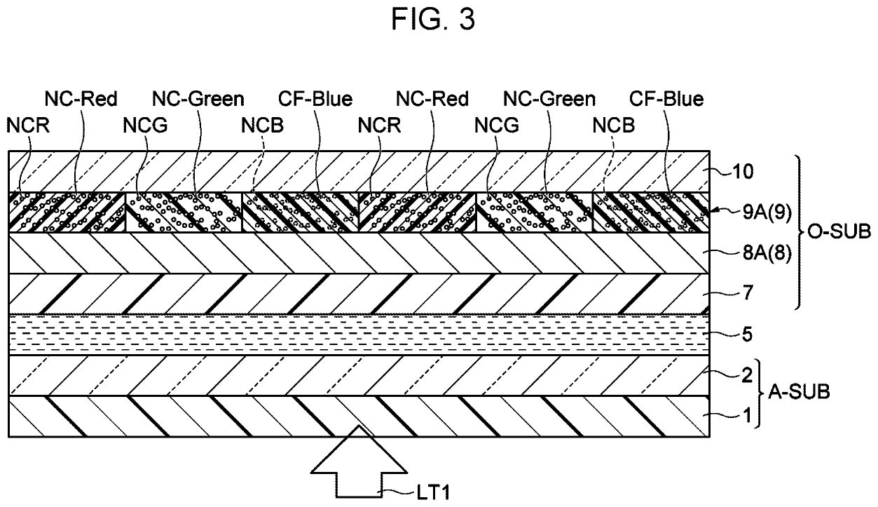

The structures of the polarizing layers 1 and 7, the liquid crystal layer 5, the light conversion layer 9, the wavelength-selective transmission layers 8 and 11, and so forth in the liquid crystal panel as illustrated in FIG. 1 or 2 will be described in more detail below. FIG. 3 is a cross-sectional view illustrating the structure of a liquid crystal panel according to an embodiment. In FIG. 3, in order to clearly explain the positional relationships among the polarizing layers, the liquid crystal layer, the light conversion layer, the wavelength-selective transmission layers, and so forth, the electrode layers 3, 3a, and 3b and the alignment layers 4 and 6 are omitted (these layers may be omitted in the same manner in the drawings subsequent to FIG. 3).

As illustrated in FIG. 3, in the liquid crystal panel illustrated in FIG. 1, as described above, the first polarizing layer 1, the first substrate 2, the liquid crystal layer 5, the second polarizing layer 7, the wavelength-selective transmission layer 8A (8), the light conversion layer 9A (9), and the second substrate 10 are stacked in this order from the side close to the backlight unit 100A (the side on which incident light is incident). A stack including the substrate (first substrate 2) located on the side of the liquid crystal layer 5 adjacent to the backlight unit (on which light LT1 is incident), and the layers stacked on the substrate is referred to as an “array substrate (A-SUB)”. A stack including the substrate (second substrate 10) opposite to the backlight unit (the side opposite to the side on which light LT1 is incident) and layers stacked on the substrate is referred to as an “opposite substrate (O-SUB)” (the same applies hereinafter).

In the embodiment illustrated in FIG. 3, the light conversion layer 9A (9) and the wavelength-selective transmission layer 8A (8) are disposed in the opposite substrate (O-SUB). This embodiment provides what is called an in-cell structure in which the light conversion layer 9A (9) and the second polarizing layer 7 are disposed between a pair of substrates (first substrate 2 and the second substrate 10).

In the case where the embodiment illustrated in FIG. 3 is used to a VA-mode liquid crystal display device, it is preferable that the first electrode layer (pixel electrode) be disposed on the first substrate 2 and that, on the opposite substrate O-SUB side, the second electrode layer (common electrode) be disposed between the liquid crystal layer 5 and the second polarizing layer 7 or between the second polarizing layer 7 and the light conversion layer 9A (9). An alignment layer is preferably disposed on a surface of at least one of the opposite substrate (O-SUB) and the array substrate (A-SUB) in contact with the liquid crystal layer 5. In FIG. 3, in the case where the liquid crystal display device is of an FFS-mode or IPS-mode, the pixel electrode and the common electrode are preferably disposed on the first substrate 2.

In a typical liquid crystal display device, each color is displayed by selecting incident light emitted from a white light source in accordance with wavelength with a color filter and partially absorbing the light. One of the features of this embodiment is that the light conversion film including the light conversion layer 9A (9) containing light-emitting nanocrystalline particles and the wavelength-selective transmission layer 8A (8) is used as an alternative to the color filter. Specifically, the light conversion film includes pixels of three primary colors of red (R), green (G), and blue (B) and thus plays the same role as the color filter.

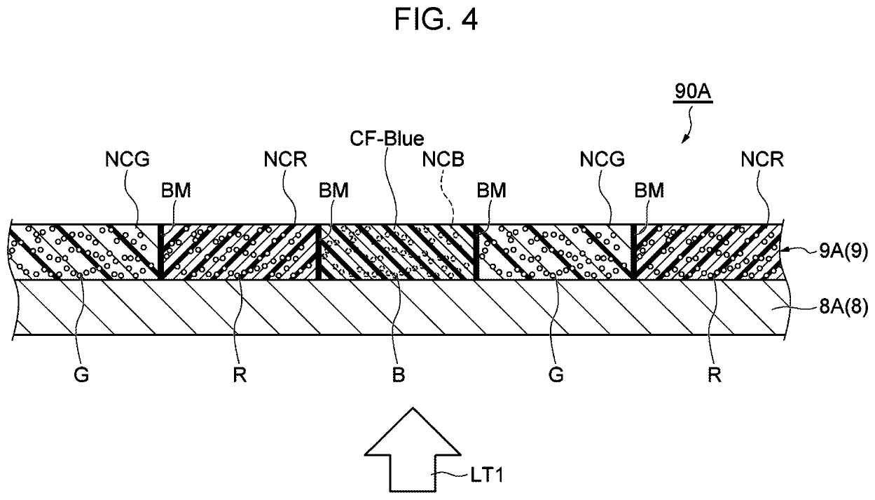

FIG. 4 is a cross-sectional view of a light conversion film according to an embodiment. The light conversion film corresponds to the light conversion film used in the liquid crystal panel illustrated in FIG. 3. As illustrated in FIGS. 3 and 4, a light conversion film 90A according to an embodiment includes the light conversion layer 9A (9) and the wavelength-selective transmission layer 8A (8) disposed on one side of the light conversion layer 9A (9).

The light conversion layer 9A (9) includes red pixel portions (R: also referred to as “red color layer portions”), green pixel portions (G: also referred to as “green color layer portions”), and blue pixel portions (B: also referred to as “blue color layer portions”). In the light conversion layer 9A (9), as illustrated in FIG. 3, the three color pixel portions (R, G, and B) may be in contact with each other. Alternatively, as illustrated in FIG. 4, in order to prevent color mixing between the color pixel portions of the colors, a black matrix (BM) that separates the three color pixel portions (R, G, and B) from one another may be disposed. In this embodiment, the wavelength-selective transmission layer 8A (8) is disposed (stacked) on one surface of the light conversion layer 9A (9). As illustrated in FIGS. 3 and 4, the light conversion film 90A is used in such a manner that light LT1 is incident from the wavelength-selective transmission layer 8A (8) side.

Each of the red pixel portions (R) is formed of, for example, a light conversion pixel layer (NC-Red) containing red light-emitting nanocrystalline particles (NCR) configured to absorb incident light and emit red light. Each of the green pixel portions (G) is formed of, for example, a light conversion pixel layer (NC-Green) containing green light-emitting nanocrystalline particles (NCG) configured to absorb incident light and emit green light. Each of the blue pixel portions (B) is formed of, for example, a light conversion pixel layer (NC-Blue) containing blue light-emitting nanocrystalline particles (NCB) configured to absorb incident light and emit blue light.

Incident light LT1 may be, for example, light (blue light) that is emitted from a blue LED or the like and that has a main peak at about 450 nm. In this case, blue light emitted from the blue LED can be used as blue light emitted from the light conversion layer. Thus, when incident light is blue light, the blue pixel portions (B) among three-color pixel portions (R, G, and B) may be light-transmitting layers that transmit blue light in such a manner that blue incident light can be used as it is, instead of the light conversion pixel layers containing the blue light-emitting nanocrystalline particles (NCB). In this case, each of the blue pixel portions (B) can be formed of, for example, a colorant layer (what is called a blue color filter) (CF-Blue) containing a transparent resin and a blue colorant. The blue light-emitting nanocrystalline particles (NCB) can be an optional component; thus, in FIGS. 3 and 4 and the subsequent drawings, the blue light-emitting nanocrystalline particles (NCB) are indicated by broken lines.

The wavelength-selective transmission layer 8A (8) is a layer that selectively transmits light in one or more predetermined wavelength ranges in accordance with the wavelength of incident light LT1 and the wavelength of light converted by the light conversion layer 9A (9). Preferably, the wavelength-selective transmission layer 8A (8) transmits light in a first wavelength range (for example, WL¹ nm to WL² nm) and reflects light in a second wavelength range (WL³ nm to WL⁴ nm) different from the first wavelength range. Of light converted by the light conversion layer 9A (9) and light incident on the light conversion layer 9A (9), light in the first wavelength range is transmitted, and light in the second wavelength range other than the first wavelength range is reflected, thereby improving the color purity. In other words, because the wavelength-selective transmission layer 8A (8) reflects light in a specific wavelength range (second wavelength range), it can also be called a wavelength-selective reflection layer (selective reflection layer).

The wavelength-selective transmission layer 8A (8) may have, in the visible light range (for example, 380 nm to 780 nm), two or more wavelength ranges (first wavelength ranges) of light to be transmitted therethrough and two or more wavelength ranges (second wavelength ranges) of light to be reflected therefrom. This can improve the color purities of two or more colors even if the wavelength-selective transmission layer 8A (8) is a single layer.

The wavelength-selective transmission layer 8A (8) preferably has at least one feature selected from the transmission of light in one or more wavelength ranges other than the blue wavelength range, the transmission of light in one or more wavelength ranges other than the green wavelength range, and the transmission of light in one or more wavelength ranges other than the red wavelength range.

The wavelength-selective transmission layer 8A (8) preferably has at least one feature selected from the reflection of light in the blue wavelength range, the reflection of light in the green wavelength range, and the reflection of light in the red wavelength range.

The wavelength-selective transmission layer 8A (8) preferably has at least one feature selected from the transmission of light in one or more wavelength ranges other than the blue wavelength range and the reflection of light in the blue wavelength range, the transmission of light in one or more wavelength ranges other than the green wavelength range and the reflection of light in the green wavelength range, and the transmission of light in one or more wavelength ranges other than the red wavelength range and the reflection of light in the red wavelength range.

In this specification, “a layer transmits light (in one or more specific wavelength ranges)” indicates that the layer has a transmittance of 70% or more for the light (in the one or more specific wavelength ranges) in a direction perpendicular thereto, and “a layer reflects light (in one or more specific wavelength ranges)” indicates that the layer has a reflectance of 10% or more for the light (in the one or more specific wavelength ranges) in the direction perpendicular thereto.

The wavelength-selective transmission layer 8A (8) preferably has transmission characteristics in which incident light LT1 is transmitted therethrough and light in the wavelength range of light emitted from the light conversion layer 9A (9), i.e., light in a wavelength range of at least one of blue, green, and red, is selectively reflected therefrom. Here, luminescence from the light conversion layer 9A (9) is attributed to the light-emitting nanocrystalline particles that have absorbed incident light LT1, and exhibits an emission mode, such as a spherical wave (isotropic particles, such as quantum dots) or a dipolar wave (anisotropic particles, such as quantum rods) in accordance with the shape of the light-emitting nanocrystalline particles. In the case where the wavelength-selective transmission layer 8A (8) that transmits incident light LT1 and reflects light emitted from the light conversion layer 9A (9) is disposed adjacent to the light conversion layer 9A (9), light in a necessary wavelength range (light to be emitted to the outside) can be emitted in one direction. Thus, in the embodiment illustrated in FIG. 3, because incident light LT1 can suitably enter the light conversion layer 9A (9) and because light emitted from the light conversion layer 9A (9) toward the liquid crystal layer 5 is reflected from the wavelength-selective transmission layer 8A (8), light emitted from the light conversion layer 9A (9) toward the second substrate 10 and the light reflected from the wavelength-selective transmission layer 8A (8) are combined and displayed (visually recognized), thus improving the luminous efficiency and the color purity.

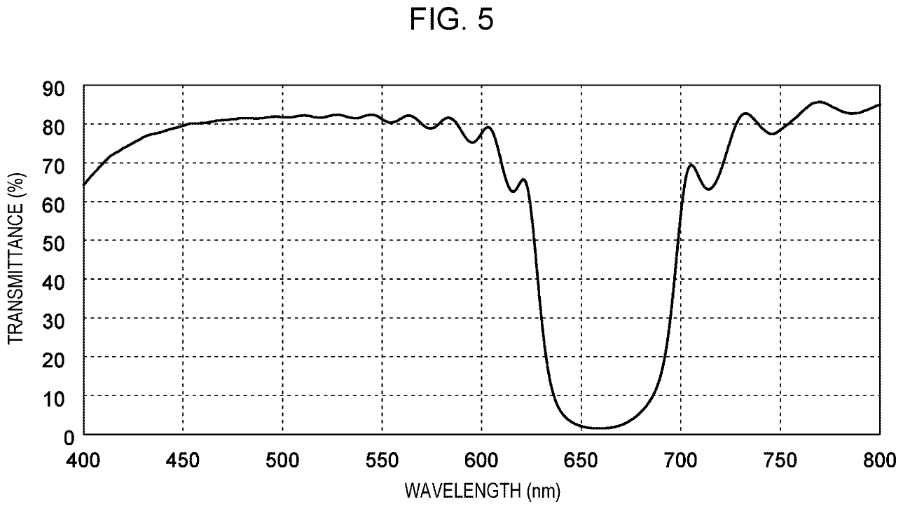

FIG. 5 is a graph illustrating an example of the transmission characteristics (the dependence of transmittance on wavelength) of a wavelength-selective transmission layer. For example, in the case where the wavelength-selective transmission layer 8A (8) has transmission characteristics as illustrated in FIG. 5, the wavelength-selective transmission layer 8A (8) selectively reflects only the red wavelength range of about 620 nm to 700 nm (in other words, it transmits light in the blue wavelength range and the green wavelength range); thus, light in the red wavelength range converted by the light conversion layer 9A (9) seems to be amplified by the reflection from the wavelength-selective transmission layer 8A (8) to improve the color purity of light in the red wavelength range.

A particularly preferred embodiment is as follows: Incident light is light (blue light) that is emitted from a blue LED or the like and that has a main peak at about 450 nm. Each red pixel portion (R) contains the red light-emitting nanocrystalline particles (NCR) configured to absorb the incident light (blue light) and emit red light. Each green pixel portion (G) contains the green light-emitting nanocrystalline particles (NCG) configured to absorb the incident light (blue light) and emit green light. Each blue pixel portion (B) is a blue light-transmitting layer configured to transmit the incident light (blue light). The wavelength-selective transmission layer 8A (8) transmits light in the blue wavelength range (the wavelength range other than the red wavelength range or the green wavelength range) and reflects light in the red wavelength range and the green wavelength range (however, the present invention is not limited to this embodiment).

In this case, incident light passes suitably through the wavelength-selective transmission layer 8A (8), enters the light conversion layer 9A (9), and is absorbed by the light-emitting nanocrystalline particles. In the red pixel portions (R), the absorbed light is converted into light in the red wavelength range. In the green pixel portions (G), the absorbed light is converted into light in the green wavelength range. In the blue pixel portions (B), the incident light is transmitted therethrough as it is. Of the light emitted from the red pixel portions (R) and the light emitted from the green pixel portions (G) of the light conversion layer 9A (9), a light component emitted toward the liquid crystal layer 5 is reflected from the wavelength-selective transmission layer 8A (8) (other light components are absorbed or transmitted), combined with a light component emitted from the light conversion layer 9A (9) toward the second substrate 10, and displayed. As described above, the use of the combination of the light conversion layer 9A (9) and the wavelength-selective transmission layer 8A (8) can achieve both of high luminous efficiency and high color purity.

A liquid crystal panel according to other embodiments may be used. While other embodiments will be described below, the same description as that of the embodiment described above is not redundantly repeated.

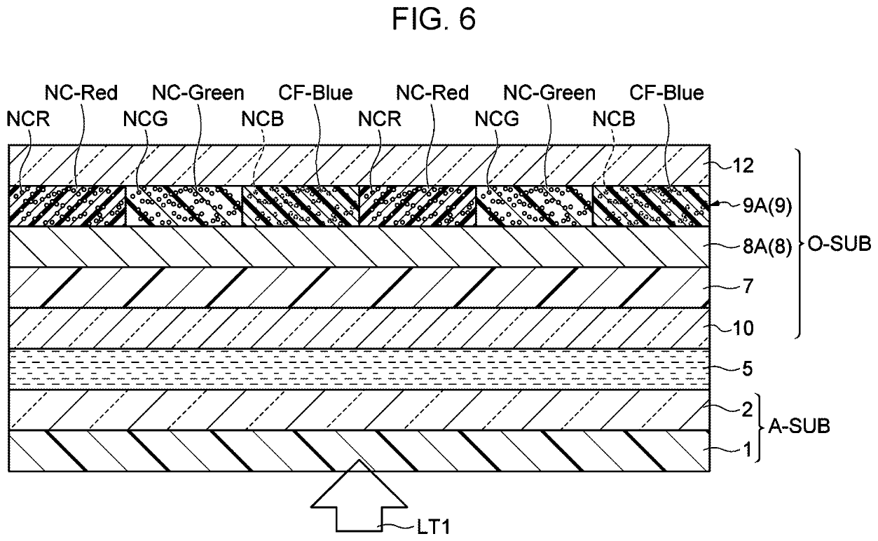

FIG. 6 is a cross-sectional view illustrating the structure of a liquid crystal panel according to another embodiment. As illustrated in FIG. 6, in this embodiment, the light conversion layer 9A (9) and the wavelength-selective transmission layer 8A (8) are disposed in the opposite substrate (O-SUB), and the light conversion layer 9A (9) is disposed outside the pair of the substrates (the first substrate 2 and the second substrate 10. Also in this embodiment, the light conversion film illustrated in FIG. 4 may be used. This embodiment further includes a supporting substrate 12 that supports the second polarizing layer 7, the light conversion layer 9A (9), and the wavelength-selective transmission layer 8A (8). The supporting substrate 12 is preferably a transparent substrate.

Specifically, in the liquid crystal panel according to this embodiment, the first polarizing layer 1, the first substrate 2, the liquid crystal layer 5, the second substrate 10, the second polarizing layer 7, the wavelength-selective transmission layer 8A (8), the light conversion layer 9A (9), and the supporting substrate 12 are stacked in this order from the side close to the backlight unit (the side on which incident light LT1 is incident).

In the case where the embodiment illustrated in FIG. 6 is used to a VA-mode liquid crystal display device, it is preferable that the first electrode layer (pixel electrode) be disposed on the first substrate 2 and that, on the opposite substrate (O-SUB), the second electrode layer (common electrode) be disposed between the liquid crystal layer 5 and the second polarizing layer 7. An alignment layer is preferably disposed on a surface of at least one of the opposite substrate (O-SUB) and the array substrate (A-SUB) in contact with the liquid crystal layer 5. In FIG. 6, in the case where the liquid crystal display device is of an FFS-mode or IPS-mode, the pixel electrode and the common electrode are preferably disposed on the first substrate 2.

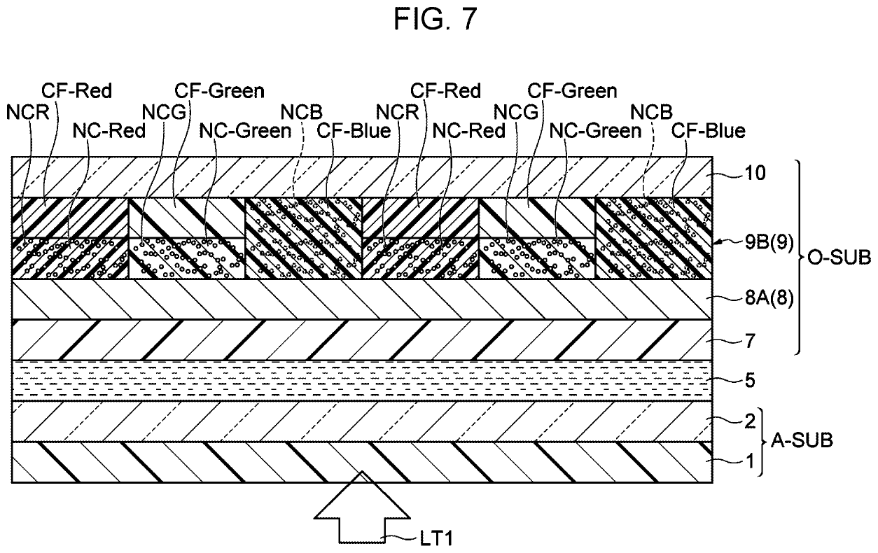

FIG. 7 is a cross-sectional view illustrating the structure of a liquid crystal panel according to another embodiment. While this embodiment illustrated in FIG. 7 provides an in-cell structure similar to the embodiment illustrated in FIG. 3, the structure of a light conversion layer 9B (9) differs from that of the embodiment illustrated in FIG. 3.

Specifically, in the light conversion layer 9B (9), each of the red pixel portions (R) has a two-layer structure in which a light conversion pixel layer (NC-Red) containing red light-emitting nanocrystalline particles (NCR) and a colorant layer containing a red colorant (what is called a red color filter) (CF-Red) are stacked in this order from the side close to the backlight unit (the side on which incident light LT1 is incident). Each of the green pixel portions (G) has a two-layer structure in which a light conversion pixel layer (NC-Green) containing green light-emitting nanocrystalline particles (NCG) that emit green light and a colorant layer containing a green colorant (what is called a green color filter) (CF-Green) are stacked in this order from the side close to the backlight unit (the side on which incident light LT1 is incident).

In this case, in the red pixel portions (R) and the green pixel portions (G), even if incident light (preferably, blue light) is not entirely converted by the light conversion pixel layer containing the light-emitting nanocrystalline particles, each red color filter (CF-Red) and each green color filter (CF-Green) do not transmit but absorb incident light, thus further improving the color purities of red and green.

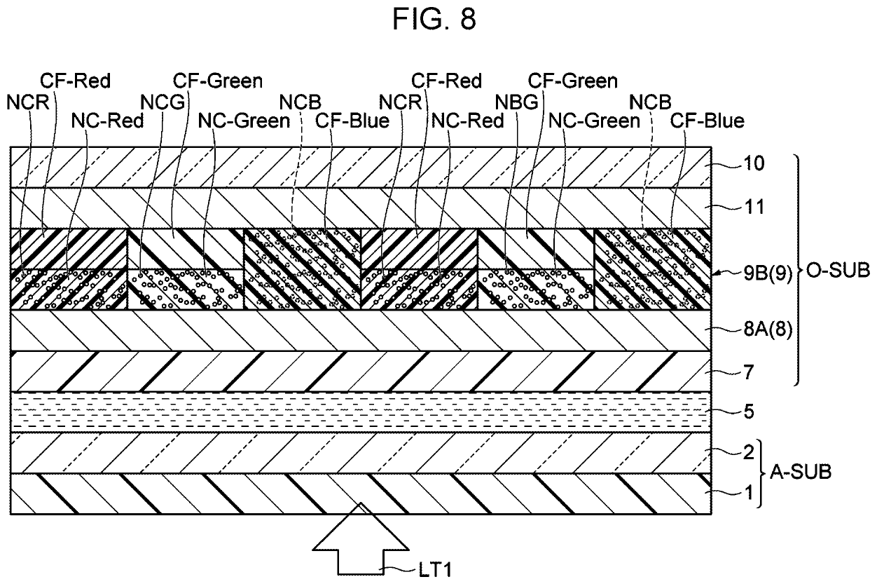

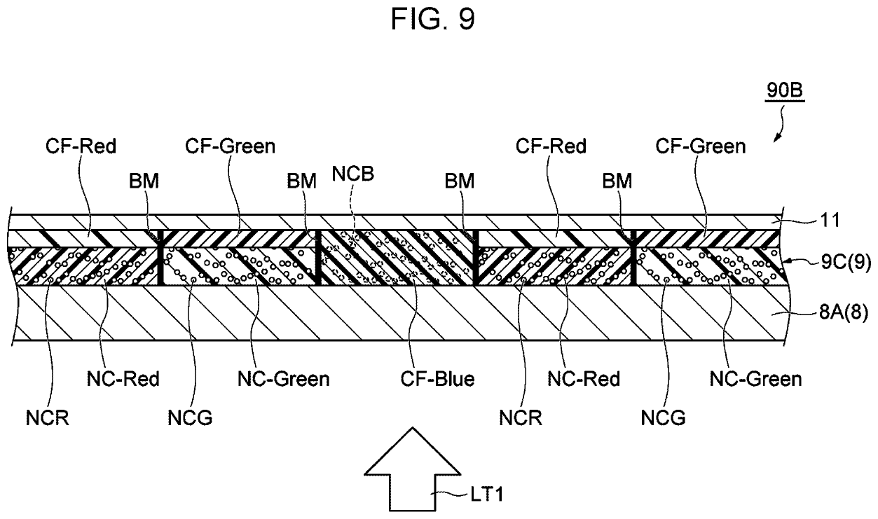

FIG. 8 is a cross-sectional view illustrating the structure of a liquid crystal panel according to another embodiment. FIG. 9 is a cross-sectional view of a light conversion film according to another embodiment. The light conversion film is suitably used for the liquid crystal panel illustrated in FIG. 8. While this embodiment illustrated in FIG. 8 provides an in-cell structure similar to the embodiment illustrated in FIG. 7, the structure of a wavelength-selective transmission layer differs from that of the embodiment illustrated in FIG. 7.

Specifically, in this embodiment, the first wavelength-selective transmission layer 8A (8) is disposed on a side of the light conversion layer 9A (9) adjacent to the backlight unit (the side on which incident light LT1 is incident), and the second wavelength-selective transmission layer 11 is disposed on the opposite side of the light conversion layer 9A (9) from the backlight unit (a side opposite to the side incident light LT1 is incident). Specifically, in the liquid crystal panel according to this embodiment, the first polarizing layer 1, the first substrate 2, the liquid crystal layer 5, the second polarizing layer 7, the first wavelength-selective transmission layer 8A (8), the light conversion layer 9A (9), the second wavelength-selective transmission layer 11, and the second substrate 10 are stacked in this order from the side close to the backlight unit (the side on which incident light LT1 is incident).

Similarly, a light conversion film 90B illustrated in FIG. 9 includes the wavelength-selective transmission layer 8A (8), the light conversion layer 9A (9), and the second wavelength-selective transmission layer 11 in this order. In other words, the light conversion film includes the light conversion layer 9A (9), the wavelength-selective transmission layer 8A (8), and the second wavelength-selective transmission layer 11 that are disposed on the respective sides of the light conversion layer 9A (9).

The second wavelength-selective transmission layer 11 may be, for example, a colorant layer containing a yellow colorant (what is called a yellow color filter) (CF-Yellow), the colorant layer being configured to absorb light in the blue wavelength range and transmit light in one or more wavelength ranges other than the blue wavelength range. The second wavelength-selective transmission layer 11 may be, for example, a second wavelength-selective transmission layer that partially reflects and partially transmits light in the blue wavelength range. By disposing the second wavelength-selective transmission layer 11 as described above, when incident light is blue light, it is possible to suppress the degradation of image quality due to the intrusion of unnecessary light (in particular, blue light) from the outside. Additionally, even when light emitted from the blue pixel portions (B) has a higher intensity than light emitted from the red pixel portions (R) and the green pixel portions (G), the color tone can be suitably adjusted.

In a light conversion layer 9C (9) of the light conversion film 90B, the red pixel portions and the green pixel portions are separated from each other by a black matrix (BM). Each of the red pixel portions has a two-layer structure in which a light conversion pixel layer (NC-Red) containing red light-emitting nanocrystalline particles (NCR) and a colorant layer containing a red colorant (red color filter) (CF-Red) are stacked in this order from the side close to the backlight unit (the side on which incident light LT1 is incident). Each of the green pixel portions has a two-layer structure in which a light conversion pixel layer (NC-Green) containing green light-emitting nanocrystalline particles (NCG) that emit green light and a colorant layer containing a green colorant (green color filter) (CF-Green) are stacked in this order from the side close to the backlight unit (the side on which incident light LT1 is incident). Each of the blue pixel portions is formed of a colorant layer containing a blue colorant (blue color filter) (CF-Blue).

In this case, in the red pixel portions and the green pixel portions, even if incident light (preferably, blue light) is not entirely converted by the light conversion pixel layer containing the light-emitting nanocrystalline particles, each red color filter (CF-Red) and each green color filter (CF-Green) do not transmit but absorb incident light, thus further improving the color purities of red and green.

In the case where the embodiment illustrated in FIG. 8 is used to a VA-mode liquid crystal display device, it is preferable that the first electrode layer (pixel electrode) be disposed on the first substrate 2 and that, on the opposite substrate (O-SUB), the second electrode layer (common electrode) be disposed between the liquid crystal layer 5 and the second polarizing layer 7. An alignment layer is preferably disposed on a surface of at least one of the opposite substrate (O-SUB) and the array substrate (A-SUB) in contact with the liquid crystal layer 5. In FIG. 8, in the case where the liquid crystal display device is of an FFS-mode or IPS-mode, the pixel electrode and the common electrode are preferably disposed on the first substrate 2.

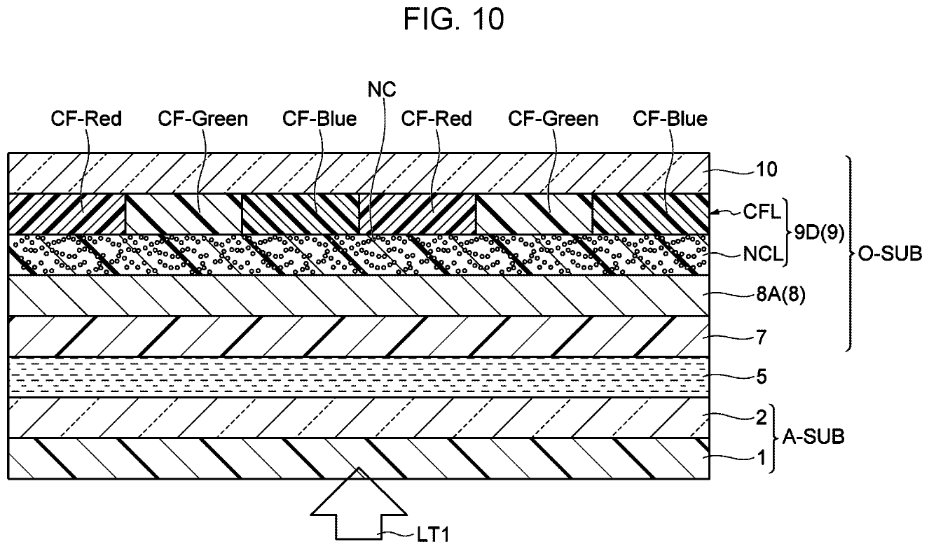

FIG. 10 is a cross-sectional view illustrating the structure of a liquid crystal panel according to another embodiment. While this embodiment illustrated in FIG. 10 provides an in-cell structure similar to the embodiments illustrated in FIGS. 3 and 7, the structure of a light conversion layer 9D (9) differs from that of the embodiment illustrated in FIG. 3 or 7.

Specifically, the light conversion layer 9A (9) has a structure in which a light-emitting layer (NCL) disposed all over the color pixel portions (R, G, and B) and a colorant layer (what is called a color filter) (CFL) including portions corresponding to the respective color pixel portions (R, G, and B) are stacked in this order from the side close to the backlight unit (the side on which incident light LT1 is incident).

The light-emitting layer (NCL) contains at least light-emitting nanocrystalline particles (NC) containing red light-emitting nanocrystalline particles and green light-emitting nanocrystalline particles. The light-emitting nanocrystalline particles (NC) may further contain blue light-emitting nanocrystalline particles, as needed.

The colorant layer (CFL) includes red color layer portions (red color filters, which do not contain light-emitting nanocrystalline particles) (CF-Red) located at positions corresponding to the respective red pixel portions (R); green color layer portions (green color filters) (CF-Green, which do not contain light-emitting nanocrystalline particles) located at positions corresponding to the respective green pixel portions (G); and blue color layer portions (blue color filters, which do not contain light-emitting nanocrystalline particles) (CF-Blue) located at positions corresponding to the respective blue pixel portions (B). Each of the green color layer portions may be a colorant layer containing a yellow colorant (yellow color filter) (CF-Yellow) in order to perform color correction in view of the transmission of excitation light. The red color layer portions (CF-Red), the green color layer portions (CF-Green), and the blue color layer portions (CF-Blue) may be in contact with each other as illustrated in FIG. 10. To prevent color mixing, a black matrix may be disposed as a light-shielding layer between the color layer portions of the colors.

In the case where the embodiment illustrated in FIG. 10 is used to a VA-mode liquid crystal display device, it is preferable that the first electrode layer (pixel electrode) be disposed on the first substrate 2 and that, on the opposite substrate (O-SUB), the second electrode layer (common electrode) be disposed between the liquid crystal layer 5 and the second polarizing layer 7. In FIG. 10, in the case where the liquid crystal display device is of an FFS-mode or IPS-mode, the pixel electrode and the common electrode are preferably disposed on the first substrate 2. In the VA-mode, FFS-mode, or IPS-mode liquid crystal display device, an alignment layer is preferably disposed on a surface of at least one of the opposite substrate (O-SUB) and the array substrate (A-SUB) in contact with the liquid crystal layer 5.

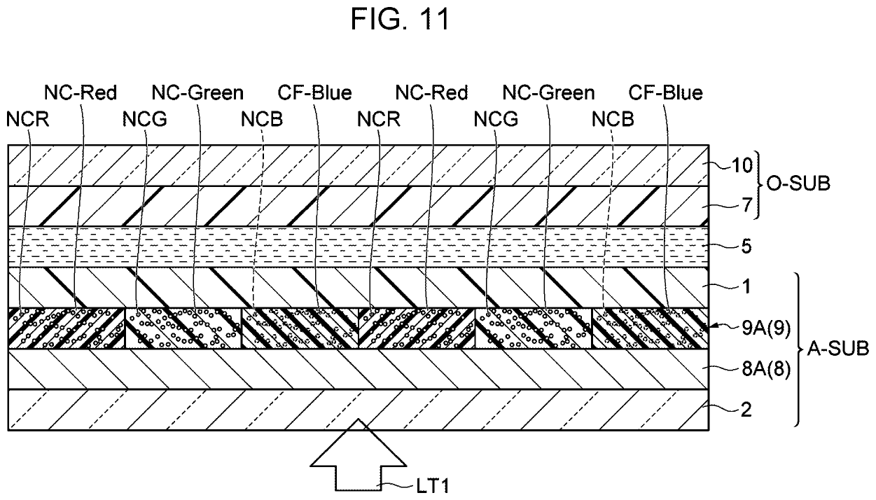

FIG. 11 is a cross-sectional view illustrating the structure of a liquid crystal panel according to another embodiment. As illustrated in FIG. 11, unlike the embodiments described above, the wavelength-selective transmission layer 8A (8) and the light conversion layer 9A (9) may be disposed in the array substrate (A-SUB). This embodiment provides what is called an in-cell structure in which the light conversion layer 9A (9), the first polarizing layer 1, and the second polarizing layer 7 are disposed between the pair of the substrates (first substrate 2 and the second substrate 10).

Specifically, in the liquid crystal panel according to this embodiment, the first substrate 2, the wavelength-selective transmission layer 8A (8), the light conversion layer 9A (9), the first polarizing layer 1, the liquid crystal layer 5, the second polarizing layer 7, and the second substrate 10 are stacked in this order from the side close to the backlight unit (the side on which incident light LT1 is incident).

In each of the embodiments described above, the second polarizing layer 7 and the second substrate 10 may be interchanged with each other, and an electrode layer including a TFT (TFT electrode layer) may be disposed between the liquid crystal layer 5 and the first polarizing layer 1 or between the liquid crystal layer 5 and the second polarizing layer 7.

That is, in a liquid crystal panel according to a modified embodiment, the TFT electrode layer, the liquid crystal layer 5, the second substrate 10, and the second polarizing layer 7 may be stacked in this order from the side close to the backlight unit (the side on which incident light LT1 is incident). To give a more specific example, in a liquid crystal panel according to a modification of the embodiment illustrated in FIG. 11, the first substrate 2, the wavelength-selective transmission layer 8A (8), the light conversion layer 9A (9), the first polarizing layer 1, the TFT electrode layer, the liquid crystal layer 5, the liquid crystal layer 5, the second substrate 10, and the second polarizing layer 7 may be stacked in this order from the side close to the backlight unit (the side on which incident light LT1 is incident).

In a liquid crystal panel according to another modification, the liquid crystal layer 5, the TFT electrode layer, the second polarizing layer 7, and the second substrate 10 may be stacked in this order from the side close to the backlight unit (the side on which incident light LT1 is incident). To give a more specific example, in a liquid crystal panel according to another modification of the embodiment illustrated in FIG. 11, the first substrate 2, the wavelength-selective transmission layer 8A (8), the light conversion layer 9A (9), the first polarizing layer 1, the liquid crystal layer 5, the TFT electrode layer, the second polarizing layer 7, and the second substrate 10 may be stacked in this order from the side close to the backlight unit (the side on which incident light LT1 is incident).

In a liquid crystal panel according to another modification, the liquid crystal layer 5, the TFT electrode layer, the second substrate 10, and the second polarizing layer 7 may be stacked in this order from the side close to the backlight unit (the side on which incident light LT1 is incident). To give a more specific example, in a liquid crystal panel according to another modification of the embodiment illustrated in FIG. 11, the first substrate 2, the wavelength-selective transmission layer 8A (8), the light conversion layer 9A (9), the first polarizing layer 1, the liquid crystal layer 5, the TFT electrode layer, the second substrate 10, and the second polarizing layer 7 may be stacked in this order from the side close to the backlight unit (the side on which incident light LT1 is incident).

In each of the embodiments described in detail above, light (incident light) emitted from a high-energy light source, such as short-wavelength visible light or ultraviolet light, passes through the liquid crystal layer 5 serving as an optical switch and the polarizing layers 1 and 7 and is absorbed by the light-emitting nanocrystalline particles contained in the light conversion layer 9. The absorbed light is converted by the light-emitting nanocrystalline particles into light having a specific wavelength and emitted to display colors.

Among these embodiments, the structure according to the embodiment in which the light conversion layer 9 is disposed in the opposite substrate (O-SUB) is particularly preferred because of its significant effect of suppressing or preventing the deterioration of the liquid crystal layer 5 due to the irradiation of a high-energy light beam.

Among these embodiments described above, in the structure according to the embodiment in which the wavelength-selective transmission layer 8 is disposed only on a side of the light conversion layer 9 adjacent to the backlight unit (the side on which incident light LT1 is incident), similarly to the embodiment illustrated in FIG. 8, the wavelength-selective transmission layer (second wavelength-selective transmission layer 11) may be further disposed on the opposite side of the light conversion layer 9 from the backlight unit (the side opposite to the side on which incident light LT1 is incident) in accordance with the type of light source used (a blue LED as a light-emitting device) and the intensity of light. The wavelength-selective transmission layer (second wavelength-selective transmission layer 11) may be further disposed between the light conversion layer) and the wavelength-selective transmission layer 8. Also in these cases, similarly to the embodiment illustrated in FIG. 8, it is possible to suppress the degradation of image quality due to the intrusion of unnecessary light (in particular, blue light) from the outside.

In these embodiments, the first wavelength-selective transmission layer 8 and the second wavelength-selective transmission layer 11 may be the same or different. A preferred embodiment is as follows: The wavelength-selective transmission layer 8 transmits light incident on the light conversion layer 9 and reflects red light emitted from the light conversion pixel layers (NC-Red) containing the red light-emitting nanocrystalline particles (NCR) and/or green light emitted from the light conversion pixel layers (NC-Green) containing the green light-emitting nanocrystalline particles (NCG). The second wavelength-selective transmission layer 11 transmits red light emitted from the light conversion pixel layers (NC-Red) containing the red light-emitting nanocrystalline particles (NCR) and/or green light emitted from the light conversion pixel layers (NC-Green) containing the green light-emitting nanocrystalline particles (NCG) and reflects or absorbs light of another color (in particular, incident light (blue light)). In this embodiment, it is possible to further improve the color purities of red and green.

In each of the embodiments described above, the light conversion layer 9 may contain at least one selected from the group consisting of the blue light-emitting nanocrystalline particles NCB, the green light-emitting nanocrystalline particles NCG, and the red light-emitting nanocrystalline particles NCR. The light conversion layer 9 preferably contains at least two selected from the group consisting of the blue light-emitting nanocrystalline particles NCB, the green light-emitting nanocrystalline particles NCG, and the red light-emitting nanocrystalline particles NCR, including the embodiments described above.

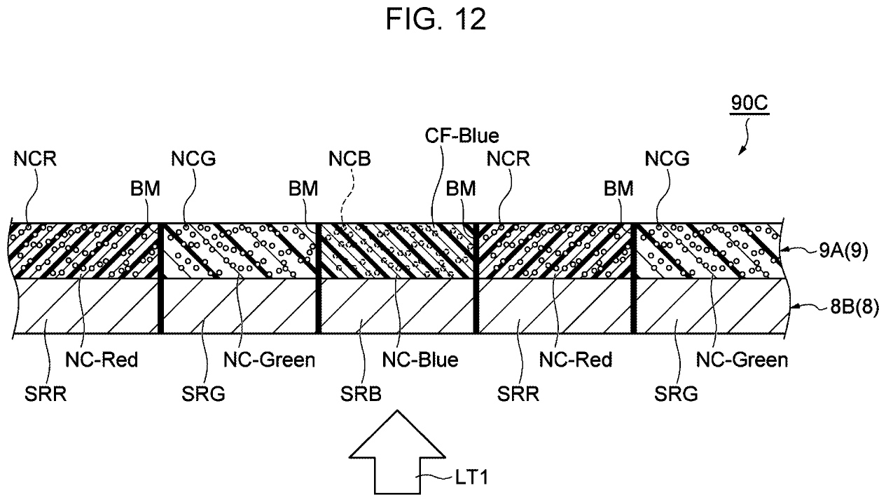

The wavelength-selective transmission layer 8 according to each of the embodiments described above is separated into portions corresponding to the respective color pixel portions (R, G, and B) in an embodiment. FIG. 12 is a perspective view of a light conversion film according to another embodiment. A light conversion film 90C is used in an embodiment in which a wavelength-selective transmission layer 8B (8) is separated into portions corresponding to the respective color pixel portions (R, G, and B).

The light conversion film 90C includes the light conversion layer 9A (9) and the wavelength-selective transmission layer 8B (8) similarly to that in the embodiment described above. However, the structure of the wavelength-selective transmission layer 8B (8) differs from those in the embodiments described above. Specifically, the wavelength-selective transmission layer 8B (8) includes wavelength-selective transmission portions SRR disposed at positions corresponding to the respective red pixel portions (R), the wavelength-selective transmission portions SRR being configured to selectively reflect light in the red wavelength range and transmit light in the other wavelength range; wavelength-selective transmission portions SRG disposed at positions corresponding to the respective green pixel portions (G), the wavelength-selective transmission portions SRG being configured to selectively reflect light in the green wavelength range and transmit light in the other wavelength range; and wavelength-selective transmission portions SRB disposed at positions corresponding to the respective blue pixel portions (B), the wavelength-selective transmission portions SRB being configured to selectively reflect light in the blue wavelength range and transmit light in the other wavelength range.

In this embodiment, in the case where incident light LT1, such as green light from a blue LED, passing through the wavelength-selective transmission layer 8B (8) is absorbed by the light conversion pixel layers (NC-Red) containing the red light-emitting nanocrystalline particles (NCR) and where red light is then emitted, an emission wave in accordance with the shape of the red light-emitting nanocrystalline particles is emitted. The red light emitted in the direction of the incoming light is reflected from the wavelength-selective transmission portions SRR configured to selectively reflect light in the red wavelength range, thus improving the intensity of red light propagating toward the light conversion layer 9A (9). Similarly, light incident on the green pixel portions (G) is also reflected from the wavelength-selective transmission portions SRG configured to selectively reflect light in the green wavelength range, thus improving the intensity of green light propagating toward the light conversion layer 9A (9).

In the embodiment illustrated in FIG. 12, the wavelength-selective transmission portions SRB configured to selectively reflect light in the blue wavelength range and transmit light in the other wavelength range are disposed in the blue pixel portions (B). However, the wavelength-selective transmission portions SRB need not be disposed in accordance with the type and intensity of incident light. For example, in the case where incident light (blue light) has a high emission intensity, the second wavelength-selective transmission layer 11 configured to selectively transmit light in the red wavelength range and/or the green wavelength range (absorb blue light) may be disposed on the opposite side of the light conversion layer 9A (9) from the wavelength-selective transmission layer 8B (8) (opposite to the backlight unit), as the embodiment illustrated in FIG. 9.

In each of the embodiments described above (light conversion film), the light conversion layer 9 and the wavelength-selective transmission layer 8 are stacked so as to be in direct contact with each other. In another embodiment, however, the light conversion layer 9 and the wavelength-selective transmission layer 8 may be stacked with another layer provided therebetween. The another layer may be, for example, an adhesive layer.

In each of the embodiments described above (light conversion film), the wavelength-selective transmission layer 8 is entirely disposed over a surface of the light conversion layer 9. In another embodiment, however, the wavelength-selective transmission layer 8 may be disposed part of the light conversion layer 9.

The light conversion layer and the wavelength-selective transmission layer in each of the embodiments described above will be described in detail below.

### (Light Conversion Layer)

Regarding the components of the pixel portions of the light conversion layer, the light-emitting nanocrystalline particles are contained as an essential component. A resin component, other molecules having an affinity for the light-emitting nanocrystals as needed, a known additive, and another colorant may be contained. As described above, the black matrix is preferably disposed at the boundary portions between the pixels in view of contrast.

The light conversion layer according to this embodiment contains the light-emitting nanocrystalline particles. The term “nanocrystalline particles” in this specification refers to particles preferably having at least one length of 100 nm or less. The nanocrystals may have any geometric shape and may be symmetric or asymmetric. Specific examples of the shape of the nanocrystals include elongated shapes, rod-like shapes, circular (spherical) shapes, elliptical shapes, pyramidal shapes, disk-like shapes, branched shapes, net-like shapes, and any irregular shape. In some embodiments, the nanocrystals are preferably quantum dots or quantum rods.

Each of the light-emitting nanocrystalline particles preferably includes a core containing at least one first semiconductor material and a shell covering the core and containing a second semiconductor material that is the same or different from that of the core.

Thus, each of the light-emitting nanocrystalline particles includes a core containing at least one first semiconductor material and a shell containing a second semiconductor material, and the first semiconductor material and the second semiconductor material may be the same or different. Additionally, the core and/or the shell may contain a third semiconductor material other than the first semiconductor material and/or the second semiconductor material. The phrase “covering the core” used here indicates that it is sufficient to cover at least part of the core.

Furthermore, each of the light-emitting nanocrystalline particles preferably includes a core containing at least one first semiconductor material, a first shell covering the core and containing a second semiconductor material that is the same or different from that of the core, and, if necessary, a second shell covering the first shell and containing a third semiconductor material that is the same or different from that of the first shell.

Accordingly, each of the light-emitting nanocrystalline particles according to the embodiment preferably has at least one of the following three structures: A structure including a core containing a first semiconductor material and a shell covering the core and containing a second semiconductor material the same as that of the core, i.e., a structure composed of one or two or more semiconductor materials (=a structure having only a core (also referred to as a core structure)); a structure including a core containing a first semiconductor material and a shell covering the core and containing a second semiconductor material different from that of the core, i.e., a core/shell structure; and a structure including a core containing a first semiconductor material, a first shell covering the core and containing a second semiconductor material different from that of the core, and a second shell covering the first shell and containing a third semiconductor material different from that of the first shell, i.e., a core/shell/shell structure.

The light-emitting nanocrystalline particles according to the embodiment, as described above, preferably include the three structures, i.e., the core structure, the core/shell structure, and the core/shell/shell structure. In this case, the core may be composed of a mixed crystal containing two or more semiconductor materials (such as CdSe+CdS or CIS+ZnS). Additionally, the shell may also be composed of a mixed crystal containing two or more semiconductor materials.

The semiconductor material according to the embodiment is preferably one or two or more selected from the group consisting of II-VI group semiconductors, III-V group semiconductors, I-III-VI group semiconductors, IV group semiconductors, and I-II-IV-VI group semiconductors. Preferred examples of the first semiconductor material, the first semiconductor material, and the third semiconductor material according to the embodiment are the same as the semiconductor materials described above.

Specifically, the semiconductor material according to the embodiment is at least one or more selected from the group consisting of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe;GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaA1PSb, GaInNP, GaInNAs, GaInNSb, GaInPAs, GaInPSb, InAlNP, InAlNAs, InAlNSb, InAlPAs, InA1PSb;SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe;Si, Ge, SiC, SiGe, AgInSe2, CuGaSe2, CuInS2, CuGaS2, CuInSe2, AgInS2, AgGaSe2, AgGaS2, C, Si, and Ge. These compound semiconductors may be used alone or in combination as a mixture of two or more. The semiconductor material is preferably at least one or more selected from the group consisting of CdS, CdSe, CdTe, ZnS, ZnSe, ZnTe, ZnO, HgS, HgSe, HgTe, InP, InAs, InSb, GaP, GaAs, GaSb, AgInS₂, AgInSe₂, AgInTe₂, AgGaS₂, AgGaSe₂, AgGaTe₂, CuInS₂, CuInSe₂, CuInTe₂, CuGaS₂, CuGaSe₂, CuGaTe₂, Si, C, Ge, and Cu₂ZnSnS₄. These compound semiconductors may be used alone or in combination as a mixture of two or more.

The light-emitting nanocrystalline particles according to the embodiment preferably contain at least one nanocrystal selected from the group consisting of red light-emitting nanocrystalline particles configured to emit red light, green light-emitting nanocrystalline particles configured to emit green light, and blue light-emitting nanocrystalline particles configured to emit blue light. Typically, the emission color of the light-emitting nanocrystalline particles depends on the particle size in accordance with the solution of the Schrödinger wave equation in a square-well potential model and also depends on the energy gap of the light-emitting nanocrystalline particles. Thus, the emission color is selected by controlling the light-emitting nanocrystalline particles used and the particle size thereof.

The upper limit of the peak wavelength of the fluorescence spectrum of the red light-emitting nanocrystalline particles configured to emit red light in the embodiment is preferably 665 nm, 663 nm, 660 nm, 658 nm, 655 nm, 653 nm, 651 nm, 650 nm, 647 nm, 645 nm, 643 nm, 640 nm, 637 nm, 635 nm, 632 nm, or 630 nm. The lower limit of the peak wavelength is preferably 628 nm, 625 nm, 623 nm, 620 nm, 615 nm, 610 nm, 607 nm, or 605 nm.

The upper limit of the peak wavelength of the fluorescence spectrum of the green light-emitting nanocrystalline particles configured to emit green light in the embodiment is preferably 560 nm, 557 nm, 555 nm, 550 nm, 547 nm, 545 nm, 543 nm, 540 nm, 537 nm, 535 nm, 532 nm, or 530 nm. The lower limit of the peak wavelength is preferably 528 nm, 525 nm, 523 nm, 520 nm, 515 nm, 510 nm, 507 nm, 505 nm, 503 nm, or 500 nm.

The upper limit of the peak wavelength of the fluorescence spectrum of the blue light-emitting nanocrystalline particles configured to emit blue light in the embodiment is preferably 480 nm, 477 nm, 475 nm, 470 nm, 467 nm, 465 nm, 463 nm, 460 nm, 457 nm, 455 nm, 452 nm, or 450 nm. The lower limit of the peak wavelength is preferably 450 nm, 445 nm, 440 nm, 435 nm, 430 nm, 428 nm, 425 nm, 422 nm, or 420 nm.

The peak emission wavelength of a semiconductor material used for the red light-emitting nanocrystalline particles configured to emit red light in the embodiment is preferably in the range of 635 nm±30 nm. The peak emission wavelength of a semiconductor material used for the green light-emitting nanocrystalline particles configured to emit green light is preferably in the range of 530 nm±30 nm. The peak emission wavelength of a semiconductor material used for the blue light-emitting nanocrystalline particles configured to emit blue light is preferably in the range of 450 nm±30 nm.

The lower limit of the fluorescence quantum yield of the light-emitting nanocrystalline particles according to the embodiment, in order of preference, is 40% or more, 30% or more, 20% or more, and 10% or more.

The upper limit of the full width at half maximum of the fluorescence spectrum of the light-emitting nanocrystalline particles according to the embodiment, in order of preference, is 60 nm or less, 55 nm or less, 50 nm or less, and 45 nm or less.

The upper limit of the particle size (primary particles) of the red light-emitting nanocrystalline particles according to the embodiment, in order of preference, is 50 nm or less, 40 nm or less, 30 nm or less, and 20 nm or less.

The upper limit of the peak wavelength of the red light-emitting nanocrystalline particles according to the embodiment is 665 nm, and the lower limit thereof is 605 nm. A compound and its particle size are selected so as to obtain the peak wavelength. The upper limit of the peak wavelength of the green light-emitting nanocrystalline particles is 560 nm, and the lower limit thereof is 500 nm. The upper limit of the peak wavelength of the blue light-emitting nanocrystalline particles is 420 nm, and the lower limit thereof is 480 nm. Compounds and the particle size thereof are selected so as to obtain the peak wavelengths.

The liquid crystal display device according to the embodiment includes at least one pixel. The color of the pixel is obtained by three adjacent pixels. The pixels contain different nanocrystals that emit light of colors: red (for example, light-emitting nanocrystalline particles composed of CdSe, rod-like light-emitting nanocrystalline particles composed of CdSe, rod-like light-emitting nanocrystalline particles having a core-shell structure in which the shell portion is composed of CdS and the inner core portion is composed of CdSe, rod-like light-emitting nanocrystalline particles having a core-shell structure in which the shell portion is composed of CdS and the inner core portion is composed of ZnSe, light-emitting nanocrystalline particles having a core-shell structure in which the shell portion is composed of CdS and the inner core portion is composed of CdSe, light-emitting nanocrystalline particles having a core-shell structure in which the shell portion is composed of CdS and the inner core portion is composed of ZnSe, light-emitting nanocrystalline particles composed of a mixed crystal of CdSe and ZnS, rod-like light-emitting nanocrystalline particles composed of a mixed crystal of CdSe and ZnS, light-emitting nanocrystalline particles composed of InP, light-emitting nanocrystalline particles composed of InP, rod-like light-emitting nanocrystalline particles composed of InP, light-emitting nanocrystalline particles composed of a mixed crystal of CdSe and CdS, rod-like light-emitting nanocrystalline particles composed of a mixed crystal of CdSe and CdS, light-emitting nanocrystalline particles composed of a mixed crystal of ZnSe and CdS, or rod-like light-emitting nanocrystalline particles composed of a mixed crystal of ZnSe and CdS); green (light-emitting nanocrystalline particles composed of CdSe, rod-like light-emitting nanocrystalline particles composed of CdSe, light-emitting nanocrystalline particles composed of a mixed crystal of CdSe and ZnS, or rod-like light-emitting nanocrystalline particles composed of a mixed crystal of CdSe and ZnS); and blue (light-emitting nanocrystalline particles composed of ZnSe, rod-like light-emitting nanocrystalline particles composed of ZnSe, light-emitting nanocrystalline particles composed of ZnS, rod-like light-emitting nanocrystalline particles composed of ZnS, light-emitting nanocrystalline particles having a core-shell structure in which the shell portion is composed of ZnSe and the inner core portion is composed of ZnS, rod-like light-emitting nanocrystalline particles having a core-shell structure in which the shell portion is composed of ZnSe and the inner core portion is composed of ZnS, light-emitting nanocrystalline particles composed of CdS, or rod-like light-emitting nanocrystalline particles composed of CdS). The light conversion layer may contain another color (for example, yellow), as needed. Furthermore, different colors obtained from adjacent four or more pixels may also be used.

The average particle size (primary particles) of the light-emitting nanocrystalline particles according to the embodiment in this specification can be measured by TEM observation. Typical examples of a method for measuring the average particle size of nanocrystals include a light scattering method, a particle size measurement method by sedimentation with a solvent, and a method in which particles are directly observed with an electron microscope and average particle size is actually measured. The light-emitting nanocrystalline particles are easily degraded by, for example, water. In this embodiment, thus, a method is preferred in which freely-selected multiple crystals are directly observed with a transmission electron microscope (TEM) or scanning electron microscope (SEM), the particle sizes of the particles are calculated from the ratio of the length of the major axis to the length of the minor axis in a two-dimensional projection image, and the average thereof is determined. In this embodiment, thus, the average particle size is calculated by the method. The term “primary particles” of the light-emitting nanocrystalline particles refers to single crystals having a size of several to several tens of nanometers or crystallites similar thereto. The size and shape of the primary particles of the light-emitting nanocrystalline particles seems to depend on, for example, the chemical composition, structure, production method, and production conditions of the primary particles.

In the light conversion layer according to the embodiment, the light-emitting nanocrystalline particles preferably have organic ligands on their surfaces in view of dispersion stability. The organic ligands may bind to the surfaces of the light-emitting nanocrystalline particles by coordinate bonds. In other words, the surfaces of the light-emitting nanocrystalline particles may be passivated with the organic ligands. Additionally, the light-emitting nanocrystalline particles may have a polymeric dispersant on their surfaces. In an embodiment, for example, the polymeric dispersant may be bonded to the surfaces of the light-emitting nanocrystalline particles by removing the organic ligands from the organic ligand-containing light-emitting nanocrystalline particles and exchanging the organic ligands for the polymeric dispersant. In view of dispersion stability when an inkjet ink containing the particles is formed, the polymeric dispersant is preferably mixed with the light-emitting nanocrystalline particles while the organic ligands are coordinated.

Such an organic ligand is a low-molecular-weight compound or a polymer having a functional group with an affinity for the light-emitting nanocrystalline particles. The functional group having an affinity is not particularly limited and is preferably a group containing one element selected from the group consisting of nitrogen, oxygen, sulfur, and phosphorus. Examples thereof include organic sulfur groups, organic phosphorus groups, a pyrrolidone group, a pyridine group, an amino group, an amide group, an isocyanate group, a carbonyl group, and a hydroxy group. Examples thereof include trioctylphosphine (TOP), trioctylphosphine oxide (TOPO), oleic acid, oleylamine, octylamine, trioctylamine, hexadecylamine, octanethiol, dodecanethiol, hexylphosphoric acid (HPA), tetradecylphosphonic acid (TDPA), and octylphosphinic acid (OPA).

As the light-emitting nanocrystalline particles, particles dispersed in an organic solvent in a colloidal form can be used. The surfaces of the light-emitting nanocrystalline particles dispersed in the organic solvent are preferably passivated with the organic ligands. Examples of the organic solvent include cyclohexane, hexane, heptane, chloroform, toluene, octane, chlorobenzene, tetralin, diphenyl ether, propylene glycol monomethyl ether acetate, butyl carbitol acetate, and mixtures thereof.

The light conversion layer according to the embodiment (or an ink composition for forming the light conversion layer) preferably contains a polymeric dispersant. The polymeric dispersant can uniformly disperse light-scattering particles in ink.

The light conversion layer in this embodiment preferably contains, in addition to the light-emitting nanocrystalline particles described above, the polymeric dispersant that appropriately disperses and stabilizes the light-emitting nanocrystalline particles.

In this embodiment, the polymeric dispersant is a polymeric compound having a weight-average molecular weight of 750 or more, a functional group with an affinity for the light-scattering particles, and the function of dispersing the light-scattering particles. The polymeric dispersant is adsorbed on the light-scattering particles with the functional group having an affinity for the light-scattering particles, so that the light-scattering particles are dispersed in the ink composition by electrostatic repulsion and/or steric repulsion between polymeric dispersant molecules. The polymeric dispersant is preferably adsorbed on the light-scattering particles by bonding to the surfaces of the light-scattering particles, may be adsorbed on the light-emitting nanoparticles by bonding to the surfaces of the light-emitting nanocrystalline particles, or may be free in the ink composition.

Examples of the functional group having an affinity for the light-scattering particles include acidic functional groups, basic functional groups, and non-ionic functional groups. Such an acidic functional group has a dissociative proton and may be neutralized with a base, such as amine or a hydroxide ion. Such a basic functional group may be neutralized with an acid, such as an organic acid or inorganic acid.

Examples of the acidic functional group include a carboxy group (—COOH), a sulfo group (—SO₃H), a sulfate group (—OSO₃H), a phosphonate group (—PO(OH)₃), a phosphate group (—OPO(OH)₃), a phosphinate group (—PO(OH)—), and a mercapto group (—SH).

Examples of the basic functional group include primary, secondary, and tertiary amino groups, an ammonium group, an imino group, and nitrogen-containing heterocyclic groups, such as pyridine, pyrimidine, pyrazine, imidazole, and triazole.

Examples of the non-ionic functional groups include a hydroxy group, an ether group, a thioether group, a sulfinyl group (—SO—), a sulfonyl group (—SO₂—), a carbonyl group, a formyl group, an ester group, a carbonate ester group, an amide group, a carbamoyl group, an ureido group, a thioamide group, a thioureido group, a sulfamoyl group, a cyano group, an alkenyl group, an alkynyl group, a phosphine oxide group, and a phosphine sulfide group.

From the viewpoint of the dispersion stability of the light-scattering particles, from the point of view that the side effect of settling the light-emitting nanocrystalline particles is less likely to occur, from the viewpoint of ease of the synthesis of the polymeric dispersant, and from the viewpoint of the stability of the functional group, a carboxy group, a sulfo group, a phosphonate group, or a phosphate group is preferably used as the acidic functional group, and an amino group is preferably used as the basic functional group. Among these, a carboxy group, a phosphonate group, and an amino group are more preferably used. An amino group is most preferably used.

The polymeric dispersant having an acidic functional group has an acid value. The polymeric dispersant having an acidic functional group preferably has an acid value of 1 to 150 mgKOH/g in terms of solid content. An acid value of 1 or more easily results in a sufficient dispersibility of the light-scattering particles. At an acid value of 150 or less, the storage stability of the pixel portions (cured product of the ink composition) is not easily decreased.

The polymeric dispersant having a basic functional group has an amine value. The polymeric dispersant having a basic functional group preferably has an amine value of 1 200 mgKOH/g in terms of solid content. An amine value of 1 or more easily results in a sufficient dispersibility of the light-scattering particles. At an amine value of 200 or less, the storage stability of the pixel portions (cured product of the ink composition) is not easily decreased.

The polymeric dispersant may be a polymer of a single monomer (homopolymer) or a copolymer of multiple monomers (co-polymer). The polymeric dispersant may be any of a random copolymer, a block copolymer, and a graft copolymer. In the case where the polymeric dispersant is a graft copolymer, the polymeric dispersant may be a comb graft copolymer or a star graft copolymer. Examples of the polymeric dispersant may include acrylic resins, polyester resins, polyurethane resins, polyamide resins, polyether, phenolic resins, silicone resins, polyurea resins, amino resins, polyamines, such as polyethyleneimine and polyallylamine, epoxy resins, and polyimide.

As the polymeric dispersant, a commercially available product can be used. Examples of the commercially available product that can be used include Ajisper PB Series available from Ajinomoto Fine-Techno Co., Inc., Disperbyk Series and BYK Series available from BYK, and Efka Series available from BASF.

The light conversion layer (or the ink composition for forming the light conversion layer) according to the embodiment preferably contains a resin component that functions as a binder in a cured product. The resin component according to the embodiment is preferably a curable resin. As the curable resin, a thermosetting resin or UV-curable resin is preferred.

The thermosetting resin has a curable group. Examples of the curable group include an epoxy group, an oxetane group, an isocyanate group, an amino group, a carboxy group, and a methylol group. From the viewpoints of achieving good heat resistance and good storage stability of the cured product of the ink composition and good adhesion to a light-shielding portion (for example, a black matrix) and a base material, an epoxy group is preferred. The thermosetting resin may have one curable group or two or more curable groups.

The thermosetting resin may be a polymer of a single monomer (homopolymer) or a copolymer of multiple monomers (co-polymer). The thermosetting resin may be any of a random copolymer, a block copolymer, and a graft copolymer.

As the thermosetting resin, a compound having two or more thermosetting functional groups in one molecule is used and is usually used in combination with a curing agent. In the case where the thermosetting resin is used, a catalyst (curing accelerator) capable of promoting a thermosetting reaction may be further added. In other words, the ink composition may contain a thermosetting component containing a thermosetting resin (and a curing agent and a curing accelerator used as needed). In addition thereto, a polymer having no polymerizability itself may be further used.

As the compound having two or more thermosetting functional groups in one molecule, for example, an epoxy resin having two or more epoxy groups in one molecule (hereinafter, also referred to as a “polyfunctional epoxy resin”) may be used. The “epoxy resin” includes both of an epoxy resin from a monomer and an epoxy resin from a polymer. The number of epoxy groups of a polyfunctional epoxy resin in one molecule is preferably 2 to 50, more preferably 2 to 20. Any epoxy group may be used as long as it has an oxirane ring structure. The epoxy group may be, for example, a glycidyl group, an oxyethylene group, or an epoxycyclohexyl group. Examples of the epoxy resin include known polyvalent epoxy resins that can be cured with a carboxylic acid. The epoxy resins are widely disclosed in, for example, Masaki Shinbo, Ed. “Epoxy Jushi Handbook (Handbook of Epoxy Resin)”; Nikkan Kogyo Shimbun, Ltd., (1987), and these may be used.

When a polyfunctional epoxy resin having a relatively small molecular weight is used as a thermosetting resin, epoxy groups are charged into the ink composition (inkjet ink) to lead to a high concentration of reactive sites in the epoxy, thus enabling an increase in crosslink density.

As the curing agent and the curing accelerator used for curing the thermosetting resin, any known and commonly used ones that can be dissolved or dispersed in the above-mentioned organic solvent can be used.

The thermosetting resin may be insoluble in alkali from the viewpoint of easily forming high-reliability color filter pixel portions. The sentence “the thermosetting resin is insoluble in alkali” indicates that the amount of the thermosetting resin dissolved in a 1% by mass aqueous solution of potassium hydroxide at 25° C. is 30% or less by mass with respect to the total mass of the thermosetting resin. The amount of the thermosetting resin dissolved is preferably 10% or less by mass, more preferably 3% or less by mass.

From the viewpoints of easily obtaining an appropriate viscosity as an inkjet ink, achieving good curability of the ink composition, and improving the solvent resistance and the wear resistance of the pixel portions (cured product of the ink composition), the thermosetting resin may have a weight-average molecular weight of 750 or more, 1,000 or more, or 2,000 or more. From the viewpoint of achieving an appropriate viscosity as the inkjet ink, the thermosetting resin may have a weight-average molecular weight of 500,000 or less, 300,000 or less, 200,000 or less. However, the molecular weight after crosslinking is not limited thereto.

From the viewpoints of achieving an appropriate viscosity as the inkjet ink, achieving good curability of the ink composition, and improving the solvent resistance and the wear resistance of the pixel portions (cured product of the ink composition), the thermosetting resin content may be 10% or more by mass, 15% or more by mass, or 20% or more by mass with respect to the mass of the non-volatile content of the ink composition. From the point of view that the thickness of the pixel portions is not excessively large with respect to a light conversion function, the thermosetting resin content may be 90% or less by mass, 80% or less by mass, 70% or less by mass, 60% or less by mass, or 50% or less by mass with respect to the mass of the non-volatile content of the ink composition.

The UV-curable resin is preferably a resin obtained by polymerization of a radically photopolymerizable compound or cationically photopolymerizable compound, which is polymerized by light irradiation, and may be a photopolymerizable monomer or oligomer. These are used together with a photopolymerization initiator. The radically photopolymerizable compound is preferably used together with a radical photopolymerization initiator. The cationically photopolymerizable compound is preferably used together with a cationic photopolymerization initiator. In other words, the ink composition for the light conversion layer according to the embodiment may contain a photopolymerizable component containing a photopolymerizable compound and a photopolymerization initiator, may contain a radically photopolymerizable component containing a radically photopolymerizable compound and a radical photopolymerization initiator, or may contain a cationically photopolymerizable component containing a cationically photopolymerizable compound and a cationic photopolymerization initiator. The radically photopolymerizable component and the cationically photopolymerizable component may be used in combination. A compound having radical photopolymerizability and cationic photopolymerizability may be used. The radical photopolymerization initiator and the cationic photopolymerization initiator may be used in combination. A single photopolymerizable compound may be used alone. Alternatively, two or more photopolymerizable compounds may be used in combination.

An example of the radical photopolymerizable compound is a (meth)acrylate compound. The (meth)acrylate compound may be a monofunctional (meth)acrylate having a (meth)acryloyl group or a polyfunctional (meth)acrylate having multiple (meth)acryloyl groups. From the viewpoint of seemingly suppressing a decrease in smoothness due to shrinkage on curing during color filter production, the monofunctional (meth)acrylate and the polyfunctional (meth)acrylate are preferably used in combination. In this specification, the term “(meth)acrylate” refers to “acrylate” and “methacrylate” corresponding thereto. The same applies to the term “(meth)acryloyl”.

Examples of cationically photopolymerizable compound include epoxy compounds, oxetane compounds, and vinyl ether compounds.

As the photopolymerizable compound according to the embodiment, photopolymerizable compounds described in paragraph Nos. 0042 to 0049 of Japanese Unexamined Patent Application Publication No. 2013-182215 can also be used.

In the ink composition for the light conversion layer according to the embodiment, in the case where a curable component is composed of the photopolymerizable compound alone or as a main component, regarding the photopolymerizable compound as described above, a polyfunctional, i.e., bi or higher functional, photopolymerizable compound having two or more polymerizable functional groups in one molecule is more preferably used as an essential component because the durability (for example, strength and heat resistance) of a cured product can be further enhanced.

The photopolymerizable compound may be insoluble in alkali from the viewpoint of easily forming high-reliability color filter pixel portions. In this specification, “the photopolymerizable compound is insoluble in alkali” indicates that the amount of the photopolymerizable compound dissolved in a 1% by mass aqueous solution of potassium hydroxide at 25° C. is 30% or less by mass with respect to the total mass of the photopolymerizable compound. The amount of the photopolymerizable compound dissolved is preferably 10% or less by mass, more preferably 3% or less by mass.

From the viewpoints of achieving good curability of the ink composition and improving the solvent resistance and the wear resistance of the pixel portions (cured product of the ink composition), the photopolymerizable compound content may be 10% or more by mass, 15% or more by mass, or 20% or more by mass with respect to the mass of the non-volatile content of the ink composition. From the viewpoint of achieving better optical properties (light leakage), the photopolymerizable compound content may be 90% or less by mass, 80% or less by mass, 70% or less by mass, 60% or less by mass, or 50% or less by mass with respect to the mass of the non-volatile content of the ink composition.

The photopolymerizable compound may have a crosslinkable group from the viewpoint of achieving good stability of the pixel portions (cured product of the ink composition) (for example, deterioration over time can be suppressed, and high-temperature storage stability and wet heat storage stability are high). The crosslinkable group is a functional group reactive with another crosslinkable group by heat or active energy rays (for example, ultraviolet light). Examples thereof include an epoxy group, an oxetane group, a vinyl group, an acryloyl group, an acryloyloxy group, and a vinyl ether group.

As the radical photopolymerization initiator, a molecular cleavage-type or hydrogen abstraction-type radical photopolymerization initiator is preferred.

The photopolymerization initiator content may be 0.1 parts or more by mass, 0.5 parts or more by mass, or 1 part or more by mass per 100 parts by mass of the photopolymerizable compound in view of the curability of the ink composition. The photopolymerization initiator content may be 40 parts or less by mass, 30 parts or less by mass, or 20 parts or less by mass per 100 parts by mass of the photopolymerizable compound in view of the temporal stability of the pixel portions (cured product of the ink composition).

Additionally, a thermoplastic resin may be used in combination with the UV-curable resin. Examples of the thermoplastic resin include urethane-based resins, acrylic resins, polyamide-based resins, polyimide-based resins, styrene-maleic acid-based resins, and styrene-maleic anhydride-based resins.

The ink composition for forming the light conversion layer according to the embodiment may contain a known organic solvent. Examples thereof include ethylene glycol monobutyl ether acetate, diethylene glycol monobutyl ether acetate, diethylene glycol monoethyl ether acetate, diethylene glycol dibutyl ether, diethyl adipate, dibutyl oxalate, dimethyl malonate, diethyl malonate, dimethyl succinate, diethyl succinate, 1,4-butanediol diacetate, and glyceryl triacetate.

Additionally, the light conversion layer (or, for example, the ink composition for forming the light conversion layer) according to the embodiment may contain known additives, such as light-scattering particles, in addition to the curable resin, the polymeric dispersant, and the light-emitting nanocrystalline particles.

In the case where the color filter pixel portions (hereinafter, also referred to simply as “pixel portions”) are formed from the ink composition containing the light-emitting nanocrystalline particles, light from a light source may leak from the pixel portions without being absorbed by the light-emitting nanocrystalline particles. The leakage light decreases the color reproducibility of the pixel portions. Thus, in the case where the pixel portions are used as a light conversion layer, the leakage light is preferably minimized. The light-scattering particles are preferably used in order to prevent light leakage from the pixel portions. The light-scattering particles are, for example, optically inactive inorganic fine particles. The light-scattering particles can scatter light emitted from the light source to the color filter pixel portions.

Examples of a material of the light-scattering particles include elemental metals, such as tungsten, zirconium, titanium, platinum, bismuth, rhodium, palladium, silver, tin, platinum, and gold; metal oxides, such as silica, barium sulfate, barium carbonate, calcium carbonate, talc, titanium oxide, clay, kaoline, barium sulfate, barium carbonate, calcium carbonate, alumina white, titanium oxide, magnesium oxide, barium oxide, aluminum oxide, bismuth oxide, zirconium oxide, and zinc oxide; metal carbonates, such as magnesium carbonate, barium carbonate, bismuth subcarbonate, and calcium carbonate; metal hydroxides, such as aluminum hydroxide; composite oxides, such as barium zirconate, calcium zirconate, calcium titanate, barium titanate, and strontium titanate; and metal salts, such as bismuth subnitrate. The light-scattering particles preferably contain at least one selected from the group consisting of titanium oxide, alumina, zirconium oxide, zinc oxide, calcium carbonate, barium sulfate, and silica, more preferably at least one selected from the group consisting of titanium oxide, barium sulfate, and calcium carbonate from the viewpoint of achieving a higher effect of reducing light leakage.

The light-scattering particles may have, for example, a spherical shape, a filamentous shape, or indefinite shape. However, particles having a shape with less directionality (for example, particles having a spherical shape or regular tetrahedral shape) are preferably used as the light-scattering particles because the uniformity, flowability, and light-scattering properties of the ink composition are enhanced.

The light-scattering particles in the ink composition may have an average particle size (volume-average size) of 0.05 μm or more, 0.2 μm or more, or 0.3 μm or more from the viewpoint of achieving a higher effect of reducing light leakage. The light-scattering particles in the ink composition may have an average particle size (volume-average size) of 1.0 μm or less, 0.6 μm or less, or 0.4 μm or less from the viewpoint of achieving good ejection stability. The light-scattering particles in the ink composition may have an average particle size (volume-average size) of 0.05 to 1.0 μm, 0.05 to 0.6 μm, 0.05 to 0.4 μm, 0.2 to 1.0 μm, 0.2 to 0.6 μm, 0.2 to 0.4 μm, 0.3 to 1.0 μm, 0.3 to 0.6 μm, or 0.3 to 0.4 μm. From the viewpoint of easily achieving such an average particle size (volume-average size), the light-scattering particles used may have an average particle size (volume-average size) of 50 nm or more and 1,000 nm or less. The average particle size (volume-average size) of the light-scattering particles is obtained by performing measurement with a dynamic light scattering-type Nanotrac particle size distribution analyzer and calculating the volume-average size. The average particle size (volume-average size) of the light-scattering particles is obtained by measuring the particle size of each particle with, for example, a transmission electron microscope or scanning electron microscope and calculating the volume-average size.

The light-scattering particle content may be 0.1% or more by mass, 1% or more by mass, 5% or more by mass, 7% or more by mass, 10% or more by mass, or 12% or more by mass with respect to the mass of the non-volatile content of the ink composition from the viewpoint of achieving a higher effect of reducing light leakage. The light-scattering particle content may be 60% or less by mass, 50% or less by mass, 40% or less by mass, 30% or less by mass, 25% or less by mass, 20% or less by mass, or 15% or less by mass with respect to the mass of the non-volatile content of the ink composition from the viewpoints of achieving good ejection stability and a higher effect of reducing light leakage. In this embodiment, because the ink composition contains the polymeric dispersant, even when the light-scattering particle content is in the above range, it is possible to appropriately disperse the light-scattering particles.

The ratio by mass of the light-scattering particle content to the light-emitting nanocrystalline particle content (light-scattering particles/light-emitting nanocrystalline particles) is 0.1 to 5.0. The ratio by mass (light-scattering particles/light-emitting nanocrystalline particles) may be 0.2 or more or 0.5 or more from the viewpoint of achieving a higher effect of reducing light leakage. The ratio by mass (light-scattering particles/light-emitting nanocrystalline particles) may be 2.0 or less or 1.5 or less from the viewpoint of achieving a higher effect of reducing light leakage. The ratio by mass (light-scattering particles/light-emitting nanocrystalline particles) may be 0.1 to 2.0, 0.1 to 1.5, 0.2 to 5.0, 0.2 to 2.0, 0.2 to 1.5, 0.5 to 5.0, 0.5 to 2.0, or 0.5 to 1.5. A mechanism for the light leakage reduction by the light-scattering particles seems to be as follows: In the case where no light-scattering particles are present, light from the backlight only passes almost straight through the pixel portions and thus seems to be less likely to be absorbed by the light-emitting nanocrystalline particles. In the case where the light-scattering particles are present in the pixel portions where the light-emitting nanocrystalline particles are also present, light from the backlight is scattered in all directions in the pixel portions. The light-emitting nanocrystalline particles can receive the light. Thus, the amount of light absorbed in the pixel portions seems to be increased even when the same backlight is used. Accordingly, this mechanism seemingly has made it possible to prevent light leakage.

The light conversion layer according to the embodiment includes three-color pixel portions of red (R), green (G), and blue (B) and may contain colorants, as needed. As the colorants, known colorants can be used. For example, it is preferable that the pixel portions of red (R) contain a diketopyrrolopyrrole pigment and/or an anionic red organic dye, the pixel portions of green (G) contain at least one selected from the group consisting of halogenated copper phthalocyanine pigments, phthalocyanine-based green dyes, and mixtures of phthalocyanine-based blue dyes and azo-based yellow organic dyes, and the pixel portions of blue (B) contain an ε-copper phthalocyanine pigment and/or a cationic blue organic dye.

In the case where the light conversion layer according to the embodiment includes yellow (Y) pixel portions (yellow color layer), the yellow color layer preferably contains, as a colorant, at least one yellow organic dye or pigment selected from the group consisting of C.I. Pigment Yellow 150, 215, 185, 138, and 139 and C.I. Solvent Yellow 21, 82, 83:1, 33, and 162.

The color filters preferably contain the colorants described above. For example, it is preferable that the red (R) color filters contain a diketopyrrolopyrrole pigment and/or an anionic red organic dye, the green (G) color filters contain at least one selected from the group consisting of halogenated copper phthalocyanine pigments, phthalocyanine-based green dyes, and mixtures of phthalocyanine-based blue dyes and azo-based yellow organic dyes, and the blue (B) color filters contain an ε-copper phthalocyanine pigment and/or a cationic blue organic dye.

The color filters may contain, for example, the foregoing transparent resin, a photocurable compound described below, and a dispersant, as needed. Regarding a method for producing the color filters, the color filters can be formed by a known photolithography method.

### (Method for Producing Light Conversion Layer)

The light conversion layer can be formed by a known method. A typical method for forming pixel portions is a photolithography method. This method is as follows: A photocurable composition containing light-emitting nanocrystals described below is applied to a surface of a traditional transparent substrate for color filters on which a black matrix is disposed. After drying by heating (prebaking), pattern exposure is then performed by irradiation with ultraviolet light using a photomask to cure portions of a curable compound disposed on positions corresponding to the respective pixel portions. Unexposed portions are developed with a developer. Non-pixel portions are removed, and the pixel portions are fixed to the transparent substrate. According to this method, the pixel portions composed of a cured color film of the photocurable composition containing the light-emitting nanocrystals are formed on the transparent substrate.

Photocurable compositions described below are prepared for red (R) pixels, green (G) pixels, blue (B) pixels, and, if necessary, other color pixels, such as yellow (Y) pixels. The foregoing operation can be repeated to produce a light conversion layer having color pixel portions of the red (R) pixels, the green (G) pixels, the blue (B) pixels, and the yellow (Y) pixels located at predetermined positions.

Examples of a method for applying the photocurable composition containing the light-emitting nanocrystalline particles described below to the transparent substrate composed of, for example, glass, include a spin coating method, a roll coating method, and an inkjet method.

Drying conditions for the coating film of the photocurable composition containing the light-emitting nanocrystalline particles applied to the transparent substrate vary in accordance with, for example, the types and proportions of components mixed. Typically, drying is performed at about 50° C. to about 150° C. for about 1 to about 15 minutes. As light used for photocuring the photocurable composition containing the light-emitting nanocrystalline particles, ultraviolet light or visible light in the wavelength range of 200 to 500 nm is preferably used. Various light sources that emit light in the wavelength range can be used.

Examples of the developing method include a liquid deposition method, a dipping method, and a spray method. After exposing and developing the photocurable composition, the transparent substrate on which the necessary color pixel portions are formed is washed with water and dried. The resulting color filters are subjected to heat treatment (post baking) with a heating device, such as a hot plate or an oven at 90° C. to 280° C. for a predetermined time. This removes a volatile component in the cured color films and allows the unreacted photocurable compound remaining in the photocurable composition containing the light-emitting nanocrystalline particles to be thermally cured, thereby completing the light conversion layer.

The colorants and the resins for the light conversion layer of the embodiment are used together with the light-emitting nanocrystalline particles of the embodiment to prevent a decrease in the voltage holding ratio (VHR) of the liquid crystal layer and deterioration and an increase in ion density (ID) due to blue light or ultraviolet light, thus enabling a liquid crystal display device to overcome display defects, such as voids, the alignment unevenness, and image-sticking.

A typical method for producing the photocurable composition containing the light-emitting nanocrystalline particles is as follows: The light-emitting nanocrystalline particles and an organic solvent are mixed together. If necessary, molecules having an affinity therefor, a dispersant, and a colorant (=a dye and/or pigment composition) are added thereto. The mixture is stirred and dispersed so as to be uniform, thereby preparing a dispersion for the formation of the pixel portions of the light conversion layer. A photocurable compound and, if necessary, a thermoplastic resin, a photopolymerization initiator, and so forth are added thereto, thereby preparing the light-emitting-nanocrystal-particle-containing photocurable composition containing the light-emitting nanocrystalline particles.

Examples of the organic solvent used here include aromatic solvents such as toluene, xylene, and methoxybenzene; acetate-based solvents such as ethyl acetate, propyl acetate, butyl acetate, propylene glycol monomethyl ether acetate, propylene glycol monoethyl ether acetate, diethylene glycol methyl ether acetate, diethylene glycol ethyl ether acetate, diethylene glycol propyl ether acetate, and diethylene glycol butyl ether acetate; propionate-based solvents such as ethoxyethyl propionate; alcoholic solvents such as methanol and ethanol; ether-based solvents such as butyl cellosolve, propylene glycol monomethyl ether, diethylene glycol ethyl ether, and diethylene glycol dimethyl ether; ketone-based solvents such as methyl ethyl ketone, methyl isobutyl ketone, and cyclohexanone; aliphatic hydrocarbon-based solvents such as hexane; nitrogen compound-based solvents such as N,N-dimethylformamide, γ-butyrolactam, N-methyl-2-pyrrolidone, aniline, and pyridine; lactone-based solvent such as γ-butyrolactone; and carbamates such as a methyl carbamate-ethyl carbamate (48:52) mixture.

Examples of the dispersant used here include dispersants, such as Disperbyk 130, Disperbyk 161, Disperbyk 162, Disperbyk 163, Disperbyk 170, Disperbyk 171, Disperbyk 174, Disperbyk 180, Disperbyk 182, Disperbyk 183, Disperbyk 184, Disperbyk 185, Disperbyk 2000, Disperbyk 2001, Disperbyk 2020, Disperbyk 2050, Disperbyk 2070, Disperbyk 2096, Disperbyk 2150, Disperbyk LPN21116, and Disperbyk LPN6919, available from BYK Chemie, Efka 46, Efka 47, Efka 452, Efka LP4008, Efka 4009, Efka LP4010, Efka LP4050, LP4055, Efka 400, Efka 401, Efka 402, Efka 403, Efka 450, Efka 451, Efka 453, Efka 4540, Efka 4550, Efka LP4560, Efka 120, Efka 150, Efka 1501, Efka 1502, and Efka 1503, available from Efka, Solsperse 3000, Solsperse 9000, Solsperse 13240, Solsperse 13650, Solsperse 13940, Solsperse 17000, 18000, Solsperse 20000, Solsperse 21000, Solsperse 20000, Solsperse 24000, Solsperse 26000, Solsperse 27000, Solsperse 28000, Solsperse 32000, Solsperse 36000, Solsperse 37000, Solsperse 38000, Solsperse 41000, Solsperse 42000, Solsperse 43000, Solsperse 46000, Solsperse 54000, and Solsperse 71000, available from Lubrizol Corporation, and Ajisper PB711, Ajisper PB821, Ajisper PB822, Ajisper PB814, Ajisper PN411, and Ajisper PA111, available from Ajinomoto Co., Inc. Examples of the resin that may be contained include acrylic resins, urethane-based resins, alkyd-based resins, natural rosin, such as wood rosin, gum rosin, and tall rosin, modified rosin, such as polymerized rosin, disproportionated rosin, hydrogenated rosin, oxidized rosin, and maleated rosin, rosin derivatives, such as rosin amines, limed rosin, alkylene oxide adducts of rosin, alkyd adducts of rosin, and rosin-modified phenol, which are liquid synthetic resins that are insoluble in water at room temperature. The addition of the dispersant and the resin contribute to the reduction of flocculation, an improvement in the dispersion stability of a pigment, and an improvement in the viscosity properties of the dispersion.

An organic pigment derivative may also be contained as a dispersion aid. Examples of the derivative that can be contained include phthalimidomethyl derivatives, sulfonic derivatives, N-(dialkylamino)methyl derivatives, and N-(dialkylaminoalkyl)sulfonic acid amide derivatives. Two or more different types of these derivatives may be used in combination.

Examples of a thermoplastic resin used for the preparation of the photocurable composition containing the light-emitting nanocrystalline particles include urethane-based resins, acrylic resins, polyamide-based resins, polyimide-based resins, styrene-maleic acid resins, and styrene-maleic anhydride resins.

Examples of the photocurable compound containing the light-emitting nanocrystalline particles include bifunctional monomers such as 1,6-hexanediol diacrylate, ethylene glycol diacrylate, neopentyl glycol diacrylate, triethylene glycol diacrylate, bis(acryloxyethoxy)bisphenol A, and 3-methylpentanediol diacrylate; multifunctional monomers having relatively small molecular weights, such as trimethylolpropatone triacrylate, pentaerythritol triacrylate, tris[2-(meth)acryloyloxyethyl)isocyanurate, dipentaerythritol hexaacrylate, and dipentaerythritol pentaacrylate; and multifunctional monomers having relatively large molecular weights, such as polyester acrylate, polyurethane acrylate, and polyether acrylate.

Examples of the photopolymerization initiator include acetophenone, benzophenone, benzyldimethylketanol, benzoyl peroxide, 2-chlorothioxanthone, 1,3-bis(4′-azidobenzal)-2-propane, 1,3-bis(4′-azidobenzal)-2-propane-2′-sulfonic acid, and 4,4′-diazidostilbene-2,2′-disulfonic acid. Examples of a commercially available photopolymerization initiator include “Irgacure (trade name)-184”, “Irgacure (trade name)-369” available from BASF, “Darocur (trade name)-1173”, and “Lucirin-TPO” available from BASF; “Kayacure (trade name) DETX” and “Kayacure (trade name) OA”, available from Nippon Kayaku Co., Ltd.; “Vicure 10” and “Vicure 55” available from Stauffer; “Trigonal PI” available from Akzo; “Sandoray 1000 “available from Sandoz; “Deap” available from The Upjohn Company; and “Biimidazole” available from Kurogane Kasei Co., Ltd.

A known photosensitizer may be used in combination with the photopolymerization initiator. Examples of the photosensitizer include amines, ureas, compounds containing sulfur atoms, compounds containing phosphorus atoms, compounds containing chlorine atoms, nitriles, and other compounds containing nitrogen atoms. These may be used alone or in combination of two or more.

The proportion of the photopolymerization initiator mixed is not particularly limited and is, by mass, preferably in the range of 0.1% to 30% based on a compound having a photopolymerizable or photocurable functional group. At less than 0.1%, the sensitivity during photocuring tends to decrease. At more than 30%, when a coating film composed of a resist containing a pigment dispersed is dried, the crystals of the photopolymerization initiator can precipitate to degrade the physical properties of the coating film.

The materials as described above are used. On a mass basis, 300 to 100,000 parts of an organic solvent and 1 to 500 parts of molecules having an affinity therefor or a dispersant per 100 parts of the light-emitting nanocrystalline particles of the embodiment are stirred and uniformly dispersed, thereby preparing a dye or pigment dispersion. Then 0.125 to 2,500 parts of the total of a thermoplastic resin and a photocurable compound based on 100 parts of the pigment dispersion, 0.05 to 10 parts of a photopolymerization initiator based on 1 part of the photocurable compound, and, if necessary, an organic solvent are stirred and uniformly dispersed, thereby enabling a photocurable composition containing the light-emitting nanocrystalline particles to be prepared for the formation of pixel portions.

A known organic solvent or aqueous alkali solution may be used as a developer. In particular, in the case where the photocurable composition contains a thermoplastic resin or a photocurable compound and where at least one of them has an acid value or is soluble in alkali, washing with an aqueous alkali solution is effective in forming color filter pixel portions.

The method for producing the color pixel portions including the R pixels, the G pixels, the B pixels, and the Y pixels by the photolithography method has been described in detail. Regarding the pixel portions formed from the composition containing the light-emitting nanocrystalline particles according to the embodiment, the color pixel portions may be formed by another method such as an electrodeposition method, a transfer method, a micelle electrolytic method, a photovoltaic electrodeposition (PVED) method, an inkjet method, a reverse printing method, or a thermal curing method to produce the light conversion layer.

A method for producing the ink composition for the light conversion layer according to the embodiment will be described. The method for producing the ink composition includes, for example, a first step of preparing a light-scattering particle dispersion containing the light-scattering particles and the polymeric dispersant and a second step of mixing the light-scattering particle dispersion and the light-emitting nanocrystalline particles. In this method, the light-scattering particle dispersion may further contain a thermosetting resin. In the second step, a thermosetting resin may be further mixed therewith. According to this method, the light-scattering particles can be sufficiently dispersed. It is thus possible to easily obtain the ink composition that can reduce light leakage in the pixel portions.

In the step of preparing the light-scattering particle dispersion, the light-scattering particle dispersion may be prepared by mixing the light-scattering particles, the polymeric dispersant, and, if necessary, the thermosetting resin and performing dispersion treatment. The mixing and the dispersion treatment may be performed with a dispersing device, such as a bead mill, a paint conditioner, or a planetary stirrer. From the viewpoints of achieving good dispersion of the light-scattering particles and easily adjusting the average particle size of the light-scattering particles to a desired range, a bead mill or a paint conditioner is preferably used.

The method for producing the ink composition may further include, before the second step, a step of preparing a light-emitting nanocrystalline particle dispersion containing the light-emitting nanocrystalline particles and a thermosetting resin. In this case, in the second step, the light-scattering particle dispersion and the light-emitting nanocrystalline particle dispersion are mixed. According to this method, the light-emitting nanocrystalline particles can be sufficiently dispersed. It is thus possible to easily obtain the ink composition that can reduce light leakage in the pixel portions. In the step of preparing the light-emitting nanocrystalline particle dispersion, the mixing and dispersion treatment of the light-emitting nanocrystalline particles and the thermosetting resin may be performed with a dispersing device similar to that used in the step of preparing the light-scattering particle dispersion.

In the case where the ink composition of the embodiment is used as an ink composition for an inkjet method, the ink composition is preferably used for a piezo-jet inkjet recording apparatus using a mechanical ejection mechanism including a piezoelectric element. In the piezo-jet method, the ink composition is not instantaneously exposed to a high temperature upon ejection. Thus, the light-emitting nanocrystalline particles are less likely to deteriorate, and expected light emission properties of the color filter pixel portions (light conversion layer) are easily obtained.

The light conversion layer according to the embodiment can be produced by, for example, forming a black matrix serving as a light-shielding portion on a substrate in a pattern, allowing the ink composition (inkjet ink) of the embodiment to selectively adhere to pixel portion formation regions separated by the light-shielding portion on the substrate using the inkjet method, and curing the ink composition by irradiation with active energy rays or heating.

An example of a method for forming the light-shielding portion is a method in which a thin metal film, such as chromium, or a thin film of a resin composition containing light-shielding particles is formed on a region to be a boundary between the multiple pixel portions on one surface of the substrate, and then the thin film is patterned. The thin metal film can be formed by, for example, a sputtering method or a vacuum deposition method. The thin film of the resin composition containing the light-shielding particles can be formed by a method, such as application or printing. An example of a patterning method is a photolithography method.

Examples of the inkjet method include a Bubble Jet (registered trademark) method in which an electrothermal transducer is used as an energy generating device, and a piezo-jet method in which a piezoelectric device is used.

In the case where the ink composition is cured by irradiation with active energy rays (for example, ultraviolet light), for example, a mercury lamp, a metal halide lamp, a xenon lamp, or an LED may be used. Irradiation light may have a wavelength of, for example, 200 nm or more and 440 nm or less. The exposure amount may be, for example, 10 mJ/cm² or more and 4,000 mJ/cm² or less.

In the case where the ink composition is cured by heating, the heating temperature may be, for example, 110° C. or higher and 250° C. or lower. The heating time may be, for example, 10 minutes or more and 120 minutes or less.

While the color filters, the light conversion layer, and the production methods thereof according to an embodiment have been described above, the present invention is not limited to the embodiment.

### (Wavelength-Selective Transmission Layer)

The average thickness of the wavelength-selective transmission layer according to the embodiment is appropriately selected in accordance with a desired wavelength range of transmitted light and a desired wavelength range of reflected light and is preferably 0.5 to 15 μm, more preferably 0.7 to 12 μm, even more preferably 1 to 10 μm.

The light conversion film according to the embodiment may include a supporting base (also referred to as a “supporting substrate”, corresponding to the supporting substrate 12 illustrated in FIG. 6) as needed. For example, a supporting substrate is used in order to support the light conversion layer, the wavelength-selective transmission layer, or the light conversion film. As the supporting substrate, a glass substrate or a transparent base (plastic film or plastic sheet) is preferred. Preferred examples of the material of a plastic transparent base include polyolefin resins, vinyl-based resins, polyester resins, acrylic resins, polyamide resins, cellulosic resins, polystyrene resins, polycarbonate resins, polyarylate, and polyimide resins. Examples thereof include polyester resins, such as a poly(ethylene terephthalate) (PET) film and cellulosic resins, such as triacetyl cellulose (TAC).

One or both surfaces of the supporting base may be subjected to physical or chemical surface treatment, such as corona discharge treatment, chromium oxidation treatment, hot-air treatment, an ozone treatment method, an ultraviolet treatment method, a sandblasting method, a solvent treatment method, or plasma treatment, in view of adhesion to a layer disposed thereon (the light conversion layer or the wavelength-selective transmission layer), as needed.

The thickness of the supporting base according to the embodiment is not particularly limited, but is usually in the range of about 20 to about 200 μm, preferably 30 to 150 μm, in view of achieving high durability and wide applicability.

The supporting base may be subjected to treatment, such as the formation of a primer layer and a back primer layer, from the viewpoints of increasing adhesion and bondability between the base material and the wavelength-selective transmission layer and between the base material and the light conversion layer. Non-limiting examples of a material used for the formation of the primer layer include acrylic resins, vinyl chloride-vinyl acetate copolymers, polyester, polyurethane, chlorinated polypropylene, and chlorinated polyethylene. A material used for the back primer layer is appropriately selected in accordance with an adherend.

The thickness of the transparent base according to the embodiment is not particularly limited, but is usually in the range of about 20 to about 200 μm, preferably 30 to 150 μm, in view of achieving high durability and wide applicability.

The wavelength-selective transmission layer according to the embodiment is preferably a dielectric multilayer film or a cholestic liquid crystal layer.

The dielectric multilayer film includes two layers with different refractive indices and is a film having a multilayer structure in which a high-refractive-index layer having a higher refractive index than the other and a low-refractive-index layer having a lower refractive index than the high-refractive-index layer are alternately stacked, the film including multiple sets of the layers (for example, two to nine sets). The stacked multilayer structure may have a configuration described in, for example, Keiji Kuriyama “Journal of the Surface Finishing Society of Japan”, 1997; vol. 48, No. 9, pp 890-894.

With such a multilayer structure, it is possible to obtain a mirror having high reflectance and edge filters (for example, short-wave-pass filters and long-wave-pass filters) configured to split light in a specific wavelength range into reflection and transmission. Typically, by designing the dielectric multilayer film to have a large difference in refractive index between the high-refractive-index layer and the low-refractive-index layer, the reflectance for light having a desired wavelength can be increased with a small number of layers. It is known that when each of the refractive index layers is designed to have an optical thickness of one-quarter wavelength, i.e., d=λ/4n, where n is the refractive index of the material of each layer for reflected light having a desired wavelength λ, waves reflected from the boundary of the layers cancel each other out, and a forbidden band for the waves is formed to decrease the transmittance.

In at least one set of the high-refractive-index layer and the low-refractive-index layer in contact with the high-refractive-index layer in this embodiment, the difference in refractive index between the high-refractive-index layer and the low-refractive-index layer is preferably 0.04 or more, more preferably 0.05 or more, further more preferably 0.08 or more, even more preferably 0.11 or more, still even more preferably 0.21 or more, particularly preferably 0.38 or more.

For example, the high-refractive-index layer preferably has a refractive index of 1.2 to 2.7, more preferably 1.5 to 2.5, even more preferably 1.7 to 2.3, particularly preferably 1.9 to 2.2. The low-refractive-index layer preferably has a refractive index of 0.9 to 1.7, more preferably 1.2 to 1.55, even more preferably 1.25 to 1.5.

The dielectric multilayer film is used for a distributed Bragg reflector (DBR) film and can selectively reflect light having one or more predetermined wavelengths. The dielectric multilayer film according to the embodiment may be composed of a material containing an oxide or nitride of at least one selected from the group consisting of Si, Ti, Zr, Nb, Ta, and Al. The dielectric multilayer film preferably has a total thickness of about 0.05 μm to about 2 μm, more preferably about 0.1 μm to about 1.5 μm.

The dielectric multilayer film according to the embodiment is obtained by alternately forming a stack of titanium oxide and silicon oxide, for example, a low-refractive-index oxide film composed of, for example, SiO₂, MgF₂, or CaF₂ and a high-refractive-index oxide film composed of, for example, TiO₂, ZnO₂, CeO₂, Ta₂O₃, or Nb₂O₅ using vacuum deposition or the like. Other examples thereof include a film having a two-layer structure of silver and SiO₂ or Al₂O₃, a film in which silica (SiO₂) layers and titania (TiO₂) layers are alternately stacked, and a film in which aluminum nitride (AlN) layers and aluminum oxide (Al₂O₃) layers are alternately stacked. The materials of the layers constituting the dielectric multilayer film can be selected from, for example, AlN, SiO₂, SiN, ZrO₂, SiO₂, TiO₂, Ta₂O₃, ITONb₂O₅, and ITO. The dielectric multilayer film having a combination of SiO₂/Ta₂O₃, SiO₂/Nb₂O₅, or SiO₂/TiO₂ is exemplified. The order of the refractive indices of these materials (TiO₂, Nb₂O₅, and Ta₂O₃) is TiO₂>Nb₂O₅>Ta₂O₃. The total thickness of SiO₂ is reduced when the dielectric multilayer film is formed of the combination of SiO₂/TiO₂.

Examples of a commercially available dielectric multilayer film include DFY-520 (yellow) (available from Optical Solutions Corporation), DFM-495 (magenta) (available from Optical Solutions Corporation), DFC-590 (cyan) (available from Optical Solutions Corporation), DFB-500 (blue) (available from Optical Solutions Corporation), DFG-505 (green) (available from Optical Solutions Corporation), DFR-610 (red) (available from Optical Solutions Corporation), DIF-50S-BLE (available from Sigmakoki Co., Ltd.), DIF-50S-GRE (available from Sigmakoki Co., Ltd.), DIF-50S-RED (available from Sigmakoki Co., Ltd.), DIF-50S-YEL (available from Sigmakoki Co., Ltd.), DIF-50S-MAG (available from Sigmakoki Co., Ltd.), and DIF-50S-CYA (available from Sigmakoki Co., Ltd).

As the dielectric multilayer film, a film configured to transmit a desired wavelength range and reflect a wavelength range other than the desired wavelength range can be appropriately used.

A method for producing the dielectric multilayer film according to the embodiment is not particularly limited. The dielectric multilayer film can be produced with reference to methods described in, for example, Japanese Patent Nos. 3704364, 4037835, 4091978, 3709402, 4860729, and 3448626, the entire contents of which are incorporated in the embodiment.

In the light conversion film according to the embodiment, regarding a method for producing the light conversion film including the dielectric multilayer film, as described above, the light conversion film including the dielectric multilayer film can be produced as follows: a planarization film is stacked on at least one surface of a light conversion layer produced by an inkjet method or a photolithography method. A selective light transmission layer is formed thereon by a vapor deposition method, such as sputtering, using a method described in the foregoing document or the like.

The planarization film has the function of planarizing the light conversion layer and may be composed of an organic material or an inorganic material. In the case of the organic material, an insulating film formed from a photosensitive resin composition can be obtained. That is, the planarization film is composed of, for example, a cyclic olefin resin, an acrylic resin, an acrylamide resin, polysiloxane, an epoxy resin, a phenolic resin, a cardo resin, a polyimide resin, a polyamide-imide resin, a polycarbonate resin, a poly(ethylene terephthalate) resin, or a novolac resin. A passivation film composed of an organic material used in the embodiment is preferably composed of a resin composition containing the resin and a known organic solvent.

In the case of the inorganic material, a film composed of, for example, an inorganic compound, such as silicon nitride or silicon oxide is exemplified. These planarization films (passivation films) may be formed by known methods in accordance with materials used for the formation of the films and can be formed by, for example, a plasma-enhanced CVD method or a vapor deposition method. The planarization film according to the embodiment is preferably formed so as to have an average thickness of 0.1 μm to 5 μm.

A cholesteric liquid crystal layer according to the embodiment is a layer configured to selectively reflect a right-handed circularly polarized light component or a left-handed circularly polarized light component of light (electromagnetic waves) incident from one surface and transmit other light components. As a material that can transmit (or reflect) only a specific circularly polarized light component, a cholestic liquid crystal or a chiral nematic liquid crystal is preferably used. Cholesteric liquid crystals are known to have circular dichroism properties, and have the feature of selectively reflecting one of the right-handed and left-handed circularly polarized light components of light (electromagnetic waves) incident along the helical axis of the planar alignment of the liquid crystals. Thus, the direction of rotation of cholesteric liquid crystals is appropriately selected, so that a circularly polarized light component having an optical rotatory direction the same as the direction of rotation can be selectively reflected.

Specifically, the selective reflection layer of cholesteric liquid crystals according to the embodiment has a helical structure (cholesteric structure) with a constant period, which is a multilayer structure in a direction normal to a surface of the transparent base (incident light angle θ=0°) and wavelength-selective reflectivity in which circularly polarized light having a wavelength corresponding to the helical pitch is reflected. The relationship between the selective reflection wavelength (λ) and the helical pitch (p) is represented by the relationship λ=p·N (where N is an average refractive index of a polymerizable cholesteric liquid crystal composition). The width (Δλ) of a wavelength selectively reflected is represented by the product of the birefringence anisotropy (Δn) of the polymerizable liquid crystal composition and p.

The peak wavelength selectively reflected by the cholesteric liquid crystals according to the embodiment is determined by the pitch length of the cholesteric structure. In the case where the cholesteric liquid crystals are obtained using nematic liquid crystal molecules (liquid crystal compound) and a chiral compound, the helical pitch length can be controlled by, for example, adjusting the amount of chiral compound added. To obtain a desired helical pitch length, thus, the adjustment can be appropriately performed in accordance with the type of chiral compound, the amount of chiral compound added, and the type of liquid crystal compound used, so that the selective wavelength range can be freely selected.

The cholesteric liquid crystal layer according to the embodiment is preferably obtained by polymerizing a polymerizable liquid crystal composition containing a polymerizable liquid crystal compound, a chiral compound, and a polymerization initiator.

In the embodiment, the term “liquid crystal” of the polymerizable liquid crystal compound indicates the case where liquid crystallinity is exhibited by only one type of polymerizable liquid crystal compound used and the case where liquid crystallinity is exhibited when a mixture of the polymerizable liquid crystal compound with another liquid crystal compound is used. The polymerizable liquid crystal composition can be subjected to polymerization treatment, such as irradiation with light, for example, ultraviolet light, heating, or a combination thereof, to be polymerized (formed into a film).

Preferred structures of the wavelength-selective transmission layer including the cholesteric liquid crystal layer according to the embodiment include a two-layer stack in which a dextrorotatory (also referred to as “right-handed”) cholesteric liquid crystal layer and a levorotatory (also referred to as “left-handed”) cholesteric liquid crystal layer are stacked; a stack in which a λ/2 plate is held between two dextrorotatory cholesteric liquid crystal layers (a stack in which the dextrorotatory cholesteric liquid crystal layer, the λ/2 plate, and the dextrorotatory cholesteric liquid crystal layer are stacked in this order); and a stack in which a λ/2 plate is held between two levorotatory cholesteric liquid crystal layers (a stack in which the levorotatory cholesteric liquid crystal layer, the λ/2 plate, and the levorotatory cholesteric liquid crystal layer are stacked in this order).

Six preferred structures of the light conversion layer according to the embodiment are as follows: a structure in which a two-layer stack including a dextrorotatory cholesteric liquid crystal layer and a levorotatory cholesteric liquid crystal layer is stacked on one surface of the light conversion layer; a structure in which a stack including a λ/2 plate held between two dextrorotatory cholesteric liquid crystal layers is disposed on one surface of the light conversion layer; a structure in which a stack including a λ/2 plate held between two levorotatory cholesteric liquid crystal layers is disposed on one surface of the light conversion layer; a structure in which a two-layer stack including a dextrorotatory cholesteric liquid crystal layer and a levorotatory cholesteric liquid crystal layer is stacked on one surface of the light conversion layer and in which a yellow color filter is disposed on the other surface; a structure in which a stack including a λ/2 plate held between two dextrorotatory cholesteric liquid crystal layers is disposed on one surface of the light conversion layer and in which a yellow color filter is disposed on the other surface; and a structure in which a stack including a λ/2 plate held between two levorotatory cholesteric liquid crystal layers is disposed on one surface of the light conversion layer and in which a yellow color filter is disposed on the other surface.

The cholesteric liquid crystal layer according to the embodiment preferably has a total thickness of about 1 μm to about 12 μm, more preferably about 1 μm to about 10 μm, even more preferably about 2 μm to about 8 μm. The “total thickness” used here refers to an average thickness, the total thickness of the two cholesteric liquid crystal layers (dextrorotatory or levorotatory) and the λ/2 plate included as needed, and does not include the thickness of the substrate disposed as needed. While the six preferred structures (stacks) of the wavelength-selective transmission layer including the cholesteric liquid crystal layer have been described above, each of the dextrorotatory cholesteric liquid crystal layers and/or the levorotatory cholesteric liquid crystal layers preferably has an average thickness of 4.1 μm or less, more preferably 3.1 μm or less. The λ/2 plate disposed as needed preferably has an average thickness of 2 μm or less.

The polymerizable liquid crystal composition used for the cholesteric liquid crystal layer according to the embodiment contains, as an essential component, a liquid crystal compound having at least one polymerizable group. The liquid crystal compound having at least one polymerizable group according to the embodiment may be a polymerizable compound having a mesogenic skeleton. The compound alone need not exhibit liquid crystallinity.

Examples thereof include rod-like polymerizable liquid crystal compounds each having a rigid portion what is called a mesogen in which multiple structures, such as 1,4-phenylene groups and 1,4-cyclohexylene groups, are linked and each having two or more polymerizable functional groups, such as a vinyl group, an acrylic group, and a (meth)acrylic group, as described in, for example, Handbook of Liquid Crystals (edited by D. Demus, J. W. Goodby, G. W. Gray, H. W. Spiess, V. Vill, published by Wiley-VCH, 1998), Kikan Kagaku Sosetsu (Quarterly Journal of Chemical Review), No. 22, Ekisho no Kagaku (Chemistry of Liquid Crystal) (edited by The Chemical Society of Japan, 1994), Japanese Unexamined Patent Application Publication Nos. 7-294735, 8-3111, 8-29618, 11-80090, 11-116538, and 11-148079; and rod-like polymerizable liquid crystal compounds each having two or more polymerizable groups including a maleimide group as described in Japanese Unexamined Patent Application Publication Nos. 2004-2373 and 2004-99446. Among these, such a rod-like liquid crystal compound having two or more polymerizable groups is preferred because a composition that exhibits a liquid-crystalline temperature range including a low temperature close to room temperature is easily prepared.

In the case where the cholesteric liquid crystal layer according to the embodiment reflects light in a green wavelength range (for example, 490 to 595 nm, preferably 510 to 590 nm), the product of p (helical pitch) and N (average refractive index of the polymerizable liquid crystal composition) is adjusted so as to satisfy the following relational expressions: 490=p×N, and 595=p×N. Similarly, in the case where light in the red wavelength range (for example, 600 to 710 nm, preferably 610 to 700 nm) is reflected, the product of p (helical pitch) and N (average refractive index of the polymerizable liquid crystal composition) is adjusted so as to the following relational expressions: 620=p×N, and 690=p×N.

Specifically, the average refractive index of each layer composed of the cured product of the polymerizable cholesteric liquid crystal composition is preferably in the range of 0.9 to 2.1, more preferably 1.0 to 2.0, even more preferably 1.1 to 1.9, still even more preferably 1.2 to 1.8, particularly preferably 1.4 to 1.75. The helical pitch p of the cured product of the polymerizable cholesteric liquid crystal composition according to the embodiment is appropriately adjusted in accordance with the amount and type of chiral compound added. When the chiral compound in the polymerizable cholesteric liquid crystal composition according to the embodiment has a high helical twisting power (HTP), the amount of chiral compound may be small. When the chiral compound in the composition has a low HTP, the amount of chiral compound added tends to increase.

In the light conversion film according to the embodiment, a method for producing the light conversion film including the cholesteric liquid crystal layer is exemplified as follows: At least one surface of the light conversion layer produced by an inkjet method or a photolithography method as described above is subjected to rubbing treatment for performing rubbing with a roll wrapped in a cloth composed of, for example, nylon, rayon, or cotton fibers in a certain direction. The polymerizable cholesteric liquid crystal composition is then applied. The cholesteric liquid crystal molecules are aligned. The polymerizable cholesteric liquid crystals are then cured by polymerization. Another method for producing the light conversion film is as follows: A composition for forming a planarization film (organic material) or a composition for forming a (photo) alignment layer is applied to at least one surface of the light conversion layer and cured. The planarization film or the alignment layer, which is a cured product, is then subjected to rubbing treatment for performing rubbing with a roll wrapped in a cloth composed of, for example, nylon, rayon, or cotton fibers in a certain direction. Alternatively, the photo-alignment layer (photo-alignment film described below) is subjected to photo-alignment treatment for irradiating the layer with polarized or unpolarized radiation.

The polymerizable liquid crystal composition used for the cholesteric liquid crystal layer according to the embodiment preferably contains, as a first component, a polymerizable liquid crystal compound represented by general formula (I-2):

[Chem. 1]

P¹²¹-(Sp¹²¹-X¹²¹)_{q121}-MG¹²¹-(X¹²²-Sp¹²²)_{q122}-P¹²² (I-2)

(wherein in the formula, P¹² and P¹²² each independently represent a polymerizable functional group, Sp¹²¹ and Sp¹²² each independently represent an alkylene group having 1 to 18 carbon atoms or a single bond, one —CH₂— or two or more non-adjacent —CH₂-'s in the alkylene group may each be independently replaced with —COO—, —OCO—, or —OCO—O—, one or two or more hydrogen atoms in the alkylene group may be replaced with a halogen atom (a fluorine atom, a chlorine atom, a bromine atom, or an iodine atom) or a CN group, X¹²¹ and X¹²² each independently represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that in P¹²¹-Sp¹²¹, P¹²²-Sp¹²², Sp¹²¹-X¹²¹, and Sp¹²²-X¹²², no direct bond between heteroatoms is included), q121 and q122 each independently represent 0 or 1,
MG¹²² represents a mesogen group represented by general formula (I-2-b):

[Chem. 2]

-(A1-Z1)ᵣ₁-A2-Z2-A3- (I-2-b)

wherein in general formula (I-2-b), A1, A2, and A3 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group-, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, or a fluorene-2,7-diyl group, Z1 and Z2 each independently represent —COO—, —OCO—, —CH₂CH₂—, —OCH₂—, —CH₂O—, —CH═CH—, —C═C—, —CH═CHCOO—, —OCOCH═CH—, —CH₂CH₂COO—, —CH₂CH₂OCO—, —COOCH₂CH₂—, —OCOCH₂CH₂—, —C═N—, —N═C—, —CONH—, —NHCO—, —C(CF₃)₂—, an alkyl group that has 2 to 10 carbon atoms and that may have a halogen atom (a fluorine atom, a chlorine atom, a bromine atom, or an iodine atom), or a single bond, r1 represents 0, 1, 2, or 3, and when a plurality of A1's and a plurality of Z1's are present, they may be the same or different).

The polymerizable liquid crystal composition preferably contains, as a second component, a polymerizable liquid crystal compound selected from compounds represented by general formula (II-2):

[Chem. 3]

P²²¹-Sp²²¹-X²²¹-MG²²¹-R²²¹ (II-2)

(wherein in the formula, P²²¹ represents a polymerizable functional group, Sp²²¹ represents an alkylene group having 1 to 18 carbon atoms, one —CH₂— or two or more non-adjacent —CH₂-'s in the alkylene group may each be independently replaced with —O—, —COO—, —OCO—, or —OCO—O—, one or two or more hydrogen atoms in the alkylene group may be replaced with a halogen atom (a fluorine atom, a chlorine atom, a bromine atom, or an iodine atom) or a CN group, X²²¹ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF—CF—, —C≡C— or a single bond (provided that in P²²¹-Sp²²¹, and Sp²²¹-X²²¹, no direct bond between heteroatoms other than C or H is included), MG²²¹ represents a mesogen group, R²²¹ represents a hydrogen atom, a halogen atom (a fluorine atom, a chlorine atom, a bromine atom, or an iodine atom), a cyano group, a linear or branched alkyl group having 1 to 12 carbon atoms, or a linear or branched alkenyl group having 1 to 12 carbon atoms, one —CH₂— or two or more non-adjacent —CH₂-'s in the alkyl group and the alkenyl group may each be independently replaced with —O—, —S—, —CO—, —COO—, —OCO—, —CO—S—, —S—CO—, —O—CO—O—, —CO—NH—, —NH—CO—, —NH—, —N(CH₃)—, —CH═CH—COO—, —CH═CH—OCO—, —COO—CH═CH—, —OCO—CH═CH—, —CH═CH—, —CF═CF—, or —C≡C—, one or two or more hydrogen atoms in the alkyl group and the alkenyl group may each be independently replaced with a halogen atom (a fluorine atom, a chlorine atom, a bromine atom, or an iodine atom) or a cyano group, and when the two or more hydrogen atoms are replaced with substituents, the substituents may be the same or different).

The polymerizable liquid crystal composition preferably contains, as a third component, a polymerizable liquid crystal compound represented by general formula (II-1):

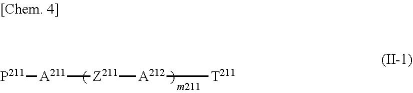

(wherein in general formula (II-1), P²¹¹ represents a polymerizable functional group,

A²¹¹ and A²¹² each independently represent a 1,4-phenylene group, a 1,4-cyclohexylene group, a bicyclo[2.2.2]octane-1,4-diyl group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, these groups may be unsubstituted or substituted with one or more substituents L,

each L represents a fluorine atom, a chlorine atom, a bromine atom, an iodine atom, a pentafluorosulfuranyl group, a nitro group, a cyano group, an isocyano group, an amino group, a hydroxy group, a mercapto group, a methylamino group, a dimethylamino group, a diethylamino group, a diisopropylamino group, a trimethylsilyl group, a dimethylsilyl group, a thioisocyano group, an optionally substituted phenyl group, an optionally substituted phenylalkyl group, an optionally substituted cyclohexylalkyl group, or a linear or branched alkyl group having 1 to 20 carbon atoms, one —CH₂— or two or more non-adjacent —CH₂-'s therein may each be independently replaced with —O—, —S—, —CO—, —COO—, —OCO—, —CO—S—, —S—CO—, —O—CO—O—, —CO—NR⁰—, —NR⁰—CO—, —CH═CH—COO—, —CH═CH—OCO—, —COO—CH═CH—, —OCO—CH═CH—, —CH═CH—, —N═N—, —CR⁰═N—, —N═CR^{°} —, —CH═N—N═CH—, —CF═CF—, or —C≡C— (wherein in the formulae, R⁰ represents a hydrogen atom or an alkyl group having 1 to 8), any hydrogen atom in the alkyl group may be replaced with a fluorine atom, when a plurality of L's in the compound are present, they may be the same or different, when a plurality of A²¹²'s are present, they may be the same or different,
Z²¹¹ represents —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, when a plurality of Z²¹¹'s are present, they may be the same or different,

m211 represents an integer of 1 to 3,

T²¹¹ represents a hydrogen atom, a —OH group, a —SH group, a —CN group, a —COOH group, a —NH₂ group, a —NO₂ group, a —COCH₃ group, a —O(CH₂)ₙCH₃, or —(CH₂)ₙCH₃, and n represents an integer of 0 to 20).

The polymerizable liquid crystal composition preferably contains a chiral compound as a fourth component.

In general formula (I-2), each of P¹²¹ and P¹²² independently represents a polymerizable functional group, preferably a group selected from the group consisting of formulae (P-1) to (P-17) below.

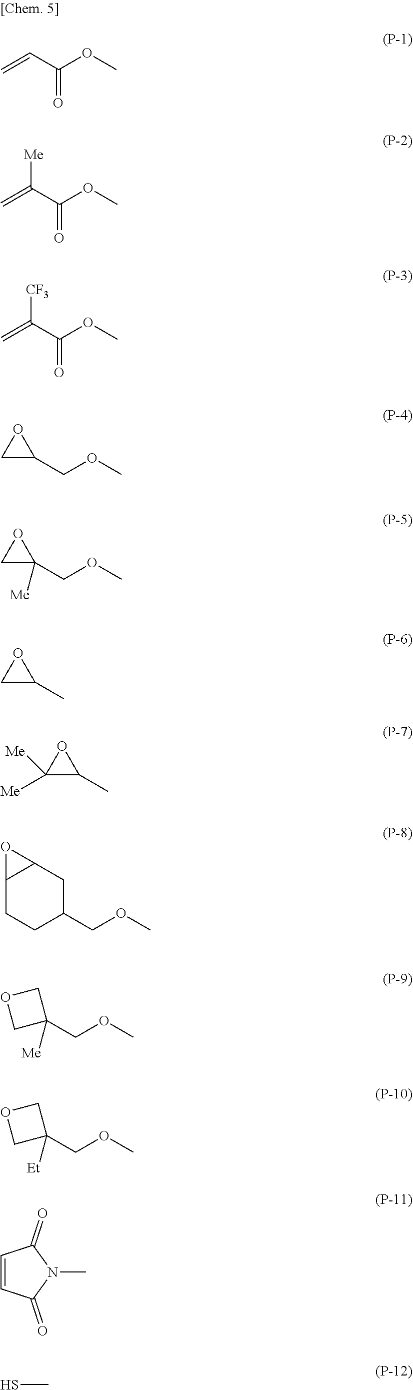

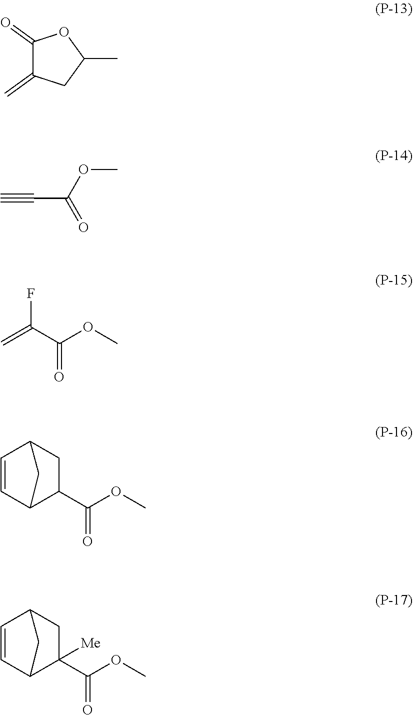

These polymerizable groups are polymerized by radical polymerization, radical addition polymerization, cationic polymerization or anionic polymerization. In particular, in the case where ultraviolet polymerization is used as a polymerization method, formula (P-1), (P-2), (P-3), (P-4), (P-8), (P-10), (P-12), or (P-15) is preferred. Formula (P-1), (P-2), (P-3), (P-4), (P-8), or (P-10) is more preferred. Formula (P-1), (P-2), or (P-3) is even more preferred. Formula (P-1) or (P-2) is particularly preferred.

In general formula (I-2), each of Sp¹²¹ and Sp¹²² preferably independently represents an alkylene group having 1 to 15 carbon atoms. One —CH₂— or two or more non-adjacent —CH₂-'s in the alkylene group may each be independently replaced with —COO—, —OCO—, or —OCO—O—. One or two or more hydrogen atoms in the alkylene group may each be replaced with a halogen atom (preferably, a fluorine atom, a chlorine atom, a bromine atom, or an iodine atom) or a CN group. Each of Sp¹¹ and Sp¹² preferably independently represents an alkylene group having 1 to 12 carbon atoms. One —CH₂— or two or more non-adjacent —CH₂-'s in the alkylene group may each be independently replaced with —O—, —COO—, —OCO—, or —OCO—O—.

In general formula (I-2), each of X¹²¹ and X¹²² preferably independently represents —O—, —OCH₂—, —CH₂O—, —CO—, —COO—, —OCO—, —O—CO—O—, —CO—NH—, —NH—CO—, —CF₂O—, —OCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C═C—, or a single bond. Each of X¹²¹ and X¹²² more preferably independently represents —O—, —OCH₂—, —CH₂O—, —CO—, —COO—, —OCO—, —O—CO—O—, —CF₂O—, —OCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —CF═CF—, —C═C—, or a single bond.

MG¹²² represents a mesogen group represented by general formula (I-2-b):

[Chem. 6]

-(A1-Z1)ᵣ₁-A2-Z2-A3- (I-2-b)

wherein in general formula (I-2-b), A1, A2, and A3 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group-, a 1,2,3,4-a tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, or a fluorene-2,7-diyl group, and may each have, as substituents L², one or more of F, Cl, CF₃, OCF₃, CN group, an alkyl group having 1 to 8 carbon atoms, an alkoxy group having 1 to 8 carbon atoms, an alkanoyl group having 1 to 8 carbon atoms, an alkanoyloxy group having 1 to 8 carbon atoms, an alkoxycarbonyl group having 1 to 8 carbon atoms, an alkenyl group having 2 to 8 carbon atoms, an alkenyloxy group having 2 to 8 carbon atoms, an alkenoyl group having 2 to 8 carbon atoms, and an alkenoyloxy group having 2 to 8 carbon atoms,

Z1 and Z2 each independently represent —COO—, —OCO—, —CH₂CH₂—, —OCH₂—, —CH₂O—, —CH═CH—, —C≡C—, —CH═CHCOO—, —OCOCH═CH—, —CH₂CH₂COO—, —CH₂CH₂OCO—, —COOCH₂CH₂—, —OCOCH₂CH₂—, —C═N—, —N═C—, —CONH—, —NHCO—, —C(CF₃)₂—, an alkyl group that has 2 to 10 carbon atoms and that may have a halogen atom (preferably, a fluorine atom, a chlorine atom, a bromine atom, or an iodine atom), or a single bond, each of Z1 and Z2 preferably independently represents —COO—, —OCO—, —CH₂CH₂—, —OCH₂—, —CH₂O—, —CH═CH—, —C≡C—, —CH═CHCOO—, —OCOCH═CH—, —CH₂CH₂COO—, —CH₂CH₂OCO—, —COOCH₂CH₂—, —OCOCH₂CH₂—, or a single bond, more preferably —COO—, —OCO—, —OCH₂—, —CH₂O—, —CH₂CH₂O—, —CH₂CH₂OCO—, —COOCH₂CH₂—, —OCOCH₂CH₂—, or a single bond, r1 represents 0, 1, 2, or 3, when a plurality of A1's and a plurality of Z1's are present, they may be the same or different. Of these, each of A1, A2, and A3 preferably independently represents a 1,4-phenylene group, a 1,4-cyclohexylene group, a 2,6-naphthylene group (the 1,4-phenylene group and the 2,6-naphthylene group may each have a substituent L²).

Examples of general formula (I-2) may include, but are not limited thereto, compounds represented by general formulae (I-2-1) to (I-2-4) below.

[Chem. 7]

P¹²¹-(Sp¹²¹-X¹²¹)_{q121}-A2-Z2-A3-(X¹²²-Sp¹²²)_{q122}-P¹²² (I-2-1)

P¹²¹-(Sp¹²¹-X¹²¹)_{q121}-A11-Z11-A2-Z2-A3-(X¹²²-Sp¹²²)_{q122}-P¹¹² (I-2-2)

P¹²¹-(Sp¹²¹-X¹²¹)_{q121}-A11-Z11-A12-Z12-A2-Z2-A3-(X¹²²-Sp¹²²)_{q122}-P¹²² (I-2-3)

P¹²¹-(Sp¹²¹-X¹²¹)_{q121}-A11-Z11-A12-Z12-A13-Z13-A2-Z2-A3-(X¹²²-Sp¹²²)_{q122}-P¹²² (I-2-4)

In the formulae, P¹²¹, Sp¹²¹, X¹²¹, q121, X¹²², Sp¹²², q122, and P¹²² are as defined in general formula (I-2).

A11, A12, A13, A2, and A3 are defined the same as A1 to A3 in general formula (I-2-b), and they may be the same or different.

Z11, Z12, Z13, and Z2 are defined the same as Z1 and Z2 in general formula (I-2-b), and they may be the same or different.

Among the compounds represented by general formulae (I-1-1-1) to (I-1-1-4), the compounds represented by general formulae (I-2-2) to (I-2-4) and each having three or more ring structures are preferably used because optically anisotropic products to be obtained exhibit good alignment. The Compound having three ring structures and represented by general formula (I-2-2) is particularly preferably used.

Examples of the compounds represented by general formulae (I-2-1) to (I-2-4) include, but are not limited to, compounds represented by general formulae (I-2-1-1) to (I-2-1-21).

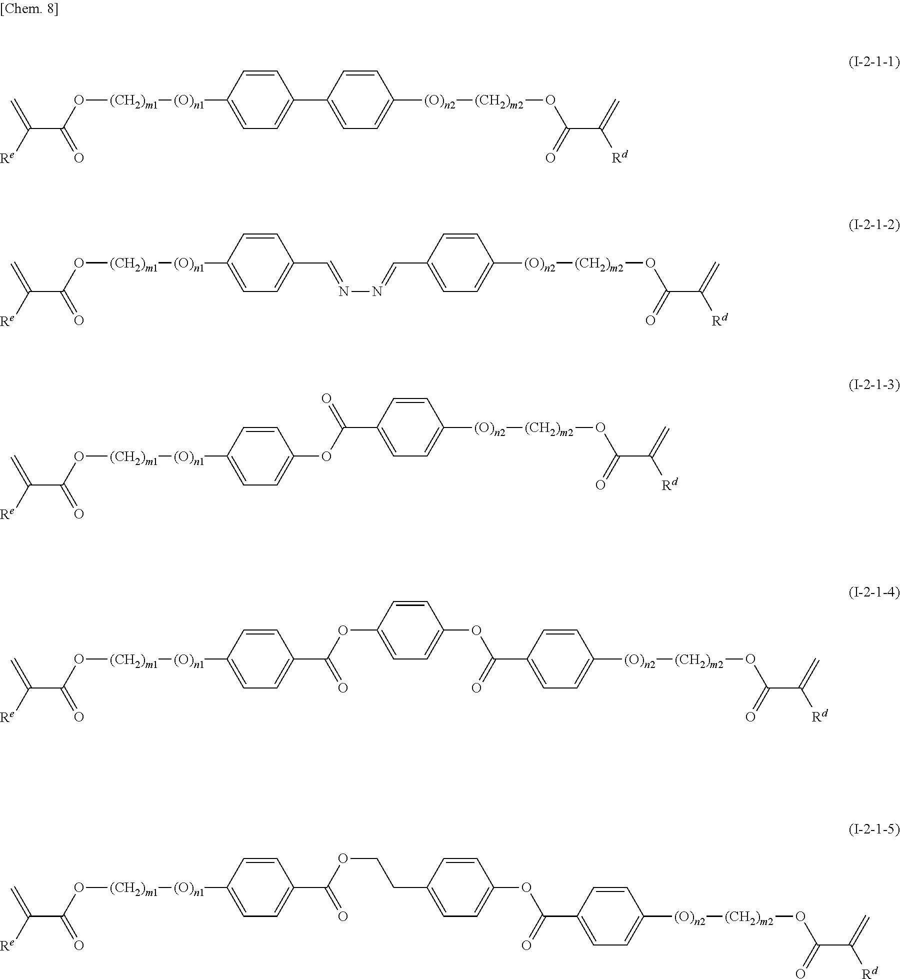

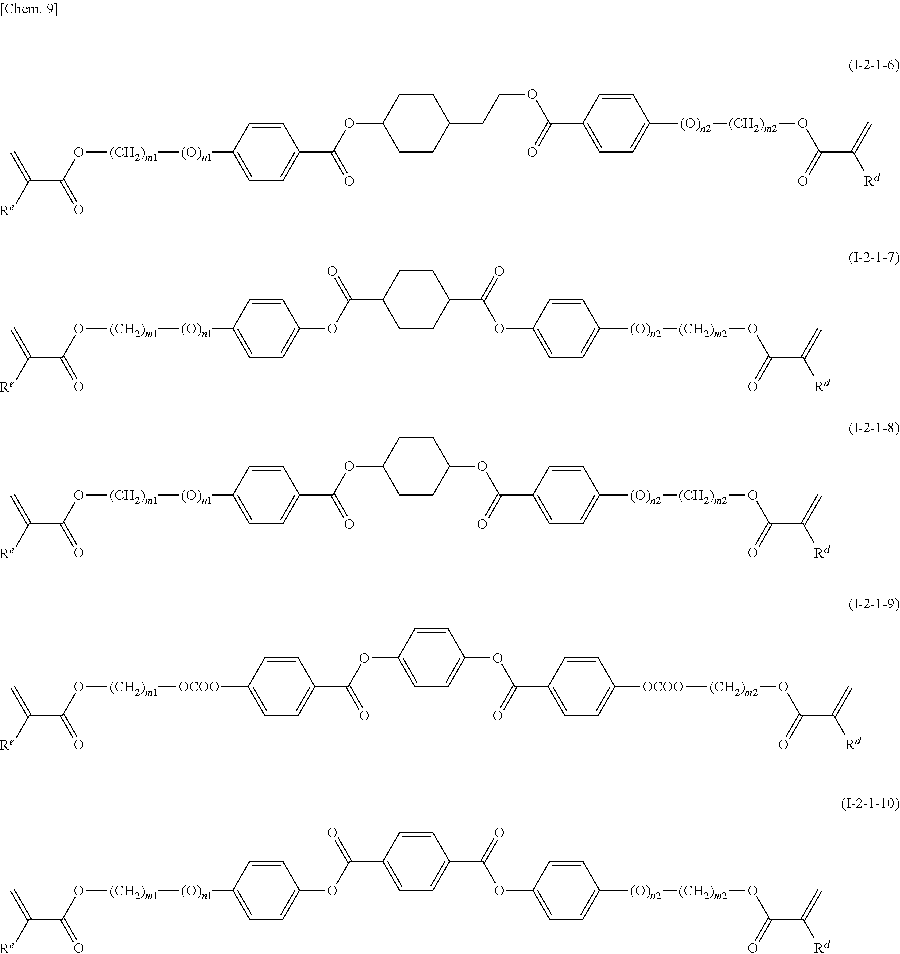

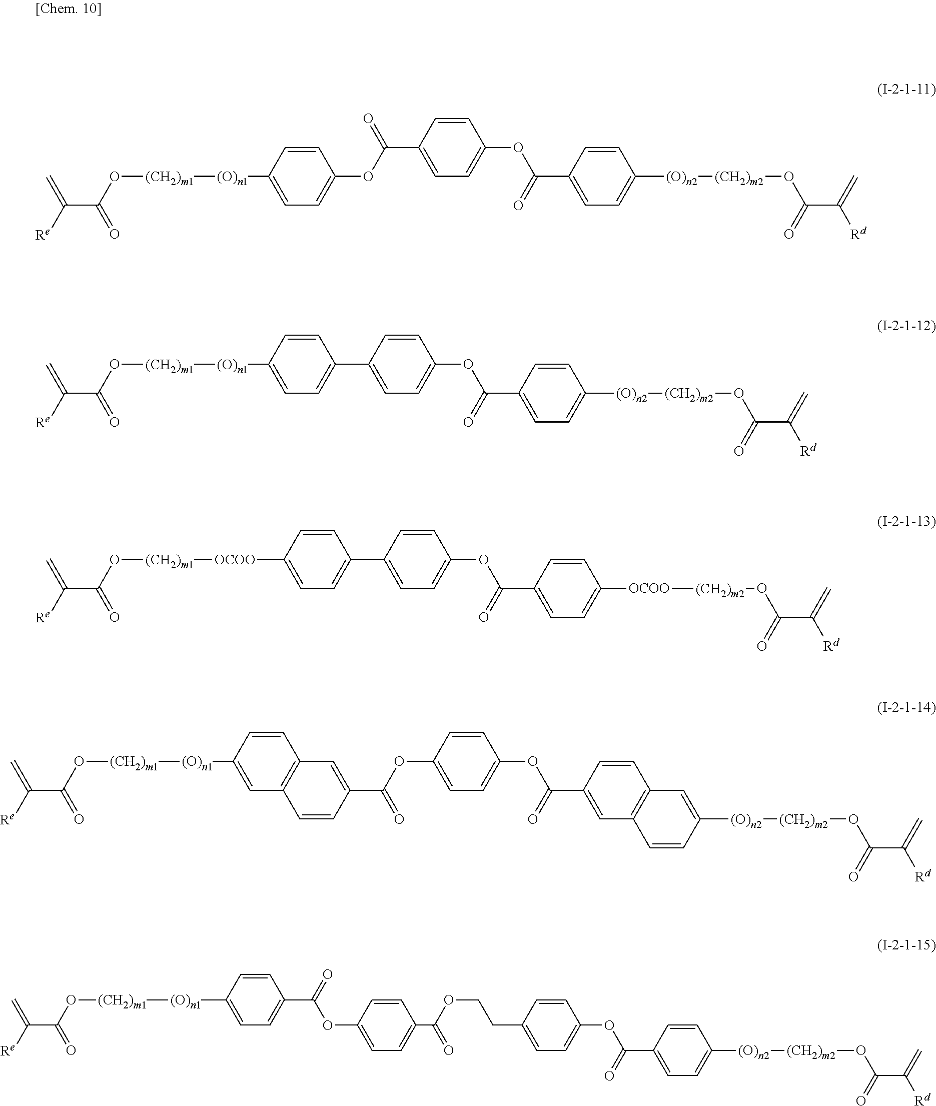

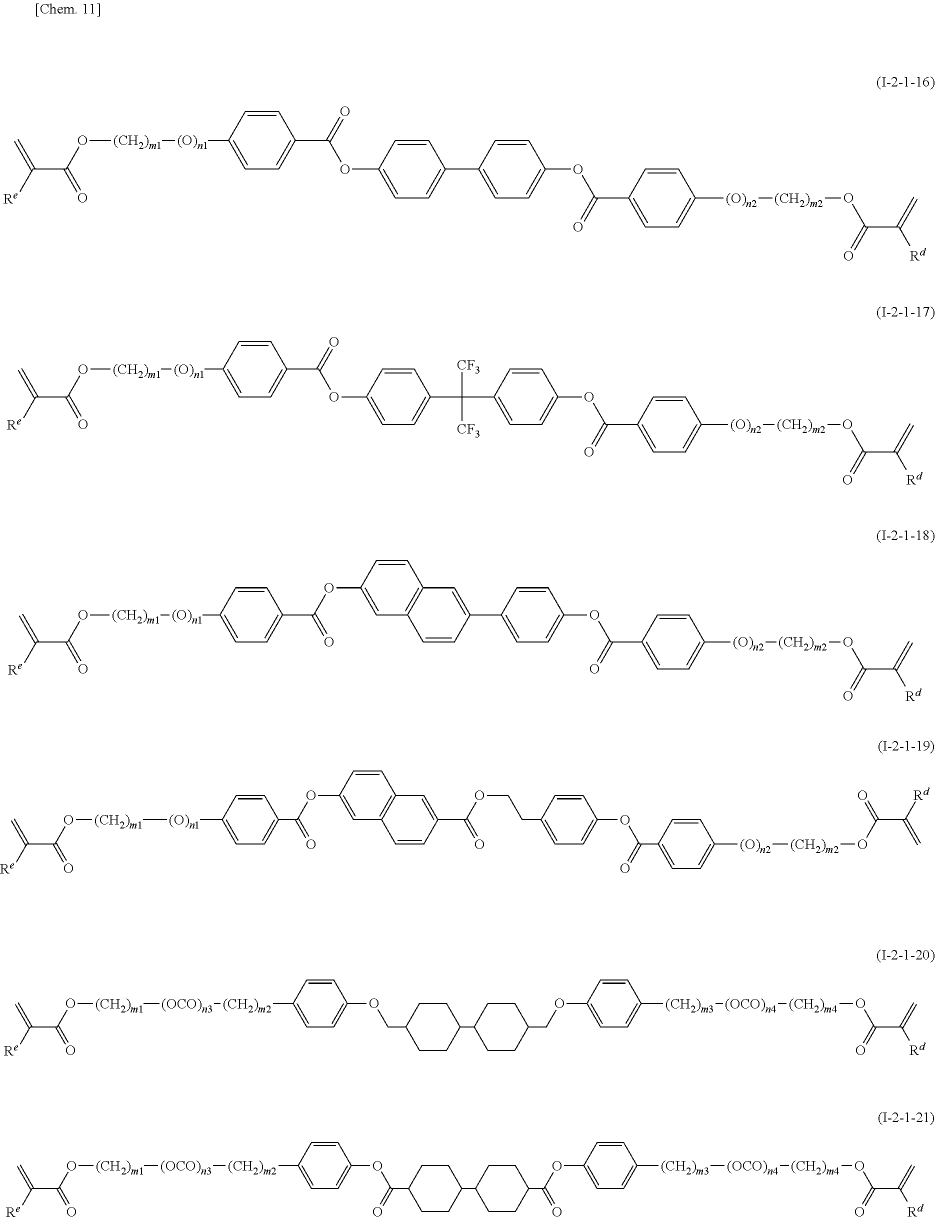

In general formulae (I-2-1-1) to (I-2-1-21), each R^{d} and each R^{e} each independently represent a hydrogen atom or a methyl group.

Each of the cyclic groups may have, as substituents, one or more of F, Cl, CF₃, OCF₃, a CN group, an alkyl group having 1 to 8 carbon atoms, an alkoxy group having 1 to 8 carbon atoms, an alkanoyl group having 1 to 8 carbon atoms, an alkanoyloxy group having 1 to 8 carbon atoms, an alkoxycarbonyl group having 1 to 8 carbon atoms, an alkenyl group having 2 to 8 carbon atoms, an alkenyloxy group having 2 to 8 carbon atoms, an alkenoyl group having 2 to 8 carbon atoms, and an alkenoyloxy group having 2 to 8 carbon atoms.

m1, m2, m3, and m4 each independently represent an integer of 0 to 18, preferably an integer of 0 to 8. n1, n2, n3, and n4 each independently represent 0 or 1.

One or two or more bifunctional polymerizable liquid crystal compounds represented by general formula (I-2) may be used. The total amount of the bifunctional polymerizable liquid crystal compounds represented by general formula (I-2) contained is preferably 0% to 50% by mass, more preferably 0% to 30% by mass based on the total amount of the polymerizable liquid crystal compounds used in the polymerizable liquid crystal composition. In the case where a chiral compound is added to the polymerizable liquid crystal composition, a compound having an asymmetric structure or a substituent-containing mesogen skeleton portion is preferred in order to easily develop a twisted nematic phase or a cholesteric phase. The compound is particularly preferably contained in an amount of 0% to 20% by mass based on the total amount of the polymerizable liquid crystal compound used in the polymerizable liquid crystal composition. Specifically, also in the case where the compounds represented by general formulae (I-2-1) to (I-2-4), more specifically, the compounds represented by general formulae (I-2-1-1) to (I-2-1-21), are used, the compounds are preferably contained in the percentage.

Specific examples of the compounds represented by general formulae (I-2-1-1) to (I-2-1-21) include, but are not limited to, compounds represented by general formulae (I-2-2-1) to (I-2-2-24) below.

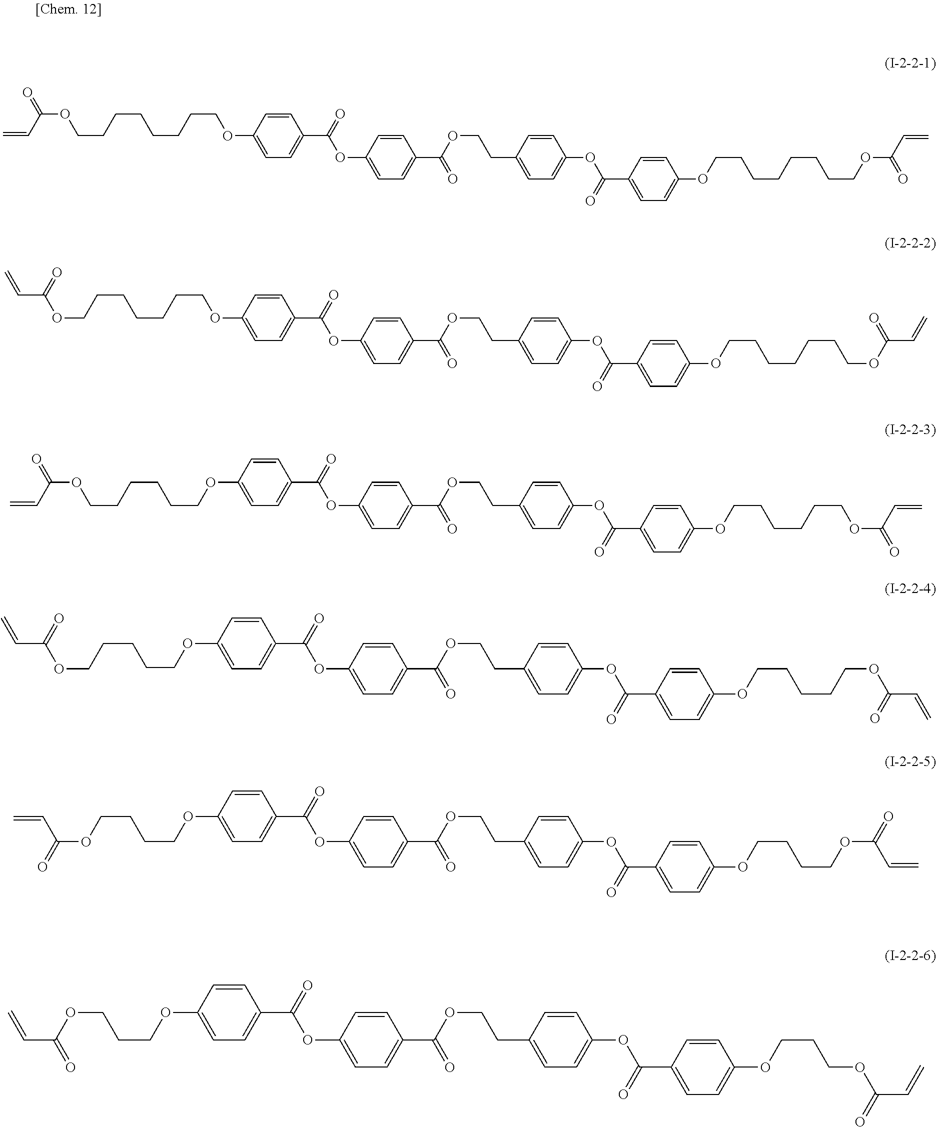

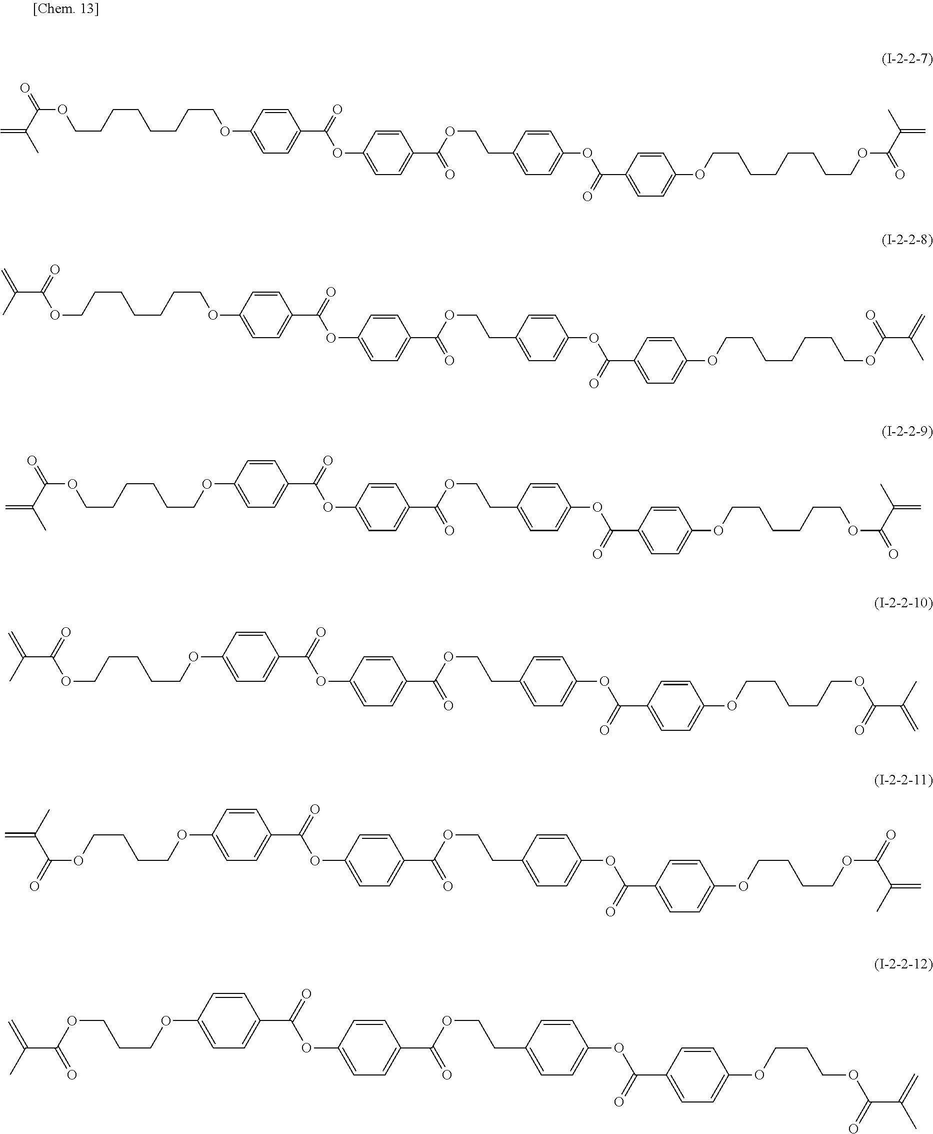

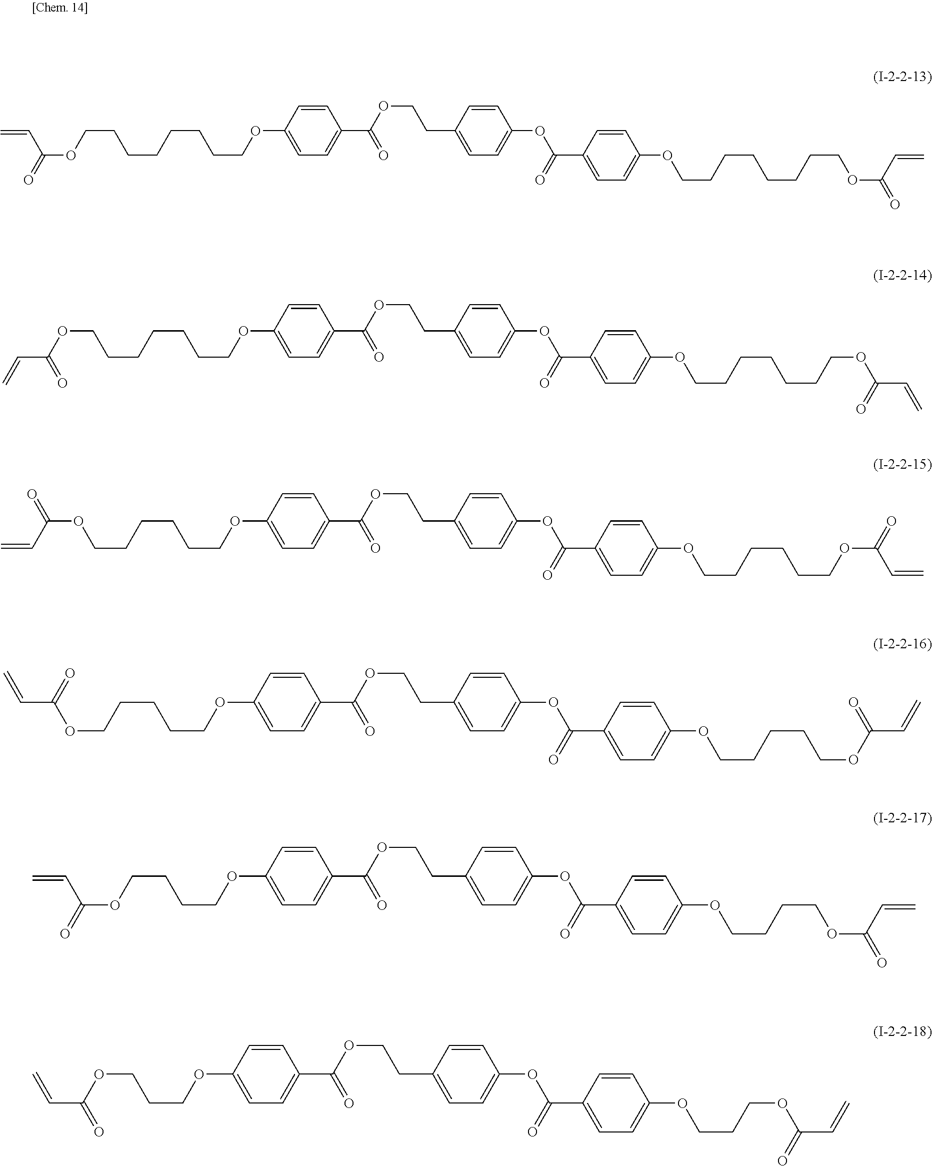

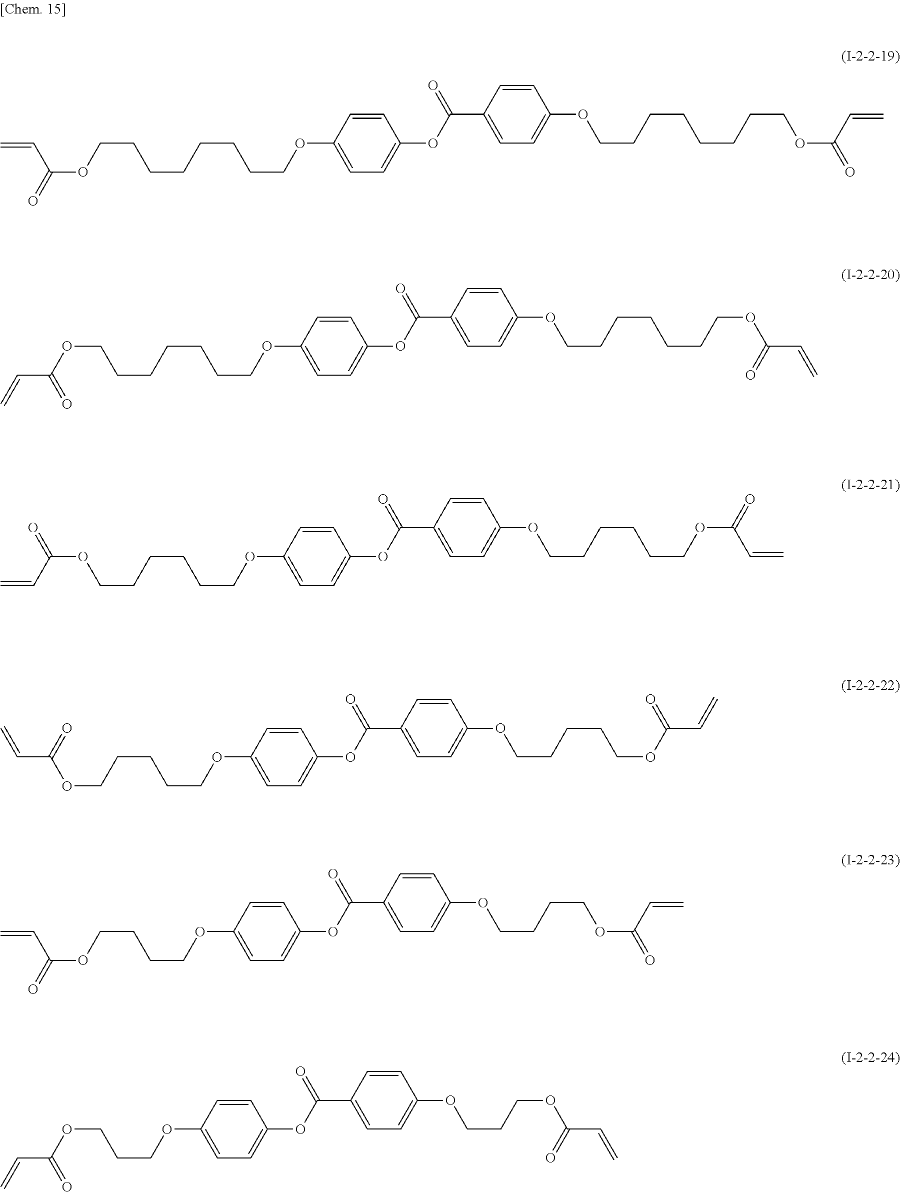

One or two or more bifunctional polymerizable liquid crystal compounds represented by general formula (I-2) may be used. The total amount of the bifunctional polymerizable liquid crystal compounds represented by general formula (I-2) is preferably 5% to 50% by mass, more preferably 5% to 40% by mass, particularly preferably 5% to 30% by mass, most preferably 5% to 20% by mass in view of adhesion and heat resistance.

Specifically, the compounds represented by general formula (I-2) are preferably compounds represented by formulae (I-1-1) to (I-1-7) below.

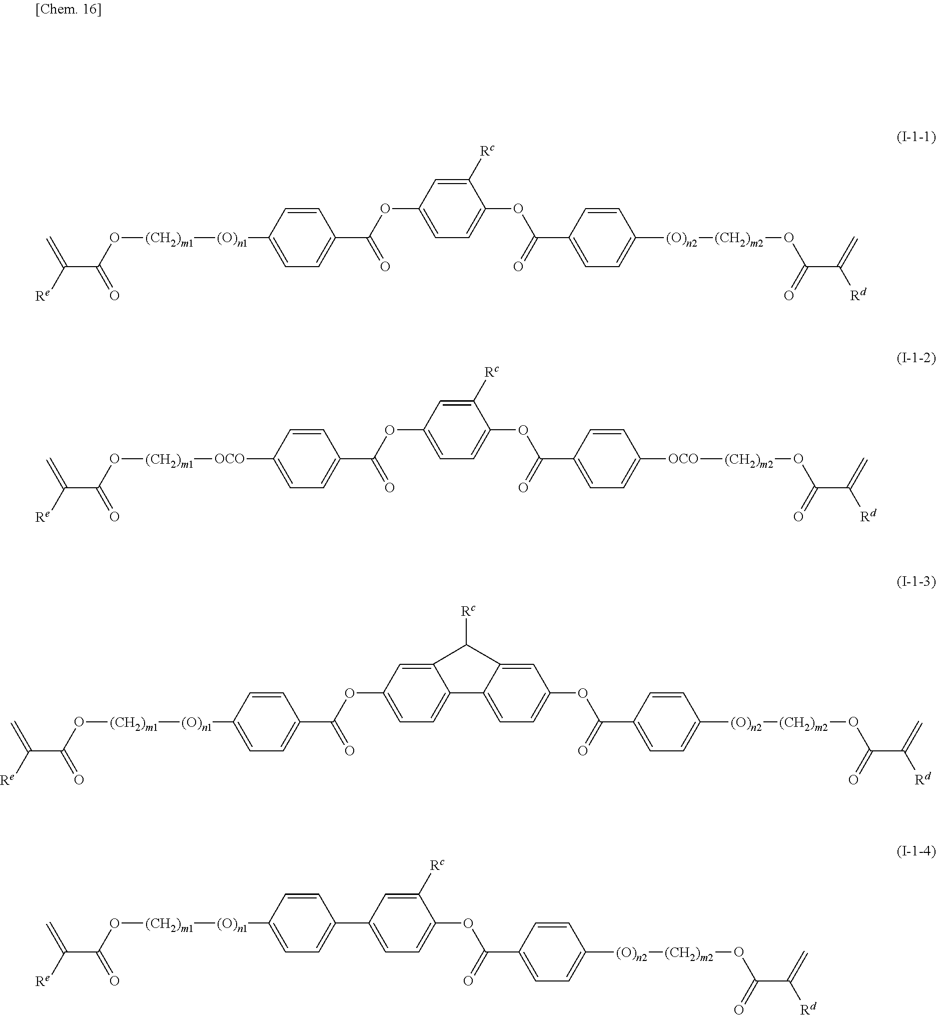

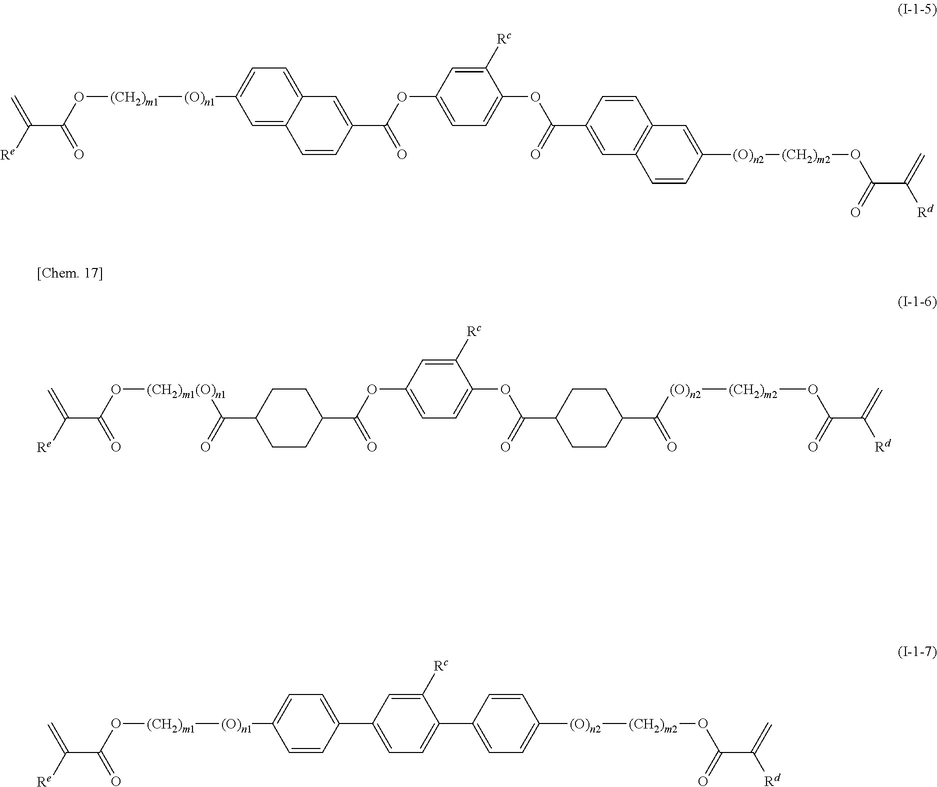

(wherein in general formulae (I-1-1) to (I-1-7), each R^{e} and each R^{d} each independently represent a hydrogen atom or a methyl group, m1 and m2 each independently represent an integer of 0 to 8, n1 and n2 each independently represent 0 or 1, when m1=0, n1=0, and when m2=0, n2=0).

Among general formulae (I-1-1) to (I-1-7), a compound represented by general formula (I-1-1) is most preferred.

One or two or more bifunctional polymerizable liquid crystal compounds represented by general formula (I-2) may be used. The total amount of the bifunctional polymerizable liquid crystal compounds represented by general formula (I-2) contained is preferably 5% to 50% by mass, more preferably 5% to 40% by mass, particularly preferably 5% to 30% by mass, most preferably 5% to 20% by mass based on the total amount of the polymerizable liquid crystal compounds used in the polymerizable liquid crystal composition.

The polymerizable liquid crystal composition of the embodiment preferably contains the bifunctional polymerizable liquid crystal compound represented by general formula (I-2). More preferably, the composition contains, as the second component, a monofunctional polymerizable liquid crystal compound represented by general formula (II-2) below together with the bifunctional polymerizable liquid crystal compound. This increases the compatibility of the polymerizable liquid crystal composition and reduces a change in selective reflection wavelength after exposure to high temperature when measurement is performed at a practical level of UV irradiation.

[Chem. 18]

P²²¹-Sp²²¹-X²²¹-MG²²¹-R²²¹ (II-2)

wherein in the formula, P²²¹ represents a polymerizable functional group, Sp²²¹ represents an alkylene group having 1 to 18 carbon atoms, one —CH₂— or two or more non-adjacent —CH₂-'s in the alkylene group may each be independently replaced with —O—, —COO—, —OCO—, or —OCO—O—, one or two or more hydrogen atoms in the alkylene group may each be replaced with a halogen atom (a fluorine atom, a chlorine atom, a bromine atom, or an iodine atom) or a CN group, X²²¹ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that in P²²¹-Sp²²¹, and Sp²²¹-X²²¹, no direct bond between heteroatoms other than C or H is included), MG²²¹ represents a mesogen group, R²²¹ represents a hydrogen atom, a halogen atom (a fluorine atom, a chlorine atom, a bromine atom, or an iodine atom), a cyano group, a linear or branched alkyl group having 1 to 12 carbon atoms, a linear or branched alkenyl group having 1 to 12 carbon atoms, one —CH₂— or two or more non-adjacent —CH₂-'s in the alkyl group and the alkenyl group may each be independently replaced with —O—, —S—, —CO—, —COO—, —OCO—, —CO—S—, —S—CO—, —O—CO—O—, —CO—NH—, —NH—CO—, —NH—, —N(CH₃)—, —CH═CH—COO—, —CH═CH—OCO—, —COO—CH═CH—, —OCO—CH═CH—, —CH═CH—, —CF═CF—, or —C≡C—, one or two or more hydrogen atoms in the alkyl group and the alkenyl group may each be independently replaced with a halogen atom (a fluorine atom, a chlorine atom, a bromine atom, or an iodine atom) or a cyano group, and when the two or more hydrogen atoms are replaced with substituents, the substituents may be the same or different.

In general formula (II-2), P²²¹ represents a polymerizable functional group, preferably a group selected from formulae (P-1) to (P-17) above. These polymerizable groups are polymerized by radical polymerization, radical addition polymerization, cationic polymerization, or anionic polymerization. In particular, in the case where ultraviolet polymerization is used as a polymerization method, formula (P-1), (P-2), (P-3), (P-4), (P-8), (P-10), (P-12), or (P-15) is preferred. Formula (P-1), (P-2), (P-3), (P-4), (P-8), or (P-10) is more preferred. Formula (P-1), (P-2), or formula (P-3) is even more preferred. Formula (P-1) or (P-2) is particularly preferred.

In general formula (II-2), Sp²²¹ preferably represents an alkylene group having 1 to 8 carbon atoms. One —CH₂— or two or more non-adjacent —CH₂-'s in the alkylene group may each be independently replaced with —O—, —COO—, —OCO—, or —OCO—O—. One or two or more hydrogen atoms in the alkylene group may each be replaced with a halogen atom (a fluorine atom, a chlorine atom, a bromine atom, or an iodine atom) or a CN group.

In general formula (II-2), X²²¹ preferably represents —O—, —OCH₂—, —CH₂O—, —CO—, —COO—, —OCO—, —O—CO—O—, —CO—NH—, —NH—CO—, —CF₂O—, —OCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond. X²²¹ more preferably represents —O—, —OCH₂—, —CH₂O—, —CO—, —COO—, —OCO—, —O—CO—O—, —CF₂O—, —OCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —CF═CF—, —C═C—, or a single bond.

In general formula (II-2), MG²²¹ represents a mesogen group represented by general formula (II-2-b):

[Chem. 19]

-(A1-Z1)ᵣ₁-A2-Z2-A3- (II-2-b)

(wherein in formula, A1, A2, and A3 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group, a 1,2,3,4-a tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, a fluorene-2,7-diyl group, a cholesteryl group, or a cholestaryl group, and may each have, as substituents L², one or more of F, Cl, CF₃, OCF₃, a CN group, an alkyl group having 1 to 8 carbon atoms, an alkoxy group having 1 to 8 carbon atoms, an alkanoyl group having 1 to 8 carbon atoms, an alkanoyloxy group having 1 to 8 carbon atoms, an alkoxycarbonyl group having 1 to 8 carbon atoms, an alkenyl group having 2 to 8 carbon atoms, an alkenyloxy group having 2 to 8 carbon atoms, an alkenoyl group having 2 to 8 carbon atoms, and an alkenoyloxy group having 2 to 8 carbon atoms. Of these, each of A1 to A3 preferably independently represent a 1,4-phenylene group, a 1,4-cyclohexylene group, or a 2,6-naphthylene group, which may have the substituent L². The substituent L² is preferably F, an alkyl group having 1 to 8 carbon atoms, or an alkoxy group having 1 to 8 carbon atoms.

In general formula (II-2), R²²¹ preferably represents a hydrogen atom, a halogen atom (a fluorine atom, a chlorine atom, a bromine atom, or an iodine atom), a cyano group, a linear or branched alkyl group having 1 to 8 carbon atoms, or a linear or branched alkenyl group having 1 to 8 carbon atoms. One —CH₂— or two or more non-adjacent —CH₂-'s in the alkyl group and the alkenyl group may each be independently replaced with —O—, —CO—, —COO—, —OCO—, —O—CO—O—, —CH═CH—COO—, —CH═CH—OCO—, —COO—CH═CH—, —OCO—CH═CH—, —CH═CH—, or —C≡C—. One or two or more hydrogen atoms in the alkyl group and the alkenyl group may each be independently replaced with a halogen atom (a fluorine atom, a chlorine atom, a bromine atom, or an iodine atom) or a cyano group. When the two or more hydrogen atoms are replaced with substituents, the substituents may be the same or different.

Examples of general formula (II-2) include, but are not limited to, compounds represented by general formulae (II-2-1) to (II-2-4) below.

[Chem. 20]

P²²¹-Sp²²¹-X²²¹-A2-Z2-A3-R²²¹ (II-2-1)

P²²¹-Sp²²¹-X²²¹-A11-Z11-A2-Z2-A3-R²²¹ (II-2-2)

P²²¹-Sp²²¹-X²²¹-A11-Z11-A12-Z12-A2-Z2-A3-R²²¹ (II-2-3)

P²²¹-Sp²²¹-X²²¹-A11-Z11-A12-Z12-A13-Z13-A2-Z2-A3-R²²¹ (II-2-4)

In the formulae, P²²¹, Sp²²¹, X²²¹, and R²²¹ are as defined in general formula (II-2).

A11, A12, A13, A2, and A3 are defined the same as A1 to A3 in general formula (II-2-b), and they may be the same or different.

Z11, Z12, Z13, and Z2 are defined the same as Z1 to Z3 in general formula (II-2-b), and they may be the same or different.

Examples of the compounds represented by general formulae (II-2-1) to (II-2-4) include, but are not limited to, compound represented by general formulae (II-2-1-1) to (II-2-1-26)

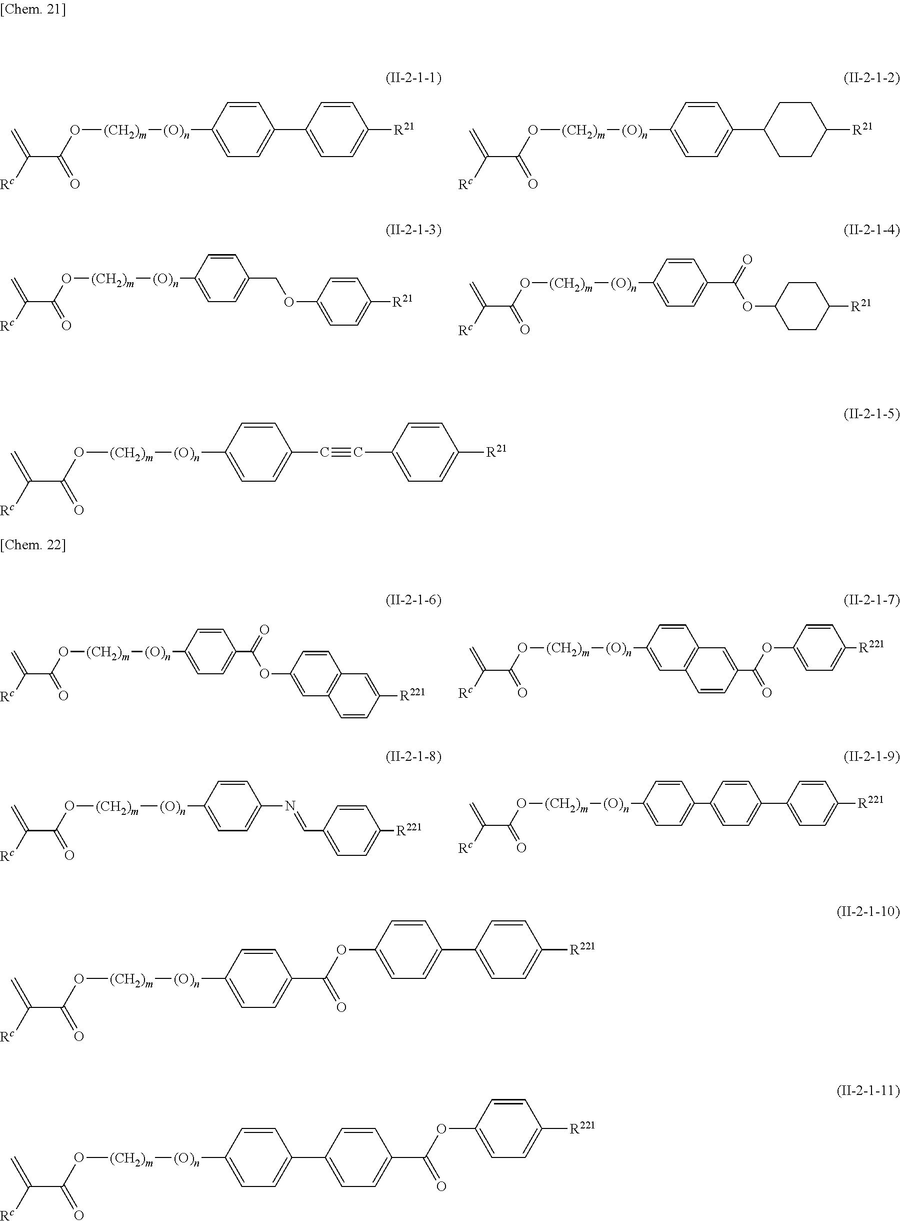

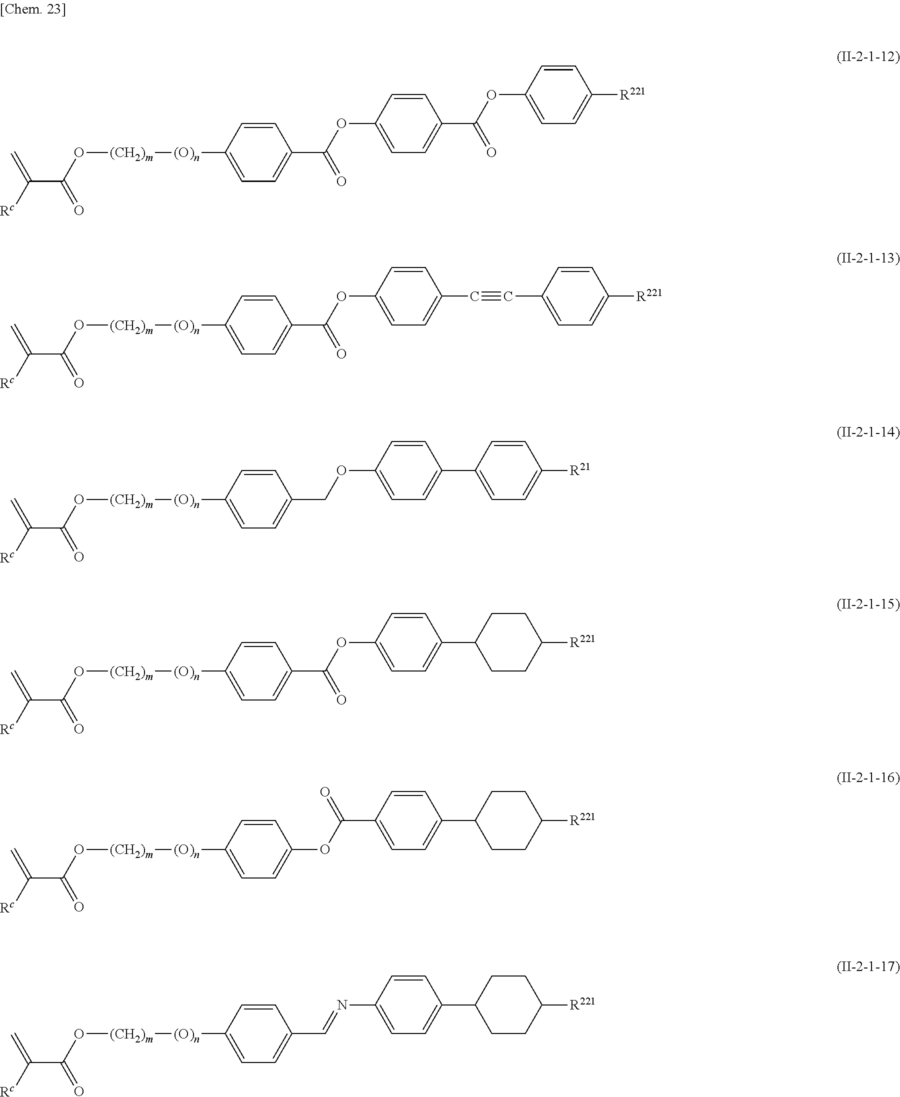

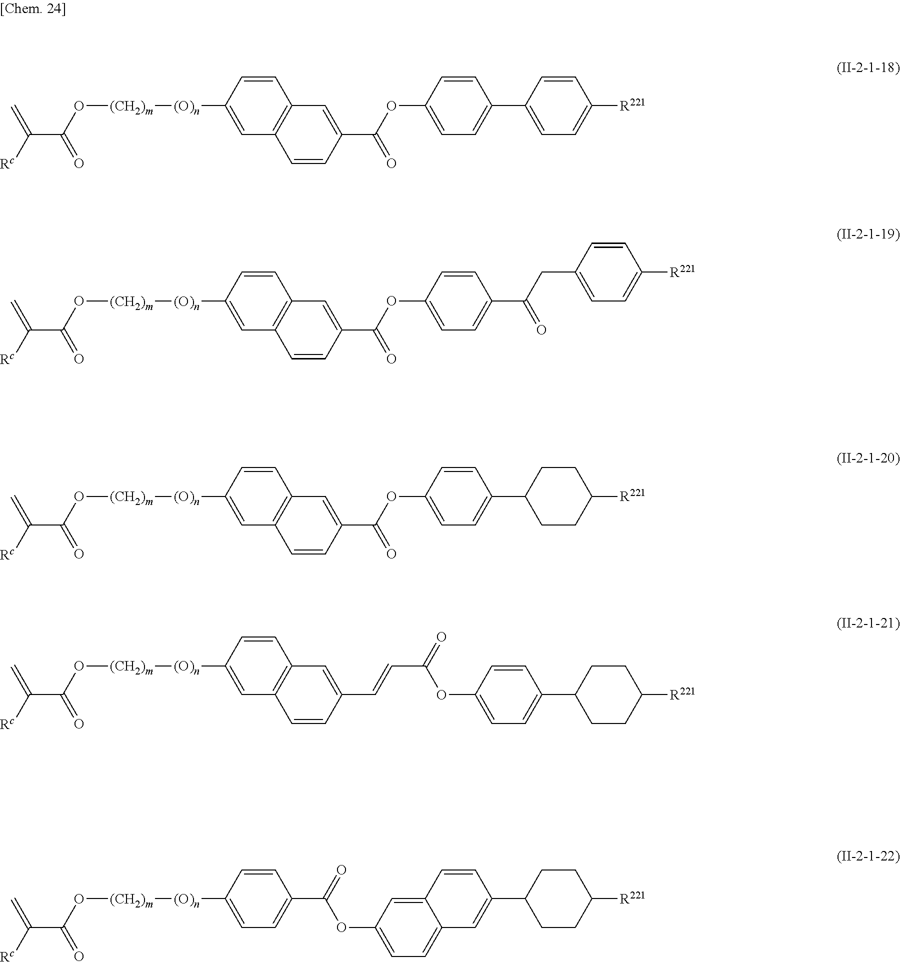

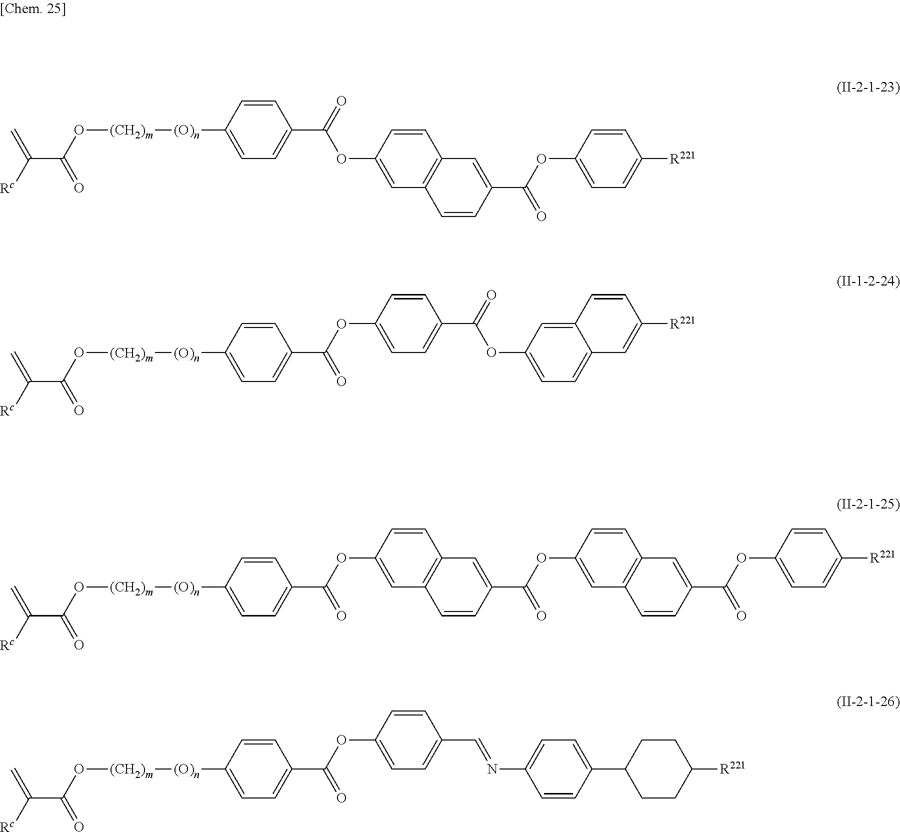

In general formulae (II-2-1-1) to (II-2-1-26), each R^{c} represents a hydrogen atom or a methyl group. Each m represents an integer of 1 to 8. Each n represents 0 or 1. Each R²²¹ is as defined in general formulae (II-2-1) to (II-2-4). Each R²²¹ preferably represents a hydrogen atom, a halogen atom (a fluorine atom, a chlorine atom, a bromine atom, or an iodine atom), a cyano group, a linear alkyl group that has 1 to 6 carbon atoms, or a linear alkenyl group having 1 to 6, in which one —CH₂— may be replaced with —O—, —CO—, —COO—, or —OCO—.

In general formulae (II-2-1-1) to (II-2-1-26), each of the cyclic groups may have, as substituents, one or more of F, Cl, CF₃, OCF₃, a CN group, an alkyl group having 1 to 8 carbon atoms, an alkoxy group having 1 to 8 carbon atoms, an alkanoyl group having 1 to 8 carbon atoms, an alkanoyloxy group having 1 to 8 carbon atoms, an alkoxycarbonyl group having 1 to 8 carbon atoms, an alkenyl group having 2 to 8 carbon atoms, an alkenyloxy group having 2 to 8 carbon atoms, an alkenoyl group having 2 to 8 carbon atoms, and an alkenoyloxy group having 2 to 8 carbon atoms.

One or two or more monofunctional polymerizable liquid crystal compounds represented by (II-2) may be used. The total amount of the monofunctional polymerizable liquid crystal compounds represented by general formula (II-2) contained is preferably 30% to 90% by mass, more preferably 40% to 90% by mass, particularly preferably 45% to 90% by mass, most preferably 50% to 90% by mass based on the total amount of the polymerizable liquid crystal compounds used in the polymerizable liquid crystal composition.

In this embodiment, the monofunctional polymerizable liquid crystal compound represented by general formula (II-1) is used as the third component, thereby further reducing the full width at half maximum (Δλ) at a wavelength selectively reflected and further increasing adhesion to the base material. Here, in the case of cholesteric liquid crystals having a selective reflection wavelength, the typical relationship between the selective reflection wavelength (λ) and the helical pitch (p) is represented by the relationship λ=p·N (where N is an average refractive index of a cholesteric liquid crystal composition). The full width at half maximum (Δλ) at a wavelength selectively reflected is represented by the product of the birefringence anisotropy (Δn) of the polymerizable liquid crystal composition and p. For example, when only a specific wavelength is selectively reflected, the width (Δλ) at the wavelength selectively reflected is desirably reduced. In general formula (II-1), a polymerizable liquid crystal compound containing one polymerizable functional group directly linked to a cyclic group without using a spacer group is contained. Thus, when the polymerizable liquid crystal composition is polymerized, mesogen skeleton portions present in the polymerizable liquid crystal compound represented by each general formula are partially uneven in orientation, thereby providing a polymer with low orientational order. Thus, the birefringence anisotropy (Δn) can be kept low, and the width (Δλ) of the wavelength selectively reflected can be reduced.

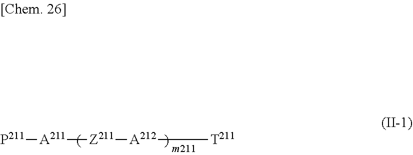

(wherein in general formula (II-1), P²¹¹ represents a polymerizable functional group, A²¹¹ and A²¹² each independently represent a 1,4-phenylene group, a 1,4-cyclohexylene group, a bicyclo[2.2.2]octane-1,4-diyl group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group, these groups may be unsubstituted or substituted with one or more substituents L,

each L represents a fluorine atom, a chlorine atom, a bromine atom, an iodine atom, a pentafluorosulfuranyl group, a nitro group, a cyano group, an isocyano group, an amino group, a hydroxy group, a mercapto group, a methylamino group, a dimethylamino group, a diethylamino group, a diisopropylamino group, a trimethylsilyl group, a dimethylsilyl group, a thioisocyano group, an optionally substituted phenyl group, an optionally substituted phenylalkyl group, an optionally substituted cyclohexylalkyl group, or a linear or branched alkyl group having 1 to 20 carbon atoms, one —CH₂— or two or more non-adjacent —CH₂-'s in the alkyl group may each be independently replaced with —O—, —S—, —CO—, —COO—, —OCO—, —CO—S—, —S—CO—, —O—CO—O—, —CO—NR⁰—, —NR⁰—CO—, —CH═CH—COO—, —CH═CH—OCO—, —COO—CH═CH—, —OCO—CH═CH—, —CH═CH—, —N═N—, —CR⁰═N—, —N═CR⁰—, —CH═N—N═CH—, —CF═CF—, or —C≡C— (wherein in the formulae, R⁰ represents a hydrogen atom or an alkyl group having 1 to 8), any hydrogen atom in the alkyl group may be replaced with a fluorine atom, when a plurality of L's in the compound are present, they may be the same or different, when a plurality of A²¹²'s are present, they may be the same or different,

Z²¹¹ represents —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond, when a plurality of Z²¹¹'s are present, they may be the same or different,

m211 represents an integer of 1 to 3,

T²¹¹ represents a hydrogen atom, a —OH group, a —SH group, a —CN group, a —COOH group, a —NH₂ group, a —NO₂ group, a —COCH₃ group, a —O(CH₂)ₙCH₃, or —(CH₂)ₙCH₃, and n represents an integer of 0 to 20).

In general formula (II-1), P²¹¹ represents a polymerizable functional group, preferably a group selected from formulae (P-1) to (P-17) above. These polymerizable groups are polymerized by radical polymerization, radical addition polymerization, cationic polymerization, or anionic polymerization. In particular, in the case where ultraviolet polymerization is used as a polymerization method, formula (P-1), (P-2), (P-3), (P-4), (P-8), (P-10), (P-12), or (P-15) is preferred. Formula (P-1), (P-2), (P-3), (P-4), (P-8), or (P-10) is more preferred. Formula (P-1), (P-2), or (P-3) is even more preferred. Formula (P-1) or (P-2) is particularly preferred.

In general formula (II-1), A²¹¹ and A²¹² each independently represent a 1,4-phenylene group, a 1,4-cyclohexylene group, a bicyclo[2.2.2]octane-1,4-diyl group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group. These groups may be unsubstituted or substituted with one or more substituents L. In view of ease of synthesis, ease of availability of raw materials, and liquid crystallinity, A²¹¹ and A²¹² preferably each independently represent unsubstituted or a 1,4-phenylene group, a 1,4-cyclohexylene group, a bicyclo[2.2.2]octane-1,4-diyl group, a naphthalene-2,6-diyl group, or a naphthalene-1,4-diyl group optionally substituted with one or more substituents L, and more preferably independently represents a group selected from formulae (A-1) to (A-16) below.

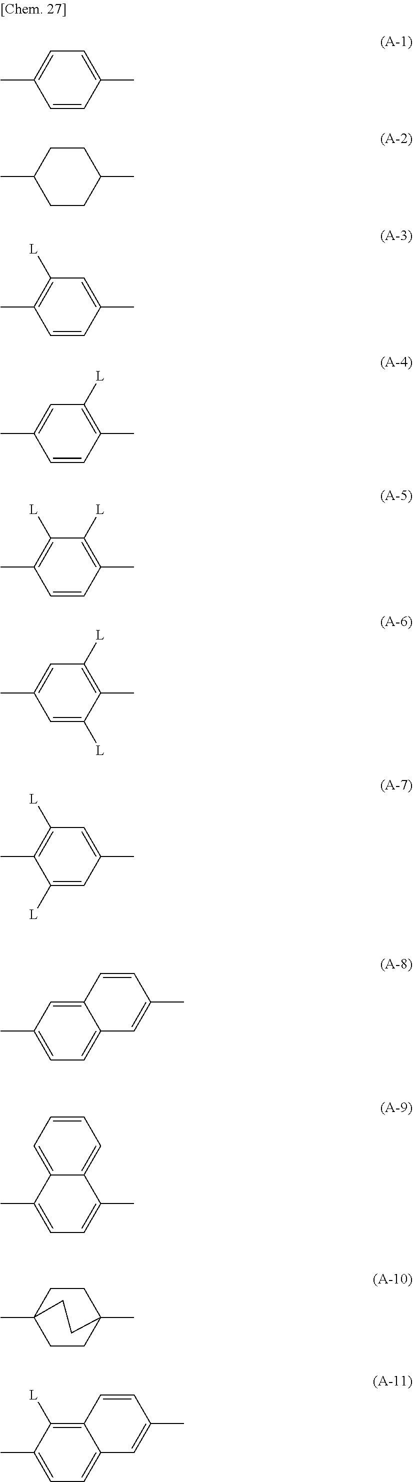

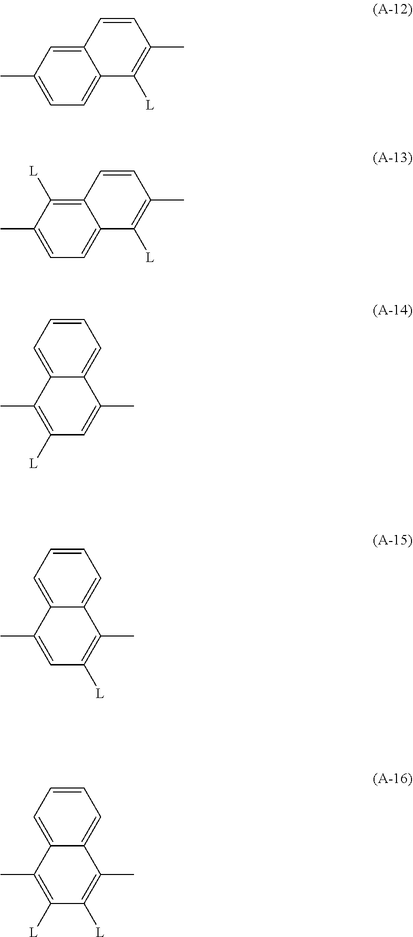

Additionally, from the viewpoint of achieving low refractive index anisotropy, it is more preferable that at least one of A²¹ and A²¹² represent a group selected from formula (A-2) or (A-10) and the remaining groups independently represent a group selected from formulae (A-1) to (A-7) and formula (A-10). It is even more preferable that at least one of A²¹¹ and A²¹² represent a group represented by formula (A-2) and the remaining groups independently represent a group selected from formulae (A-1) to (A-7). It is particularly preferable that at least one of A²¹¹ and A²¹² represent a group represented by formula (A-2) and the remaining groups independently represent a group selected from formulae (A-1) to (A-4). When a plurality of A²¹²'s are present, they may be the same or different.

In general formula (II-1), each L represents a fluorine atom, a chlorine atom, a bromine atom, an iodine atom, a pentafluorosulfuranyl group, a nitro group, a cyano group, an isocyano group, an amino group, a hydroxy group, a mercapto group, a methylamino group, a dimethylamino group, a diethylamino group, a diisopropylamino group, a trimethylsilyl group, a dimethylsilyl group, a thioisocyano group, an optionally substituted phenyl group, an optionally substituted phenylalkyl group, an optionally substituted cyclohexylalkyl group, or a linear or branched alkyl group having 1 to 20 carbon atoms, one —CH₂— or two or more non-adjacent —CH₂-'s in the alkyl group may each be independently replaced with —O—, —S—, —CO—, —COO—, —OCO—, —CO—S—, —S—CO—, —O—CO—O—, —CO—NR⁰—, —NR⁰—CO—, —CH═CH—COO—, —CH═CH—OCO—, —COO—CH═CH—, —OCO—CH═CH—, —CH═CH—, —N═N—, —CR⁰═N—, —N═CR⁰—, —CH═N—N═CH—, —CF═CF—, or —C≡C— (each R⁰ represents a hydrogen atom or an alkyl group having 1 to 8). Any hydrogen atom in the alkyl group may be replaced with a fluorine atom. When a plurality of L's are present in the compound, they may be the same or different. In view of liquid crystallinity and ease of synthesis, each substituent L preferably represents a fluorine atom, a chlorine atom, a pentafluorosulfuranyl group, a nitro group, a methylamino group, a dimethylamino group, a diethylamino group, a diisopropylamino group, or a linear or branched alkyl group having 1 to 20 carbon atoms, any hydrogen atom in the alkyl group being optionally replaced with a fluorine atom, one —CH₂— or two or more non-adjacent —CH₂-'s in the alkyl group each being optionally independently replaced with a group selected from —O—, —S—, —CO—, —COO—, —OCO—, —O—CO—O—, —CH═CH—, —CF═CF—, and —C≡C—. Each substituent L more preferably represents a fluorine atom, a chlorine atom, or a linear or branched alkyl group having 1 to 12 carbon atoms, any hydrogen atom in the alkyl group being optionally replaced with a fluorine atom, one —CH₂— or two or more non-adjacent —CH₂-'s in the alkyl group each being optionally independently replaced with a group selected from —O—, —COO—, and —OCO—. Each substituent L even more preferably represents a fluorine atom, a chlorine atom, a linear or branched alkyl group having 1 to 12 carbon atoms, or an alkoxy group, any hydrogen atom in the alkyl group or the alkoxy group being optionally replaced with a fluorine atom. Each substituent L particularly preferably represents a fluorine atom, a chlorine atom, a linear alkyl group having 1 to 8 carbon atoms, or a linear alkoxy group.

In general formula (II-1), Z²¹² represents —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond. When a plurality of Z²¹²'s are present, they may be the same or different.

In general formula (II-1), in the case where importance is placed on a small number of orientation defects, when a plurality of Z²¹²'s are present, they may be the same or different, and each Z²¹² preferably represents —OCH₂—, —CH₂O—, —CH₂CH₂—, —COO—, —OCO—, —CO—NH—, —NH—CO—, —CF₂O—, —OCF₂—, —CH═CH—COO—, —OCO—CH═CH—, —COO—CH₂CH₂—, —CH₂CH₂—OCO—, —CH═CH—, —N═N—, —CH═N—, —N═CH—, —CH═N—N═CH—, —CF═CF—, —C≡C—, or a single bond. When a plurality of Z²¹²'s are present, they may be the same or different, and each Z²¹² more preferably represents —COO—, —OCO—, —CO—NH—, —NH—CO—, —CF₂O—, —OCF₂—, —CH═CH—COO—, —OCO—CH═CH—, —CH═CH—, —N═N—, —CH═N—N═CH—, —CF═CF—, —C≡C—, or a single bond. When a plurality of Z²¹²'s are present, they may be the same or different, and each Z²¹² even more preferably represents —COO—, —OCO—, —CO—NH—, —NH—CO—, —CF₂O—, —OCF₂—, or a single bond. When a plurality of Z²¹²'s are present, they may be the same or different, and each Z²¹² particularly preferably represents —COO—, —OCO—, —CF₂O—, —OCF₂—, or a single bond.

In general formula (II-1), m211 represents an integer of 1 to 3. m211 preferably represents 1 or 2. m211 preferably represents 1.

In general formula (II-1), T²¹¹ represents a hydrogen atom, a —OH group, a —SH group, a —CN group, a —COOH group, a —NH₂ group, a —NO₂ group, a —COCH₃ group, a —O(CH₂)ₙCH₃, or —(CH₂)ₙCH₃ (wherein n represents an integer of 0 to 20). T²¹¹ more preferably represents a hydrogen atom, —O(CH₂)ₙCH₃, or —(CH₂)ₙCH₃ (wherein n represents an integer of 0 to 10). T²¹¹ particularly preferably represents —O(CH₂)ₙCH₃ or —(CH₂)ₙCH₃ (wherein n represents an integer of 0 to 8).

As the compounds represented by general formula (II-1), specifically, compounds represented by formulae (II-1-1) to (II-1-7) below are preferred.

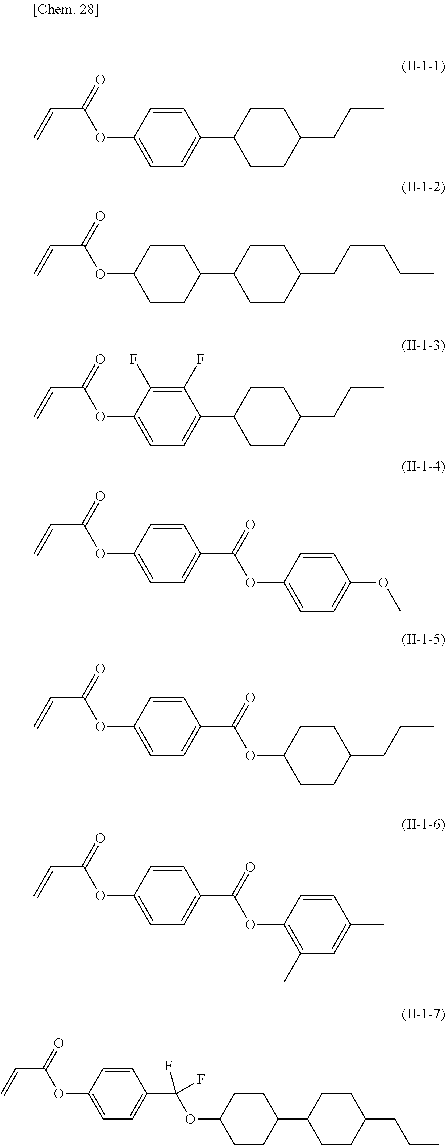

One or two or more monofunctional polymerizable liquid crystal compounds represented by general formula (II-1) may be used. In view of adhesion, the total amount of the monofunctional polymerizable liquid crystal compounds represented by general formula (II-1) contained is preferably 5% to 50% by mass, more preferably 5% to 40% by mass, particularly preferably 10% to 40% by mass, most preferably 15% to 35% by mass based on the total amount of the polymerizable liquid crystal compounds used in the polymerizable liquid crystal composition.

In this embodiment, a compound represented by general formula (I-1) is used as a bifunctional polymerizable liquid crystal compound, and compounds represented by general formulae (II-1) and (II-2) are both used as the monofunctional polymerizable liquid crystal compound. In this case, the total of the compounds, which are monofunctional components, represented by general formulae (II-1) and (II-2) is preferably in the range of 50% to 95% by mass, 60% to 95% by mass, particularly preferably 70% to 95% by mass based on the total amount of the polymerizable liquid crystal compounds used in the polymerizable liquid crystal composition in view of adhesion and heat resistance.

The polymerizable liquid crystal composition of the embodiment may contain a polymerizable liquid crystal compound having three or more polymerizable functional groups in its molecule as long as the physical properties are not impaired. Examples of the polymerizable liquid crystal compound having three or more polymerizable functional groups in its molecule include compounds represented by general formulae (III-1) and (III-2) below.

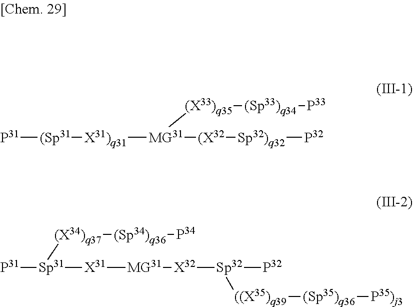

In the formulae, P³¹ to P³⁵ each independently represent a polymerizable functional group. Sp³¹ to S³⁵ each independently represent an alkylene group having 1 to 18 carbon atoms or a single bond. One —CH₂— or two or more non-adjacent —CH₂-'s in the alkylene may each be independently replaced with —O—, —COO—, —OCO—, or —OCO—O—. One or two or more hydrogen atoms in the alkylene group may each be replaced with a halogen atom (preferably, a fluorine atom, a chlorine atom, a bromine atom, or an iodine atom) or a CN group. X³¹ to X³⁵ each independently represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond (provided that in P³¹-Sp³¹, P³²-Sp³², P³³-Sp³³, P³⁴-Sp³⁵, P³⁵-Sp³⁵, Sp³¹-X³¹, Sp³²-X 32, Sp³³-X³³, Sp³⁴-X³⁴, and Sp³⁵-X³⁵, no direct bond between oxygen atoms is included). q31, q32, q34, q35, q36, q37, q38, and q39 each independently represent 0 or 1. j3 represents 0 or 1. MG³¹ represents a mesogen group.

In general formulae (III-1) to (III-2), P³¹ to P³⁵ preferably each independently represent a substituent selected from polymerizable groups represented by formulae (P-2-1) to (P-2-20) below.

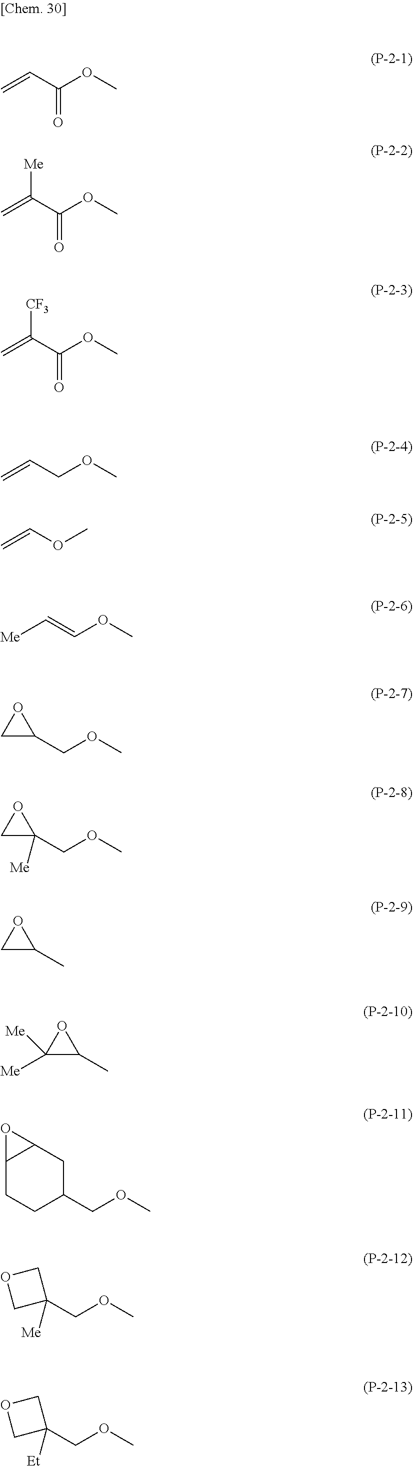

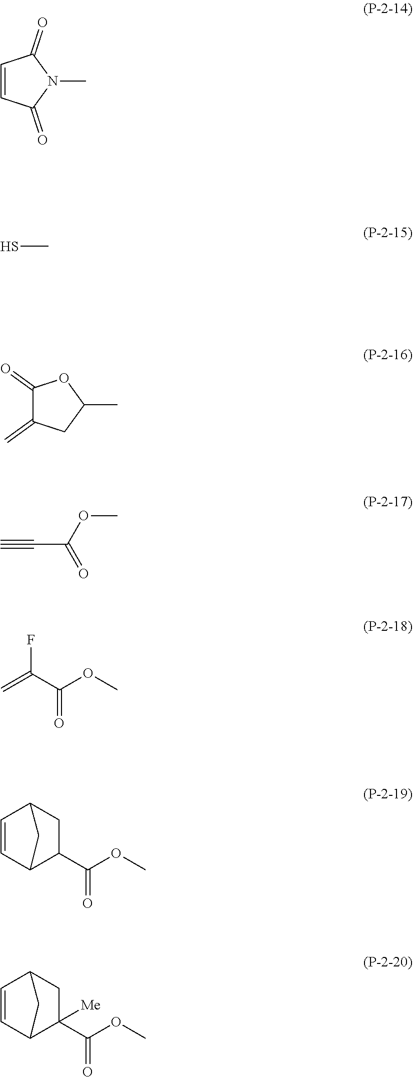

Among these polymerizable functional groups, from the viewpoint of increasing polymerizability, formulae (P-2-1), (P-2-2), (P-2-7), (P-2-12), and (P-2-13) are preferred. Formulae (P-2-1) and (P-2-2) are more preferred.

In general formulae (III-1) and (III-2), Sp³¹ to Sp³⁵ preferably each independently represent an alkylene group having 1 to 15 carbon atoms. One —CH₂— or two or more non-adjacent —CH₂-'s in the alkylene group may each be independently replaced with —O—, —COO—, —OCO—, or —OCO—O—. One or two or more hydrogen atoms in the alkylene group may each be replaced with a halogen atom (preferably, a fluorine atom, a chlorine atom, a bromine atom, or an iodine atom) or a CN group. Sp³¹ to Sp³⁵ preferably each independently represent an alkylene group having 1 to 12. One —CH₂— or two or more non-adjacent —CH₂-'s in the alkylene group may each be independently replaced with —O—, —COO—, —OCO—, or —OCO—O—.

In general formulae (III-1) and (III-2), X³¹ to X³⁵ preferably each independently represent —O—, —OCH₂—, —CH₂O—, —CO—, —COO—, —OCO—, —O—CO—O—, —CO—NH—, —NH—CO—, —CF₂O—, —OCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond. X³¹ to X³⁵ preferably each independently represent —O—, —OCH₂—, —CH₂O—, —CO—, —COO—, —OCO—, —O—CO—O—, —CF₂O—, —OCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —CF═CF—, —C═C—, or a single bond.

In general formulae (III-1) and (III-2), MG³¹ represents a mesogen group represented by general formula (III-A):

[Chem. 31]

-(A1-Z1)ᵣ₁-A2-Z2-A3- (III-A)

In the formula, A1, A2, and A3 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group-, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, or a fluorene-2,7-diyl group and may have, as substituents, one or more of F, Cl, CF₃, OCF₃, a CN group, an alkyl group having 1 to 8 carbon atoms, an alkoxy group having 1 to 8 carbon atoms, an alkanoyl group having 1 to 8 carbon atoms, an alkanoyloxy group having 1 to 8 carbon atoms, an alkoxycarbonyl group having 1 to 8 carbon atoms, an alkenyl group having 2 to 8 carbon atoms, an alkenyloxy group having 2 to 8 carbon atoms, an alkenoyl group having 2 to 8 carbon atoms, and/or an alkenoyloxy group having 2 to 8 carbon atoms. In the case where the structure represented by general formula (III-1) is formed, any of existing A1, A2, and A3 has a —(X³³)_{q35}-(Sp³³)_{q34}-P³³ group. Z1 and Z2 each independently represent —COO—, —OCO—, —CH₂CH₂—, —OCH₂—, —CH₂O—, —CH═CH—, —C≡C—, —CH═CHCOO—, —OCOCH═CH—, —CH₂CH₂COO—, —CH₂CH₂OCO—, —COOCH₂CH₂—, —OCOCH₂CH₂—, —C═N—, —N═C—, —CONH—, —NHCO—, —C(CF₃)₂—, an alkyl group that has 2 to 10 carbon atoms and that may have a halogen atom (preferably, a fluorine atom, a chlorine atom, a bromine atom, or an iodine atom), or a single bond. Z1 and Z2 preferably each independently represent —COO—, —OCO—, —CH₂CH₂—, —OCH₂—, —CH₂O—, —CH═CH—, —C≡C—, —CH═CHCOO—, —OCOCH═CH—, —CH₂CH₂COO—, —CH₂CH₂OCO—, —COOCH₂CH₂—, —OCOCH₂CH₂—, or a single bond. r1 represents 0, 1, 2, or 3. When a plurality of A1's and a plurality of Z1's are present, they may be the same or different). Among these, A1, A2, and A3 preferably each independently represent a 1,4-phenylene group, a 1,4-cyclohexylene group, or a 2,6-naphthylene group.

Examples of general formula (III) include, but are not limited to, compounds represented by general formulae (III-1-1) to (III-1-8) and (III-2-1) to )III-2-2) below.

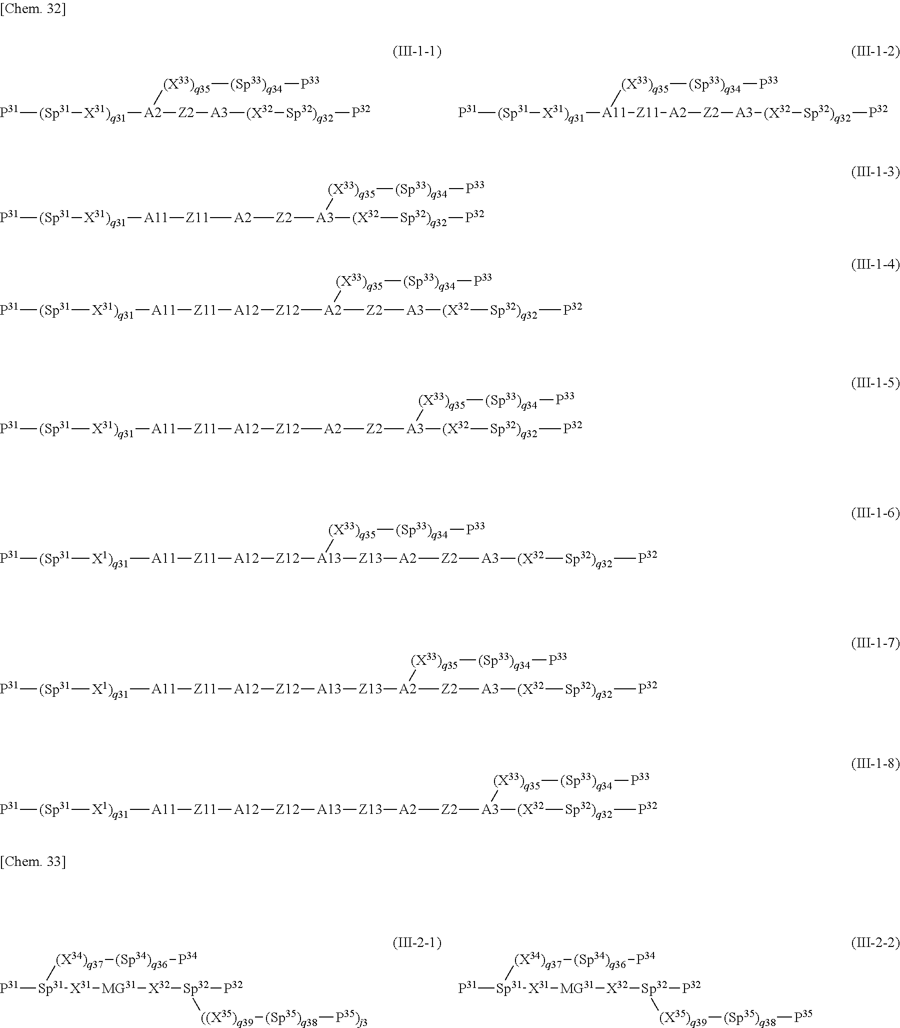

In the formulae, P³¹ to P³⁵, Sp³¹ to Sp³⁵, X³¹ to X³⁵, and q31 to q39MG³ are as defined in general formulae (III-1) and (III-2).

A11, A12, A13, A2, and A3 are defined the same as A1 to A3 in general formula (III-A), and they may be the same or different.

Z11, Z12, Z13, and Z2 are defined the same as Z1 and Z2 in general formula (III-A), and they may be the same or different.

Examples of compounds represented by general formulae (III-1-1) to (III-1-8), (III-2-1), and (III-2-2) above include, but are not limited to, compounds represented by general formulae (III-9-1) to (III-9-6) below.

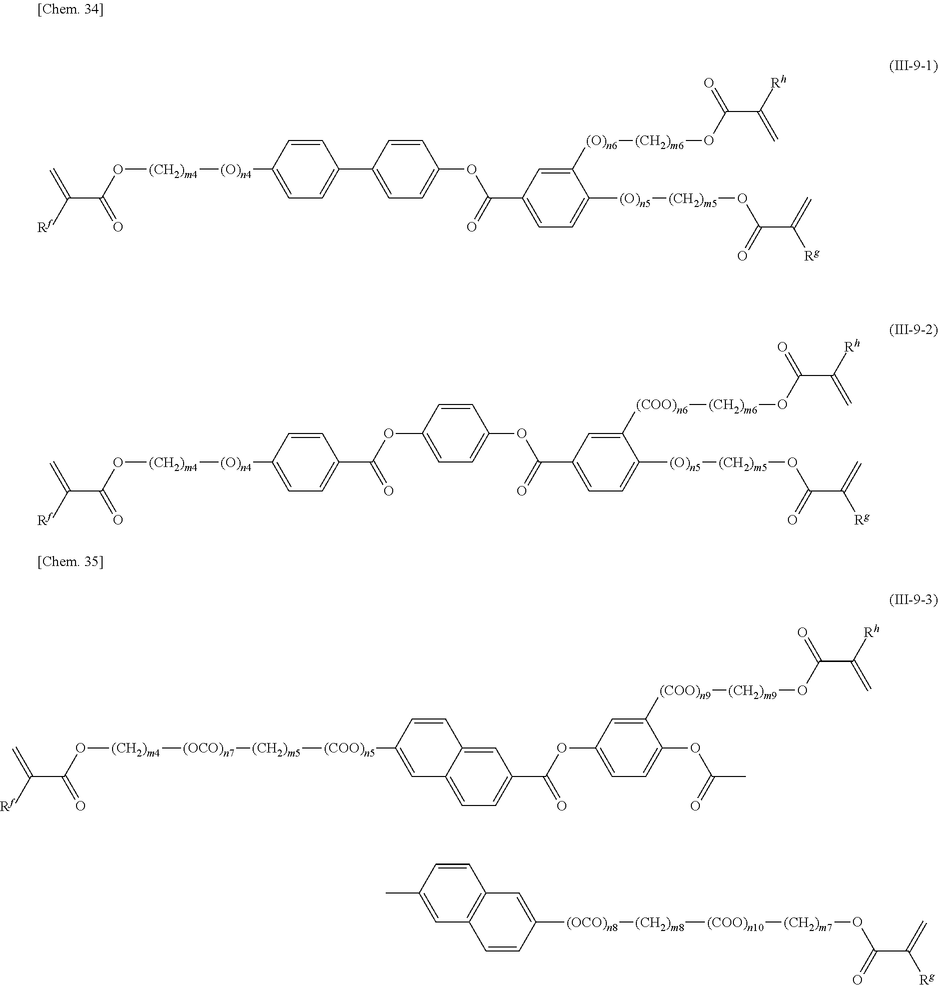

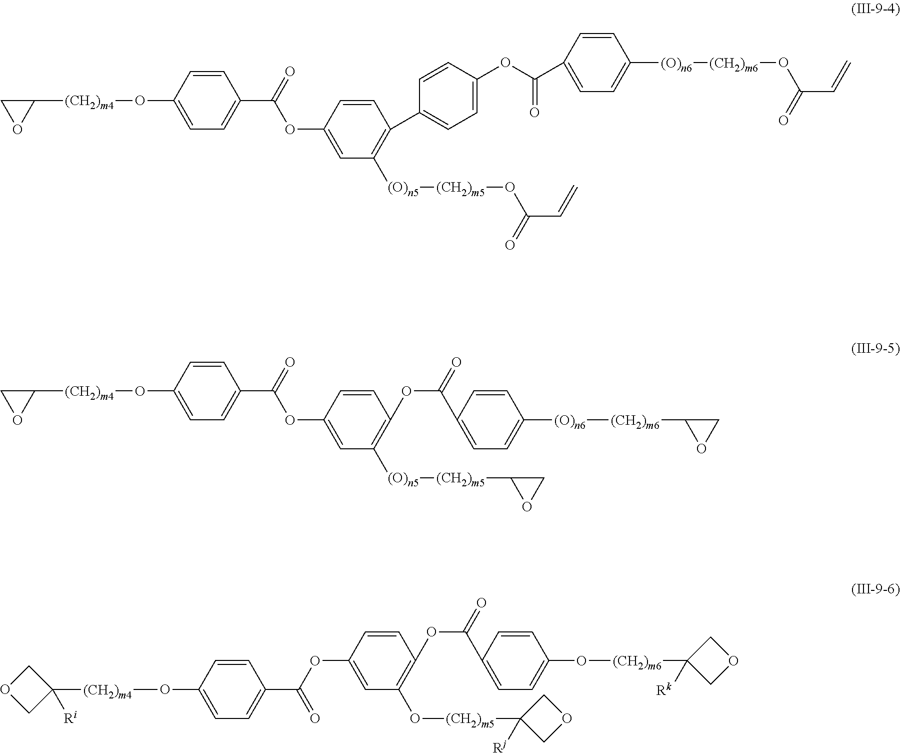

In general formulae (III-9-1) to (III-9-6), R^{f}, R^{g}, and R^{h} each independently represent a hydrogen atom or a methyl group. Rⁱ, R^{j}, and R^{k} each independently represent a hydrogen atom, a halogen atom (preferably, a fluorine atom, a chlorine atom, a bromine atom, or an iodine atom), an alkyl group having 1 to 6 carbon atoms, an alkoxy group having 1 to 6 carbon atoms, or a cyano group. When these groups are alkyl groups each having 1 to 6 carbon atoms or alkoxy groups each having 1 to 6 carbon atoms, these groups are all unsubstituted or may be substituted with one or two or more halogen atoms (preferably, fluorine atoms, chlorine atoms, bromine atoms, or iodine atoms). The cyclic groups may each have, as substituents, one or more of F, Cl, CF₃, OCF₃, a CN group, an alkyl group having 1 to 8 carbon atoms, an alkoxy group having 1 to 8 carbon atoms, an alkanoyl group having 1 to 8 carbon atoms, an alkanoyloxy group having 1 to 8 carbon atoms, an alkoxycarbonyl group having 1 to 8 carbon atoms, an alkenyl group having 2 to 8 carbon atoms, an alkenyloxy group having 2 to 8 carbon atoms, an alkenoyl group having 2 to 8 carbon atoms, or an alkenoyloxy group having 2 to 8 carbon atoms.

m4 to m9 each independently represent an integer of 0 to 18. n4 to n10 each independently represent 0 or 1.

One or two or more polyfunctional polymerizable liquid crystal compounds each having three or more polymerizable functional groups may be used.

The total amount of the polyfunctional polymerizable liquid crystal compounds each having three or more polymerizable functional groups in its molecule is preferably in the range of 20% or less by mass, more preferably 10% or less by mass, particularly preferably 5% or less by mass based on the total amount of the polymerizable liquid crystal compounds used in the polymerizable liquid crystal composition.

A compound containing a mesogen group having no polymerizable group may be added to the polymerizable liquid crystal composition of the embodiment. Examples thereof include compounds used for usual liquid crystal devices, such as super-twisted nematic (STN) liquid crystals, twisted nematic (TN) liquid crystals, and thin-film transistor (TFT) liquid crystals.

Specifically, the compound containing a mesogen group having no polymerizable group is preferably a compound represented by general formula (5) below.

[Chem. 37]

R⁵¹-MG3-R⁵² (5)

The mesogen group or a mesogenic supporting group represented by MG3 is represented by general formula (5-b):

[Chem. 38]

—Z0^{d}-(A1^{d}-Z1^{d})ₙₑ-A2^{d}-Z2^{d}-A3^{d}-Z3^{d}- (5-b)

(wherein in the formula, A1^{d}, A2^{d}, and A3^{d} each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group-, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, or a fluorene-2,7-diyl group, and may have, as substituents, one or more of F, Cl, CF₃, OCF₃, a CN group, an alkyl group having 1 to 8 carbon atoms, an alkoxy group, an alkanoyl group, an alkanoyloxy group, an alkenyl group having 2 to 8 carbon atoms, an alkenyloxy group, an alkenoyl group, and an alkenoyloxy group,

Z0^{d}, Z1^{d}, Z2^{d}, and Z3^{d} each independently represent —COO—, —OCO—, —CH₂CH₂—, —OCH₂—, —CH₂O—, —CH═CH—, —C═C—, —CH═CHCOO—, —OCOCH═CH—, —CH₂CH₂COO—, —CH₂CH₂OCO—, —COOCH₂CH₂—, —OCOCH₂CH₂—, —CONH—, —NHCO—, an alkylene group that has 2 to 10 carbon atoms and that may have a halogen atom (preferably, a fluorine atom, a chlorine atom, a bromine atom, or an iodine atom), or a single bond,

n^{e} represents 0, 1, or 2,

R⁵¹ and R⁵² each independently represent a hydrogen atom, a halogen atom (preferably, a fluorine atom, a chlorine atom, a bromine atom, or an iodine atom), a cyano group, or an alkyl group having 1 to 18 carbon atoms, the alkyl group may be substituted with one or more halogen atoms (preferably, fluorine atoms, chlorine atoms, bromine atoms, or iodine atoms) or CN, and one CH₂ group or two or more non-adjacent CH₂ groups present in this group may each be independently replaced with —O—, —S—, —NH—, —N(CH₃)—, —CO—, —COO—, —OCO—, —OCOO—, —SCO—, —COS—, or —C≡C— in a form in which oxygen atoms are not directly bonded to each other).

Non-limiting specific examples thereof are described below.

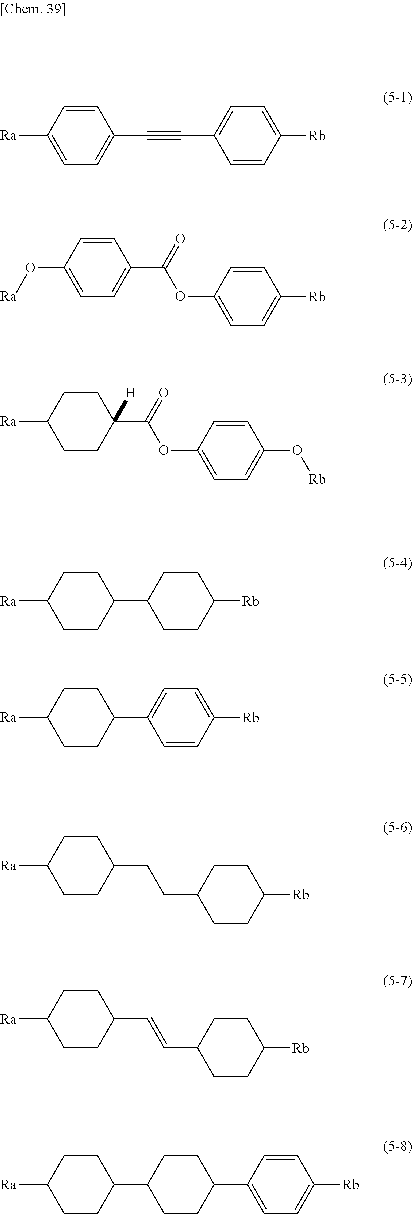

Each Ra and each Rb each independently represent a hydrogen atom, an alkyl group having 1 to 6 carbon atoms, an alkoxy group having 1 to 6 carbon atoms, an alkenyl group having 1 to 6 carbon atoms, or a cyano group. When these groups are alkyl groups each having 1 to 6 carbon atoms or alkoxy groups each having 1 to 6 carbon atoms, these groups are all unsubstituted or may be substituted with one or two or more halogen atoms.

The total amount of the mesogen group-containing compounds contained is preferably 0% or more by mass and 20% or less by mass based on the total amount of the polymerizable liquid crystal composition, preferably 1% or more by mass, preferably 2% or more by mass, preferably 5% or more by mass, and preferably 15% or less by mass, preferably 10% or less by mass, when used.

The polymerizable liquid crystal composition according to the embodiment contains a chiral compound that may exhibit or need not exhibit liquid crystallinity in order to allow an optical film to be obtained to have cholesteric liquid crystallinity. As the chiral compound, a polymerizable chiral compound having polymerizability is preferably used.

The polymerizable chiral compound used in the embodiment preferably has one or more polymerizable functional groups. Examples of the compound include polymerizable chiral compounds each containing a chiral saccharide, such as isosorbide, isomannitol, or glucoside, a rigid moiety, such as a 1,4-phenylene group or a 1,4-cyclohexylene group, and a polymerizable functional group, such as a vinyl group, an acryloyl group, a (meth)acryloyl group, or a maleimide group, as described in, for example, Japanese Unexamined Patent Application Publication Nos. 11-193287 and 2001-158788, Japanese Unexamined Patent Application Publication (Translation of PCT Application) No. 2006-52669, and Japanese Unexamined Patent Application Publication Nos. 2007-269639, 2007-269640, or 2009-84178; polymerizable chiral compounds composed of terpenoid derivatives as described in Japanese Unexamined Patent Application Publication No. 8-239666; polymerizable chiral compounds each containing a mesogen group and a spacer having a chiral moiety as described in, for example, NATURE VOL. 35, pp 467-469 (published on Nov. 30, 1995) or NATURE VOL. 392, pp 476-479 (published on Apr. 2, 1998); and polymerizable chiral compounds each having a binaphthyl group as described in Japanese Unexamined Patent Application Publication (Translation of PCT Application) No. 2004-504285 or Japanese Unexamined Patent Application Publication No. 2007-248945. Among these, a chiral compound having a high helical twisting power (HTP) is preferably used for the polymerizable liquid crystal composition of the embodiment.

In chiral compounds, examples of the chiral compound having a high helical twisting power (HTP) include general formulae (3-1) to (3-4). Chiral compounds selected from general formulae (3-1) to (3-3) are more preferably used. Among the chiral compounds selected from general formulae (3-1) to (3-3), a polymerizable chiral compound having a polymerizable group represented by general formula (3-a) below is particularly preferably used. In particular, a compound represented by general formula (3-1) in which R^{3a} and R^{3b} are each (P1) is more preferred.

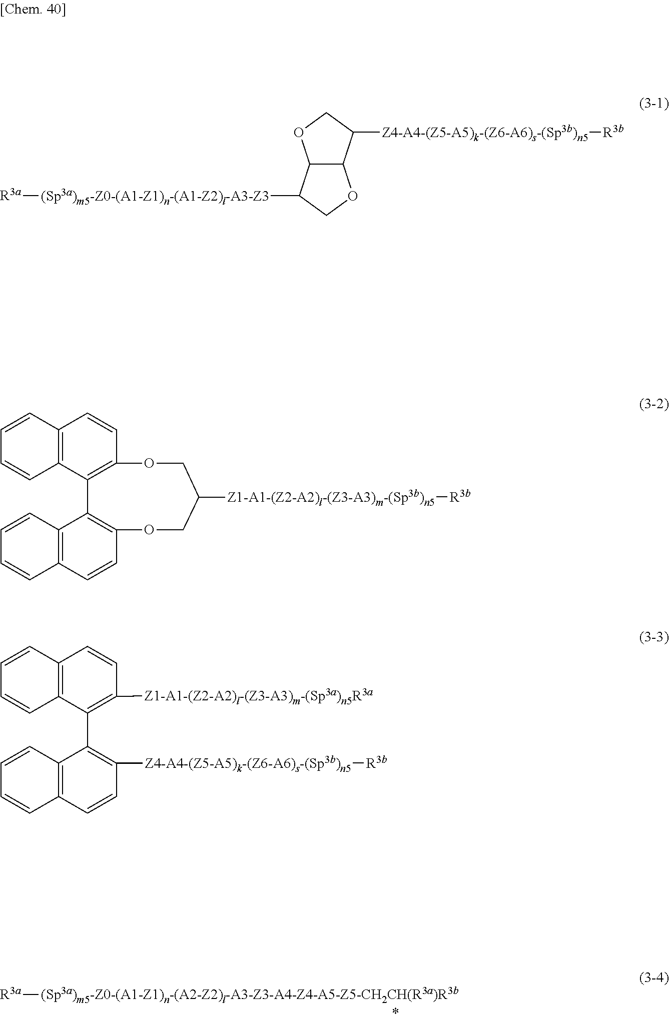

In the formulae, each Sp^{3a} and each Sp^{3b} each independently represent an alkylene group having 0 to 18 carbon atoms. The alkylene group may be substituted with one or more halogen atoms, a CN group, or a polymerizable functional group-containing alkyl group having 1 to 8 carbon atoms. One CH₂ group or two or more non-adjacent CH₂ groups present in this group may each be independently replaced with —O—, —S—, —NH—, —N(CH₃)—, —CO—, —COO—, —OCO—, —OCOO—, —SCO—, —COS—, or —C≡C— in a form in which oxygen atoms are not directly bonded to each other.

Each A1, each A2, each A3, each A4, each A5, and each A6 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group-, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, or a fluorene-2,7-diyl group, and may have, as substituents, one or more of F, Cl, CF₃, OCF₃, a CN group, an alkyl group having 1 to 8 carbon atoms, an alkoxy group having 1 to 8 carbon atoms, an alkanoyl group having 1 to 8 carbon atoms, an alkanoyloxy group having 1 to 8 carbon atoms, an alkoxycarbonyl group having 1 to 8 carbon atoms, an alkenyl group having 2 to 8 carbon atoms, an alkenyloxy group having 2 to 8 carbon atoms, an alkenoyl group having 2 to 8 carbon atoms, and/or an alkenoyloxy group having 2 to 8 carbon atoms. Each A1, each A2, each A3, each A4, each A5, and each A6 preferably each independently represent a 1,4-phenylene group, a 1,4-cyclohexylene group, or a 2,6-naphthylene group and may have, as substituents, one or more of F, a CN group, an alkyl group having 1 to 8 carbon atoms, or an alkoxy group having 1 to 8 carbon atoms.

Each n, each 1, each k, and each s each independently represent 0 or 1.

Each Z0, each Z1, each Z2, each Z3, each Z4, each Z5, and each Z6 each independently represent —COO—, —OCO—, —CH₂CH₂—, —OCH₂—, —CH₂O—, —CH═CH—, —C≡C—, —CH═CHCOO—, —OCOCH═CH—, —CH₂CH₂COO—, —CH₂CH₂OCO—, —COOCH₂CH₂—, —OCOCH₂CH₂—, —CONH—, —NHCO—, an alkyl group that has 2 to 10 carbon atoms and that may have a halogen atom, or a single bond.

Each n5 and each m5 each independently represent 0 or 1.

Each R^{3a} and each R^{3b} each represent a hydrogen atom, a halogen atom, a cyano group, or an alkyl group having 1 to 18 carbon atoms. The alkyl group may be substituted with one or more halogen atoms or CN. One CH₂ group or two or more non-adjacent CH₂ groups present in this group may each be independently replaced with —O—, —S—, —NH—, —N(CH₃)—, —CO—, —COO—, —OCO—, —OCOO—, —SCO—, —COS—, or —C≡C— in a form in which oxygen atoms are not directly bonded to each other.

Alternatively, each R^{3a} and each R^{3b} are each preferably represented by general formula (3-a):

[Chem. 41]

—P^{3a} (3-a)

(wherein in the formula, P^{3a} represents a polymerizable functional group).

P^{3a} preferably represents a substituent selected from polymerizable groups represented by formulae (P-1) to (P-20) below.

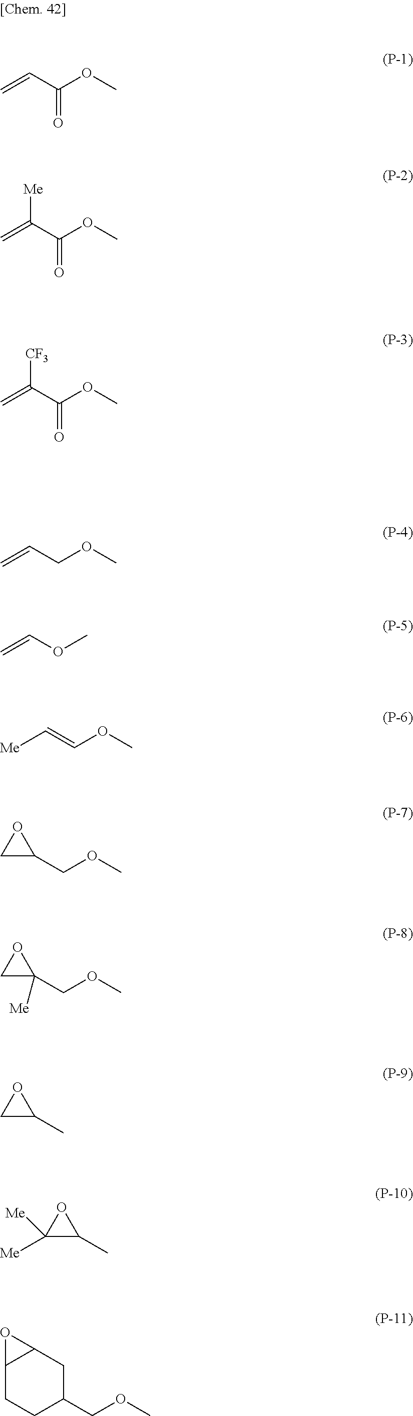

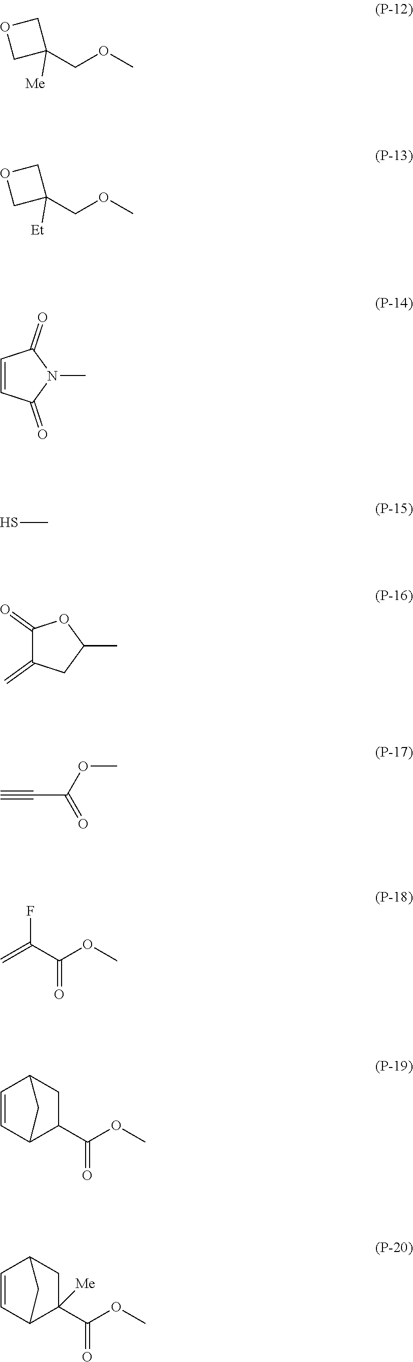

Among these polymerizable functional groups, from the viewpoints of enhancing polymerizability and storage stability, formula (P-1), (P-2), (P-7), (P-12), or (P-13) is preferred, and formula (P-1), (P-7), or (P-12) is more preferred.

Specific examples of the polymerizable chiral compound include, but are not limited to, compounds (3-5) to (3-26) below.

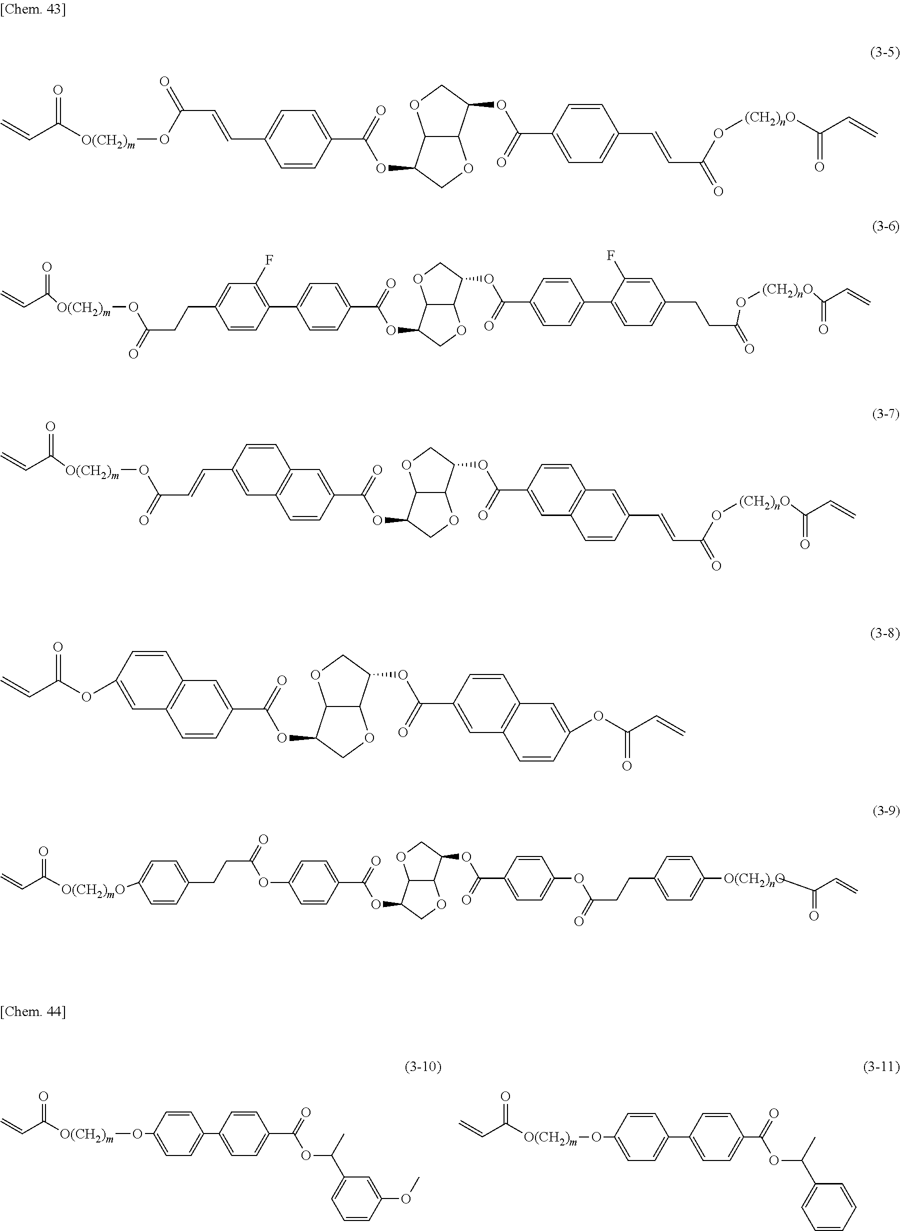

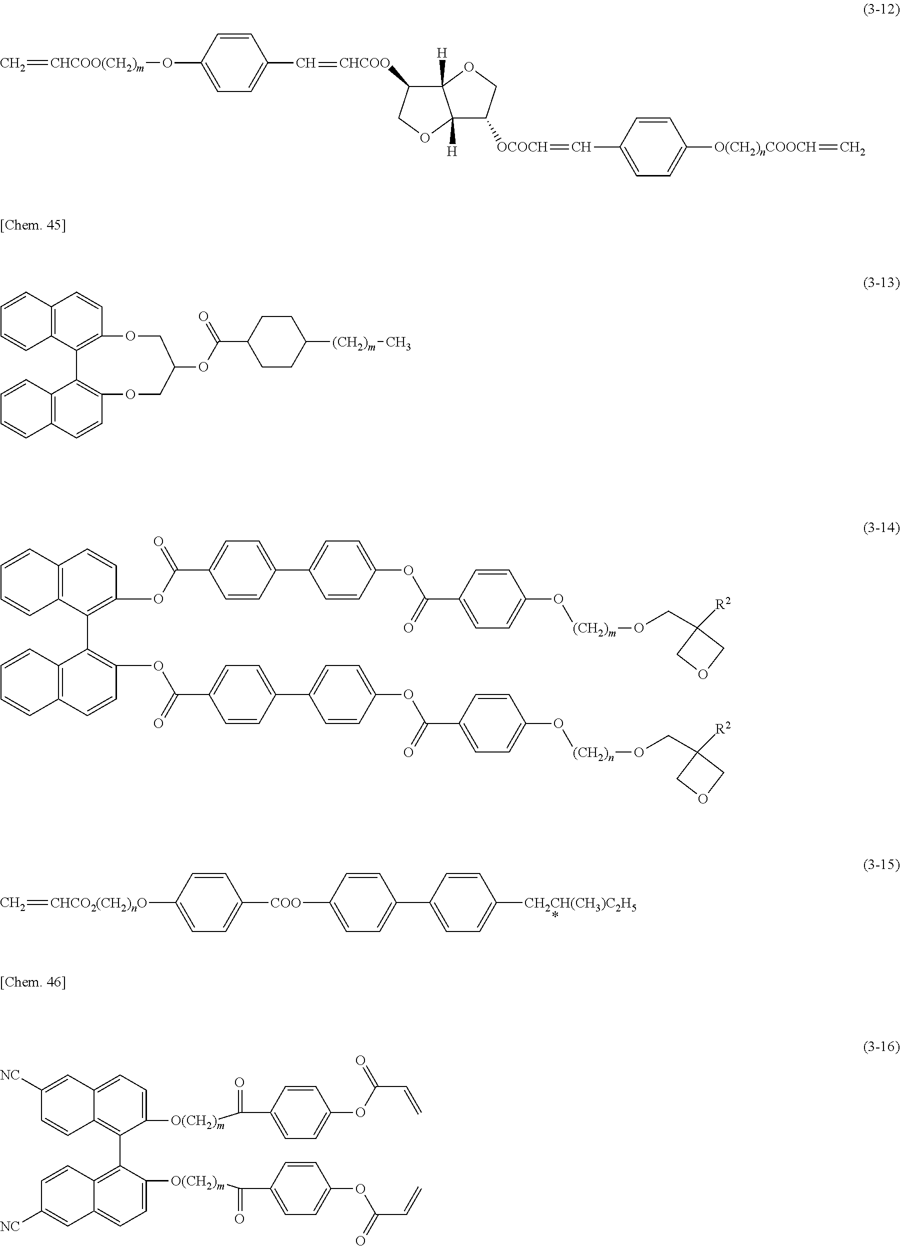

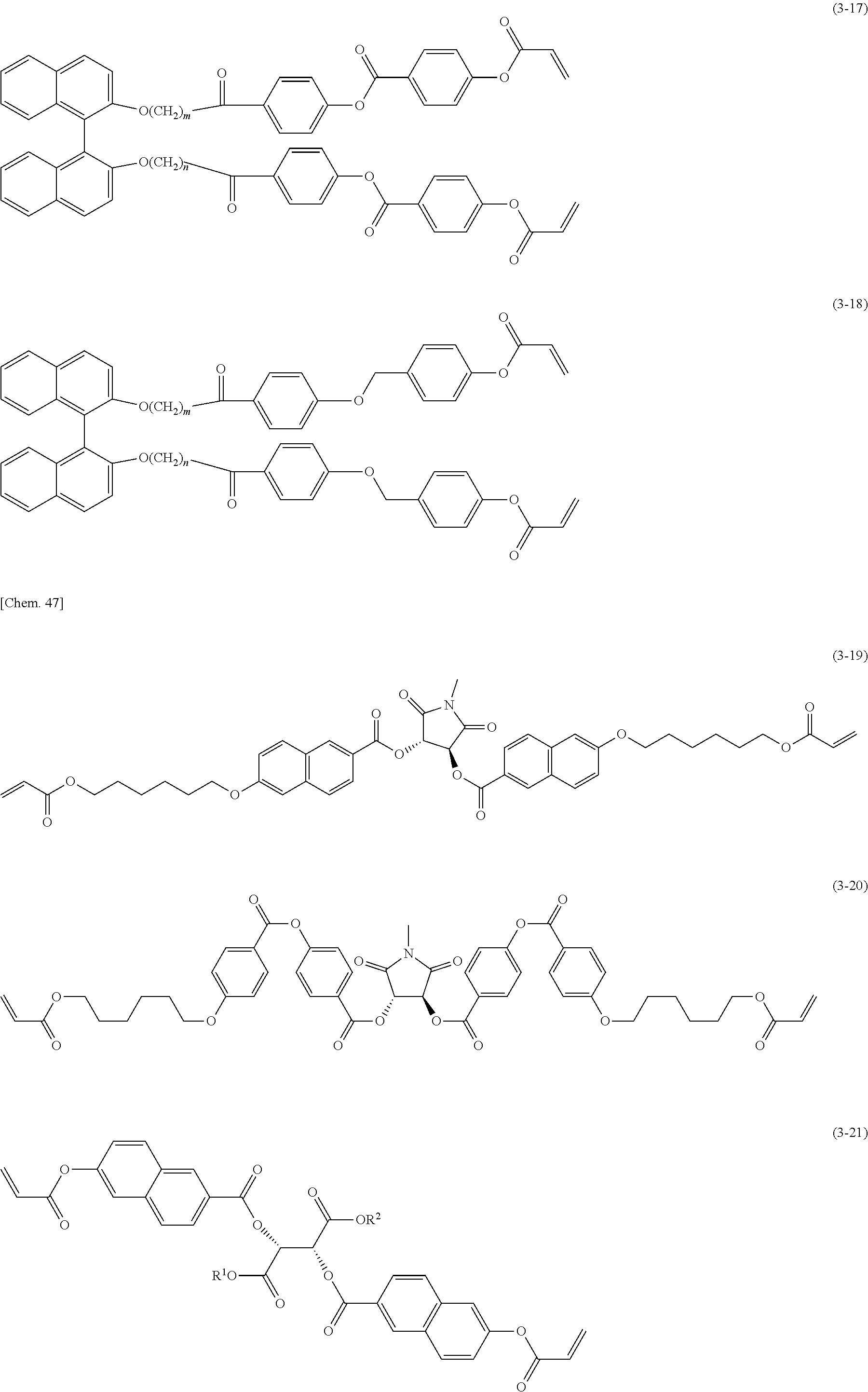

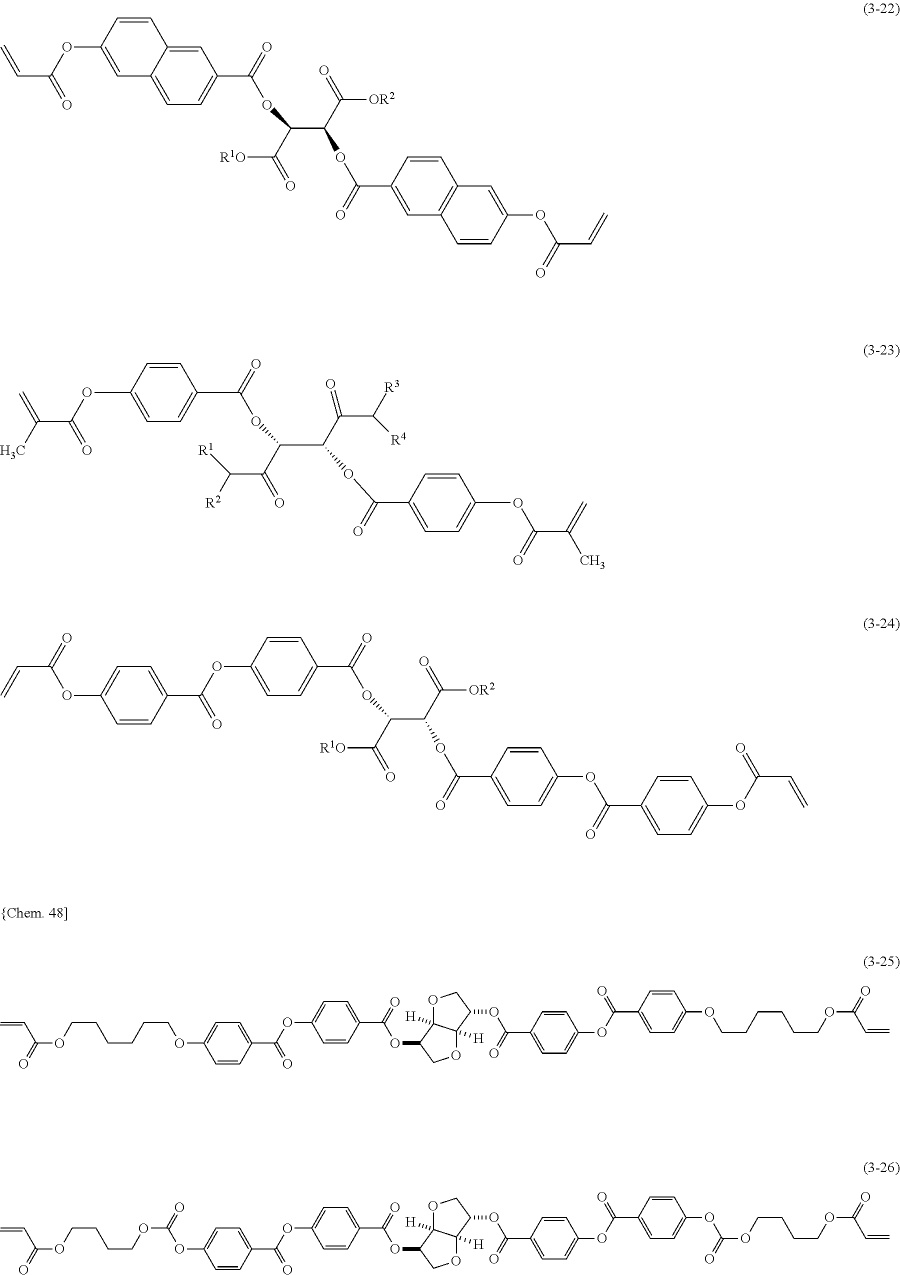

In the formulae, each m, each n, k, and l each independently represent an integer of 1 to 18. Each R¹ to each R⁴ each independently represent a hydrogen atom, an alkyl group having 1 to 6 carbon atoms, an alkoxy group having 1 to 6 carbon atoms, a carboxy group, or a cyano group. When these groups are alkyl groups each having 1 to 6 carbon atoms or alkoxy groups each having 1 to 6 carbon atoms, these groups may all be unsubstituted or may be substituted with one or two or more halogen atoms.

Among the polymerizable chiral compounds represented by general formulae (3-5) to (3-26) above, as chiral compounds having a high helical twisting power (HTP), polymerizable chiral compounds represented by general formulae (3-5) to (3-9), (3-12) to (3-14), (3-16) to (3-18), (3-25), and (3-26) are particularly preferably used, and polymerizable chiral compounds represented by (3-8), (3-25), and (3-26) are more particularly preferably used.

To allow an optical film to be obtained to have cholesteric properties and good transmittance, the chiral compound is preferably used for the polymerizable liquid crystal composition according to the embodiment in an amount of 0.5 to 20 parts by mass, more preferably 1 to 15 parts by mass, particularly preferably 1.5 to 10 parts by mass based on a total of 100 parts by mass of the polymerizable liquid crystal compounds used in the polymerizable liquid crystal composition.

The polymerizable liquid crystal composition according to the embodiment preferably contains a photopolymerization initiator. As the photopolymerization initiator, an acylphosphine oxide-based photopolymerization initiator or an α-aminoalkylphenone-based initiator is preferred in the composition of the embodiment in view of heat resistance. Regarding the photopolymerization initiator, specific examples of the acylphosphine oxide-based photopolymerization initiator include 2,4,6-trimethylbenzoyl-diphenyl-phosphine oxide (“Irgacure TPO”, available from BASF) and bis(2,4,6-trimethylbenzoyl)-phenylphosphine oxide (“Irgacure 819”, available from BASF). Specific examples of the α-aminoalkylphenone-based initiator include 2-methyl-1-(4-methylthiophenyl)-2-morpholinopropan-1-one (“Irgacure 907”, available from BASF), 2-benzyl-2-dimethylamino-1-(4-morpholinophenyl)-butanone-1 (“Irgacure 369E”, available from BASF), and 2-(dimethylamino)-2-[(4-methylphenyl)methyl]-1-[4-(4-morpholinyl)phenyl]-1-butanone (“Irgacure 379”, available from BASF).

Additionally, the foregoing photopolymerization initiator may be used in combination. Examples of the photopolymerization initiator include “Lucirin TPO”, “Darocur 1173”, and “Darocur MBF”; “Esacure 1001M”, “Esacure KIP150”, “Speedcure BEM”, “Speedcure BMS”, “Speedcure MBP”, “Speedcure PBZ”, “Speedcure ITX”, “Speedcure DETX”, “Speedcure EBD”, “Speedcure MBB”, and “Speedcure BP”, available from Lambson Ltd.; “Kayacure DMBI”, available from Nippon Kayaku Co., Ltd.; “TAZ-A”, available from Nihon Siber Hegner K.K. (current DKSH); “Adeka Optomer SP-152”, “Adeka Optomer SP-170”, “Adeka Optomer N-1414”, “Adeka Optomer N-1606”, “Adeka Optomer N-1717”, and “Adeka Optomer N-1919”, available from Adeka Corporation; “Cyracure UVI-6990”, “Cyracure UVI-6974”, and “Cyracure UVI-6992”, available from UCC; “Adeka Optomer SP-150, SP-152, SP-170, and SP-172”, available from Asahi Denka Co., Ltd.; “PHOTOINITIATOR 2074”, available from Rhodia; “Irgacure 250”, available from BASF; “UV-9380C”, available from GE Silicones; and “DTS-102”, available from Midori Kagaku Co., Ltd.

The amount of the photopolymerization initiator used is preferably 0.1 to 10 parts by mass, particularly preferably 0.5 to 7 parts by mass based on 100 parts by mass of the polymerizable liquid crystal compounds contained in the polymerizable liquid crystal composition. To increase the curability of an optically anisotropic product, 3 parts or more by mass of photopolymerization initiator is preferably used based on 100 parts by mass of the polymerizable liquid crystal compounds contained. These may be used alone or in combination of two or more as a mixture. Additionally, a sensitizer or the like may be added.

An organic solvent may be added to the polymerizable liquid crystal composition according to the embodiment. The organic solvent used is not particularly limited, is preferably an organic solvent in which the polymerizable liquid crystal compounds are appropriately soluble, and is preferably an organic solvent that can permit drying at 100° C. or lower. Examples of such a solvent include aromatic hydrocarbons, such as toluene, xylene, cumene, and mesitylene; ester-based solvents, such as methyl acetate, ethyl acetate, propyl acetate, and butyl acetate; ketone-based solvents, such as methyl ethyl ketone (MEK), methyl isobutyl ketone (MIBK), cyclohexanone, and cyclopentanone; ether-based solvents, such as tetrahydrofuran, 1,2-dimethoxyethane, and anisole; amide-based solvents, such as N,N-dimethylformamide and N-methyl-2-pyrrolidone; propylene glycol monomethyl ether acetate, diethylene glycol monomethyl ether acetate, γ-butyrolactone, and chlorobenzene. These may be used alone or in combination of two or more as a mixture. One or more of ketone-based solvents, ether-based solvents, ester-based solvents, and aromatic hydrocarbon-based solvents are preferably used in view of solution stability.

When the composition used in the embodiment is formed into a solution with the organic solvent, the solution can be applied to a substrate. The percentage of the organic solvent used in the polymerizable liquid crystal composition is not particularly limited unless a coating state is significantly impaired. The total amount of the organic solvent in the solution containing the polymerizable liquid crystal composition is preferably 10% to 95% by mass, more preferably 12% to 90% by mass, particularly preferably 15% to 85% by mass.

When the polymerizable liquid crystal composition is dissolved in the organic solvent, heating with stirring is preferred to uniformly dissolve the composition. The heating temperature during the heating with stirring may be appropriately adjusted in consideration of the solubility of the composition in the organic solvent and is preferably 15° C. to 110° C., more preferably 15° C. to 105° C., even more preferably 15° C. to 100° C., particularly preferably 20° C. to 90° C. in view of productivity.

When the solvent is added, stirring and mixing are preferably performed with a dispersion stirrer. Specific examples of the dispersion stirrer that can be used include Disper, dispersers with mixing impellers, such as propellers and turbine blades, paint shakers, planetary mixers, shaking machines, shakers, and rotary evaporators. In addition, an ultrasonic irradiation device can be used.

The stirring rotational speed in adding the solvent is preferably adjusted as appropriate in accordance with a stirrer used. To prepare a uniform polymerizable liquid crystal composition solution, the stirring rotational speed is preferably 10 rpm to 1,000 rpm, more preferably 50 rpm to 800 rpm, particularly preferably 150 rpm to 600 rpm.

A polymerization inhibitor is preferably added to the polymerizable liquid crystal composition according to the embodiment. Examples of the polymerization inhibitor include phenolic compounds, quinone-based compounds, amine-based compounds, thioether-based compounds, and nitroso compounds.

Examples of phenolic compounds include p-methoxyphenol, cresol, tert-butylcatechol, 3.5-di-tert-butyl-4-hydroxytoluene, 2.2′-methylenebis(4-methyl-6-tert-butylphenol), 2.2′-methylenebis(4-ethyl-6-t-butylphenol), 4.4′-thiobis(3-methyl-6-tert-butylphenol), 4-methoxy-1-naphthol, and 4,4′-dialkoxy-2,2′-bi-1-naphthol.

Examples of quinone-based compounds include hydroquinone, methylhydroquinone, tert-butylhydroquinone, p-benzoquinone, methyl-p-benzoquinone, tert-butyl-p-benzoquinone, 2,5-diphenylbenzoquinone, 2-hydroxy-1,4-naphthoquinone, 1,4-naphthoquinone, 2,3-dichloro-1,4-naphthoquinone, anthraquinone, and diphenoquinone.

Examples of amine-based compounds include p-phenylenediamine, 4-aminodiphenylamine, N.N′-diphenyl-p-phenylenediamine, N-i-propyl-N′-phenyl-p-phenylenediamine, N-(1.3-dimethylbutyl)-N′-phenyl-p-phenylenediamine, N.N′-di-2-naphthyl-p-phenylenediamine, diphenylamine, N-phenyl-β-naphthylamine, 4.4′-dicumyl-diphenylamine, and 4.4′-dioctyl-diphenylamine.

Examples of thioether-based compound include phenothiazine and distearyl thiodipropionate.

Examples of nitroso-based compounds include N-nitrosodiphenylamine, N-nitrosophenylnaphthylamine, N-nitrosodinaphthylamine, p-nitrosophenol, nitrosobenzene, p-nitrosodiphenylamine, α-nitroso-β-naphthol, N,N-dimethyl-p-nitrosoaniline, p-nitrosodiphenylamine, p-nitrondimethylamine, p-nitron-N,N-diethylamine, N-nitrosoethanolamine, N-nitrosodi-n-butylamine, N-nitroso-N-n-butyl-4-butanolamine, N-nitroso-diisopropanolamine, N-nitroso-N-ethyl-4-butanolamine, 5-nitroso-8-hydroxyquinoline, N-nitrosomorpholine, an ammonium salt of N-nitroso-N-phenylhydroxylamine, nitrosobenzene, 2,4.6-tri-tert-butylnitronbenzene, N-nitroso-N-methyl-p-toluenesulfonamide, N-nitroso-N-ethylurethane, N-nitroso-N-n-propylurethane, 1-nitroso-2-naphthol, 2-nitroso-1-naphthol, sodium 1-nitroso-2-naphthol-3,6-sulfonate, sodium 2-nitroso-1-naphthol-4-sulfonate, 2-nitroso-5-methylaminophenol hydrochloride, and 2-nitroso-5-methylaminophenol hydrochloride.

The amount of the polymerization inhibitor added is preferably 0.01% to 1.0% by mass, more preferably 0.05% to 0.5% by mass based on the polymerizable liquid crystal composition.

In the polymerizable liquid crystal composition according to the embodiment, a thermal polymerization initiator may be used in combination with the photopolymerization initiator. As the thermal polymerization initiator, a known and commonly used thermal polymerization initiator can be used. Examples of the thermal polymerization initiator that can be used include organic peroxides, such as methyl acetoacetate peroxide, cumene hydroperoxide, benzoyl peroxide, bis(4-tert-butylcyclohexyl) peroxydicarbonate, tert-butyl peroxybenzoate, methyl ethyl ketone peroxide, 1,1-bis(tert-hexylperoxy) 3,3,5-trimethylcyclohexane, p-pentahydroperoxide, tert-butyl hydroperoxide, dicumyl peroxide, isobutyl peroxide, di(3-methyl-3-methoxybutyl) peroxydicarbonate, and 1,1-bis(tert-butylperoxy)cyclohexane; azonitrile compounds, such as 2,2′-azobisisobutyronitrile, and 2,2′-azobis(2,4-dimethylvaleronitrile); azoamidine compounds, such as 2,2′-azobis(2-methyl-N-phenylpropione-amidine) dihydrochloride; azoamide compounds, such as 2,2′azobis{2-methyl-N-[1,1-bis(hydroxymethyl)-2-hydroxyethyl]propionamide}; and alkylazo compounds, such as 2,2′azobis(2,4,4-trimethylpentane). Specific examples thereof include “V-40” and “VF-096”, available from Wako Pure Chemical Industries, Ltd.; and “Perhexyl D” and “Perhexyl I”, available from NOF Corporation (current NOF Corporation).

The amount of the thermal polymerization initiator used is preferably 0.1 to 10 parts by mass, particularly preferably 0.5 to 5 parts by mass based on 100 parts by mass of the polymerizable liquid crystal compounds contained in the polymerizable liquid crystal composition. These may be used alone or in combination of two or more as a mixture.

The polymerizable liquid crystal composition according to the embodiment may contain at least one or more surfactants in order to reduce the non-uniformity of the thickness of an optically anisotropic product to be obtained. Examples of a surfactant that can be contained include alkyl carboxylates, alkyl phosphates, alkyl sulfonates, fluoroalkyl carboxylates, fluoroalkyl phosphates, fluoroalkyl sulfornates, polyoxyethylene derivatives, fluoroalkylethylene oxide derivatives, poly(ethylene glycol) derivatives, alkylammonium salts, and fluoroalkylammonium salts. In particular, fluoro-based or acrylic surfactants are preferred.

The surfactant in the embodiment is not an essential component. When the surfactant is added, the amount of the surfactant added is preferably 0.01 to 2 parts by mass, more preferably 0.05 to 0.5 parts by mass based on 100 parts by mass of the polymerizable liquid crystal compounds contained in the polymerizable liquid crystal composition.

The use of the surfactant enables an effective reduction in tilt angle at the air interface when the polymerizable liquid crystal composition of the embodiment is formed into an optically anisotropic product.

An example of a compound, other than the surfactant described above, effective in reducing the tilt angle at the air interface when the polymerizable liquid crystal composition according to the embodiment is formed into an optically anisotropic product is a compound having repeat units each represented by general formula (7) below and having a weight-average molecular weight of 100 or more.

[Chem. 49]

CR¹¹R¹²—CR¹³R¹⁴ (7)

In the formula, R¹¹, R¹², R¹³, and R¹⁴ each independently represent a hydrogen atom, a halogen atom, or a hydrocarbon group having 1 to 20 carbon atoms. Hydrogen atoms in the hydrocarbon group may be replaced with one or more halogen atoms.

Suitable examples of the compound represented by general formula (7) include polyethylene, polypropylene, polyisobutylene, paraffin, liquid paraffin, chlorinated polypropylene, chlorinated paraffin, and chlorinated liquid paraffin.

The amount of the compound represented by general formula (7) added is preferably 0.01 to 1 part by mass, more preferably 0.05 to 0.5 parts by mass based on 100 parts by mass of the polymerizable liquid crystal compounds contained in the polymerizable liquid crystal composition.

A compound that has a polymerizable group and that is a non-liquid crystalline compound may be added to the polymerizable liquid crystal composition of the embodiment. As such a compound, any compound that is usually recognized as a polymerizable monomer or a polymerizable oligomer in this technical field can be used without particular limitation. The amount of the polymerizable group-containing non-liquid crystalline compound added is preferably 0.01 to 15 parts by mass, more preferably 0.05 to 10 parts by mass, particularly preferably 0.05 to 5 parts by mass based on 100 parts by mass of the polymerizable liquid crystal compounds contained in the polymerizable liquid crystal composition. Specific examples thereof include mono(meth)acrylates, such as methyl (meth)acrylate, ethyl (meth)acrylate, 2-hydroxyethyl acrylate, propyl (meth)acrylate, 2-hydroxypropyl (meth)acrylate, butyl (meth)acrylate, isobutyl (meth)acrylate, 4-hydroxybutyl (meth)acrylate, 2-hydroxybutyl (meth)acrylate, octyl (meth)acrylate, 2-ethylhexyl (meth)acrylate, dodecyl (meth)acrylate, stearyl (meth)acrylate, cyclohexyl (meth)acrylate, dicyclopentanyloxylethyl (meth)acrylate, isobornyloxylethyl (meth)acrylate, isobornyl (meth)acrylate, adamantyl (meth)acrylate, dimethyladamantyl (meth)acrylate, dicyclopentanyl (meth)acrylate, dicyclopentenyl (meth)acrylate, dicyclopentenyloxyethyl (meth)acrylate, methoxyethyl (meth)acrylate, ethylcarbitol (meth)acrylate, tetrahydrofurfuryl (meth)acrylate, benzyl (meth)acrylate, phenoxyethyl (meth)acrylate, 2-phenoxy diethylene glycol (meth)acrylate, ω-carboxy-polycaprolactone (n≅2) monoacrylate, 2-hydroxy-3-phenoxypropyl acrylate, 2-hydroxy-3-phenoxyethyl (meth) acrylate, (2-methyl-2-ethyl-1,3-dioxolan-4-yl)methyl (meth)acrylate, (3-ethyloxetan-3-yl)methyl (meth)acrylate, o-phenylphenolethoxy (meth)acrylate, dimethylamino (meth)acrylate, diethylamino (meth)acrylate, 2,2,3,3,3-pentafluoropropyl (meth)acrylate, 2,2,3,4,4,4-hexafluorobutyl (meth)acrylate, 2,2,3,3,4,4,4-heptafluorobutyl (meth)acrylate, 2-(perfluorobutyl)ethyl (meth)acrylate, 2-(perfluorohexyl)ethyl (meth)acrylate, 1H,1H,3H-tetrafluoropropyl (meth)acrylate, 1H,1H,5H-octafluoropentyl (meth)acrylate, 1H,1H,7H-dodecafluoroheptyl (meth)acrylate, 1H-1-(trifluoromethyl)trifluoroethyl (meth)acrylate, 1H,1H,3H-hexafluorobutyl (meth)acrylate, 1,2,2,2-tetrafluoro-1-(trifluoromethyl)ethyl (meth)acrylate, 1H,1H-pentadecafluorooctyl (meth)acrylate, 1H,1H,2H,2H-tridecafluorooctyl (meth)acrylate, 2-(meth)acryloyloxyethylphthalic acid, 2-(meth)acryloyloxyethylhexahydrophthalic acid, glycidyl (meth)acrylate, 2-(meth)acryloyloxyethylphosphoric acid, acryloylmorpholine, dimethylacrylamide, dimethylaminopropylacrylamide, iropropylacrylamide, diethylacrylamide, hydroxyethylacrylamide, and N-acryloyloxyethylhexahydrophthalimide; diacrylates, such as 1,4-butanediol di(meth)acrylate, 1,6-hexanediol di(meth)acrylate, 1,9-nonanediol di(meth)acrylate, neopentyldiol di(meth)acrylate, tripropylene glycol di(meth)acrylate, ethylene glycol di(meth)acrylate, diethylene glycol di(meth)acrylate, triethylene glycol di(meth)acrylate, ethylene oxide-modified bisphenol A di(meth)acrylate, tricyclodecanedimethanol di(meth)acrylate, 9,9-bis[4-(2-acryloyloxyethoxy)phenyl]fluorene, glycerol di(meth)acrylate, 2-hydroxy-3-acryloyloxypropyl methacrylate, an acrylic acid adduct of 1,6-hexanediol diglycidyl ether, and an acrylic acid adduct of 1,4-butanediol diglycidyl ether; tri(meth)acrylates, such as trimethylolpropane tri(meth)acrylate, ethoxylated isocyanuric acid triacrylate, pentaerythritol tri(meth)acrylate, and ε-caprolactone-modified tris-(2-acryloyloxyethyl) isocyanurate; tetra (meth)acrylates, such as pentaerythritol tetra(meth)acrylate and ditrimethylolpropane tetra(meth)acrylate; dipentaerythritol hexa(meth)acrylate; (meth)acrylate oligomers; various urethane acrylates; various macromonomers; epoxy compounds, such as ethylene glycol diglycidyl ether, diethylene glycol diglycidyl ether, propylene glycol diglycidyl ether, neopentyl glycol diglycidyl ether, 1,6-hexanediol diglycidyl ether, glycerol diglycidyl ether, and bisphenol A diglycidyl ether; and maleimide. These may be used alone or in combination of two or more as a mixture.

A chain transfer agent is preferably added to the polymerizable liquid crystal composition according to the embodiment in order to further improve the adhesion of an optically anisotropic product to be obtained to a base material. The chain transfer agent is preferably a thiol compound, more preferably a monothiol, dithiol, trithiol, or tetrathiol compound, even more preferably a trithiol compound. Specifically, compounds represented by general formulae (8-1) to (8-13) below are preferred.

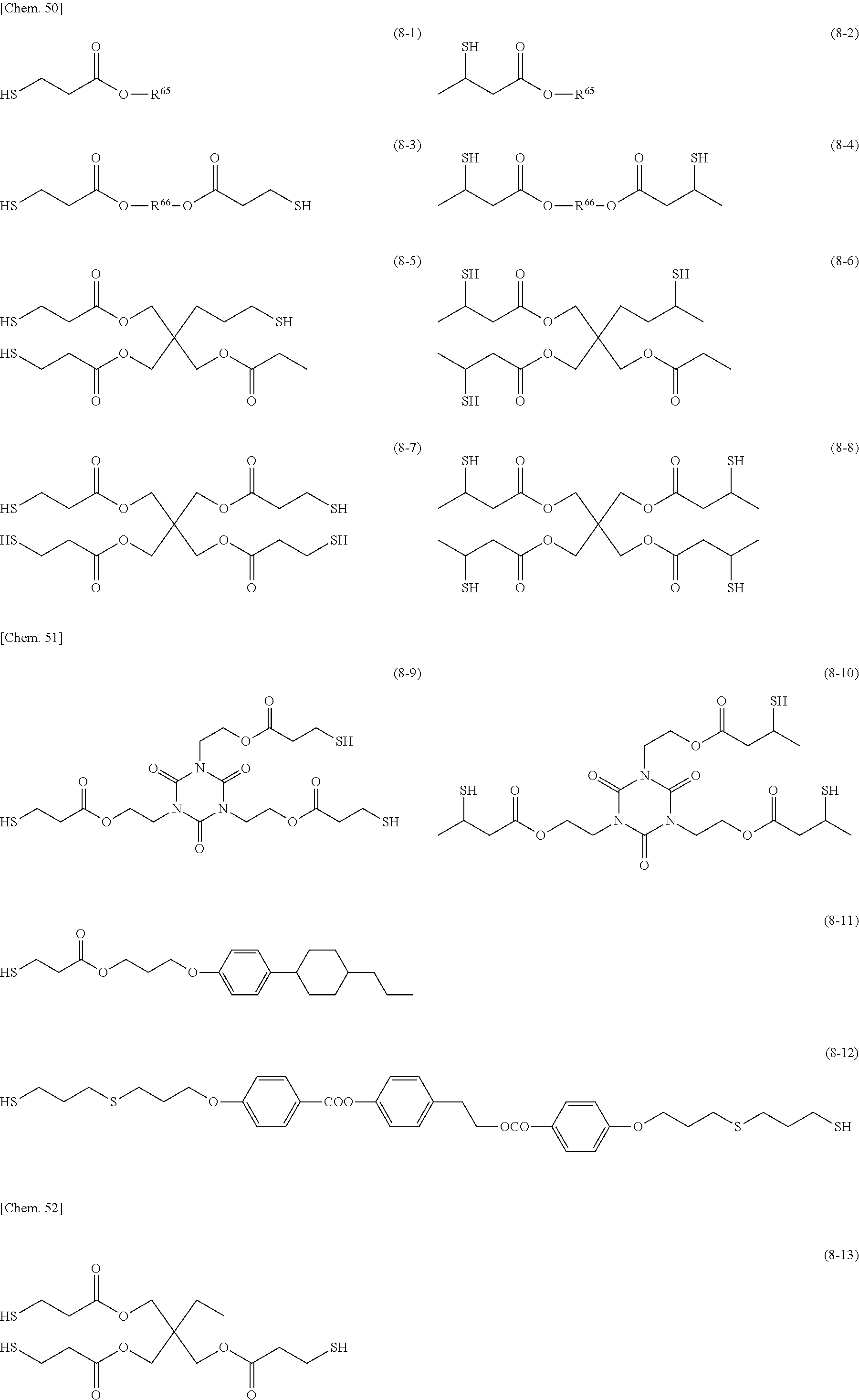

In the formulae, each R⁶⁵ represents an alkyl group having 2 to 18 carbon atoms. The alkyl group may be linear or branched. One or more methylene groups in the alkyl group may each be replaced with an oxygen atom, a sulfur atom, —CO—, —OCO—, —COO—, or —CH═CH—, provided that the oxygen atom and the sulfur atom are not directly bonded to each other. Each R⁶⁶ represents an alkylene group having 2 to 18 carbon atoms. One or more methylene groups in the alkylene group may each be replaced with an oxygen atom, a sulfur atom, —CO—, —OCO—, —COO—, or —CH═CH—, provided that the oxygen atom and the sulfur atom are not directly bonded to each other.

As a chain transfer agent other than thiol, α-methylstyrene dimer is also preferably used. The amount of the chain transfer agent added is preferably 0.5 to 10 parts by mass, more preferably 1.0 to 5.0 parts by mass based on 100 parts by mass of the polymerizable liquid crystal compounds in the polymerizable liquid crystal composition.

The polymerizable liquid crystal composition of the embodiment may contain a dye, as needed. The dye used is not particularly limited. A known and commonly used dye may be contained to the extent that the orientation is not disturbed.

Examples of the dye described above include dichroic dyes and fluorescent dyes. Examples of such a dye include polyazo dyes, anthraquinone dyes, cyanine dyes, phthalocyanine dyes, perylene dyes, perinone dyes, and squalirium dyes. From the viewpoint of addition, a dye that exhibits liquid crystallinity is preferred. For example, dyes that may be used are described in, for example, U.S. Pat. No. 2,400,877, Dreyer J. F., Phys. and Colloid Chem., 1948, 52, 808., “The Fixing of Molecular Orientation”, Dreyer J. F., Journal de Physique, 1969, 4, 114., “Light Polarization from Films of Lyotropic Nematic Liquid Crystals”, J. Lydon, “Chromonics” in “Handbook of Liquid Crystals Vol. 2B: Low Molecular Weight Liquid Crystals II”, D. Demus, J. Goodby, G. W. Gray, H. W. Spiessm, V. Villed, Willey-VCH, P. 981-1007 (1998), Dichroic Dyes for Liquid Crystal Display A. V. Ivashchenko CRC Press, 1994, and “Kinosei Shikiso Shijo no Shin Tenkai (New Development of Functional Dye Market)”, first chapter, p. 1, 1994, published by CMC Corporation.

Examples of the dichroic dyes include dichroic dyes represented by formulae (d-1) to (d-8) below.

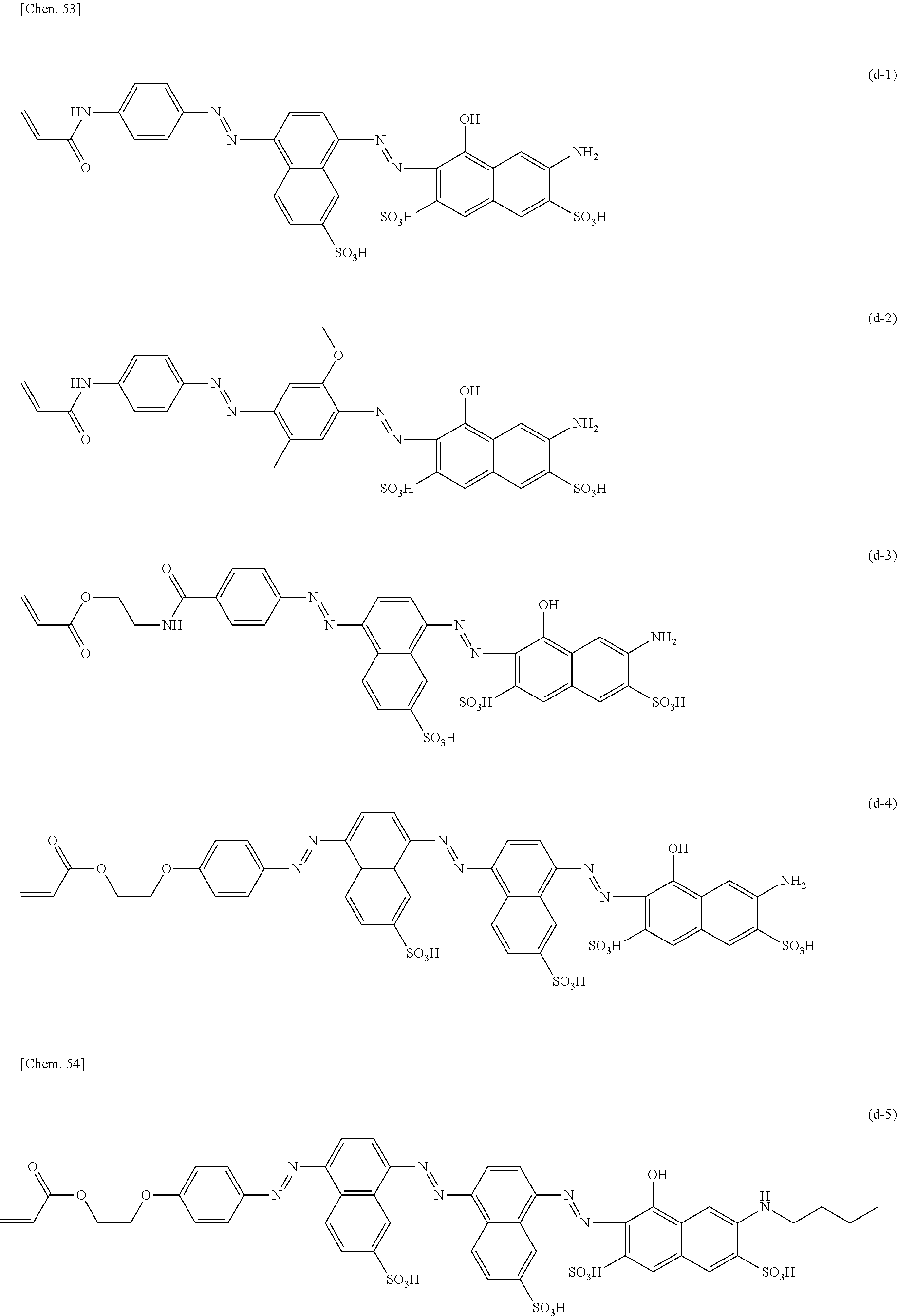

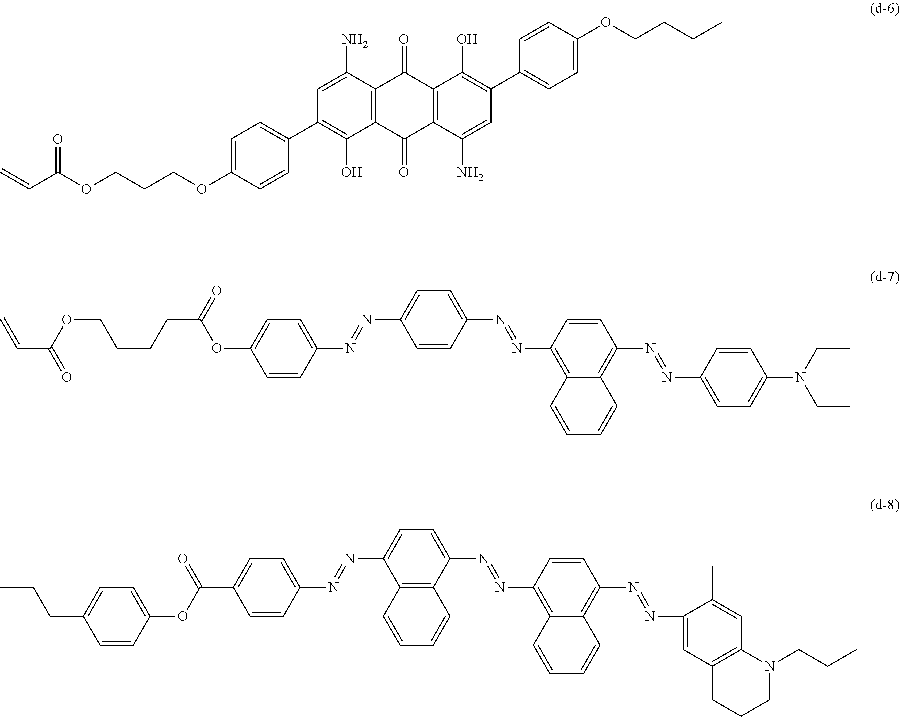

The amount of dye, such as the dichroic dye, added is preferably 0.001 to 10 parts by mass, more preferably 0.01 to 5 parts by mass based on 100 parts by mass of the total amount of the polymerizable liquid crystal compound contained in a powder mixture.

The polymerizable liquid crystal composition of the embodiment may contain a filler, as needed. The filler used is not particularly limited. A known and commonly used filler may be contained to the extent that the thermal conductivity of a polymer to be obtained does not decrease. Specific examples thereof include inorganic fillers, such as alumina, titanium white, aluminum hydroxide, talc, clay, mica, barium titanate, zinc oxide, and glass fibers, metal powers, such as silver powder and copper powder, thermally conductive fillers, such as aluminum nitride, boron nitride, silicon nitride, gallium nitride, silicon carbide, magnesia (aluminum oxide), alumina (aluminum oxide), crystalline silica (silicon oxide), and fused silica (silicon oxide), and silver nanoparticles.

For the purpose of adjusting the physical properties, additives, such as a non-liquid crystalline polymerizable compound, a thixotropic agent, an ultraviolet absorber, an infrared absorber, an antioxidant, and a surface treatment agent, may be added to the extent that the alignment ability of the liquid crystals is not significantly decreased, according to the purposes.

Next, the optical film of the embodiment is composed of the cured product of the polymerizable liquid crystal composition that has been described in detail above. A specific example of a method for producing an optical film from the polymerizable liquid crystal composition of the embodiment is a method in which the polymerizable liquid crystal composition is applied to a base material, dried, and subjected to ultraviolet irradiation.

The base material used for the optical film of the embodiment is a base material that is usually used for liquid crystal devices, displays, optical components, and optical films and is not particularly limited as long as it is a material having heat resistance that can withstand heating during drying after application of the polymerizable liquid crystal composition of the embodiment. Examples of such a base material include organic materials, such as glass base materials, metal base materials, ceramic base materials, and plastic base materials. In particular, when the base material is composed of an organic material, examples thereof include cellulose derivatives, polyolefin, polyester, polycarbonate, polyacrylate (acrylic resins), polyarylate, poly(ether sulfone), polyimide, poly(phenylene sulfide), poly(phenylene ether), nylon, and polystyrene. Among these, plastic base materials, such as polyester, polystyrene, polyacrylate, polyolefin, cellulose derivatives, polyarylate, and polycarbonate, are preferred. The base materials such as polyester, polyacrylate, polyolefin, and cellulose derivatives are more preferred. It is particularly preferable that poly(ethylene terephthalate) (PET) be used as polyester, a cycloolefin polymer (COP) be used as polyolefin, triacetyl cellulose (TAC) be used as a cellulose derivative, and poly(methyl methacrylate) (PMMA) be used as polyacrylate. The base material may have a flat plate shape or a shape with a curved surface. These base materials may each have an electrode layer, an antireflection function, and a reflection function, as needed.

To improve the coatability and adhesion of the polymerizable liquid crystal composition of the embodiment, these base materials may be subjected to surface treatment. Examples of the surface treatment include ozone treatment, plasma treatment, corona treatment, and silane coupling treatment. To adjust the transmittance and reflectance of light, for example, an organic thin film, an inorganic oxide thin film, or a thin metal film may be provided by a method, such as vapor deposition. To add optical value, the base material may be, for example, a pickup lens, a rod lens, an optical disc, a retardation film, a light diffusing film, or a color filter. Among these, the pickup lens, the retardation film, the light diffusing film, and the color filter are preferred because of their higher added value.

Regarding the base material, an alignment film is preferably disposed on a glass base material alone or the base material in such a manner that the polymerizable liquid crystal composition is aligned when the polymerizable liquid crystal composition of the embodiment is applied and dried. Examples of alignment treatment include stretching treatment, rubbing treatment, polarized ultraviolet-visible light irradiation treatment, and ion-beam treatment. When the alignment film is used, a known and commonly used alignment film is used. As such an alignment film, for example, polyimide, polyamide, lecithin, a hydrophilic polymer containing a hydroxy group, a carboxylic group, or a sulfonic group, a hydrophilic inorganic compound, or a photo-alignment film can be used. Examples of the hydrophilic polymer include poly(vinyl alcohol), poly(acrylic acid), sodium polyacrylate, polymethacrylate, sodium polyalginate, polycarboxymethylcellulose sodium salt, pullulan, and poly(styrene sulfonate). Examples of the hydrophilic inorganic compound include inorganic compounds, such as oxides and fluorides of Si, Al, Mg, and Zr. The hydrophilic base material is effective in aligning the optical axes of the optically anisotropic product substantially parallel to the normal direction of the base material and is thus preferred to obtain the optically anisotropic product of a positive C-plate. When the hydrophilic base material is subjected to rubbing treatment, the hydrophilic base material acts as a homogeneous alignment film. Thus, rubbing treatment on the hydrophilic polymer layer adversely affects homeotropic alignment properties and thus is not preferable in order to obtain an optical film of a positive C-plate.

As a method of applying the polymerizable liquid crystal composition of the embodiment to the above-described base material, the following known and commonly used methods can be employed: for example, an applicator method, a bar coating method, a spin coating method, a roll coating method, a direct gravure coating method, a reverse gravure coating method, a flexographic coating method, an inkjet method, a die coating method, a cap coating method, a dip coating method, and a slit coating method. The polymerizable liquid crystal composition is applied, and then a solvent contained in the polymerizable liquid crystal composition is evaporated by heating, as needed.

The polymerization operation of the polymerizable liquid crystal composition of the embodiment is typically performed by irradiation with light, such as ultraviolet light or by heating, in a state in which the liquid crystal compound in the polymerizable liquid crystal composition is cholesterically aligned with respect to the base material. When the polymerization is performed by irradiation with light, specifically, it is preferable to perform irradiation with ultraviolet light with a wavelength of 390 nm or less. It is most preferable to perform irradiation with light with a wavelength of 250 to 370 nm. However, when the polymerizable liquid crystal composition is decomposed by ultraviolet light with a wavelength of 390 nm or less, polymerization treatment is preferably performed by ultraviolet light with a wavelength of 390 nm or more, in some cases. This light is preferably diffused and unpolarized light.

Examples of a method for polymerizing the polymerizable liquid crystal composition of the embodiment include a method for irradiation with active energy rays; and a thermal polymerization method. Because a reaction proceeds at room temperature without the need for heating, the method for irradiation with active energy rays is preferred. In particular, a method for irradiation with light, such as ultraviolet light, is preferred because of its simple operation.

The temperature during irradiation is a temperature at which the polymerizable liquid crystal composition of the embodiment can maintain a liquid crystal phase and is preferably 50° C. or lower as much as possible to avoid induction of thermal polymerization of the polymerizable liquid crystal composition.

When irradiation is performed with light, such as ultraviolet light, the irradiation intensity and the irradiation energy greatly affect the heat resistance of an optical film to be obtained. An insufficiently low irradiation intensity or irradiation energy causes the formation of a portion where a polymerization reaction is not completed and thus affects the heat resistance. An excessively high irradiation intensity or irradiation energy causes a difference in the degree of polymerization in the depth direction of the layer and similarly affects the heat resistance. Regarding the irradiation intensity, irradiation is preferably performed with UVA light (UVA is ultraviolet light with a wavelength of 315 to 380 nm) having an irradiation intensity of 30 to 2,000 mW/cm², more preferably 50 to 1,500 mW/cm², even more preferably 120 to 1,000 mW/cm², most preferably 250 to 1,000 mW/cm². Regarding the irradiation energy, irradiation is preferably performed with UVA light with 100 to 5,000 mJ/cm², more preferably 150 to 4,000 mJ/cm², even more preferably 200 to 3,000 mJ/cm², most preferably 300 to 1,000 mJ/cm². For the UV irradiation, a method in which irradiation is performed multiple times may also be employed. The intensity at the first irradiation is preferably the UV intensity described above. The energy at the first irradiation is more preferably the UV irradiation energy described above.

In the case where the bifunctional polymerizable liquid crystal compound represented by general formula (I-1) and the monofunctional polymerizable liquid crystal compound represented by general formula (II-1) in the embodiment are used in a ratio by mass of 90/10 to 50/50 [(I-1)/(II-1)], irradiation is preferably performed with UVA in an amount of irradiation of 300 to 1,000 mJ/cm² from the viewpoint of achieving good heat resistance.

An optical film obtained by polymerizing the polymerizable liquid crystal composition of the embodiment can be peeled off from a substrate and used alone as an optical film, or can be used as it is without peeling off from the substrate. In particular, the optical film is less likely to contaminate other members and is thus useful when used as a substrate to be stacked or when bonded to another substrate and used.

The optical film obtained in this way can exhibit good color purity as a cholesteric reflection film. The cholesteric reflection film can be used as: a negative C-plate in which a rod-like liquid crystal compound is cholesterically aligned with respect to a base material, a selective reflection film (band-stop filter) that reflects light having a specific wavelength, and a twisted positive A-plate in which a rod-like liquid crystal compound is homogeneously aligned in a twisted alignment state with respect to a base material.

The cholesteric liquid crystal layer of the embodiment can be stacked with a λ/4 plate and a dual brightness enhanced film (DBEF) to selectively reflect only an unnecessary color of light from a light source, thereby increasing the color purity.

A λ/2 plate (or λ/2 layer) according to the embodiment is not particularly limited. A known λ/2 plate can be used. A preferable λ/2 plate obtained by appropriately changing it, as needed, can be used.

The λ/2 plate is obtained, for example, by stretching a cured product of a composition containing a combination of the polymerizable liquid crystal compounds or a film composed of a transparent resin. As the transparent resin, a transparent resin having an average film pressure of 0.1 mm and a total light transmittance of 80% or more can be used. Examples thereof include acetate-based resins, such as triacetylcellulose, polyester-based resins, poly(ether sulfone)-based resins, polycarbonate-based resins, linear polyolefin-based resins, polymer resins having alicyclic structures (norbornene-based polymers, monocyclic olefin-based polymers, cyclic conjugated diene-based polymers, vinyl alicyclic hydrocarbon polymers, and hydrogenated resins thereof), acrylic resins, poly(vinyl alcohol)-based resins, and poly(vinyl chloride)-based resins.

If necessary, known additives, such as an antioxidant, a heat stabilizer, a light stabilizer, an ultraviolet absorber, an antistatic agent, and a dispersant, may be added to the transparent resin.

### (Liquid Crystal Panel)

The structure of the liquid crystal panel of the liquid crystal display device will be described below.

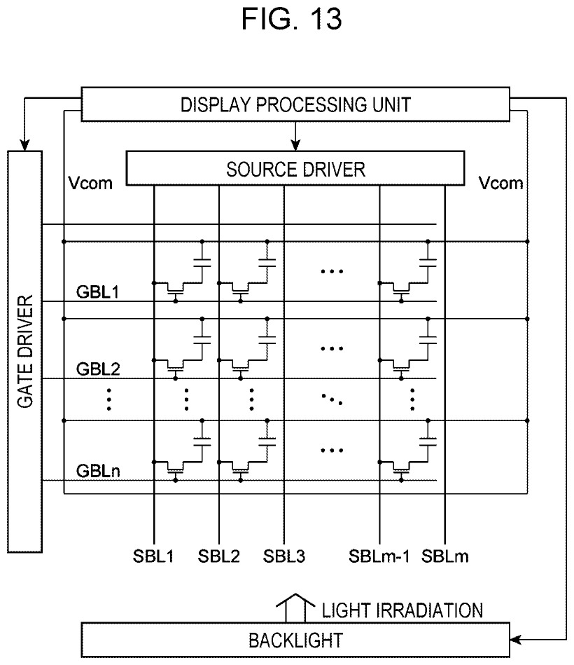

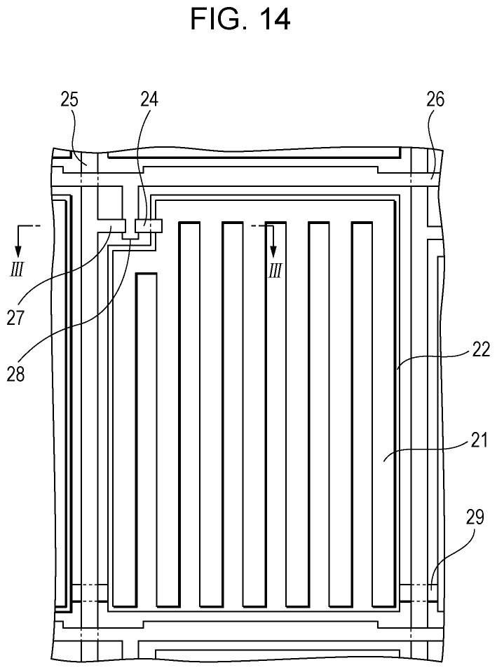

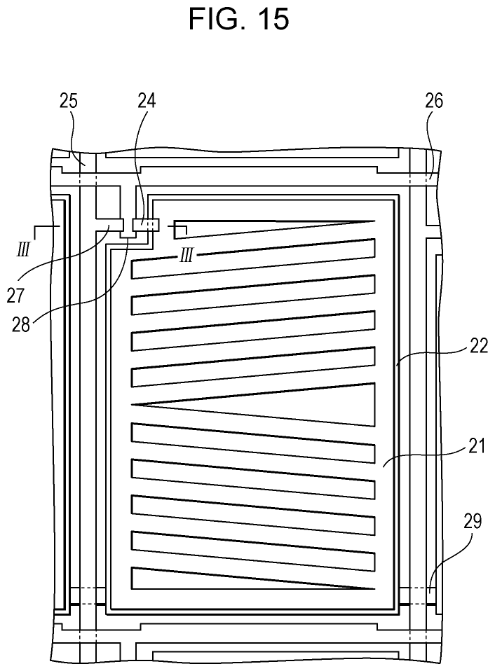

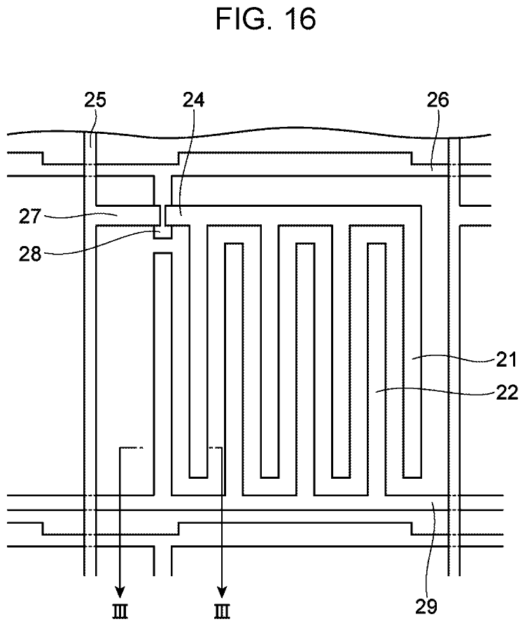

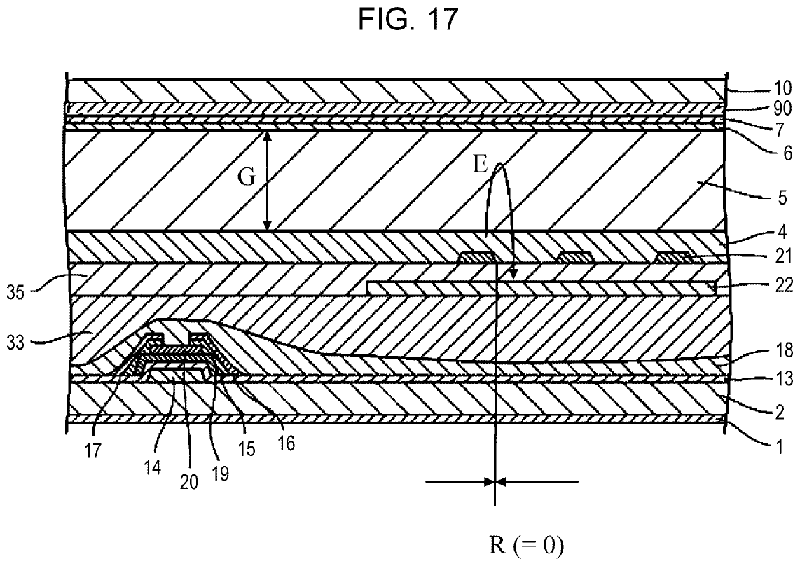

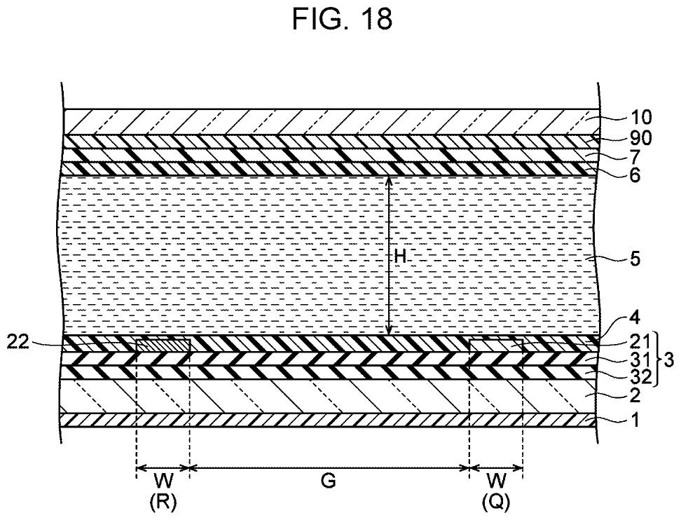

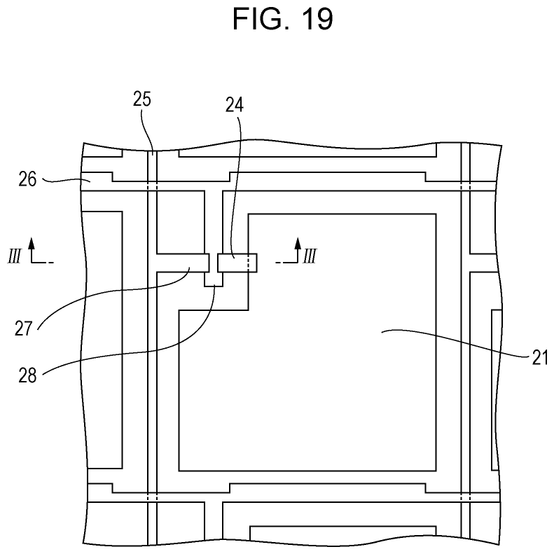

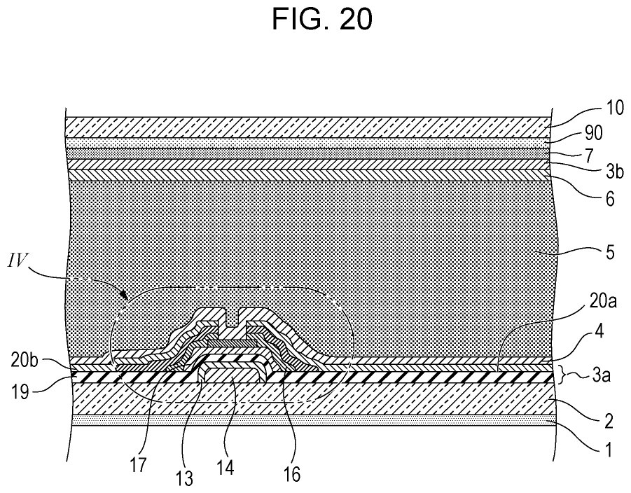

Preferred embodiments of the liquid crystal panels 200A and 200B will be described with reference to FIGS. 13 to 20. FIG. 13 is a schematic structural diagram of the electrode layer 3 in a liquid crystal display portion and is a schematic diagram of an equivalent circuit of the electrode portion of each of the liquid crystal panels 200A and 200B. FIGS. 14 and 15 are each a schematic view of an example of the shape of pixel electrodes and are each a schematic view of the electrode structure of an FFS-mode liquid crystal display device according to an example of the embodiment. FIG. 17 is a schematic cross-sectional view of the liquid crystal panel of the FFS-mode liquid crystal display device. FIG. 16 is a schematic view of the electrode structure of an IPS-mode liquid crystal display device according to an example of the embodiment. FIG. 18 is a schematic cross-sectional view of the liquid crystal panel of the IPS-mode liquid crystal display device. FIG. 19 is a schematic view of the electrode structure of a VA-mode liquid crystal display device according to an example of the embodiment. FIG. 20 is a schematic cross-sectional view of the liquid crystal panel of a VA-mode liquid crystal display device. As illustrated in FIGS. 1 and 2, the liquid crystal panels 200A and 200B are driven as liquid crystal display devices by providing a backlight unit as an illuminating unit for illuminating the liquid crystal panels 200A and 200B from the side surface or the back surface.

In FIGS. 1, 2, and 13, the electrode layers 3a and 3b each include one or more common electrodes and/or one or more pixel electrodes. For example, in an FFS-mode liquid crystal display device, the pixel electrodes are disposed above the common electrodes with an insulating layer (for example, silicon nitride (SiN)) provided therebetween. In a VA-mode liquid crystal display device, the pixel electrodes and the common electrodes are disposed opposite each other with the liquid crystal layer 5 provided therebetween.

The pixel electrodes are disposed in respective display pixels and have slit-like opening portions. The common electrodes and the pixel electrodes are transparent electrodes composed of, for example, indium tin oxide (ITO). The electrode layer 3 includes, in the display portion, gate bus lines GBLs (GBL1, GBL2, . . . , and GBLm) extending along rows of multiple display pixels, source bus lines SBLs (SBL1, SBL2, . . . , and SBLm) extending along columns of multiple display pixels, and thin-film transistors serving as pixel switches near positions where the gate bus lines and the source bus lines intersect. The thin-film transistors have gate electrodes electrically connected to corresponding gate bus lines GBLs. The thin-film transistors have source electrodes electrically connected to corresponding signal lines SBLs. The thin-film transistors have drain electrodes electrically connected to corresponding pixel electrodes.

The electrode layer 3 includes a gate driver and a source driver as driving units for driving the multiple display pixels. The gate driver and the source driver are disposed around the liquid crystal display portion. The multiple gate bus lines are electrically connected to output terminals of the gate driver. The multiple source bus lines are electrically connected to output terminals of the source driver.

The gate driver sequentially applies an on-state voltage to the multiple gate bus lines and supplies an on-state voltage to the gate electrodes of the thin-film transistors electrically connected to the selected gate bus lines. Electrical conduction is established between the source electrode and the drain electrode of each thin-film transistor whose gate electrode is supplied with the on-state voltage. The source driver supplies output signals corresponding to the respective source bus lines. Each of the signals supplied to the source bus lines is applied to a corresponding one of the pixel electrodes via the thin-film transistor in which the electrical conduction is established between the source electrode and the drain electrode. The operations of the gate driver and the source driver are controlled by a display processing unit (also referred to as a “control circuit”) disposed outside the liquid crystal display device.

The display processing unit according to the embodiment may have a low-frequency driving function and an intermittent driving function in addition to normal driving in order to reduce the driving power and controls the operation of the gate driver that is an LSI configured to drive the gate bus lines of the TFT-matrix liquid crystal panel and the operation of the source driver that is an LSI configured to drive the source bus lines of the TFT-matrix liquid crystal panel. Additionally, the display processing unit supplies a common voltage V_{COM} to the common electrodes and also controls the operation of the backlight unit. For example, the display processing unit according to the embodiment may have local-dimming means in which the entire display screen is divided into multiple areas and the light intensity of backlight is adjusted in accordance with the brightness of an image displayed on each of the areas.

Examples of an FFS-mode liquid crystal panel according to the embodiment will be described with reference to FIGS. 14, 15, and 17.

FIG. 14 illustrates a comb-shaped pixel electrode as an example of shapes of the pixel electrodes and is an enlarge plan view of a region of the electrode layer 3 surrounded by line XIV, the electrode layer 3 being disposed on the first substrate 2 in FIGS. 4 and 2. As illustrated in FIG. 14, in the electrode layer 3 including the thin-film transistor disposed on the surface of the first substrate 2, multiple gate bus lines 26 for supplying a scan signal and multiple source bus lines 25 for supplying a display signal are arranged in a matrix so as to intersect with each other. A unit pixel of the liquid crystal display device is defined by a region surrounded by the multiple gate bus lines 26 and the multiple source bus lines 25. In the unit pixel, a pixel electrode 21 and a common electrode 22 are disposed. A thin-film transistor including a source electrode 27, a drain electrode 24, and a gate electrode 28 is disposed near an intersectional portion of the gate bus lines 26 and the source bus lines 25. The thin-film transistor serving as a switching element for supplying a display signal to the pixel electrode 21 is connected to the pixel electrode 21. A common line 29 is disposed parallel to the gate bus lines 26. The common line 29 is connected to the common electrode 22 to supply a common signal to the common electrode 22.

The common electrode 22 is disposed over the entire back surface of the pixel electrode 21 with an insulating layer 18 (not illustrated). The horizontal component of the shortest separation path between the common and pixel electrodes adjacent to each other is shorter than the shortest separation distance (cell gap) between the alignment layers (or the substrates). A surface of the pixel electrode is preferably covered with a protective insulating film and the alignment layer. The “horizontal component of the shortest separation path” used here indicates a component in the horizontal direction with respect to the substrate when the shortest separation path connecting the common electrode and the pixel electrode adjacent to each other is divided into the horizontal direction with respect to the substrate and the vertical direction (=thickness direction) with respect to the substrate. A storage capacitor (not illustrated) for storing a display signal supplied through the source bus line 25 may be disposed in the region surrounded by the multiple gate bus lines 26 and the multiple source bus lines 25.

FIG. 15 is a modification of FIG. 14 and illustrates a slit pixel electrode as an example of the shapes of the pixel electrode. The pixel electrode 21 illustrated in FIG. 15 is a substantially rectangular flat plate electrode, the middle portion and both end portions of the flat plate having triangular holes, and the other portion having substantially rectangular holes. The shapes of the holes are not particularly limited. Holes having known shapes, such as ellipses, circles, rectangles, rhombi, triangles, and parallelograms, can be used.

FIGS. 14 and 15 each illustrate only a pair of the gate bus lines 26 and a pair of the source bus lines 25 in one pixel.

FIG. 17 is a cross-sectional view of an example of a liquid crystal display device taken along line III-III of FIG. 14 or 15. The first substrate 2 including the first alignment layer 4 and the electrode layer 3 having the thin-film transistor (TFT) disposed on one surface thereof and the first polarizing layer 1 disposed on the other surface thereof is spaced apart from the second substrate 10 including the second alignment layer 6, the second polarizing layer 7, and a light conversion film 90 disposed on one surface thereof at a predetermined gap G in such a manner that the alignment layers face each other. The liquid crystal layer 5 containing a liquid crystal composition is disposed between the first substrate 2 and the second substrate 10. A gate insulating layer 13, the thin-film transistor (14, 15, 16, 17, and 19), a passivation film 18, a planarization film 33, the common electrode 22, an insulating film 35, the pixel electrode 21, and the first alignment layer 4 are stacked in this order on part of a surface of the first substrate 2. While FIG. 17 illustrates an example in which two layers of the passivation film 18 and the planarization film 33 are separately disposed, one layer of a planarization film having functions of both the passivation film 18 and the planarization film 33 may be disposed. While FIG. 17 illustrates an example in which the alignment layers 4 and 6 are disposed, the alignment layers 4 and 6 need not necessarily be disposed as illustrated in FIG. 2. The light conversion film 90 includes the light conversion layer and the wavelength-selective transmission layer.

In the FFS-mode liquid crystal panel illustrated in FIG. 17, the preferred embodiment of the light conversion film according to the embodiment has been described above. The preferred embodiment of the light conversion film can also be applied to the light conversion film 90 in an IPS-mode liquid crystal display device or a VA-mode liquid crystal display device.

In FIG. 17, the thin-film transistor according to a preferred embodiment has a structure including a gate electrode 14 disposed on a surface of the substrate 2, the gate insulating layer 13 disposed so as to cover the gate electrode 14 and substantially the entire surface of the substrate 2, a semiconductor layer 19 disposed on a surface of the gate insulating layer 13 so as to face the gate electrode 14, a protective film 20 disposed so as to partially cover a surface of the semiconductor layer 19, a drain electrode 16 disposed so as to cover one side end portion of each of the protective film 20 and the semiconductor layer 19 and so as to be in contact with the gate insulating layer 13 disposed on the surface of the substrate 2, a source electrode 17 so as to cover the other side end portion of each of the protective film 20 and the semiconductor layer 19 and so as to be in contact with the gate insulating layer 13 disposed on the surface of the substrate 2, and the insulating protective film 18 disposed so as to cover the drain electrode 16 and the source electrode 17. An anodized film (not illustrated) may be disposed on a surface of the gate electrode 14 for the purpose of, for example, eliminating a step from the gate electrode.

In the FFS-mode liquid crystal panel according to the embodiment as illustrated in FIG. 17, the common electrode 22 is a flat-plate electrode disposed over substantially the entire surface of the gate insulating layer 13. The pixel electrode 21 is a comb-shaped electrode disposed on the insulating protective layer 18 covering the common electrode 22. That is, the common electrode 22 is disposed closer to the first substrate 2 than the pixel electrode 21, and these electrodes are disposed so as to overlap each other with the insulating protective layer 18 provided therebetween. The pixel electrode 21 and the common electrode 22 are composed of, for example, a transparent conductive material, such as indium tin oxide (ITO), indium zinc oxide (IZO), or indium zinc tin oxide (IZTO). Because the pixel electrode 21 and the common electrode 22 are composed of the transparent conductive material, the aperture area of the unit pixel is large, thus resulting in a higher aperture ratio and a higher transmittance.

The pixel electrode 21 and the common electrode 22 generate a fringing electric field therebetween and thus are formed in such a manner that the horizontal component R of the interelectrode path between the pixel electrode 21 and the common electrode 22 (also referred to as a “horizontal component of the shortest separation path”) is smaller than the thickness G of the liquid crystal layer 5 between the first substrate 2 and the second substrate 10. Here, the horizontal component R of the interelectrode path indicates the interelectrode distance in a horizontal direction with respect to the substrates. FIG. 17 illustrates the flat plate-shaped common electrode 22 and the comb-shaped pixel electrode 21 overlapping each other and thus an example in which the horizontal component of the shortest separation path (or the interelectrode distance) R=0. The horizontal component R of the shortest separation path is smaller than the thickness G (also referred to as a “cell gap”) of the liquid crystal layer between the first substrate 2 and the second substrate 10, thereby generating the fringing electric field E. Accordingly, in the FFS-mode liquid crystal display device, a horizontal electric field generated in a direction perpendicular to a line parallel to the comb shape of the pixel electrode 21 and a parabolic electric field can be used. The electrode width 1 of the comb-shaped portion of the pixel electrode 21 and the gap width m of the comb-shaped portion of the pixel electrode 21 are preferably determined to the extent that all the liquid crystal molecules in the liquid crystal layer 5 can be driven by the generated electric fields. The horizontal component R of the shortest separation path between the pixel electrode and the common electrode can be adjusted by the (average) thickness of the insulating film 35 or the like.

An example of an IPS-mode liquid crystal panel, which is a modified embodiment of the FFS-mode liquid crystal panel of the liquid crystal display device according to the embodiment, will be described with reference to FIGS. 16 and 18. The liquid crystal panel of the IPS-mode liquid crystal display device has a structure in which the electrode layer 3 (including common electrodes, pixel electrodes, and TFTs) is disposed on one substrate, similarly to the FFS mode illustrated in FIG. 1. The structure includes the first polarizing layer 1, the first substrate 2, the electrode layer 3, the first alignment layer 4, the liquid crystal layer 5 containing a liquid crystal composition, the second alignment layer 6, the second polarizing layer 7, the light conversion film 90, and the second substrate 10 stacked in this order.

FIG. 16 is an enlarged plan view of a region of the electrode layer 3 surrounded by line XIV, the electrode layer 3 being disposed on the first substrate 2 of an IPS-mode liquid crystal display portion in FIG. 13. As illustrated in FIG. 16, a comb-shaped first electrode (for example, a pixel electrode) 21 and a comb-shaped second electrode (for example, a common electrode) 22 are disposed in a state in which these electrodes are loosely fitted with each other (a state in which both electrodes are separated and engaged with a certain distance kept therebetween) in a region (in a unit pixel) surrounded by the multiple gate bus lines 26 for supplying a scan signal and the multiple source bus lines 25 for supplying a display signal. In the unit pixel, a thin-film transistor including the source electrode 27, the drain electrode 24, and the gate electrode 28 is disposed near an intersectional portion of the gate bus lines 26 and the source bus lines 25. The thin-film transistor serves as a switching element for supplying a display signal to the first electrode 21 and is connected to the first electrode 21. The common line (V_{COM}) 29 is disposed parallel to the gate bus lines 26. The common line 29 is connected to the second electrode 22 in order to supply a common signal to the second electrode 22.

FIG. 18 is a cross-sectional view of the IPS-mode liquid crystal panel taken along line III-III of FIG. 16. A gate insulating layer 32 is disposed on the first substrate 2 so as to cover the gate bus lines 26 (not illustrated) and substantially the entire surface of the first substrate 2. An insulating protective layer 31 is disposed on a surface of the gate insulating layer 32. The first electrode (pixel electrode) 21 and the second electrode (common electrode) 22 are disposed on the insulating protective layer 31 and are spaced apart from each other. The insulating protective layer 31 has an insulating function and is composed of, for example, silicon nitride, silicon dioxide, or silicon oxynitride. The first substrate 2 including the first alignment layer 4 and the electrode layer 3 having the thin-film transistor (TFT) disposed on one surface thereof and the first polarizing layer 1 disposed on the other surface thereof is spaced apart from the second substrate 10 including the second alignment layer 6, the second polarizing layer 7, and the light conversion layer 9 disposed on one surface thereof at a predetermined gap in such a manner that the alignment layers face each other. The liquid crystal layer 5 containing a liquid crystal composition is disposed in the gap. The light conversion film 90 includes the light conversion layer and the wavelength-selective transmission layer described above. The description of the light conversion film 90 is as described above.

In the example illustrated in FIGS. 16 and 18, the first electrode 21 and the second electrode 22 are the comb-shaped electrodes disposed on the insulating protective layer 31, i.e., on the same layer, and are spaced apart from and engaged with each other. In the IPS-mode liquid crystal display portion, the interelectrode distance G between the first electrode 21 and the second electrode 22 and the thickness (cell gap) H of the liquid crystal layer between the first substrate 2 and the second substrate 10 satisfy the relationship: G≥H. The interelectrode distance G indicates the shortest distance between the first electrode 21 and the second electrode 22 in the horizontal direction with respect to the substrate. In the embodiment illustrated in FIGS. 16 and 18, the interelectrode distance indicates a distance, in the horizontal direction, between the fingers of the first electrode 21 and the fingers of the second electrode 22 alternately loosely fitted. The distance H between the first substrate 2 and the second substrate 10 indicates the thickness of the liquid crystal layer between the first substrate 2 and the second substrate 10. Specifically, the distance indicates a distance (i.e., cell gap) between the alignment layers 4 (outermost surfaces) disposed on the first substrate 2 and the second substrate 10, in other words, indicates the thickness of the liquid crystal layer.

FIG. 18 illustrates an example in which the alignment layers 4 and 6 are disposed. However, the alignment layers 4 and 6 need not necessarily be disposed as illustrated in FIG. 4.

In the foregoing FFS-mode liquid crystal panel, the thickness of the liquid crystal layer between the first substrate 2 and the second substrate 10 is equal to or larger than the shortest distance between the pixel electrode 21 and the common electrode 22 in the horizontal direction with respect to the substrate. In the IPS-mode liquid crystal display portion, the thickness of the liquid crystal layer between the first substrate 2 and the second substrate 10 is less than the shortest distance between the pixel electrode 21 and the common electrode 22 in the horizontal direction with respect to the substrate.

In the IPS-mode liquid crystal panel, liquid crystal molecules are driven by the use of an electric field generated between the pixel electrode 21 and the common electrode 22 in the horizontal direction with respect to the substrate surface. The electrode width Q of the first electrode 21 and the electrode width R of the second electrode 22 are preferably determined to the extent that all the liquid crystal molecules in the liquid crystal layer 5 can be driven by the generated electric field.

Another preferred embodiment of the liquid crystal panel according to the embodiment is a vertical alignment-mode liquid crystal panel (VA-mode liquid crystal display). An example of the VA-mode liquid crystal panel of the liquid crystal display device according to the embodiment will be described with reference to FIGS. 19 and 20. FIG. 19 is an enlarged plan view of a region of the electrode layer 3 (also referred to as a “thin-film transistor layer 3”) surrounded by line XIV, the electrode layer 3 including a thin-film transistor on a substrate. FIG. 20 is a cross-sectional view of the liquid crystal panel, illustrated in FIGS. 3 and 8, taken along line III-III of FIG. 19.

The liquid crystal panel of the liquid crystal display device according to the embodiment includes, as illustrated in FIGS. 3 and 8, the second substrate 10 including the (transparent) electrode layer 3b (also referred to as a “common electrode 3b”), the second polarizing layer 7, and the light conversion layer 9, the first substrate 2 including the electrode layer 3 that includes a pixel electrode and a thin-film transistor that is disposed in each pixel and that controls the pixel electrode, and the liquid crystal layer 5 (composed of a liquid crystal composition) held between the first substrate 2 and the second substrate 10. The liquid crystal molecules in the liquid crystal composition are aligned substantially perpendicular to the substrates 2 and 7 when no voltage is applied. One of the features of this liquid crystal display device is that a specific liquid crystal composition is used for the light conversion layer. The electrode layer 3b is preferably composed of a transparent conductive material, similarly to other liquid crystal display devices. Although FIG. 18 illustrates an example in which the light conversion film 90 is disposed between the second substrate 10 and the second polarizing layer 7, the present invention is not necessarily limited thereto. Additionally, the pair of alignment layers 4 and 6 may be disposed on surfaces of the transparent electrodes (layers) 3a and 3b, as needed, so as to be adjacent to the liquid crystal layer 5 according to the embodiment and so as to be in direct contact with the liquid crystal composition contained in the liquid crystal layer 5 (in FIG. 20, the alignment layers 4 and 6 are illustrated). The first polarizing layer 1 is disposed on a surface of the first substrate 2 adjacent to the backlight unit. The second polarizing layer 7 is disposed between the transparent electrode (layer) 3b and the light conversion film 90. Accordingly, one of the preferred examples of the liquid crystal panel of the liquid crystal display device according to the embodiment has a structure in which the first substrate 2 including the first alignment layer 4 and the electrode layer 3 having the thin-film transistor disposed on one surface thereof and including the first polarizing layer 1 disposed on the other surface thereof is spaced apart from the second substrate 10 including the second alignment layer 6, the transparent electrode (layer) 3b, the second polarizing layer 7, and the light conversion film 90 disposed on one surface thereof at a predetermined gap in such a manner that the alignment layers face each other, and the liquid crystal layer 5 containing the liquid crystal composition is disposed between the first substrate 2 and the second substrate 10. The description of the light conversion film 90 is as described above.

FIG. 19 illustrates the pixel electrode having a “reversed L shape” as an example of the shape of the pixel electrode 21 and an enlarged plan view of a region of the electrode layer 3 surrounded by line XIV, the electrode layer 3 being disposed on the first substrate 2 in FIGS. 12 and 4. The pixel electrode 21 is disposed on substantially the entire surface of a region surrounded by the gate bus lines 26 and the source bus lines 25 so as to have the “reversed L shape”, similarly to FIGS. 14, 14, and 15. However, the shape of the pixel electrode is not limited thereto. A pixel electrode having a fishbone structure may be used for PSVA or the like. Other structures, functions, and the like of the pixel electrode 21 are as described above and thus are omitted here.

Unlike the IPS or FFS mode, in the liquid crystal panel portion of a vertical alignment-mode liquid crystal display device, the common electrode 3b (not illustrated) is opposed to and spaced apart from the pixel electrode 21 and is disposed on a substrate facing a TFT. In other words, the pixel electrode 21 is disposed on a substrate different from a substrate on which the common electrode 22 is disposed. In contrast, in each of the FFS- and IPS-mode liquid crystal display devices, the pixel electrode 21 and the common electrode 22 are disposed on the same substrate.

In the light conversion film 90, a black matrix (not illustrated) may be disposed on portions corresponding to the thin-film transistors and storage capacitors 23 from the viewpoint of preventing light leakage.

FIG. 20 is a cross-sectional view of the liquid crystal display device, illustrated in FIGS. 3 and 8, taken along line III-III of FIG. 19. That is, a liquid crystal panel 200 of the liquid crystal display device according to the embodiment has a structure in which the first polarizing layer 1, the first substrate 2, the electrode layer 3a (also referred to as a “thin-film transistor layer”) including a thin-film transistor, the first alignment layer 4, the liquid crystal layer 5 containing a liquid crystal composition, the second alignment layer 6, the common electrode 3b, the second polarizing layer 7, the light conversion film 90, and the second substrate 10 are stacked in this order. A preferred example of the structure of the thin-film transistor (region IV of FIG. 20) of the liquid crystal display device according to the embodiment is as described above and thus is omitted here.

The liquid crystal display device according to the embodiment may employ a local dimming technique in which the contrast is improved by controlling the luminance of a backlight unit 100 for each of multiple sections less than the number of liquid crystal pixels.

Regarding the local dimming technique, multiple light-emitting devices L can be used as light sources for specific regions of the liquid crystal panel and can be individually controlled in accordance with the luminance levels of the display regions. In this case, the multiple light-emitting devices L may be arranged in a plane or may be arranged in a row on one side of the liquid crystal panel 200.

Regarding the local dimming technique, in the case of a structure including the light guide section 102 of the backlight unit 100 and the liquid crystal panel 200, a control layer, serving as the light guide section 102, for controlling the amount of backlight for each of the specific sections less than the number of liquid crystal pixels may be disposed between a light guide plate (and/or a light diffusion plate) and the substrate of the liquid crystal panel adjacent to the light source.

Regarding a method for controlling the amount of backlight, liquid crystal devices less than the number of liquid crystal pixels may further be included. Various existing techniques may be used for the liquid crystal devices. An LCD layer containing a liquid crystal having a polymer network formed therein is preferred in view of transmittance. The layer containing the (nematic) liquid crystal having the polymer network formed therein (a layer containing the (nematic) liquid crystal having the polymer network and being held by a pair of transparent electrodes as needed) scatters light when the voltage is OFF and transmits light when the voltage is ON. The LCD layer containing the liquid crystal having the polymer network divided so as to divide the entire display screen into multiple sections is disposed between the light guide plate (and/or the light diffusion plate) and the substrate of the liquid crystal panel adjacent to the light source, thereby achieving local dimming.

The liquid crystal layer, the alignment layer, and so forth, which are components of the liquid crystal panel portion of the liquid crystal display device according to the embodiment, will be described below.

The liquid crystal layer according to the embodiment a liquid crystal composition containing a compound represented by general formula (i):

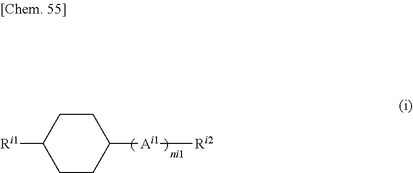

(wherein in the formula, Rⁱ¹ and Rⁱ² each independently represent an alkyl group having 1 to 8 carbon atoms, an alkenyl group having 2 to 8 carbon atoms, an alkoxy group having 1 to 8 carbon atoms, or an alkenyloxy group having 2 to 8 carbon atoms, Aⁱ¹ represents a 1,4-phenylene group or a trans-1,4-cyclohexylene group, and nⁱ¹ represents 0 or 1).

The use of the compound described above enables the formation of the liquid crystal layer containing the compound having high reliability of light resistance; thus, the deterioration of the liquid crystal layer due to light from the light source, particularly blue light (from a blue LED), can be suppressed or prevented. Additionally, the retardation of the liquid crystal layer can be adjusted; thus, a decrease in the transmittance of the liquid crystal display device is suppressed or prevented.

In the liquid crystal layer according to the embodiment, the lower limit of the amount of the compound represented by the general formula (i) contained is preferably 1% by mass, 2% by mass, 3% by mass, 5% by mass, 7% by mass, 10% by mass, 15% by mass, 20% by mass, 25% by mass, 30% by mass, 35% by mass, 40% by mass, 45% by mass, 50% by mass, or 55% by mass based on the total amount of the composition of the embodiment. The upper limit of the amount contained is preferably 95% by mass, 90% by mass, 85% by mass, 80% by mass, 75% by mass, 70% by mass, 65% by mass, 60% by mass, 55% by mass, 50% by mass, 45% by mass, 40% by mass, 35% by mass, 30% by mass, or 25% by mass based on the total amount of the composition of the embodiment.

The liquid crystal layer according to the embodiment particularly preferably contains 10% to 50% by mass of the compound represented by general formula (i).

The compound represented by general formula (i) is preferably a compound selected from the group consisting of compounds represented by general formulae (i-1) and (i-2).

A compound general formula (i-1) is a compound below.

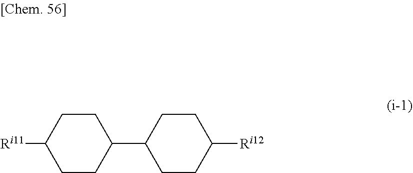

(wherein in the formula, Rⁱ¹¹ and Rⁱ¹² each independently represent the same meaning as Rⁱ¹ and Rⁱ² in general formula (i))

Each of R^{i1l} and R^{il2} is preferably a linear alkyl group having 1 to 5 carbon atoms, a linear alkoxy group having 1 to 4 carbon atoms, and a linear alkenyl group having 2 to 5 carbon atoms.

The compound represented by general formula (i-1) may be used alone. Alternatively, two or more compounds thereof may be used in combination. The types of compounds that can be combined are not particularly limited. The compounds are used in combination as appropriate in accordance with performance requirements regarding, for example, the solubility at a low temperature, transition temperature, electrical reliability, and birefringence. The number of types of compounds used in an example of the embodiment is, for example, 1, 2, 3, 4, or 5 or more.

The lower limit of the content is preferably 1% by mass, 2% by mass, 3% by mass, 5% by mass, 7% by mass, 10% by mass, 12% by mass, 15% by mass, 17% by mass, 20% by mass, 22% by mass, 25% by mass, 27% by mass, 30% by mass, 35% by mass, 40% by mass, 45% by mass, 50% by mass, or 55% by mass based on the total amount of the composition of the embodiment. The upper limit of the content is preferably 95% by mass, 90% by mass, 85% by mass, 80% by mass, 75% by mass, 70% by mass, 65% by mass, 60% by mass, 55% by mass, 50% by mass, 48% by mass, 45% by mass, 43% by mass, 40% by mass, 38% by mass, 35% by mass, 33% by mass, 30% by mass, 28% by mass, 25% by mass, 23% by mass, or 20% by mass based on the total amount of the composition of the embodiment.

In the case where the composition of the embodiment is required to have a high response speed with the viscosity thereof kept low, the lower limit is preferably high, and the upper limit is preferably high. In the case where the composition of the embodiment is required to have good temperature stability with T_{NI} kept high, the lower limit is preferably moderate, and the upper limit is preferably moderate. In the case where high dielectric anisotropy is intended to be achieved in order to keep the driving voltage low, the lower limit is preferably low, and the upper limit is preferably low.

The compound represented by general formula (i-1) is preferably a compound selected from the group consisting of compounds represented by general formula (i-1-1):

[Chem. 57]

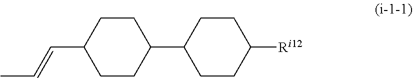

(wherein in the formula, R^{il2} represents the same meaning as in general formula (i-1)).

The compound represented by general formula (i-1-1) is preferably a compound selected from the group consisting of compounds represented by general formulae (i-1-1.1) to (i-1-1.3), preferably a compound represented by formula (i-1-1.2) or (i-1-1.3), particularly preferably a compound represented by formula (i-1-1.3).

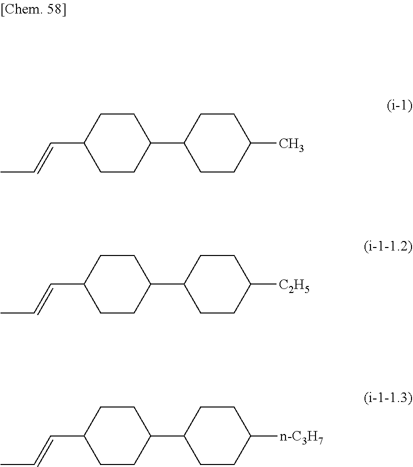

The lower limit of the amount of the compound represented by formula (i-1-1.3) contained is preferably 1% by mass, 2% by mass, 3% by mass, 5% by mass, 7% by mass, or 10% by mass based on the total amount of the composition of the embodiment. The upper limit of the amount contained is preferably 20% by mass, 15% by mass, 13% by mass, 10% by mass, 8% by mass, 7% by mass, 6% by mass, 5% by mass, or 3% by mass based on the total amount of the composition of the embodiment.

The compound represented by general formula (i-1) is preferably a compound selected from the group consisting of compounds represented by general formula (i-1-2) because good durability and a good voltage holding ratio are developed even when irradiation is performed with light, serving as backlight, having a wavelength of 200 to 400 nm in the ultraviolet range:

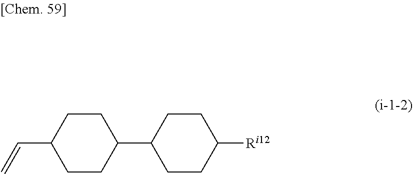

(wherein in the formula, R¹¹² represents the same meaning as in general formula (i-1)).

The lower limit of the amount of the compound represented by formula (i-1-2) contained is preferably 1% by mass, 5% by mass, 10% by mass, 15% by mass, 17% by mass, 20% by mass, 23% by mass, 25% by mass, 27% by mass, 30% by mass, or 35% by mass based on the total amount of the composition of the embodiment. The upper limit of the amount contained is preferably 60% by mass, 55% by mass, 50% by mass, 45% by mass, 42% by mass, 40% by mass, 38% by mass, 35% by mass, 33% by mass, or 30% by mass based on the total amount of the composition of the embodiment.

The compound represented by general formula (i-1-2) is preferably a compound selected from the group consisting of compounds represented by formulae (i-1-2.1) to (i-1-2.4), preferably a compound represented by any of formulae (i-1-2.2) to (i-1-2.4). The compound represented by formula (i-1-2.2) is particularly preferred because it significantly improves the response speed of the composition of the embodiment. In the case where high T_{NI} is achieved rather than the response speed, the compound represented by formula (i-1-2.3) or (i-1-2.4) is preferably used. It is not preferable to use the compounds represented by formulae (i-1-2.3) and (i-1-2.4) in amounts of 30% or more by mass in order to improve the solubility at a low temperature.

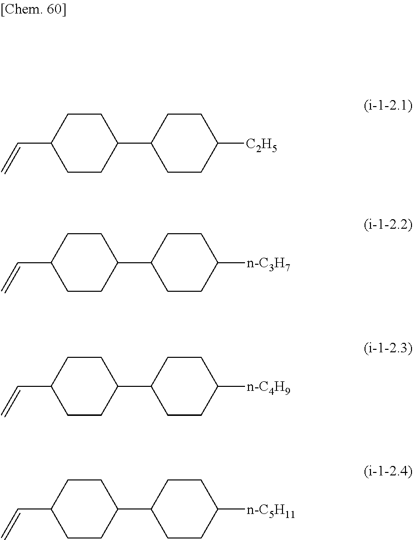

The lower limit of the amount of the compound formula (i-1-2.2) contained is preferably 10% by mass, 15% by mass, 18% by mass, 20% by mass, 23% by mass, 25% by mass, 27% by mass, 30% by mass, 33% by mass, 35% by mass, 38% by mass, or 40% by mass based on the total amount of the composition of the embodiment. The upper limit of the amount contained is preferably 60% by mass, 55% by mass, 50% by mass, 45% by mass, 43% by mass, 40% by mass, 38% by mass, 35% by mass, 32% by mass, 30% by mass, 20% by mass, 15% by mass, or 10% by mass based on the total amount of the composition of the embodiment. Of these, the upper limit of the amount contained is preferably 15% by mass, particularly preferably 10% by mass from the viewpoint of preventing the deterioration of the liquid crystal layer due to visible blue light.

The lower limit of the total amount of the compound represented by formula (i-1-1.3) and the compound represented by formula (i-1-2.2) contained is preferably 10% by mass, 15% by mass, 20% by mass, 25% by mass, 27% by mass, 30% by mass, 35% by mass, or 40% by mass based on the total amount of the composition of the embodiment. The upper limit of the amount contained is preferably 60% by mass, 55% by mass, 50% by mass, 45% by mass, 43% by mass, 40% by mass, 38% by mass, 35% by mass, 32% by mass, 30% by mass, 27% by mass, 25% by mass, or 22% by mass based on the total amount of the composition of the embodiment.

The compound represented by general formula (i-1) is preferably a compound selected from the group consisting of compounds represented by general formula (i-1-3):

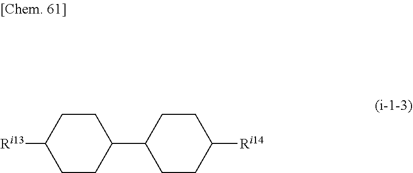

(wherein in the formula, R¹¹³ and R¹¹⁴ each independently represent an alkyl group having 1 to 8 carbon atoms or an alkoxy group having 1 to 8 carbon atoms).

Each of Rⁱ¹³ and Rⁱ¹⁴ is preferably a linear alkyl group having 1 to 5 carbon atoms, a linear alkoxy group having 1 to 4 carbon atoms, or a linear alkenyl group having 2 to 5 carbon atoms.

The lower limit of the amount of the compound represented by formula (i-1-3) contained is preferably 1% by mass, 5% by mass, 10% by mass, 13% by mass, 15% by mass, 17% by mass, 20% by mass, 23% by mass, 25% by mass, or 30% by mass based on the total amount of the composition of the embodiment. The upper limit of the amount contained is preferably 60% by mass, 55% by mass, 50% by mass, 45% by mass, 40% by mass, 37% by mass, 35% by mass, 33% by mass, 30% by mass, 27% by mass, 25% by mass, 23% by mass, 20% by mass, 17% by mass, 15% by mass, 13% by mass, or 10% by mass based on the total amount of the composition of the embodiment. Furthermore, the compound represented by general formula (i-1-3) is preferably a compound selected from the group consisting of compounds represented by formulae (i-1-3.1) to (i-1-3.12), preferably a compound represented by formula (i-1-3.1), (i-1-3.3), or (i-1-3.4). The compound represented by formula (i-1-3.1) is particularly preferred because it significantly improves the response speed of the composition of the embodiment. In the case where high T_{NI} is intended to be achieved rather than the response speed, the compounds represented by formulae (i-1-3.3), (i-1-3.4), (L-1-3.11), and (i-1-3.12) are preferably used. It is not preferable to use the compounds represented by formulae (i-1-3.3), (i-1-3.4), (i-1-3.11), and (i-1-3.12) in a total amount of 20% or more by mass in order to improve the solubility at a low temperature.

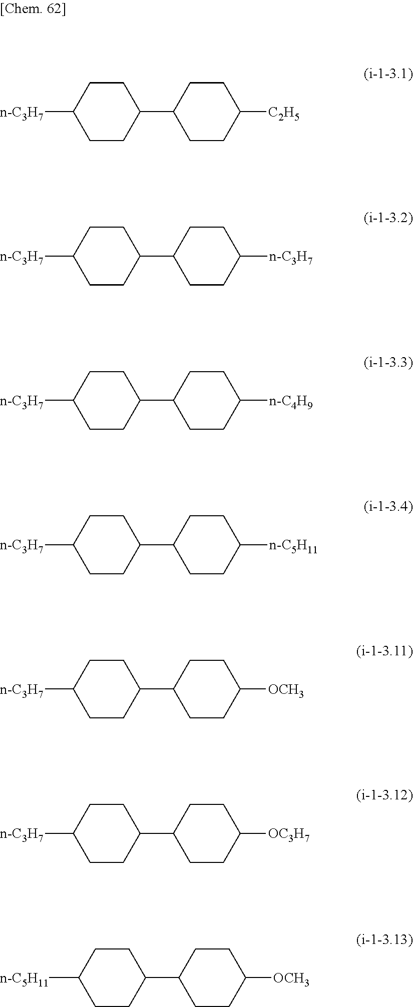

The compound represented by general formula (i-1) is preferably a compound selected from the group consisting of compounds represented by general formula (i-1-4) and (i-1-5):

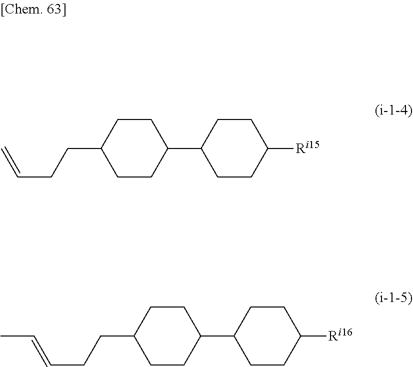

(wherein in the formulae R¹¹⁵ and R¹¹⁶ each independently represent an alkyl group having 1 to 8 carbon atoms or an alkoxy group having 1 to 8 carbon atoms).

Each of R¹¹⁵ and R¹¹⁶ is preferably a linear alkyl group having 1 to 5 carbon atoms, a linear alkoxy group having 1 to 4 carbon atoms, or a linear alkenyl group having 2 to 5 carbon atoms.

The lower limit of the amount of the compound represented by formula (i-1-4) contained is preferably 1% by mass, 5% by mass, 10% by mass, 13% by mass, 15% by mass, 17% by mass, or 20% by mass based on the total amount of the composition of the embodiment. The upper limit of the amount contained is preferably 25% by mass, 23% by mass, 20% by mass, 17% by mass, 15% by mass, 13% by mass, or 10% by mass based on the total amount of the composition of the embodiment.

The lower limit of the amount of the compound represented by formula (i-1-5) contained is preferably 1% by mass, 5% by mass, 10% by mass, 13% by mass, 15% by mass, 17% by mass, or 20% by mass based on the total amount of the composition of the embodiment. The upper limit of the amount contained is preferably 25% by mass, 23% by mass, 20% by mass, 17% by mass, 15% by mass, 13% by mass, or 10% by mass based on the total amount of the composition of the embodiment.

Each of the compounds represented by general formulae (i-1-4) and (i-1-5) is preferably a compound selected from the group consisting of compounds represented by formulae (i-1-4.1) to (i-1-5.3), preferably a compound represented by formula (i-1-4.2) or (i-1-5.2).

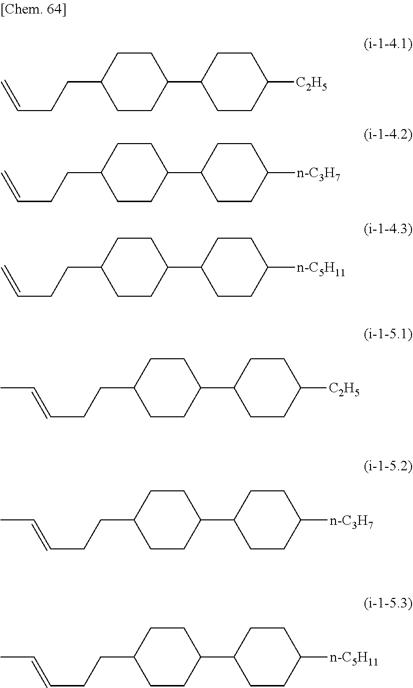

The lower limit of the amount of the compound represented by formula (i-1-4.2) contained is preferably 1% by mass, 2% by mass, 3% by mass, 5% by mass, 7% by mass, 10% by mass, 13% by mass, 15% by mass, 18% by mass, or 20% by mass based on the total amount of the composition of the embodiment. The upper limit of the amount contained is preferably 20% by mass, 17% by mass, 15% by mass, 13% by mass, 10% by mass, 8% by mass, 7% by mass, or 6% by mass based on the total amount of the composition of the embodiment.

Two or more compounds selected from compounds represented by formulae (i-1-1.3), (i-1-2.2), (i-1-3.1), (i-1-3.3), (i-1-3.4), (i-1-3.11), and (i-1-3.12) are preferably combined. Two or more compounds selected from compounds represented by formulae (i-1-1.3), (i-1-2.2), (i-1-3.1), (i-1-3.3), (i-1-3.4), and (i-1-4.2) are preferably combined. The lower limit of the total amount of these compounds contained is preferably 1% by mass, 2% by mass, 3% by mass, 5% by mass, 7% by mass, 10% by mass, 13% by mass, 15% by mass, 18% by mass, 20% by mass, 23% by mass, 25% by mass, 27% by mass, 30% by mass, 33% by mass, or 35% by mass based on the total amount of the composition of the embodiment. The upper limit thereof is preferably 80% by mass, 70% by mass, 60% by mass, 50% by mass, 45% by mass, 40% by mass, 37% by mass, 35% by mass, 33% by mass, 30% by mass, 28% by mass, 25% by mass, 23% by mass, or 20% by mass based on the total amount of the composition of the embodiment. In the case where importance is placed on the reliability of the composition, two or more compounds selected from compounds represented by formulae (i-1-3.1), (i-1-3.3), and (i-1-3.4)) are preferably combined. In the case where importance is placed on the response speed of the composition, two or more compounds selected from compounds represented by formulae (i-1-1.3) and (i-1-2.2) are preferably combined.

The compound represented by general formula (i-1) is preferably a compound selected from the group consisting of compounds represented by general formula (i-1-6):

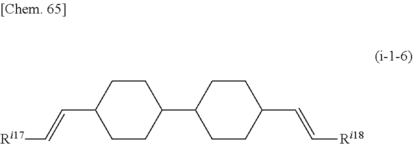

(wherein in the formula, R¹¹⁷ and R¹¹⁸ each independently represent a methyl group or a hydrogen atom).

The lower limit of the amount of the compound represented by formula (i-1-6) contained is preferably 1% by mass, 5% by mass, 10% by mass, 15% by mass, 17% by mass, 20% by mass, 23% by mass, 25% by mass, 27% by mass, 30% by mass, or 35% by mass based on the total amount of the composition of the embodiment. The upper limit of the amount contained is preferably 60% by mass, 55% by mass, 50% by mass, 45% by mass, 42% by mass, 40% by mass, 38% by mass, 35% by mass, 33% by mass, or 30% by mass based on the total amount of the composition of the embodiment.

The compound represented by general formula (i-1-6) is preferably a compound selected from the group consisting of compounds represented by formulae (i-1-6.1) to (i-1-6.3).

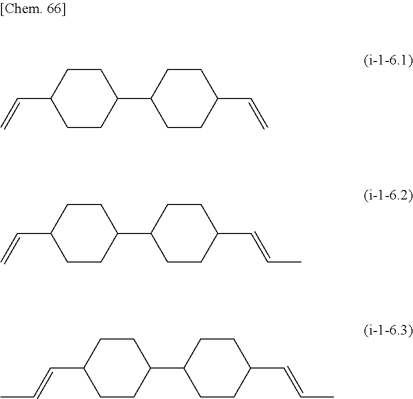

A compound represented by general formula (i-2) is a compound as follows:

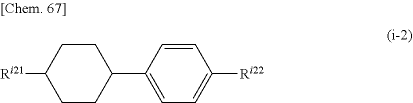

(wherein in the formula, Rⁱ²¹ and Rⁱ²² each independently represent the same meaning as Rⁱ¹ and Rⁱ² in general formula (i)).

Rⁱ²¹ is preferably an alkyl group having 1 to 5 carbon atoms or an alkenyl group having 2 to 5 carbon atoms. R^{L22} is preferably an alkyl group having 1 to 5 carbon atoms, an alkenyl group having 4 or 5 carbon atoms, or an alkoxy group having 1 to 4 carbon atoms.

The compound represented by general formula (i-2) may be used alone. Alternatively, two or more compounds thereof may also be used in combination. The types of compounds that can be combined are not particularly limited. The compounds are used in combination as appropriate in accordance with performance requirements regarding, for example, the solubility at a low temperature, transition temperature, electrical reliability, and birefringence. The number of types of compounds used in an example of the embodiment is, for example, 1, 2, 3, 4, or 5 or more.

In the case where importance is placed on the solubility at a low temperature, a larger amount contained is more effective. In the case where importance is placed on the response speed, a smaller amount contained is more effective. In the case where drop marks and image-sticking characteristics are improved, the amount contained is preferably in the intermediate range.

The lower limit of the amount of the compound represented by formula (i-2) contained is preferably 1% by mass, 2% by mass, 3% by mass, 5% by mass, 7% by mass, or 10% by mass based on the total amount of the composition of the embodiment. The upper limit of the amount contained is preferably 20% by mass, 15% by mass, 13% by mass, 10% by mass, 8% by mass, 7% by mass, 6% by mass, 5% by mass, or 3% by mass based on the total amount of the composition of the embodiment.

Preferably, the composition of the embodiment further contains one or two or more compounds selected from compounds represented by general formulae (N-1), (N-2), (N-3), and (N-4). These compounds correspond to dielectrically negative compounds (the sign of Δε is negative, and the absolute value is greater than 2).

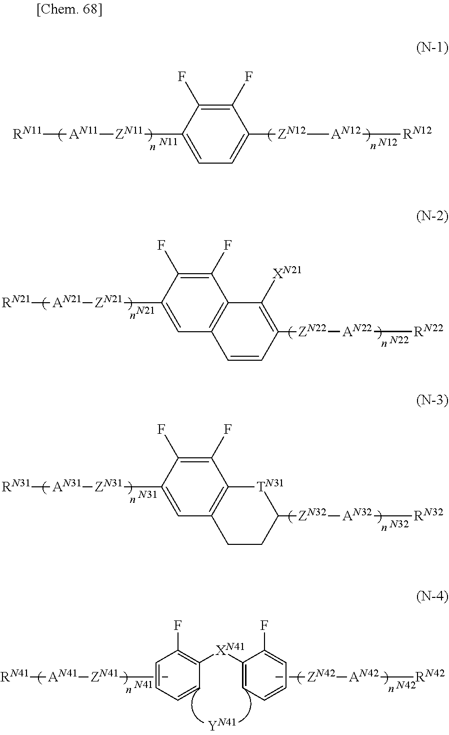

[In general formulae (N-1), (N-2), (N-3), and (N-4), R^{N11}, R^{N12}, R^{N21}, R^{N22}, R^{N31}, R^{N32}, R^{N41}, and R^{N42} each independently represent an alkyl group having 1 to 8 carbon atoms or a structural moiety having a chemical structure in which one —CH₂— or two or more non-adjacent —CH₂-'s in an alkyl chain having 2 to 8 carbon atoms is each independently replaced with —CH═CH—, —C≡C—, —O—, —CO—, —COO—, or —OCO—,

A^{N11}, A^{N12}, A^{N21}, A^{N22}, A^{N31}, A^{N32}, A^{N41}, and A^{N42} each independently represent a group selected from the group consisting of:

(a) a 1,4-cyclohexylene group (wherein one —CH₂— or two or more non-adjacent —CH₂-'s present in this group may be replaced with —O—);
(b) a 1,4-phenylene group (wherein one —CH═ or two or more non-adjacent —CH═'s present in this group may be replaced with —N═);
(c) a naphthalene-2,6-diyl group, a 1,2,3,4-tetrahydronaphthalene-2,6-diyl group, and a decahydronaphthalene-2,6-diyl group (wherein one —CH═ or two or more non-adjacent —CH═'s present in the naphthalene-2,6-diyl group or the 1,2,3,4-tetrahydronaphthalene-2,6-diyl group may be replaced with —N═); and
(d) a 1,4-cyclohexenylene group,

wherein hydrogen atoms in the structures of the groups (a), (b), (c), and (d) may each independently be replaced with a cyano group, a fluorine atom, or a chlorine atom,

Z^{N11}, Z^{N12}, Z^{N21}, Z^{N22}, Z^{N31}, Z^{N32}, Z^{N41}, and Z^{N42} each independently represent a single bond, —CH₂CH₂—, —(CH₂)₄—, —OCH₂—, —CH₂O—, —COO—, —OCO—, —OCF₂—, —CF₂O—, —CH═N—N═CH—, —CH═CH—, —CF═CF—, or —C≡C—,

X^{N21} represents a hydrogen atom or a fluorine atom, T^{N31} represents —CH₂— or an oxygen atom, X^{N41} represents an oxygen atom, a nitrogen atom, or —CH₂—, Y^{N41} represents a single bond or —CH₂—, n^{N11}, n^{N12}, n^{N21}, n^{N22}, n^{N31}, n^{N32}, n^{N41}, and n^{N42} each independently represent an integer of 0 to 3, n^{N11}+n^{N12}n^{N21}+^{N22}, and n^{N31}+n^{N32} are each independently 1, 2, or 3, when a plurality of A^{N11}'s to a plurality of A^{N32}'s and a plurality of Z^{N11}'s to a plurality of Z^{N32}'s are present, they may be the same or different, n^{N41}+n^{N42} represents an integer of 0 to 3, and when a plurality of A^{N41}'s, a plurality of A^{N42}'s, a plurality of Z^{N41}'s, and a plurality of Z^{N42}'s are present, they may be the same or different].

Each of the compounds represented by general formulae (N-1), (N-2), (N-3), and (N-4) is preferably a compound in which Δε is negative and the absolute value thereof is greater than 2.

In general formulae (N-1), (N-2), (N-3), and (N-4), each of R^{N11}, R^{N12}, R^{N21}, R^{N22}, R^{N31}, R^{N32}, R^{N41}, and R^{N42} is preferably independently an alkyl group having 1 to 8 carbon atoms, an alkoxy group having 1 to 8 carbon atoms, an alkenyl group having 2 to 8 carbon atoms, or an alkenyloxy group having 2 to 8 carbon atoms, preferably an alkyl group having 1 to 5 carbon atoms, an alkoxy group having 1 to 5 carbon atoms, an alkenyl group having 2 to 5 carbon atoms, or an alkenyloxy group having 2 to 5 carbon atoms, more preferably an alkyl group having 1 to 5 carbon atoms or an alkenyl group having 2 to 5 carbon atoms, even more preferably an alkyl group having 2 to 5 carbon atoms, or an alkenyl group having 2 or 3 carbon atoms, particularly preferably an alkenyl group having 3 carbon atoms (propenyl group).

When a ring structure to which it is attached is a phenyl group (aromatic group), a linear alkyl group having 1 to 5 carbon atoms, a linear alkoxy group having 1 to 4 carbon atoms, and an alkenyl group having 4 or 5 carbon atoms are preferred. When a ring structure to which it is attached is a saturated ring structure, such as cyclohexane, pyran, or dioxane, a linear alkyl group having 1 to 5 carbon atoms, a linear alkoxy group having 1 to 4 carbon atoms, and a linear alkenyl group having 2 to 5 carbon atoms are preferred. To stabilize the nematic phase, the total of carbon atoms and, if present, oxygen atoms is preferably 5 or less, and a straight-chain shape is preferred.

The alkenyl group is preferably selected from groups represented by formulae (R1) to (R5) (a black dot in each formula represents a carbon atom in a ring structure).

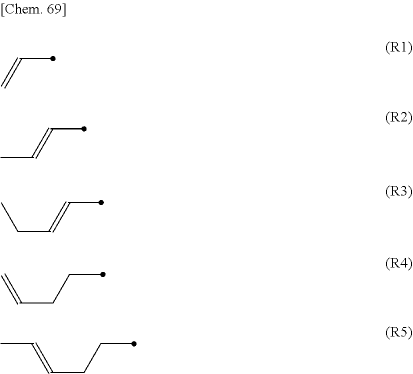

Each of A^{N11}, A^{N12}, A^{N21}, A^{N22}, A^{N31}, and A^{N32} is preferably independently an aromatic group when Δn is required to be increased, preferably an aliphatic group in order to improve the response speed, preferably a trans-1,4-cyclohexylene group, a 1,4-phenylene group, a 2-fluoro-1,4-phenylene group, a 3-fluoro-1,4-phenylene group, a 3,5-difluoro-1,4-phenylene group, a 2,3-difluoro-1,4-phenylene group, a 1,4-cyclohexenylene group, a 1,4-bicyclo[2.2.2]octylene group, a piperidine-1,4-diyl group, a naphthalene-2,6-diyl group, a decahydronaphthalene-2,6-diyl group, or a 1,2,3,4-tetrahydronaphthalene-2,6-diyl group, more preferably any of structures below:

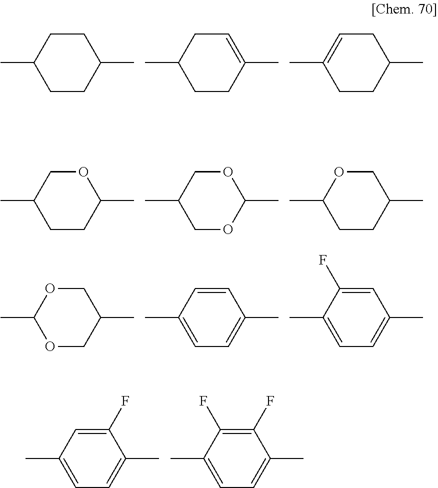

more preferably a trans-1,4-cyclohexylene group, a 1,4-cyclohexenylene group, or a 1,4-phenylene group.

Each of Z^{N11}, Z^{N12}, Z^{N21}, Z^{N22}, Z^{N31}, and Z^{N32} preferably independently represent —CH₂O—, —CF₂O—, —CH₂CH₂—, —CF₂CF₂—, or a single bond, more preferably —CH₂O—, —CH₂CH₂—, or a single bond, particularly preferably —CH₂O— or a single bond.

X^{N21} is preferably a fluorine atom.

T^{N31} is preferably an oxygen atom.

Each of n^{N11}+n^{N12}, n^{N21}+n^{N22}, and n^{N31}+n^{N32} is preferably 1 or 2. Preferred are a combination in which n^{N11} is 1 and n^{N12} is 0, a combination in which n^{N11} is 2 and n^{N12} is 0, a combination in which n^{N11} is 1 and n^{N12} is 1, a combination in which n^{N11} is 2 and n^{N12} is 1, a combination in which n^{N22} is 1 and n^{N22} is 0, a combination in which n^{N21} is 2 and n^{N22} is 0, a combination in which n^{N31} is 1 and n^{N32} is 0, and a combination in which n^{N31} is 2 and n^{N32} is 0.

The lower limit of the amount of the compound represented by formula (N-1) contained is preferably 1% by mass, 10% by mass, 20% by mass, 30% by mass, 40% by mass, 50% by mass, 55% by mass, 60% by mass, 65% by mass, 70% by mass, 75% by mass, or 80% by mass based on the total amount of the composition of the embodiment. The upper limit of the amount contained is preferably 95% by mass, 85% by mass, 75% by mass, 65% by mass, 55% by mass, 45% by mass, 35% by mass, 25% by mass, or 20% by mass.

The lower limit of the amount of the compound represented by formula (N-2) contained is preferably 1% by mass, 10% by mass, 20% by mass, 30% by mass, 40% by mass, 50% by mass, 55% by mass, 60% by mass, 65% by mass, 70% by mass, 75% by mass, or 80% by mass based on the total amount of the composition of the embodiment. The upper limit of the amount contained is preferably 95% by mass, 85% by mass, 75% by mass, 65% by mass, 55% by mass, 45% by mass, 35% by mass, 25% by mass, or 20% by mass.

The lower limit of the amount of the compound represented by formula (N-3) contained is preferably 1% by mass, 10% by mass, 20% by mass, 30% by mass, 40% by mass, 50% by mass, 55% by mass, 60% by mass, 65% by mass, 70% by mass, 75% by mass, 80% by mass based on the total amount of the composition of the embodiment. The upper limit of the amount contained is preferably 95% by mass, 85% by mass, 75% by mass, 65% by mass, 55% by mass, 45% by mass, 35% by mass, 25% by mass, or 20% by mass.

In the case where the composition of the embodiment is required to have a high response speed with the viscosity thereof kept low, it is preferable that the lower limit be low and the upper limit be low. In the case where the composition of the embodiment is required to have good temperature stability with the T_{NI} of the composition kept high, it is preferable that the lower limit be low and the upper limit be low. In the case where the dielectric anisotropy is intended to be increased in order to keep the driving voltage low, it is preferable that the lower limit be high and the upper limit be high.

The liquid crystal composition according to the embodiment preferably contains the compound represented by general formula (N-1) among the compound represented by (N-1), the compound represented by general formula (N-2), the compound represented by general formula (N-3), and the compound represented by general formula (N-4).

Examples of the compound represented by general formula (N-1) include compounds represented by general formulae (N-1a) to (N-1g) below.

Examples of the compound represented by general formula (N-4) include compounds represented by general formula (N-1h) below.

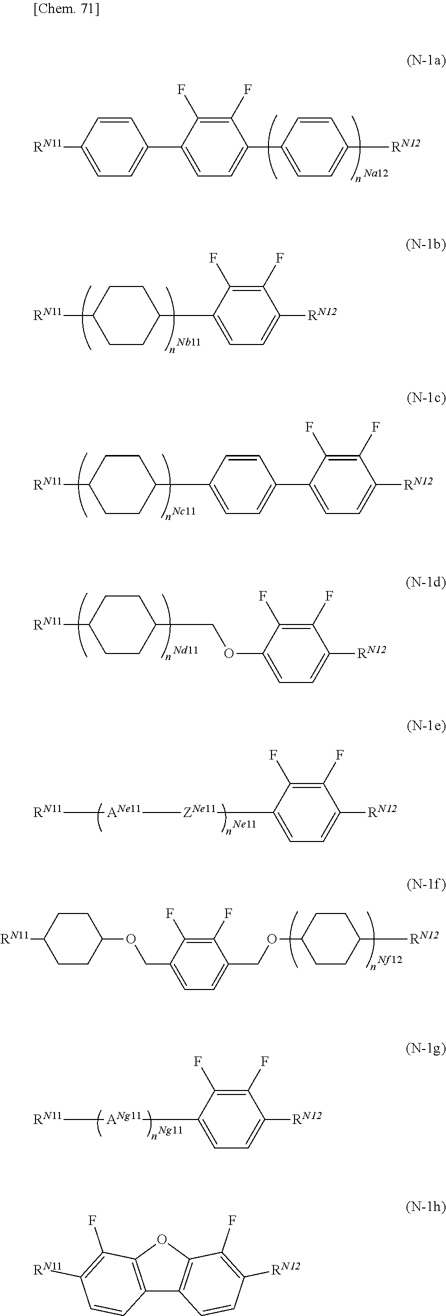

(wherein in each formula, R^{N11} and R^{N12} each represent the same meaning as R^{N11} and R^{N12} in general formula (N-1), n^{Na11} represents 0 or 1, n^{Nb11} represents 0 or 1, n^{Nc11} represents 0 or 1, n^{Nd11} represents 0 or 1, n^{Ne11} represents 1 or 2, n^{Nf11} represents 1 or 2, n^{Ng11} represents 1 or 2, A^{Ne11} represents a trans-1,4-cyclohexylene group or a 1,4-phenylene group, A^{Ng11} represents a trans-1,4-cyclohexylene group, a 1,4-cyclohexenylene group, or a 1,4-phenylene group, provided that at least one A^{Ng11} represents a 1,4-cyclohexenylene group, and Z^{Ne11} represents a single bond or ethylene, provided that at least one Z^{Ne11} represents ethylene).

More specifically, the compound represented by general formula (N-1) is preferably a compound selected from the group consisting of compounds represented by general formulae (N-1-1) to (N-1-21).

### (P-Type Compound)

Preferably, the composition of the embodiment further contains one or two or more compounds represented by general formula (J), and these compounds correspond to dielectrically positive compounds (Δε is greater than 2):

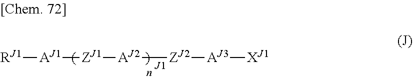

(wherein in the formula, R^{J1} represents an alkyl group having 1 to 8 carbon atoms, one or two or more non-adjacent —CH₂-'s in the alkyl group may each be preferably independently replaced with —CH═CH—, —C═C—, —O—, —CO—, —COO—, or —OCO—,

n^{J1} represents 0, 1, 2, 3, or 4,

A^{J1}, A^{J2}, and A^{J3} each independently represent a group selected from the group consisting of:

(a) a 1,4-cyclohexylene group (wherein one —CH₂— or two or more non-adjacent —CH₂-'s present in this group may be replaced with —O—);
(b) a 1,4-phenylene group (wherein one —CH═ or two or more non-adjacent —CH═'s present in this group may be replaced with —N═); and
(c) a naphthalene-2,6-diyl group, a 1,2,3,4-tetrahydronaphthalene-2,6-diyl group, and decahydronaphthalene-2,6-diyl group (wherein one —CH═ or two or more non-adjacent —CH═'s present in the naphthalene-2,6-diyl group and the 1,2,3,4-tetrahydronaphthalene-2,6-diyl group may be replaced with —N═),

wherein the groups (a), (b), and (c) may each be independently substituted with a cyano group, a fluorine atom, a chlorine atom, a methyl group, a trifluoromethyl group, or a trifluoromethoxy group,

Z^{J1} and Z^{J2} each independently represent a single bond, —CH₂CH₂—, —(CH₂)₄—, —OCH₂—, —CH₂O—, —OCF₂—, —CF₂O—, —COO—, —OCO—, or —C≡C—,

in the case where n^{J1} is 2, 3, or 4 and where a plurality of A^{J2}'s are present, they may be the same or different, in the case where n^{J1} is 2, 3, or 4 and where a plurality of Z^{J1}'s are present, they may be the same or different, and

X^{J1} represents a hydrogen atom, a fluorine atom, a chlorine atom, a cyano group, a trifluoromethyl group, a fluoromethoxy group, a difluoromethoxy group, a trifluoromethoxy group, or a 2,2,2-trifluoroethyl group).

In general formula (J), R^{J1} is preferably an alkyl group having 1 to 8 carbon atoms, an alkoxy group having 1 to 8 carbon atoms, an alkenyl group having 2 to 8 carbon atoms, or an alkenyloxy group having 2 to 8 carbon atoms, preferably an alkyl group having 1 to 5 carbon atoms, an alkoxy group having 1 to 5 carbon atoms, an alkenyl group having 2 to 5 carbon atoms, or an alkenyloxy group having 2 to 5 carbon atoms, more preferably an alkyl group having 1 to 5 carbon atoms or an alkenyl group having 2 to 5 carbon atoms, more preferably an alkyl group having 2 to 5 carbon atoms or an alkenyl group having 2 or 3 carbon atoms, particularly preferably an alkenyl group having 3 carbon atoms (propenyl group).

When importance is placed on the reliability, R^{J1} is preferably an alkyl group. When importance is placed on a reduction in viscosity, R^{J1} is preferably an alkenyl group.

When a ring structure to which it is attached is a phenyl group (aromatic group), a linear alkyl group having 1 to 5 carbon atoms, a linear alkoxy group having 1 to 4 carbon atoms, and an alkenyl group having 4 or 5 carbon atoms are preferred. When a ring structure to which it is attached is a saturated ring structure, such as cyclohexane, pyran, or dioxane, a linear alkyl group having 1 to 5 carbon atoms, a linear alkoxy group having 1 to 4 carbon atoms, and a linear alkenyl group having 2 to 5 carbon atoms are preferred. To stabilize the nematic phase, the total of carbon atoms and, if present, oxygen atoms is preferably 5 or less, and a straight-chain shape is preferred.

The alkenyl group is preferably selected from groups represented by formulae (R1) to (R5) (a black dot in each formula represents a carbon atom in a ring structure to which the alkenyl group is attached).

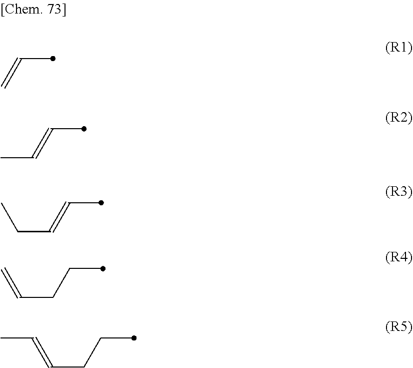

A^{J1}, A^{J2}, and A^{J3} are preferably each independently an aromatic group when Δn is required to be increased, preferably an aliphatic group in order to improve the response speed. A^{J1}, A^{J2}, and A^{J7} preferably each independently represent a trans-1,4-cyclohexylene group, a 1,4-phenylene group, a 1,4-cyclohexenylene group, a 1,4-bicyclo[2.2.2]octylene group, a piperidine-1,4-diyl group, a naphthalene-2,6-diyl group, a decahydronaphthalene-2,6-diyl group, or 1,2,3,4-tetrahydronaphthalene-2,6-diyl group. These groups may be substituted with a fluorine atom. A^{J1}, A^{J2}, and A^{J3} more preferably each independently represent any of structures below.

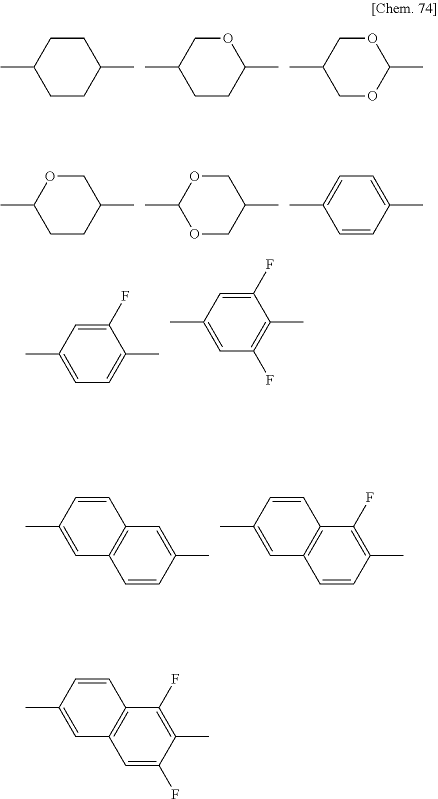

A^{J1}, A^{J2}, and A^{J3} more preferably each independently represent any of structures below.

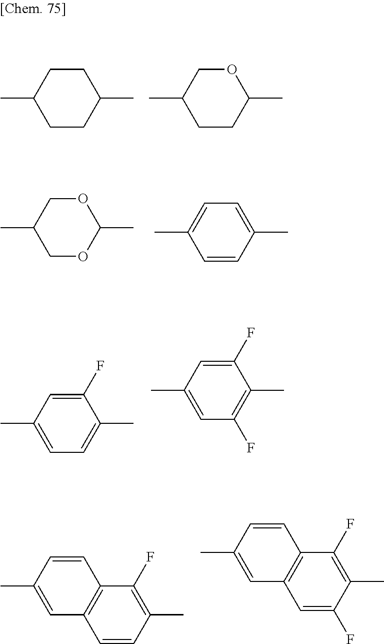

Z^{J1} and Z^{J2} preferably each independently represent —CH₂O—, —OCH₂—, —CF₂O—, —CH₂CH₂—, —CF₂CF₂—, or a single bond, more preferably —OCH₂—, —CF₂O—, —CH₂CH₂—, or a single bond, particularly preferably —OCH₂—, —CF₂O—, or a single bond.

X^{J1} is preferably a fluorine atom or a trifluoromethoxy group, preferably a fluorine atom.

n^{J1} is preferably 0, 1, 2, or 3, preferably 0, 1, or 2. When importance is placed on an improvement in Δε, n^{J1} is preferably 0 or 1. When importance is placed on T_{NI}, n^{J1} is preferably 1 or 2.

The types of compounds that can be combined are not particularly limited. The compounds are used in combination in accordance with performance requirements regarding, for example, the solubility at a low temperature, transition temperature, electrical reliability, and birefringence. The number of types of compounds used in an example of the embodiment is, for example, 1, 2, or 3. The number of types of compounds used in another example of the embodiment is 4, 5, 6, or 7 or more.

In the composition of the embodiment, the amount of the compound represented by general formula (J) contained needs to be appropriately adjusted in accordance with performance requirements regarding, for example, the solubility at a low temperature, transition temperature, electrical reliability, birefringence, process suitability, drop marks, image-sticking, and dielectric anisotropy.

The lower limit of the amount of the compound represented by formula (J) contained is preferably 1% by mass, 10% by mass, 20% by mass, 30% by mass, 40% by mass, 50% by mass, 55% by mass, 60% by mass, 65% by mass, 70% by mass, 75% by mass, or 80% by mass based on the total amount of the composition of the embodiment. In an example of the embodiment, the upper limit of the amount contained is preferably 95% by mass, 85% by mass, 75% by mass, 65% by mass, 55% by mass, 45% by mass, 35% by mass, or 25% by mass based on the total amount of the composition of the embodiment.

In the case where the composition of the embodiment is required to have a high response speed with the viscosity thereof kept low, it is preferable that the lower limit be low and the upper limit be low. In the case where the composition of the embodiment is required to have good temperature stability with the T_{NI} of the composition kept high, it is preferable that the lower limit be low and the upper limit be low. In the case where the dielectric anisotropy is intended to be increased in order to keep the driving voltage low, it is preferable that the lower limit be high and the upper limit be high.

When importance is placed on the reliability, R^{J1} is preferably an alkyl group. When importance is placed on a reduction in viscosity, R^{J1} is preferably an alkenyl group.

The compounds represented by general formula (J) are preferably compounds represented by general formulae (M) and (K).

Preferably, the composition of the embodiment further contains one or two or more compounds represented by general formula (M). These compounds correspond to dielectrically positive compounds (Δε is greater than 2).

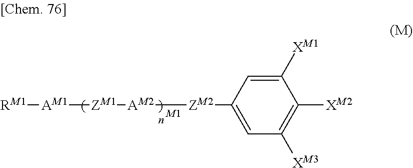

(wherein in the formula, R^{M1} represents an alkyl group having 1 to 8 carbon atoms, one or two or more non-adjacent —CH₂-'s in the alkyl group may each be independently replaced with —CH═CH—, —C═C—, —O—, —CO—, —COO—, or —OCO—,

n^{M1} represents 0, 1, 2, 3, or 4,

A^{M1} and A^{M2} each independently represent a group selected from the group consisting of:

(a) a 1,4-cyclohexylene group (wherein one —CH₂— or two or more non-adjacent —CH₂-'s present in this group may be replaced with —O— or —S—); and
(b) a 1,4-phenylene group (wherein one —CH═ or two or more non-adjacent —CH═'s present in this group may be replaced with —N═),

wherein hydrogen atoms in the groups (a) and (b) may each be independently replaced with a cyano group, a fluorine atom, or a chlorine atom,

Z^{M1} and Z^{M2} each independently represent a single bond, —CH₂CH₂—, —(CH₂)₄—, —OCH₂—, —CH₂O—, —OCF₂—, —CF₂O—, —COO—, —OCO—, or —C≡C—,

in the case where n^{M1} is 2, 3, or 4 and where a plurality of A^{M2}'s are present, they may be the same or different, in the case where n^{M1} is 2, 3, or 4 and where a plurality of Z^{M1}'s are present, they may be the same or different,

X^{M1} and X^{M3} each independently represent a hydrogen atom, a chlorine atom, or a fluorine atom, and

X^{M2} represents a hydrogen atom, a fluorine atom, a chlorine atom, a cyano group, a trifluoromethyl group, a fluoromethoxy group, a difluoromethoxy group, a trifluoromethoxy group, or a 2,2,2-trifluoroethyl group.

In general formula (M), R^{M1} is preferably an alkyl group having 1 to 8 carbon atoms, an alkoxy group having 1 to 8 carbon atoms, an alkenyl group having 2 to 8 carbon atoms, or an alkenyloxy group having 2 to 8 carbon atoms, preferably an alkyl group having 1 to 5 carbon atoms, an alkoxy group having 1 to 5 carbon atoms, an alkenyl group having 2 to 5 carbon atoms, or an alkenyloxy group having 2 to 5 carbon atoms, more preferably an alkyl group having 1 to 5 carbon atoms or an alkenyl group having 2 to 5 carbon atoms, more preferably an alkyl group having 2 to 5 carbon atoms or an alkenyl group having 2 or 3 carbon atoms, particularly preferably an alkenyl group having 3 carbon atoms (propenyl group).

When importance is placed on the reliability, R^{M1} is preferably an alkyl group. When importance is placed on a reduction in viscosity, R^{M1} is preferably an alkenyl group.

When a ring structure to which it is attached is a phenyl group (aromatic group), a linear alkyl group having 1 to 5 carbon atoms, a linear alkoxy group having 1 to 4 carbon atoms, and an alkenyl group having 4 or 5 carbon atoms are preferred. When a ring structure to which it is attached is a saturated ring structure, such as cyclohexane, pyran, or dioxane, a linear alkyl group having 1 to 5 carbon atoms, a linear alkoxy group having 1 to 4 carbon atoms, and a linear alkenyl group having 2 to 5 carbon atoms are preferred. To stabilize the nematic phase, the total of carbon atoms and, if present, oxygen atoms is preferably 5 or less, and a straight-chain shape is preferred.

The alkenyl group is preferably selected from groups represented by formulae (R1) to (R5) (a black dot in each formula represents a carbon atom in a ring structure to which the alkenyl group is attached).

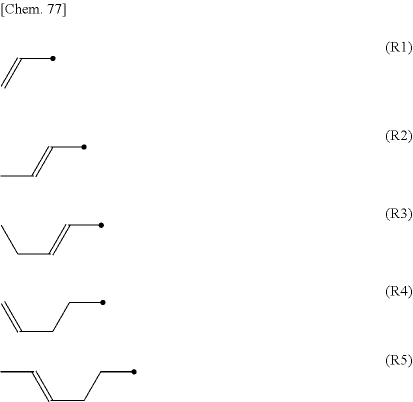

A^{M1} and A^{M2} are preferably each independently an aromatic group when Δn is required to be increased, preferably an aliphatic group in order to improve the response speed. A^{M1} and A^{M2} preferably each independently represent a trans-1,4-cyclohexylene group, a 1,4-phenylene group, a 2-fluoro-1,4-phenylene group, a 3-fluoro-1,4-phenylene group, a 3,5-difluoro-1,4-phenylene group, a 2,3-difluoro-1,4-phenylene group, a 1,4-cyclohexenylene group, a 1,4-bicyclo[2.2.2]octylene group, a piperidine-1,4-diyl group, a naphthalene-2,6-diyl group, a decahydronaphthalene-2,6-diyl group, or a 1,2,3,4-tetrahydronaphthalene-2,6-diyl group. A^{M1} and A^{M2} more preferably each independently represent any of structures below.

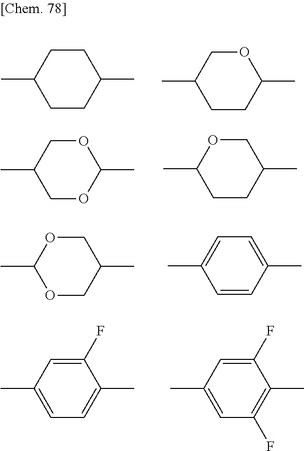

A^{M1} and A^{M2} more preferably each independently represent any of structures below.

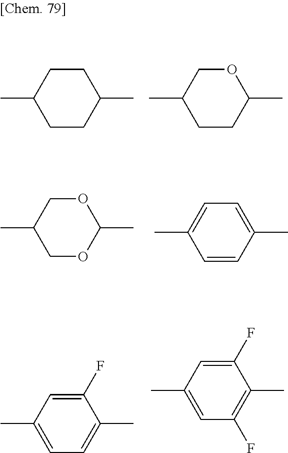

Z^{M1} and Z^{M2} preferably each independently represent —CH₂O—, —CF₂O—, —CH₂CH₂—, —CF₂CF₂—, or a single bond, more preferably —CF₂O—, —CH₂CH₂—, or a single bond, particularly preferably —CF₂O— or a single bond.

n^{M1} is preferably 0, 1, 2, or 3, preferably 0, 1, or 2. When importance is placed on an improvement in Δε, n^{M1} is preferably 0 or 1. When importance is placed on T_{NI}, n^{M1} is preferably 1 or 2.

The types of compounds that can be combined are not particularly limited. The compounds are used in combination in accordance with performance requirements regarding, for example, the solubility at a low temperatures, transition temperature, electrical reliability, and birefringence. The number of types of compounds used in an example of the embodiment is, for example, 1, 2, or 3. The number of types of compounds used in another example of the embodiment is 4, 5, 6, or 7 or more.

In the composition of the embodiment, the amount of the compound represented by general formula (M) contained needs to be appropriately adjusted in accordance with performance requirements regarding, for example, the solubility at a low temperature, transition temperature, electrical reliability, birefringence, process suitability, drop marks, image-sticking, and dielectric anisotropy.

The lower limit of the amount of the compound represented by formula (M) contained is preferably 1% by mass, 10% by mass, 20% by mass, 30% by mass, 40% by mass, 50% by mass, 55% by mass, 60% by mass, 65% by mass, 70% by mass, 75% by mass, or 80% by mass based on the total amount of the composition of the embodiment. In an example of the embodiment, the upper limit of the amount contained is preferably 95% by mass, 85% by mass, 75% by mass, 65% by mass, 55% by mass, 45% by mass, 35% by mass, or 25% by mass based on the total amount of the composition of the embodiment.

In the case where the composition of the embodiment is required to have a high response speed with the viscosity thereof kept low, it is preferable that the lower limit be low and the upper limit be low. In the case where the composition of the embodiment is required to have good temperature stability with the Ti of the composition kept high, it is preferable that the lower limit be low and the upper limit be low. In the case where the dielectric anisotropy is intended to be increased in order to keep the driving voltage low, it is preferable that the lower limit be high and the upper limit be high.

Preferably, the liquid crystal composition of the embodiment further contains one or two or more compounds represented by general formula (L). The compounds represented by general formula (L) correspond to dielectrically substantially neutral compounds (the value of Δε is −2 to 2).

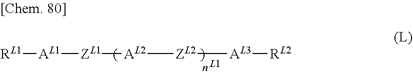

(In the formula, R^{L1} and R^{L2} each independently represent an alkyl group having 1 to 8 carbon atoms, one or two or more non-adjacent —CH₂-'s in the alkyl group may each be independently replaced with —CH═CH—, —C≡C—, —O—, —CO—, —COO—, or —OCO—,

n^{L1} represents 0, 1, 2, or 3,

A^{L1}, A^{L2}, and A^{L3} each independently represent a group selected from the group consisting of:

(a) a 1,4-cyclohexylene group (wherein one —CH₂— or two or more non-adjacent —CH₂-'s present in this group may each be replaced with —O—);
(b) a 1,4-phenylene group (wherein one —CH═ or two or more non-adjacent —CH═'s present in this group may each be replaced with —N═); and
(c) a naphthalene-2,6-diyl group, a 1,2,3,4-tetrahydronaphthalene-2,6-diyl group, and a decahydronaphthalene-2,6-diyl group (wherein one —CH═ or two or more non-adjacent —CH═'s present in the naphthalene-2,6-diyl group and the 1,2,3,4-tetrahydronaphthalene-2,6-diyl group may each be replaced with —N═),

wherein the groups (a), (b), and (c) may each be independently substituted with a cyano group, a fluorine atom, or a chlorine atom,

Z^{L1} and Z^{L2} each independently represent a single bond, —CH₂CH₂—, —(CH₂)₄—, —OCH₂—, —CH₂O—, —COO—, —OCO—, —OCF₂—, —CF₂O—, —CH═N—N═CH—, —CH═CH—, —CF═CF—, or —C≡C—,

in the case where n^{L1} is 2 or 3 and where a plurality of A^{L2}'s are present, they may be the same or different, and in the case where n^{L1} is 2 or 3 and where a plurality of Z^{L2}'s are present, they may be the same or different, provided that compounds represented by general formulae (N-1), (N-2), (N-3), (J), and (i) are excluded).

The compounds represented by general formula (L) may be used alone or in combination. The types of compounds that can be combined are not particularly limited. The compounds are used in appropriate combination in accordance with performance requirements regarding, for example, the solubility at a low temperatures, transition temperature, electrical reliability, and birefringence. The number of types of compounds used in an example of the embodiment is, for example, 1. The number of types of compounds used in another example of the embodiment is 2, 3, 4, 5, 6, 7, 8, 9, or 10 or more.

In the composition of the embodiment, the amount of the compound represented by general formula (L) contained needs to be appropriately adjusted in accordance with performance requirements regarding, for example, the solubility at a low temperature, transition temperature, electrical reliability, birefringence, process suitability, drop marks, image-sticking, and dielectric anisotropy.

The lower limit of the amount of the compound represented by formula (L) contained is preferably 1% by mass, 10% by mass, 20% by mass, 30% by mass, 40% by mass, 50% by mass, 55% by mass, 60% by mass, 65% by mass, 70% by mass, 75% by mass, or 80% by mass based on the total amount of the composition of the embodiment. The upper limit of the amount contained is preferably 95% by mass, 85% by mass, 75% by mass, 65% by mass, 55% by mass, 45% by mass, 35% by mass, or 25% by mass.

In the case where the composition of the embodiment is required to have a high response speed with the viscosity thereof kept low, it is preferable that the lower limit be high and the upper limit be high. In the case where the composition of the embodiment is required to have good temperature stability with the T_{NI} of the composition kept high, it is preferable that the lower limit be high and the upper limit be high. In the case where the dielectric anisotropy is intended to be increased in order to keep the driving voltage low, it is preferable that the lower limit be low and the upper limit be low.

When importance is placed on the reliability, each of R^{L1} and R^{L2} is preferably an alkyl group. When importance is placed on a reduction in the volatility of the compound, each of R^{L1} and R^{L2} is preferably an alkoxy group. When importance is placed on a reduction in viscosity, at least one of R^{L1} and R^{L2} is preferably an alkenyl group.

The number of halogen atoms present in its molecule is preferably 0, 1, 2, or 3, preferably 0 or 1. When importance is placed on compatibility with other liquid crystal molecules, the number of halogen atoms present in its molecule is preferably 1.

When a ring structure to which each of R^{L1} and R^{L2} is attached is a phenyl group (aromatic group), each of R^{L1} and R^{L2} is preferably a linear alkyl group having 1 to 5 carbon atoms, a linear alkoxy group having 1 to 4 carbon atoms, or an alkenyl group having 4 or 5 carbon atoms. When a ring structure to which it is attached is a saturated ring structure, such as cyclohexane, pyran, or dioxane, each of R^{L1} and R^{L2} is preferably a linear alkyl group having 1 to 5 carbon atoms, a linear alkoxy group having 1 to 4 carbon atoms, or a linear alkenyl group having 2 to 5 carbon atoms. To stabilize the nematic phase, the total of carbon atoms and, if present, oxygen atoms is preferably 5 or less, and a straight-chain shape is preferred.

The alkenyl group is preferably selected from groups represented by formulae (R1) to (R5) (a black dot in each formula represents a carbon atom in a ring structure).

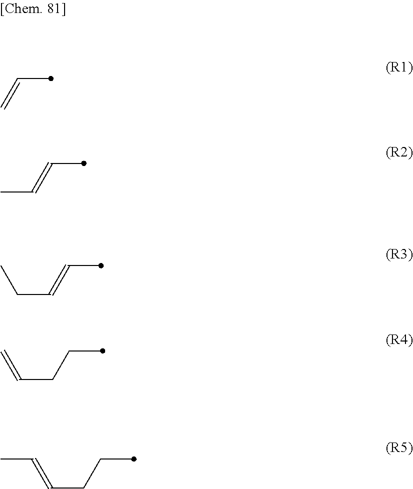

When importance is placed on the response speed, n^{L1} is preferably 0. To improve the upper-limit temperature of the nematic phase, n^{L1} is preferably 2 or 3. To strike a balance therebetween, n^{L1} is preferably 1. To provide a composition that satisfies required properties, compounds having different n^{L1} values are preferably combined.

When an increase in Δn is required, A^{L1}, A^{L2}, and A^{L3} each independently represent an aromatic group. To improve the response speed, A^{L1}, A^{L2}, and A^{L3} each independently preferably represent an aliphatic group, preferably a trans-1,4-cyclohexylene group, a 1,4-phenylene group, a 2-fluoro-1,4-phenylene group, a 3-fluoro-1,4-phenylene group, a 3,5-difluoro-1,4-phenylene group, a 1,4-cyclohexenylene group, a 1,4-bicyclo[2.2.2]octylene group, a piperidine-1,4-diyl group, a naphthalene-2,6-diyl group, a decahydronaphthalene-2,6-diyl group, or a 1,2,3,4-tetrahydronaphthalene-2,6-diyl group, more preferably represent any of structures below.

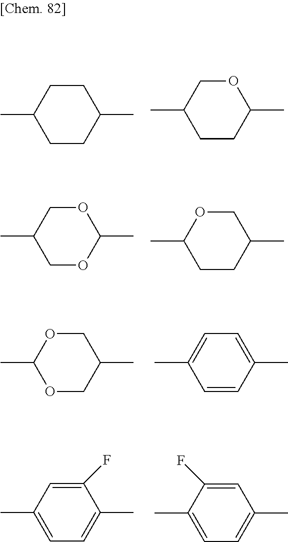

More preferably, A^{L1}, A^{L2}, and A^{L3} each independently represent a trans-1,4-cyclohexylene group or a 1,4-phenylene group.

When importance is placed on the response speed, Z^{L1} and Z^{L2} are each preferably a single bond.

The compound represented by general formula (L) preferably has 0 or 1 halogen atom in its molecule.

The compound represented by general formula (L) is preferably a compound selected from the group consisting of compounds represented by general formulae (L-3) to (L-8).

A compound represented by general formula (L-3) is a compound as follows:

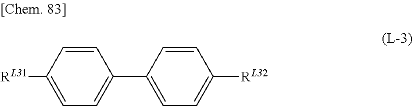

(wherein in the formula, R^{L31} and R^{L32} each independently represent the same meaning as R^{L1} and R^{L2} in general formula (L)).

R^{L31} and R^{L32} are preferably each independently an alkyl group having 1 to 5 carbon atoms, an alkenyl group having 4 or 5 carbon atoms, or an alkoxy group having 1 to 4 carbon atoms.

The compound represented by general formula (L-3) may be used alone. Alternatively, two or more compounds thereof may also be used in combination. The types of compounds that can be combined are not particularly limited. The compounds are used in appropriate combination in accordance with performance requirements regarding, for example, the solubility at a low temperatures, transition temperature, electrical reliability, and birefringence. The number of types of compounds used in an example of the embodiment is, for example, 1, 2, 3, 4, or 5 or more.

The lower limit of the amount of the compound represented by formula (L-3) contained is preferably 1% by mass, 2% by mass, 3% by mass, 5% by mass, 7% by mass, or 10% by mass based on the total amount of the composition of the embodiment. The upper limit of the amount contained is preferably 20% by mass, 15% by mass, 13% by mass, 10% by mass, 8% by mass, 7% by mass, 6% by mass, 5% by mass, or 3% by mass based on the total amount of the composition of the embodiment.

A compound represented by general formula (L-4) is a compound as follows:

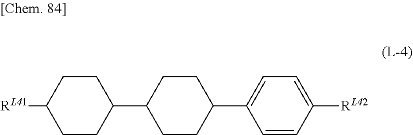

(wherein in the formula, R^{L41} and R^{L42} each independently represent the same meaning as Rⁱ¹ and Rⁱ² in general formula (L)).

R^{L41} is preferably an alkyl group having 1 to 5 carbon atoms or an alkenyl group having 2 to 5 carbon atoms. R^{L42} is preferably an alkyl group having 1 to 5 carbon atoms, an alkenyl group having 4 or 5 carbon atoms, or an alkoxy group having 1 to 4 carbon atoms.

The compound represented by general formula (L-4) may be used alone. Alternatively, two or more compounds thereof may also be used in combination. The types of compounds that can be combined are not particularly limited. The compounds are used in appropriate combination in accordance with performance requirements regarding, for example, the solubility at a low temperatures, transition temperature, electrical reliability, and birefringence. The number of types of compounds used in an example of the embodiment is, for example, 1, 2, 3, 4, or 5 or more.

In the composition of the embodiment, the amount of the compound represented by general formula (L-4) contained needs to be appropriately adjusted in accordance with performance requirements regarding, for example, the solubility at a low temperature, transition temperature, electrical reliability, birefringence, process suitability, drop marks, image-sticking, and dielectric anisotropy.

The lower limit of the amount of the compound represented by formula (L-4) contained is preferably 1% by mass, 2% by mass, 3% by mass, 5% by mass, 7% by mass, 10% by mass, 14% by mass, 16% by mass, 20% by mass, 23% by mass, 26% by mass, 30% by mass, 35% by mass, or 40% by mass based on the total amount of the composition of the embodiment. The upper limit of the amount of the compound represented by formula (L-4) contained is preferably 50% by mass, 40% by mass, 35% by mass, 30% by mass, 20% by mass, 15% by mass, 10% by mass, or 5% by mass based on the total amount of the composition of the embodiment.

A compound represented by general formula (L-5) is a compound as follows:

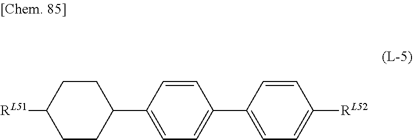

(wherein in the formula, R^{L51} and R^{L52} each independently represent the same meaning as R^{L1} and R^{L2} in general formula (L)).

R^{L51} is preferably an alkyl group having 1 to 5 carbon atoms or an alkenyl group having 2 to 5 carbon atoms. R^{L52} is preferably an alkyl group having 1 to 5 carbon atoms, an alkenyl group having 4 or 5 carbon atoms, or an alkoxy group having 1 to 4 carbon atoms.

The compound represented by general formula (L-5) may be used alone. Alternatively, two or more compounds thereof may also be used in combination. The types of compounds that can be combined are not particularly limited. The compounds are used in appropriate combination in accordance with performance requirements regarding, for example, solubility at a low temperature, transition temperature, electrical reliability, and birefringence. The number of types of compounds used in an example of the embodiment is, for example, 1, 2, 3, 4, or 5 or more.

In the composition of the embodiment, the amount of the compound represented by general formula (L-5) contained needs to be appropriately adjusted in accordance with performance requirements regarding, for example, the solubility at a low temperature, transition temperature, electrical reliability, birefringence, process suitability, drop marks, image-sticking, and dielectric anisotropy.

The lower limit of the amount of the compound represented by formula (L-5) contained is preferably 1% by mass, 2% by mass, 3% by mass, 5% by mass, 7% by mass, 10% by mass, 14% by mass, 16% by mass, 20% by mass, 23% by mass, 26% by mass, 30% by mass, 35% by mass, or 40% by mass based on the total amount of the composition of the embodiment. The upper limit of the amount of the compound represented by formula (L-5) contained is preferably, 50% by mass, 40% by mass, 35% by mass, 30% by mass, 20% by mass, 15% by mass, 10% by mass, or 5% by mass based on the total amount of the composition of the embodiment.

A compound represented by general formula (L-6) is a compound as follows:

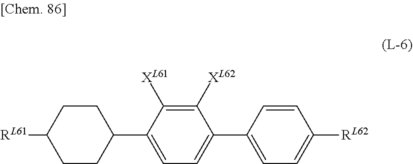

(wherein in the formula, R^{L61} and R^{L62} each independently represent the same meaning as R^{L1} and R^{L2} in general formula (L), and R^{L61} and R^{L62} each independently represent a hydrogen atom or a fluorine atom).

R^{L61} and R^{L62} are preferably each independently an alkyl group having 1 to 5 carbon atoms or an alkenyl group having 2 to 5 carbon atoms. It is preferable that one of X^{L61} and X^{L62} be a fluorine atom and the other be a hydrogen atom.

The compound represented by general formula (L-6) may be used alone. Alternatively, two or more compounds thereof may also be used in combination. The types of compounds that can be combined are not particularly limited. The compounds are used in appropriate combination in accordance with performance requirements regarding, for example, the solubility at a low temperatures, transition temperature, electrical reliability, and birefringence. The number of types of compounds used in an example of the embodiment is, for example, 1, 2, 3, 4, or 5 or more.

The lower limit of the amount of the compound represented by formula L-6) contained is preferably 1% by mass, 2% by mass, 3% by mass, 5% by mass, 7% by mass, 10% by mass, 14% by mass, 16% by mass, 20% by mass, 23% by mass, 26% by mass, 30% by mass, 35% by mass, or 40% by mass based on the total amount of the composition of the embodiment. The upper limit of the amount of the compound represented by formula (L-6) contained is preferably 50% by mass, 40% by mass, 35% by mass, 30% by mass, 20% by mass, 15% by mass, 10% by mass, or 5% by mass based on the total amount of the composition of the embodiment. When importance is placed on an increase in Δn, the amount contained is preferably increased. When importance is placed on precipitation at a low temperature, the amount contained is preferably reduced.

A compound represented by general formula (L-7) is a compound as follows:

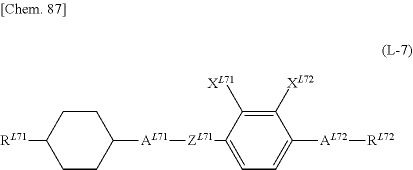

(wherein in the formula, R^{L71} and R^{L72} each independently represent the same meaning as R^{L1} and R^{L2} in general formula (L), A^{L71} and A^{L72} each independently represent the same meaning as A^{L2} and A^{L3} in general formula (L), hydrogen atoms in A^{L71} and A^{L72} may each be independently replaced with a fluorine atom, Z^{L71} represents the same meaning as Z^{L2} in general formula (L), X^{L71} and X^{L72} each independently represent a fluorine atom or a hydrogen atom).

In the formula, R^{L71} and R^{L72} are preferably each independently an alkyl group having 1 to 5 carbon atoms, an alkenyl group having 2 to 5 carbon atoms, or an alkoxy group having 1 to 4 carbon atoms. A^{L71} and A^{L72} are preferably each independently a 1,4-cyclohexylene group or a 1,4-phenylene group. Hydrogen atoms in A^{L71} and A^{L72} may each be independently replaced with a fluorine atom. Z^{L71} is preferably a single bond or COO—, preferably a single bond. X^{L71} and X^{L72} is preferably a hydrogen atom.

The types of compounds that can be combined are not particularly limited. The compounds are used in combination in accordance with performance requirements regarding, for example, the solubility at a low temperatures, transition temperature, electrical reliability, and birefringence. The number of types of compounds used in an example of the embodiment is, for example, 1, 2, 3, or 4.

In the composition of the embodiment, the amount of the compound represented by general formula (L-7) contained needs to be appropriately adjusted in accordance with performance requirements regarding, for example, the solubility at a low temperature, transition temperature, electrical reliability, birefringence, process suitability, drop marks, image-sticking, and dielectric anisotropy.

The lower limit of the amount of the compound represented by formula (L-7) contained is preferably 1% by mass, 2% by mass, 3% by mass, 5% by mass, 7% by mass, 10% by mass, 14% by mass, 16% by mass, or 20% by mass based on the total amount of the composition of the embodiment. The upper limit of the amount of compound represented by formula (L-7) contained is preferably 30% by mass, 25% by mass, 23% by mass, 20% by mass, 18% by mass, 15% by mass, 10% by mass, or 5% by mass based on the total amount of the composition of the embodiment.

When the composition according to an example of the embodiment is desired to have high T_{NI}, the amount of the compound represented by formula (L-7) contained is preferably increased. When the composition according to an example of the embodiment is desired to have low viscosity, the amount contained is preferably reduced.

A compound represented by general formula (L-8) is a compound as follows:

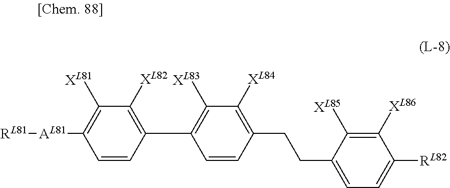

(wherein in the formula, R^{L81} and R^{L82} each independently represent the same meaning as R^{L1} and R^{L2} in general formula (L), A^{L81} represents the same meaning as A^{L1} in general formula (L) or a single bond. Hydrogen atoms in A^{L81} may each be independently replaced with a fluorine atom, and X^{L81} to X^{L86} each independently represent a fluorine atom or a hydrogen atom).

In the formula, R^{L81} and R^{L82} are preferably each independently an alkyl group having 1 to 5 carbon atoms, an alkenyl group having 2 to 5 carbon atoms, or an alkoxy group having 1 to 4 carbon atoms. A^{L81} is preferably a 1,4-cyclohexylene group or a 1,4-phenylene group. Hydrogen atoms in A^{L71} and A^{L72} may each be replaced with a fluorine atom. Zero or 1 fluorine atom is preferably present on the same ring structure in general formula (L-8). Zero or 1 fluorine atom is preferably present in its molecule.

The types of compounds that can be combined are not particularly limited. The compounds are used in combination in accordance with performance requirements regarding, for example, the solubility at a low temperatures, transition temperature, electrical reliability, and birefringence. The number of types of compounds used in an example of the embodiment is, for example, 1, 2, 3, or 4.

In the composition of the embodiment, the amount of the compound represented by general formula (L-8) contained needs to be appropriately adjusted in accordance with performance requirements regarding, for example, the solubility at a low temperature, transition temperature, electrical reliability, birefringence, process suitability, drop marks, image-sticking, and dielectric anisotropy.

The lower limit of the amount of the compound represented by formula (L-8) contained is preferably 1% by mass, 2% by mass, 3% by mass, 5% by mass, 7% by mass, 10% by mass, 14% by mass, 16% by mass, or 20% by mass based on the total amount of the composition of the embodiment. The upper limit of the amount of the compound represented by formula (L-8) contained is preferably 30% by mass, 25% by mass, 23% by mass, 20% by mass, 18% by mass, 15% by mass, 10% by mass, or 5% by mass based on the total amount of the composition of the embodiment.

When the composition according to an example of the embodiment is desired to have high T_{NI}, the amount of the compound represented by formula (L-8) contained is preferably increased. When the composition according to an example of the embodiment is desired to have low viscosity, the amount contained is preferably reduced.

The lower limit of the total amount of the compounds represented by general formulae (i), (L), (N-1), (N-2), (N-3), and (J) contained is preferably 80% by mass, 85% by mass, 88% by mass, 90% by mass, 92% by mass, 93% by mass, 94% by mass, 95% by mass, 96% by mass, 97% by mass, 98% by mass, 99% by mass, or 100% by mass based on the total amount of the composition of the embodiment. The upper limit of the amount contained is preferably 100% by mass, 99% by mass, 98% by mass, or 95% by mass. From the viewpoint of achieving a composition whose absolute value of &A is large, one of the compounds represented by general formulae (N-1), (N-2), (N-3), and (J) is preferably 0% by mass.

Preferably, the composition of the embodiment does not contain a compound having a structure in which oxygen atoms are bonded to each other, such as a peroxide structure (—CO—OO—) in its molecule.

When importance is placed on the reliability and long-term stability of the composition, the composition preferably has a carbonyl group-containing compound content of 5% or less by mass, more preferably 3% or less by mass, even more preferably 1% or less by mass based on the total mass of the composition. Most preferably, the composition is substantially free of the carbonyl group-containing compound.

When importance is placed on stability under UV irradiation, the composition preferably has a chlorine atom-substituted compound content of 15% or less by mass, preferably 10% or less by mass, preferably 8% or less by mass, more preferably 5% or less by mass, preferably 3% or less by mass based on the total mass of the composition. Even more preferably, the composition is substantially free of the chlorine atom-substituted compound.

It is preferable to increase the amount of a compound in which all ring structures in its molecule are formed of six-membered rings. The composition preferably contains the compound in which all ring structures in its molecule are formed of six-membered rings in an amount of 80% or more by mass, more preferably 90% or more by mass, even more preferably 95% or more by mass based on the total mass of the composition. Most preferably, the composition consists substantially only of the compound in which all ring structures in its molecule are formed of six-membered rings.

To suppress the deterioration of the composition due to oxidation, it is preferable to reduce the amount of a compound having a cyclohexenylene group as a ring structure. The composition preferably has a cyclohexenylene group-containing compound content of 10% or less by mass, preferably 8% or less by mass, more preferably 5% or less by mass, preferably 3% or less by mass based on the total mass of the composition. More preferably, the composition is substantially free of the cyclohexenylene group-containing compound.

When importance is placed on improvements in viscosity and T_{NI}, it is preferable to reduce the amount of a compound having a 2-methylbenzene-1,4-diyl group with a hydrogen atom optionally replaced with a halogen atom in its molecule. The composition preferably contains the compound having a 2-methylbenzene-1,4-diyl group in its molecule in an amount of 10% or less by mass, preferably 8% or less by mass, more preferably 5% or less by mass, preferably 3% or less by mass based on the total mass of the composition. Even more preferably, the composition is substantially free of the compound having a 2-methylbenzene-1,4-diyl group.

In this application, “substantially free of” indicates that something is not contained, except for unintentionally incorporated something.

In the case where a compound contained in the composition according to a first embodiment of the embodiment contains an alkenyl group serving as a side chain, when the alkenyl group is bonded to cyclohexane, the alkenyl group preferably has 2 to 5 carbon atoms. When the alkenyl group is bonded to benzene, the alkenyl group preferably has 4 to 5 carbon atoms, and preferably, the unsaturated bond of the alkenyl group is not directly bonded to benzene.

The composition of the embodiment can contain a polymerizable compound in order to produce a liquid crystal display device of a PS mode, a horizontal electric field-type PSA mode, or a horizontal electric field-type PSVA mode. Examples of the polymerizable compound that can be used include photopolymerizable monomers that are polymerized by energy rays, such as light. Regarding the structure thereof, examples thereof include polymerizable compounds having liquid crystal skeletons, such as biphenyl derivatives and terphenyl derivatives, each including multiple six-membered rings linked together. More specifically, preferred is a bifunctional monomer represented by general formula (XX):

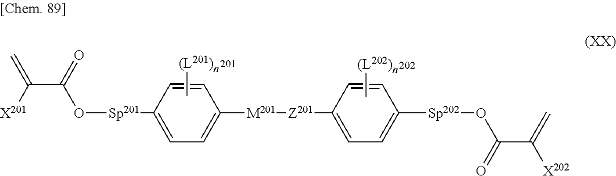

(wherein in the formula, X²⁰¹ and X²⁰² each independently represent a hydrogen atom or a methyl group,

Sp²⁰¹ and Sp²⁰² each independently represent a single bond, an alkylene group having 1 to 8 carbon atoms, or —O—(CH₂)ₛ— (wherein in the formula, s represents an integer of 2 to 7, and the oxygen atom is attached to an aromatic ring),

Z²⁰¹ represents —OCH₂—, —CH₂O—, —COO—, —OCO—, —CF₂O—, —OCF₂—, —CH₂CH₂—, —CF₂CF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CY¹═CY²— (wherein in the formula, Y¹ and Y² each independently represent a fluorine atom or a hydrogen atom), —C≡C—, or a single bond,

L²⁰¹ and L²⁰² each independently represent a fluorine atom, an alkyl group having 1 to 8 carbon atoms, or an alkoxy group having 1 to 8 carbon atoms,

M²⁰¹ represents a 1,4-phenylene group, a trans-1,4-cyclohexylene group, or a single bond, any hydrogen atom in all the 1,4-phenylene groups in the formula may be replaced with a fluorine atom, an alkyl group having 1 to 8 carbon atoms, or an alkoxy group having 1 to 8 carbon atoms, and n201 and n202 each independently represent an integer of 0 to 4).

A diacrylate derivative in which X²⁰¹ and X²⁰² each represent a hydrogen atom and a dimethacrylate derivative in which X²⁰¹ and X²⁰² each represent a methyl group are equally preferred. A compound in which one of X²⁰¹ and X²⁰² represents a hydrogen atom and the other represents a methyl group is also preferred. The polymerization rates of these compounds are the highest for the diacrylate derivative, the lowest for the dimethacrylate derivative, and moderate for the asymmetric compound. A preferable embodiment can be used in accordance with the application. For a PSA-mode display device, a dimethacrylate derivative is particularly preferred.

Sp²⁰¹ and Sp²⁰² each independently represent a single bond, an alkylene group having 1 to 8 carbon atoms, or —O—(CH₂)ₛ—. For a PSA-mode display device, at least one of Sp²⁰¹ and Sp²⁰² is preferably a single bond. A compound in which Sp²⁰¹ and Sp²⁰² each represent a single bond is preferred. An embodiment in which one of Sp²⁰¹ and Sp²⁰² represents a single bond and the other represents an alkylene group having 1 to 8 carbon atoms or —O—(CH₂)ₙ— is preferred. In this case, 1 to 4 alkyl groups are preferred, and s is preferably 1 to 4.

Z²⁰¹ is preferably —OCH₂—, —CH₂O—, —COO—, —OCO—, —CF₂O—, —OCF₂—, —CH₂CH₂—, —CF₂CF₂—, or a single bond, more preferably —COO—, —OCO—, or a single bond, particularly preferably a single bond.

M²⁰¹ represents a 1,4-phenylene group in which any hydrogen atom may be replaced with a fluorine atom, a trans-1,4-cyclohexylene group, or a single bond, preferably a 1,4-phenylene group or a single bond. When C represents a ring structure excluding a single bond, Z²⁰¹ is also preferably a linking group excluding a single bond. When M²⁰¹ is a single bond, Z²⁰¹ is preferably a single bond.

In view of the above, the ring structure between Sp²⁰¹ and Sp²⁰² in general formula (XX) is preferably any of specific structures below.

In the case where M²⁰¹ represents a single bond and where the ring structure is formed of two rings in general formula (XX), the ring structure is preferably represented by any of formulae (XXa-1) to (XXa-5), more preferably represented by any of formulae (XXa-1) to (XXa-3), most preferably represented by formula (XXa-1):

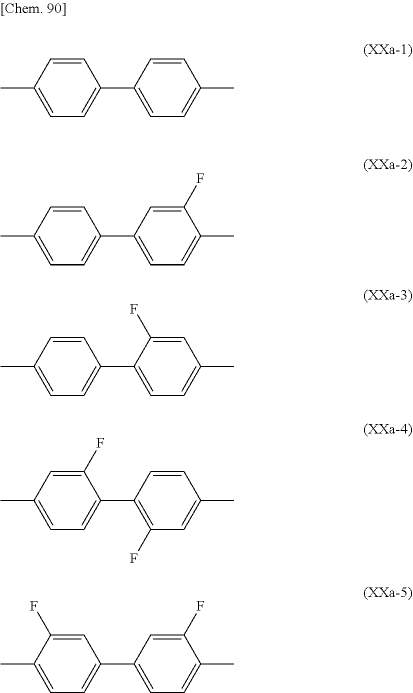

(wherein in each of the formulae, each of two ends is bonded to Sp²⁰¹ or Sp²⁰²).

The anchoring strength of polymerizable compounds containing these skeletons after polymerization is optimal for PSA-mode liquid crystal display devices, resulting in good alignment state. Thus, display nonuniformity is suppressed or does not occur at all.

From the above, polymerizable monomers represented by general formulae (XX-1) to (XX-4) are particularly preferred. Of these, a compound represented by general formula (XX-2) is most preferred:

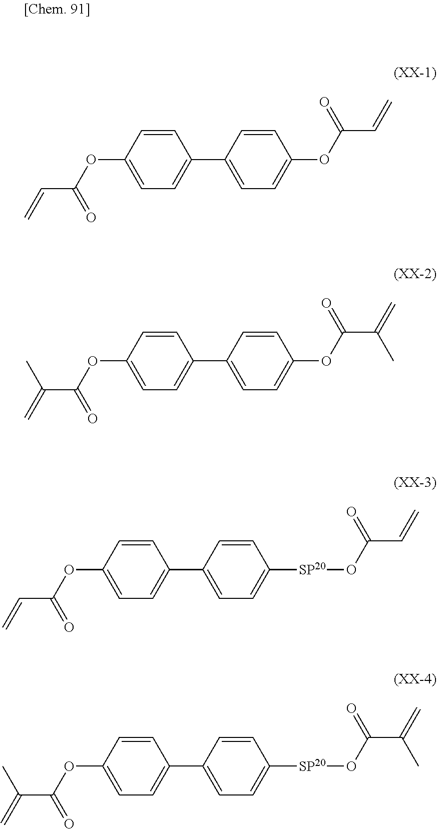

(wherein in each of the formulae, benzene may be substituted with a fluorine atom, and Sp²⁰ represents an alkylene group having 2 to 5 carbon atoms).

In the case where the composition of the embodiment contains the polymerizable compound, the composition preferably has a polymerizable compound content of 0.01% by mass to 5% by mass, preferably 0.05% by mass to 3% by mass, preferably 0.1% by mass to 2% by mass.

In the case where the monomer is added to the composition of the embodiment, polymerization proceeds even in the absence of a polymerization initiator. To promote the polymerization, a polymerization initiator may be contained. Examples of the polymerization initiator include benzoin ethers, benzophenones, acetophenones, benzylketals, and acylphosphine oxides.

The liquid crystal display device of the embodiment may include the alignment layers 4 and 6 as described above. However, it is preferable to avoid using the alignment layers because it facilitates the production of the liquid crystal display device. The liquid crystal molecules are preferably aligned by incorporating a spontaneous alignment agent into the liquid crystal composition contained in the liquid crystal layer according to the embodiment to make the liquid crystal molecules self-aligning without an alignment film, by using a solvent-soluble alignment-type polyimide, or by using a photoalignment film, in particular, a non-polyimide-based photoalignment film.

The liquid crystal composition according to the embodiment preferably contains a spontaneous alignment agent. The spontaneous alignment agent can control the alignment direction of liquid crystal molecules in the liquid crystal composition contained in the liquid crystal layer. It is believed that the component of the spontaneous alignment agent is accumulated at interfaces of the liquid crystal layer or adsorbed on the interfaces, thereby enabling the control of the alignment direction of the liquid crystal molecules. Accordingly, when the liquid crystal composition contains the spontaneous alignment agent, the liquid crystal panel needs no alignment layer.

The liquid crystal composition according to the embodiment preferably has a spontaneous alignment agent content of 0.1% to 10% by mass based on the entire liquid crystal composition. The spontaneous alignment agent in the liquid crystal composition according to the embodiment may be used in combination with the polymerizable compound.

The spontaneous alignment agent is preferably represented by general formula (al-1) and/or (al-2):

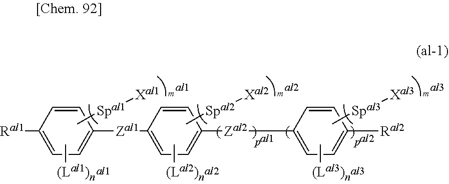

(wherein in the formula, R^{a11}, R^{a12}, Z^{a11}, Z^{a12}, L^{a11}, L^{a12}, L^{a13}, Sp^{a11}, Sp^{a12}, Sp^{a13}, X^{a11}, X^{a12}, X^{a13}, m^{a11}, m^{a12}, m^{a13}, n^{a11}, n^{a12}, n^{a13}, p^{a11}, and p^{a12} are independent of one another,

R^{a11} represents a hydrogen atom, halogen, or a linear, branched, or cyclic alkyl group having 1 to 20 carbon atoms, one or two or more non-adjacent CH₂ groups in the alkyl group may be replaced with —O—, —S—, —CO—, —CO—O—, —O—CO—, —O—CO—O— in such a manner that O and/or S atoms are not directly bonded to each other, one or two or more hydrogen atoms may be replaced with F or Cl,

R^{a12} represents a group having any of the following moieties:

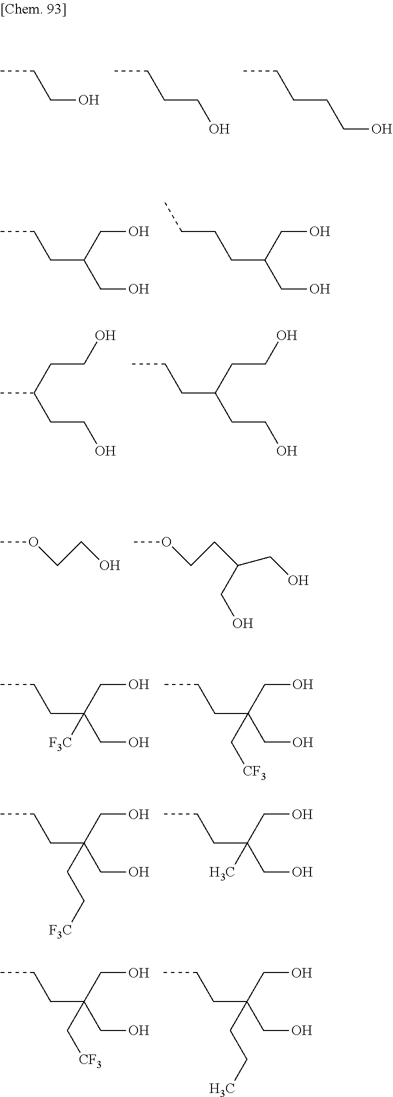

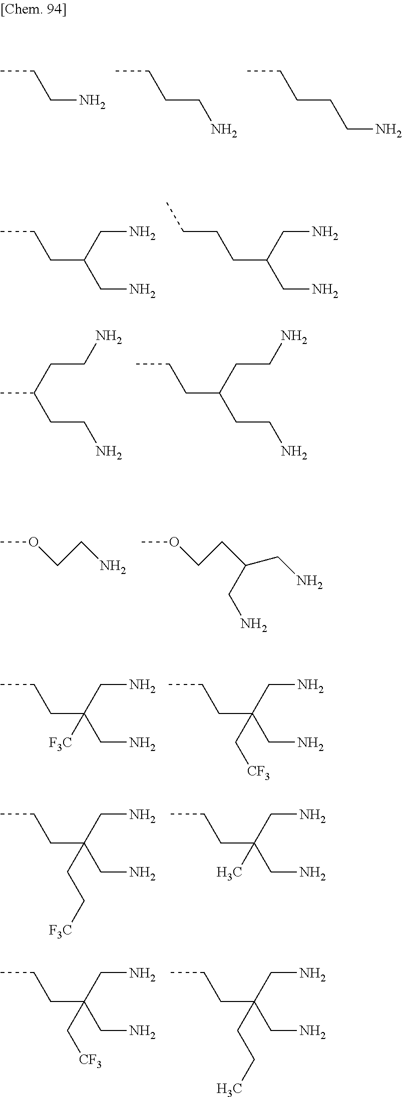

Sp^{a11}, Sp^{a12}, and Sp^{a13} each independently represent an alkyl group having 1 to 12 carbon atoms or a single bond,

X^{a11}, X^{a12}, and X^{a13} each independently represent an alkyl group, an acrylate group, a methacrylate group, or a vinyl group,

Z^{a11} represents —O—, —S—, —CO—, —CO—O—, —OCO—, —O—CO—O—, —OCH₂—, —CH₂O—, —SCH₂—, —CH₂S—, —CF₂O—, —OCF₂—, —CF₂S—, —SCF₂—, —(CH₂)ₙ^{a1}—, —CF₂CH₂—, —CH₂CF₂—, —(CF₂)ₙ^{a1}—, —CH═CH—, —CF═CF—, —C≡C—, —CH═CH—COO—, —OCO—CH═CH—, —(CR^{a13}R^{a14})ₙ^{a1}—, —CH(-Sp^{a11}-X^{a11})—, —CH₂CH(-Sp^{a11}-X^{a11})—, or —CH(-Sp^{a11}-X^{a11})CH(-Sp^{a11}-X^{a11})—,

Z^{a12} independently represents a single bond, —O—, —S—, —CO—, —CO—O—, —OCO—, —O—CO—O—, —OCH₂—, —CH₂O—, —SCH₂—, —CH₂S—, —CF₂O—, —OCF₂—, —CF₂S—, —SCF₂—, —(CH₂)n1-, —CF₂CH₂—, —CH₂CF₂—, —(CF₂)ₙ^{a1}—, —CH═CH—, —CF═CF—, —C≡C—, —CH═CH—COO—, —OCO—CH═CH—, —(CR^{a13}R^{a14})ₙₐ₁—, —CH(-Sp^{a11}-X^{a11})—, —CH₂CH(-Sp^{a11}-X^{a11})—, or —CH(—Sp^{a11}-X^{a11})CH(-Sp^{a11}-X^{a11})—,

L^{a11}, L^{a12}, and L^{a13} each independently represent a hydrogen atom, a fluorine atom, a chlorine atom, a bromine atom, an iodine atom, —CN, —NO₂, —NCO, —NCS, —OCN, —SCN, —C(═O)N(R^{a13})₂, —C(═O)R^{a13}, an optionally substituted silyl group having 3 to 15 carbon atoms, an optionally substituted aryl or cycloalkyl group, or 1 to 25 carbon atoms, one or two or more hydrogen atoms may be replaced with a halogen atom (a fluorine atom or a chlorine atom),

R^{a13} represents an alkyl group having 1 to 12 carbon atoms, R^{a14} represents a hydrogen atom or an alkyl group 1 to 12 carbon atoms, n^{a1} represents an integer of 1 to 4,

p^{a11} and p^{a12} each independently represent 0 or 1, m^{a11}, m^{a12}, and m^{a13} each independently represent an integer of 0 to 3, and n^{a11}, n^{a12}, and n^{a13} each independently represent an integer of 0 to 3),

general formula (A1-2)

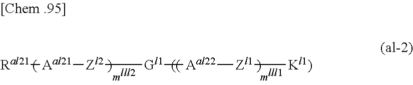

(wherein in the formula, Z¹¹ and Z¹² each independently represent a single bond, —CH═CH—, —CF═CF—, —C≡C—, —COO—, —OCO—, —OCOO—, —OOCO—, —CF₂O—, —OCF₂—, —CH═CHCOO—, —OCOCH═CH—, —CH₂—CH₂COO—, —OCOCH₂—CH₂—, —CH═C(CH₃)COO—, —OCOC(CH₃)═CH—, —CH₂—CH(CH₃)COO—, —OCOCH(CH₃)—CH₂—, —OCH₂CH₂O—, or an alkylene group having 2 to 20 carbon atoms, one or two or more non-adjacent —CH₂-'s in the alkylene group may be replaced with —O—, —COO—, or —OCO—, provided that when K¹¹ is (K-11), a mesogen group contains at least any one of —CH₂—CH₂COO—, —OCOCH₂—CH₂—, —CH═C(CH₃)COO—, —OCOC(CH₃)═CH—, —CH₂—CH(CH₃)COO—, —OCOCH(CH₃)—CH₂—, and —OCH₂CH₂O—,

A^{a121} and A^{a122} each independently represent a divalent six-membered aromatic group or a divalent six-membered alicyclic group, preferably an unsubstituted divalent six-membered aromatic group, an unsubstituted divalent six-membered alicyclic group, or a group in which a hydrogen atom in any of these ring structures is not replaced or is replaced with an alkyl group having 1 to 6 carbon atoms, an alkoxy group having 1 to 6 carbon atoms, or a halogen atom, preferably a unsubstituted divalent six-membered aromatic group, a group in which a hydrogen atom in this ring structure is replaced with a fluorine atom, or an unsubstituted divalent six-membered alicyclic group, preferably a 1,4-phenylene group, a 2,6-naphthalene group, or a 1,4-cyclohexyl group, in which a hydrogen atom in the substituent may be replaced with a halogen atom, an alkyl group, or an alkoxy group, provided that at least one substituent is replaced with Pⁱ¹-Spⁱ¹-,

when a plurality of Zⁱ¹'s, a plurality of A^{a121}'s, and a plurality of Aa¹²²'s are present, they may be the same or different,

Spⁱ¹ preferably represents a linear alkylene group having 1 to 18 carbon atoms or a single bond, more preferably a linear alkylene group having 2 to 15 carbon atoms or a single bond, even more preferably a linear alkylene group having 3 to 12 carbon atoms or a single bond,

R^{a121} represents a hydrogen atom, a linear or branched alkyl group having 1 to 20 carbon atoms, a halogenated alkyl group, or Pⁱ¹-Spⁱ¹-, each —CH₂— in the alkyl group is preferably —O—, —OCO—, or —COO— (provided that adjacent —O-'s are not directly bonded to each other), more preferably a hydrogen atom, a linear or branched alkyl group having 1 to 18 carbon atoms, or Pⁱ¹-Spⁱ¹-, and each —CH₂— in the alkyl group represents —O— or —OCO— (provided that adjacent —O-'s are not directly bonded to each other),

Kⁱ¹ represents a substituent represented by any of general formulae (K-1) to (K-11),

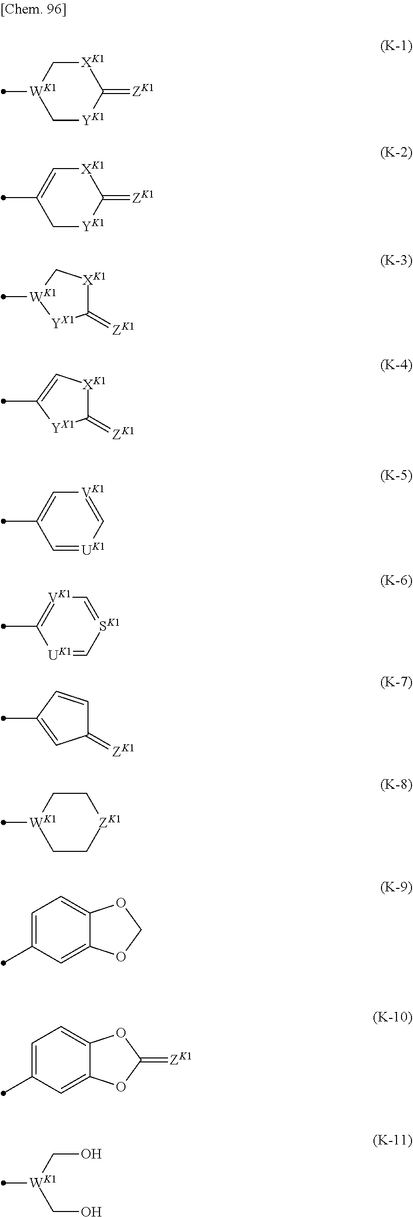

Pⁱ¹ represents a polymerizable group and a substituent selected from the group consisting of substituents represented by general formulae (P-1) to (P-15) (wherein in each of the formulae, a black dot at the right end represents a bond),

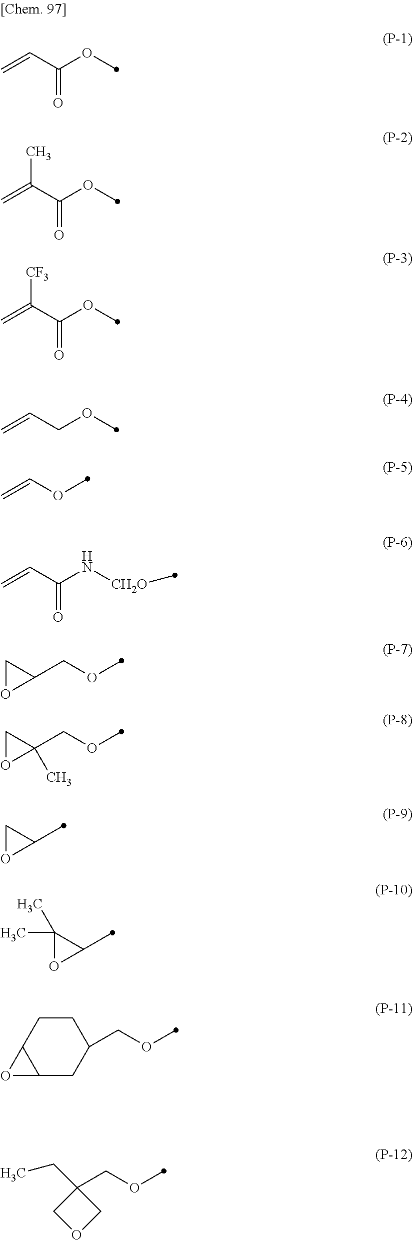

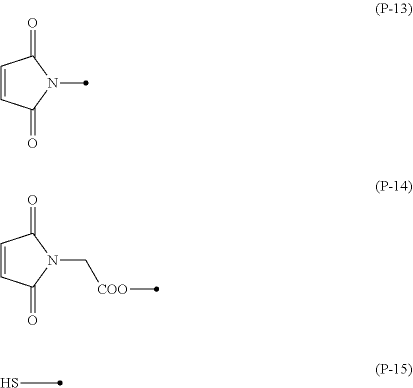

when a plurality of Zⁱ¹'s, a plurality of Zⁱ²'s, a plurality of A^{a121}'s, a plurality of m¹ⁱⁱ¹'s, and/or a plurality of A^{a122}'s are present, they may be the same or different, provided that one of Aⁱ¹ and Aⁱ² is replaced with at least one Pⁱ¹-Spⁱ¹-, when Kⁱ¹ is (K-11), Zⁱⁱ¹ contains at least one of —CH₂—CH₂COO—, —OCOCH₂—CH₂—, —CH₂—CH(CH₃)COO—, —OCOCH(CH₃)—CH₂—, and —OCH₂CH₂O—,

mⁱⁱⁱ¹ represents an integer of 1 to 5,

mⁱⁱⁱ² represents an integer of 1 to 5,

Gⁱ¹ represents a divalent, trivalent, or tetravalent branched structure or a divalent, trivalent, or tetravalent aliphatic or aromatic ring structure, and

mⁱⁱⁱ³ represents an integer smaller by 1 than the valence of Gⁱ¹).

Another example of a method for eliminating the need for the alignment layers of the liquid crystal panel is a method in which when the polymerizable compound-containing liquid crystal composition is charged into the gap between the first substrate and the second substrate, the liquid crystal composition is charged at a temperature equal to or higher than Tni, and then the polymerizable compound-containing liquid crystal composition is subjected to UV irradiation to cure the polymerizable compound.

The composition according to the embodiment may further contain a compound represented by general formula (Q):

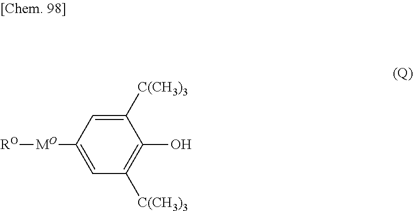

(wherein in the formula, R^{Q} represents a linear alkyl group having 1 to 22 carbon atoms or a branched alkyl group, one or two or more CH₂ groups in the alkyl group may be replaced with —O—, —CH═CH—, —CO—, —OCO—, —COO—, —C≡C—, —CF₂O—, or —OCF₂— in such a manner that oxygen atoms are not directly adjacent to each other, and M^{Q} represents a trans-1,4-cyclohexylene group, a 1,4-phenylene group, or a single bond).

R^{Q} represents a linear or branched alkyl group having 1 to 22 carbon atoms, one or two or more CH₂ groups in the alkyl group may be replaced with —O—, —CH═CH—, —CO—, —OCO—, —COO—, —C═C—, —CF₂O—, or —OCF₂— in such a manner that oxygen atoms are not directly adjacent to each other. R^{Q} is preferably a linear alkyl group having 1 to 10 carbon atoms, a linear alkoxy group, a linear alkyl group in which one CH₂ group is replaced with —OCO— or —COO—, a branched alkyl group, a branched alkoxy group, or a branched alkyl group in which one CH₂ group is replaced with —OCO— or —COO—, more preferably a linear alkyl group having 1 to 20 carbon atoms, a linear alkyl group in which one CH₂ group is replaced with —OCO— or —COO—, a branched alkyl group, a branched alkoxy group, a branched alkyl group in which one CH₂ group is replaced with —OCO— or —COO—. M^{Q} represents a trans-1,4-cyclohexylene group, a 1,4-phenylene group, or a single bond, preferably a trans-1,4-cyclohexylene group or a 1,4-phenylene group.

More specifically, the compound represented by general formula (Q) is preferably any of compounds represented by general formulae (Q-a) to (Q-d) below.

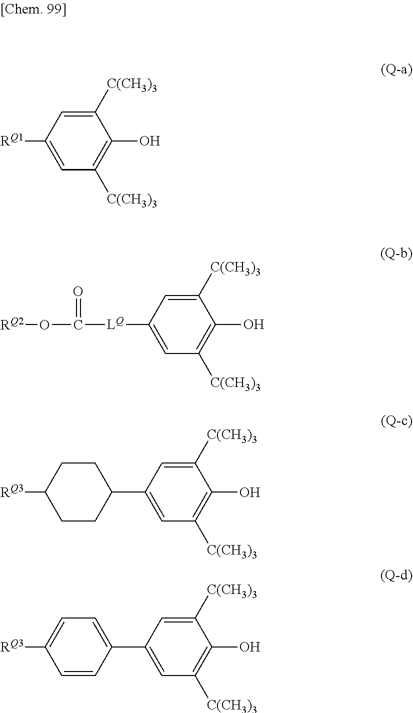

In the formulae, R^{Q1} is preferably a linear alkyl group having 1 to 10 carbon atoms or a branched alkyl group. R^{Q2} is preferably a linear alkyl group having 1 to 20 or a branched alkyl group. R^{Q3} is preferably a linear alkyl group having 1 to 8 carbon atoms, a branched alkyl group, a linear alkoxy group, or a branched alkoxy group. L^{Q} is preferably a linear alkylene group having 1 to 8 carbon atoms or a branched alkylene group. Among the compounds represented by general formulae (Q-a) to (Q-d), the compounds represented by general formulae (Q-c) and (Q-d) are more preferred.

The composition of the embodiment preferably contains one or two, more preferably one to five compounds represented by general formula (Q), and preferably has a compound content of 0.001% to 1% by mass, more preferably 0.001% to 0.1% by mass, particularly preferably 0.001% to 0.05% by mass.

The composition containing the polymerizable compound of the embodiment is used for a liquid crystal display device in which the polymerizable compound contained therein is polymerized by ultraviolet irradiation to provide the ability to align liquid crystal molecules and the amount of light transmitted is controlled by the use of the birefringence of the composition.

In the case where the liquid crystal composition of the embodiment contains the polymerizable compound, because appropriate polymerization rate is desired in order to allow the liquid crystal to have good alignment ability, a method for polymerizing the polymerizable compound is preferably a method in which the polymerizable compound is irradiated with active energy rays, such as ultraviolet light or electron beams, separately, in combination, or sequentially to perform polymerization. When ultraviolet light is used, a polarized light source or a non-polarized light source may be used. In the case where the polymerizable compound-containing composition is polymerized while being held between two substrates, at least the substrate located on the irradiation side needs to have appropriate transparency. The following means may also be employed: Only a specific portion is polymerized using a mask at the time of light irradiation. The alignment state of an unpolymerized portion is then changed by changing conditions, such as an electric field, a magnetic field, or a temperature, and is polymerized by further irradiation with active energy rays. In particular, in the case of performing ultraviolet exposure, the ultraviolet exposure is preferably performed while an alternating electric field is applied to the polymerizable compound-containing composition. The alternating electric field applied preferably has a frequency of 10 Hz to 10 kHz, more preferably 60 Hz to 10 kHz. The voltage is selected in accordance with a desired pretilt angle of the liquid crystal display device. That is, the pretilt angle of the liquid crystal display device can be controlled by the voltage applied. A transverse electric field-type MVA-mode liquid crystal display device is preferably controlled to have a pretilt angle of 80° to 89.9° in view of alignment stability and contrast.

The temperature during the irradiation is preferably within a temperature range in which the liquid crystal state of the composition of the embodiment can be maintained. The polymerization is preferably performed at a temperature close to room temperature, i.e., typically at a temperature of 15° C. to 35° C. Examples of a lamp that can be used to emit ultraviolet light include metal halide lamps, high-pressure mercury lamps, and ultrahigh-pressure mercury lamps. Regarding the wavelength of ultraviolet light used for the irradiation, the irradiation is preferably performed with ultraviolet light in a wavelength range different from the wavelength range of ultraviolet light absorbed by the composition. The ultraviolet light absorbed by the composition is preferably cut off, as needed. The irradiation intensity of ultraviolet light is preferably 0.1 mW/cm² to 100 W/cm², more preferably 2 mW/cm² to 50 W/cm². The amount of irradiation energy of ultraviolet light can be appropriately adjusted and is preferably 10 mJ/cm to 500 J/cm², more preferably 100 mJ/cm² to 200 J/cm². When irradiation is performed with ultraviolet light, the intensity may be changed. The irradiation time of ultraviolet light is appropriately selected in accordance with the irradiation intensity of ultraviolet light and is preferably 10 seconds to 3,600 seconds, more preferably 10 seconds to 600 seconds.

A preferred liquid crystal display device according to the embodiment may include, as needed, an alignment layer on a surface in contact with the liquid crystal composition between the first substrate and the second substrate in order to align liquid crystal molecules in the liquid crystal layer 5. In a liquid crystal display device that requires an alignment layer, the alignment layer is disposed between the light conversion layer and the liquid crystal layer. Even in the case of a thick alignment layer, the thickness is as small as 100 nm or less. Thus, the alignment layer does not completely block the interaction between the light-emitting nanocrystalline particles and the colorants, such as pigments, contained in the light conversion layer and the liquid crystal compounds contained in the liquid crystal layer.

A liquid crystal display device that includes no alignment layer has a greater interaction between the light-emitting nanocrystalline particles and the colorants, such as pigments, contained in the light conversion layer and the liquid crystal compounds contained in the liquid crystal layer.

The alignment layer according to the embodiment is preferably at least one selected from the group consisting of rubbed alignment layers and photoalignment layers. In the case of a rubbed alignment layer, a known polyimide-based alignment layer can be suitably used without any particular limitation.

As a material for the rubbed alignment layer, a transparent organic material, such as polyimide, polyamide, a benzocyclobutene polymer (BCB), poly(vinyl alcohol), can be used. Particularly preferred is a polyimide alignment layer obtained by imidization of poly(amic acid) synthesized from a diamine, such as an aliphatic or alicyclic diamine, e.g., p-phenylenediamine or 4,4′-diaminodiphenylmethane, and an aliphatic or alicyclic tetracarboxylic anhydride, such as butanetetracarboxylic anhydride or 2,3,5-tricarboxycyclopentylacetic anhydride, or an aromatic tetracarboxylic anhydride, such as pyromellitic dianhydride. When it is used for, for example, a homeotropic alignment layer, it can also be used without imparting alignment.

In the case where the alignment layer according to the embodiment is a photoalignment layer, the alignment layer only needs to contain one or more types of photoresponsive molecules. The photoresponsive molecule is preferably at least one selected from the group consisting of photodimerizable molecules, which dimerize to form a crosslinked structure in response to light, photoisomerizable molecules, which isomerize and align substantially perpendicular or parallel to the polarization axis in response to light, and photodegradable polymers, which break their polymer chains in response to light. The photoisomerizable molecules are particularly preferred in view of sensitivity and anchoring strength.

An image display device according to another embodiment is an organic electroluminescent display device (OLED) including a pair of electrode substrates in which a first electrode substrate and a second electrode substrate are disposed opposite each other, an electroluminescent layer disposed between the first electrode and the second electrode, the light conversion layer including multiple pixels and being configured to convert light that has a blue emission spectrum and that is emitted from the electroluminescent layer into light having a different wavelength, and the wavelength-selective transmission layer disposed between the first electrode or the second electrode and the light conversion layer.

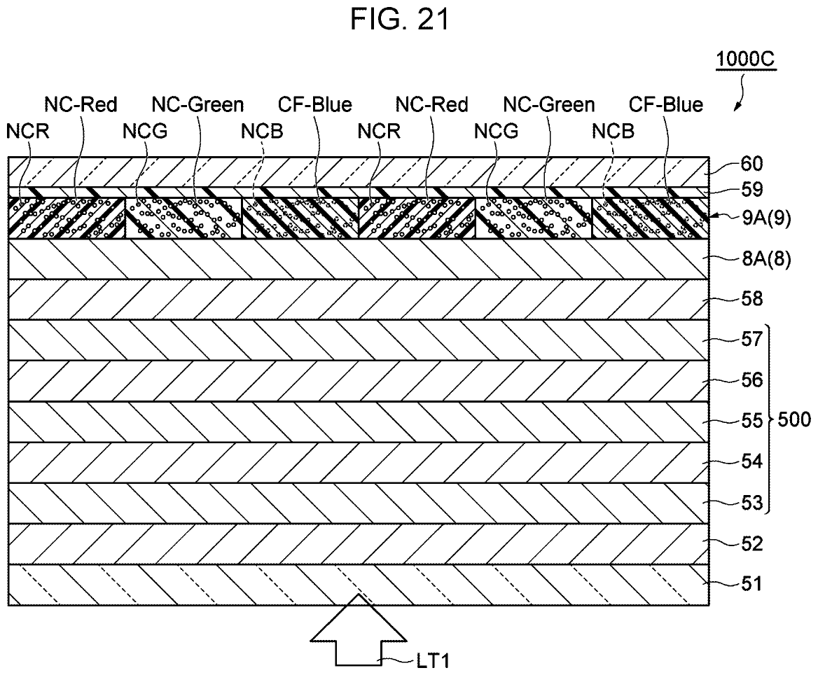

FIG. 21 is a cross-sectional view of an image display device (OLED) according to an embodiment. An image display device (OLED) 1000C according to an embodiment includes a first electrode 52 and a second electrode 58 serving as a pair of opposite electrodes, an electroluminescent layer 500 between the electrodes, and the wavelength-selective transmission layer 8A (8) and the light conversion layer 9A (9) disposed, in this order from the electroluminescent layer 500 side, on a surface of the second electrode 58 remote from the electroluminescent layer 500.

The electroluminescent layer 500 only needs to include at least a light-emitting layer 55 and more preferably includes an electron transport layer 56, the light-emitting layer 55, a hole transport layer 54, and a hole injection layer 53. The electroluminescent layer 512 preferably includes an electron injection layer 57, the electron transport layer 56, the light-emitting layer 55, the hole transport layer 54, and the hole injection layer 53. An electron blocking layer (not illustrated) may be disposed between the light-emitting layer 55 and the hole transport layer 54 in order to increase the external quantum efficiency and improve the emission intensity. Similarly, a hole blocking layer (not illustrated) may be disposed between the light-emitting layer 55 and the electron transport layer 56 in order to increase the external quantum efficiency and improve the emission intensity.

In the image display device (OLED) 1000C, the electroluminescent layer 500 has a structure in which the hole injection layer 53 in contact with the first electrode 52, the hole transport layer 54, the light-emitting layer 55, and the electron transport layer 56 are stacked in this order.

In this embodiment, for convenience, the first electrode 52 will be described as an anode, and the second electrode 58 will be described as a cathode. However, the structure of the image display device (LED panel) 1000C is not limited thereto. The first electrode 52 may be a cathode, the second electrode 58 may be an anode, and the order of the layers stacked between these electrodes may be reversed. In other words, the hole injection layer 53, the hole transport layer 54, the electron blocking layer optionally disposed, the light-emitting layer 55, the hole blocking layer optionally disposed, the electron transport layer 56, and the electron injection layer 57 may be stacked in this order from the second electrode 58 on the anode side.

The light conversion layer 9A (9) and the wavelength-selective transmission layer 8A (8) may be the same as the light conversion layer 9 and the wavelength-selective transmission layer 8, respectively, in the foregoing liquid crystal display device. One of the features of this embodiment is that the light conversion layer 9A (9) and the wavelength-selective transmission layer 8A (8) are used as alternative members of color filters.

In this embodiment, in the case where light (light having a blue emission spectrum) having a main peak at about 450 nm is emitted from the electroluminescent layer 500, the light conversion layer 9A (9) can use the blue light as blue color. Thus, in the case where light emitted from the electroluminescent layer 500 serving as a light source is blue light, among the light conversion pixel layers of each color (NC-Red, NC-Green, and NC-Blue), the light conversion pixel layer (NC-Blue) is omitted, and backlight may be used as it is for blue color, as illustrated in FIG. 21. In this case, a color layer for displaying blue color can be formed of a colorant layer containing a transparent resin and a blue colorant (what is called a blue color filter) (CF-Blue) or the like.

Red color layers R, green color layers G, and blue color layers B may appropriately contain colorants, as needed. Layers (NCL) containing light-emitting nanocrystals NC may contain colorants corresponding to the respective colors.

In the image display device 1000C illustrated in FIG. 21, applying a voltage between the first electrode 52 and the second electrode 58 injects electrons from the second electrode 58 serving as a cathode into the electroluminescent layer 500 and holes from the first electrode 52 serving as an anode into the electroluminescent layer 500 to allow a current to flow. The injected electrons are recombined with the holes to form excitons. Accordingly, the light-emitting material contained in the light-emitting layer 55 is in an excited state and emits light.

The light emitted from the light-emitting layer 55 passes through the electron transport layer 56, the electron injection layer 57, and the second electrode 58. Light in one or more specific wavelength ranges is selected by the wavelength-selective transmission layer 8A (8) and incident on a surface of the light conversion layer 9A (9). The light incident on the light conversion layer 9A (9) is absorbed by the light-emitting nanocrystalline particles and converted into light having any of a red (R), green (G), or blue (B) emission spectrum, so that one of red (R), green (G), or blue (B) colors is displayed. The light conversion layer 9A (9) is adjacent to the wavelength-selective transmission layer 8A (8). Because light in a wavelength range other than one or more specific wavelength ranges transmitted is reflected, light from the light-emitting nanocrystalline particles can be emitted in one direction.

For the purpose of reducing the potential barrier of hole or electron injection, improving the hole or electron transport properties, inhibiting the hole or electron transport properties, or suppressing or preventing the quenching phenomenon due to the electrodes, the electroluminescent layer 500 may include a single or multiple layers that exhibit various effects, as needed.

An overcoat layer 59 may be disposed so as to cover the light conversion layer 9A (9) and the wavelength-selective transmission layer 8A (8). If necessary, a substrate 60 composed of, for example, glass may be bonded to the entire surface of the overcoat layer 59. In this case, a known adhesive layer (for example, a thermosetting or ultraviolet-curable resin) may be disposed between the overcoat layer 59 and the substrate 60, as needed. In the case where the light-emitting device is of a top-emission type in which light is displayed through the substrate 60, each of the overcoat layer 59 and the substrate 60 is preferably composed of a transparent material. In contrast, in the case of a bottom-emission type, the overcoat layer 59 and the substrate 51 are not particularly limited.

FIG. 21 illustrates a structure in which the first electrode 52 is disposed on a substrate 51. The substrate is a support for supporting a stack including the first electrode 52, the electroluminescent layer 500, the second electrode 58, the light conversion layer 9A (9), and the wavelength-selective transmission layer 8A (8). A known support can be used.

In the embodiment illustrated in FIG. 21, electroluminescent light is emitted from the organic electroluminescent layer. In another embodiment, electroluminescent light may originate from light-emitting nanocrystalline particles. In this case, the image display device is also called a QLED. In this case, the electroluminescent layer may have a known structure that can emit electroluminescent light originating from the light-emitting nanocrystalline particles.

### EXAMPLES

While the present invention will be described in more detail below by way of examples, the present invention is not limited thereto. In these examples, the following abbreviations are used for describing compounds. Note that n represents a natural number.

### (Side Chain)

-n: —CₙH₂ₙ₊₁, linear alkyl group having n carbon atoms

n-: CₙH₂ₙ₊₁—, linear alkyl group having n carbon atoms

—On: —OCₙH₂ₙ₊₁, linear alkoxy group having n carbon atoms

nO—: CₙH₂ₙ₊₁O—, linear alkoxy group having n carbon atoms

—V: —CH═CH₂

V—: CH₂═CH—

—V1: —CH═CH—CH₃

1V—: CH₃—CH═CH—

-2V: —CH₂—CH₂—CH═CH₃

V2-: CH₂═CH—CH₂—CH₂—

-2V1: —CH₂—CH₂—CH═CH—CH₃

1V2-: CH₃—CH═CH—CH₂—CH₂

### (Linking Group)

-n-: —CₙH₂ₙ—

-nO—: —CₙH₂ₙ—O—

—On-: —O—CₙH₂ₙ—

—COO—: —C(═O)—O—

—OCO—: —O—C(═O)—

—CF2O—: —CF₂—O—

—OCF2-: —O—CF₂—

### (Ring Structure)

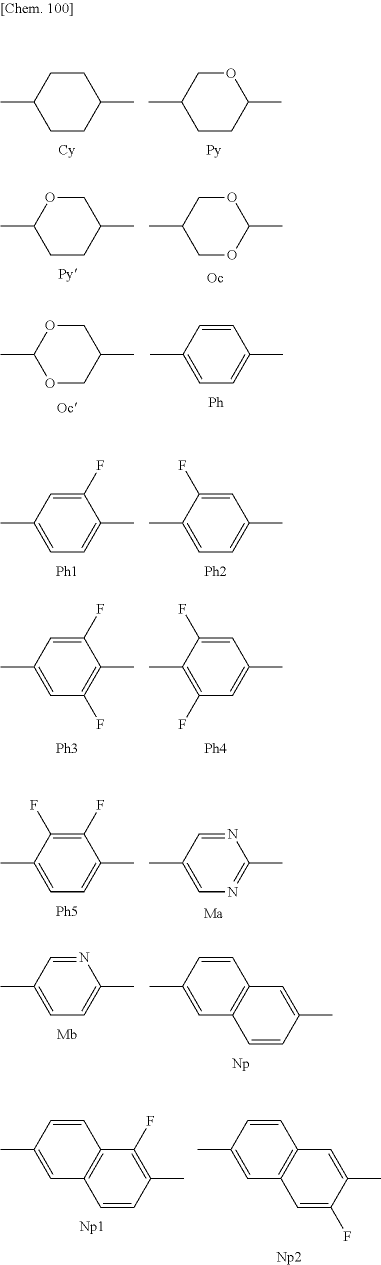

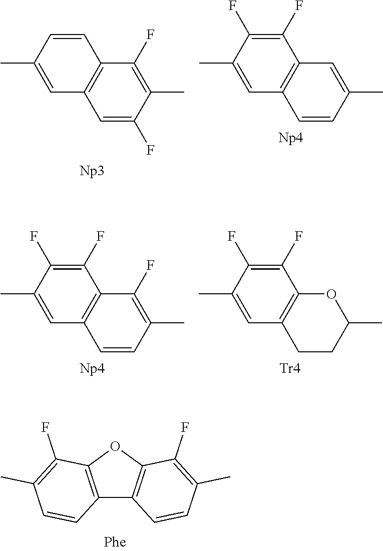

The properties measured in the examples are described below.

T_{NI}: nematic-isotropic liquid phase transition temperature (° C.)

Δn: refractive index anisotropy at 20° C.

Δε: dielectric anisotropy at 20° C.

η: viscosity at 20° C. (mPa·s)

γ₁: rotational viscosity at 20° C. (mPa·s)

K₁₁: elastic constant K₁₁ at 20° C. (pN)

K₃₃: elastic constant K₃₃ at 20° C. (pN)

K_{AVG}: average of K₁₁ and K₃₃ (K_{AVG}=(K₁₁+K₃₃)/2) (pN)

### VHR Measurement

(A voltage holding ratio (%) at 333 K under conditions of a frequency of 60 Hz and an applied voltage of 1 V)
Light resistance test with LED that emits light having a main emission peak at 450 nm:

The VHR was measured before and after one-week exposure to light from a 20,000 cd/m² visible-light LED light source that emits light having a main emission peak of 450 nm. Light resistance test with LED that emits light having a main emission peak at 385 nm:

The VHR was measured before and after irradiation at 130 J for 60 seconds with a monochromatic LED that emits light having a peak at 385 nm.

### <Production of Light Conversion Film>

### “Production of Light-Emitting Nanocrystalline Particles”

Operations to produce light-emitting nanocrystalline particles and ink were performed in a nitrogen-filled glove box or in a flask under a stream of nitrogen with air cut off.

Regarding all materials illustrated below, air in containers was replaced with nitrogen gas by introducing nitrogen gas into the containers in advance before use. Regarding liquid materials, nitrogen gas was introduced into the liquid to replace dissolved oxygen with nitrogen gas before use. Titanium oxide was heated at 120° C. for 2 hours under a reduced pressure of 1 mmHg and allowed to cool in a nitrogen gas atmosphere before use.

Organic solvents and liquid materials used below were dehydrated and dried for 48 hours or more before use by adding molecular sieves 3A, available from Kanto Chemical Co., Inc., thereto in a proportion of 1 g per 10 ml in a nitrogen gas atmosphere.

### [Production of Red Light-Emitting Nanocrystalline Particles]

Into a 1000 ml flask, 17.48 g of indium acetate, 25.0 g of trioctylphosphine oxide, and 35.98 g of lauric acid were charged. The mixture was stirred at 160° C. for 40 minutes while bubbled with nitrogen gas. The mixture was further stirred at 250° C. for 20 minutes, heated to 300° C., and kept stirred. In a glove box, 4.0 g of tris(trimethylsilyl)phosphine was dissolved in 15.0 g of trioctylphosphine, and the solution was charged into a glass syringe. The solution was injected into the flask heated to 300° C., and the mixture was reacted at 250° C. for 10 minutes. In the glove box, 5 ml of a liquid mixture prepared by dissolving 7.5 g of tris(trimethylsilyl)phosphine in 30.0 g of trioctylphosphine was added dropwise to the reaction solution over a period of 12 minutes. Then the liquid mixture was added to the reaction solution in portions of 5 ml each at intervals of 15 minutes until used up.

Into another three-necked flask, 5.595 g of indium acetate, 10.0 g of trioctylphosphine oxide, 11.515 g of lauric acid were charged. The mixture was stirred at 160° C. for 40 minutes while bubbled with nitrogen gas. The mixture was further stirred at 250° C. for 20 minutes, heated to 300° C., and cooled to 70° C. The mixture solution was added to the reaction solution above. In the glove box, 5 ml of a liquid mixture prepared by dissolving 4.0 g of tris(trimethylsilyl)phosphine in 15.0 g of trioctylphosphine was again added dropwise to the reaction solution over a period of 12 minutes. Then the liquid mixture was added to the reaction solution in portions of 5 ml each at intervals of 15 minutes until used up. The mixture was kept stirred for 1 hour and was cooled to room temperature. Then 100 ml of toluene and 400 ml of ethanol were added to the mixture to lead to aggregation of fine particles. The fine particles were precipitated with a centrifuge. The supernatant liquor was discarded, and then the precipitated fine particles were dissolved in trioctylphosphine to prepare a solution of red light-emitting nanocrystalline indium phosphide (InP) particles in trioctylphosphine.

### [Production of Green Light-Emitting Nanocrystalline Particles]

Into a 1000 ml flask, 23.3 g of indium acetate, 40.0 g of trioctylphosphine oxide, and 48.0 g of lauric acid were charged. The mixture was stirred at 160° C. for 40 minutes while bubbled with nitrogen gas. The mixture was further stirred at 250° C. for 20 minutes, heated to 300° C., and kept stirred. In a glove box, 10.0 g of tris(trimethylsilyl)phosphine was dissolved in 30.0 g of trioctylphosphine, and the solution was charged into a glass syringe. The solution was injected into the flask heated to 300° C., and the mixture was reacted at 250° C. for 5 minutes. The flask was cooled to room temperature. Then 100 ml of toluene and 400 ml of ethanol were added to the mixture to lead to aggregation of fine particles. The fine particles were precipitated with a centrifuge. The supernatant liquor was discarded, and then the precipitated fine particles were dissolved in trioctylphosphine to prepare a solution of green light-emitting nanocrystalline indium phosphide (InP) particles in trioctylphosphine.

### [Production of InP/ZnS Core-Shell Nanocrystals]

The solution of the red light-emitting nanocrystalline indium phosphide (InP) particles in trioctylphosphine was prepared so as to contain 3.6 g of InP and 90 g of trioctylphosphine and then charged into a 1,000 ml flask. Furthermore, 90 g of trioctylphosphine oxide and 30 g of lauric acid were added thereto. In a glove box, 42.9 ml of a 1 M solution of diethyl zinc in hexane and 92.49 g of a 9.09% by weight solution of bis(trimethylsilyl) sulfide in trioctylphosphine were mixed with 162 g of trioctylphosphine to prepare a stock solution. The atmosphere in the flask was replaced with a nitrogen atmosphere. The temperature of the flask was set to 180° C. When the temperature reached 80° C., 15 ml of the stock solution was added thereto. The stock solution was then added in portion of 15 ml each at intervals of 10 minutes (the flask temperature was kept at 180° C.). After the end of the last addition, the reaction was terminated by maintaining the temperature for another 10 minutes. After the completion of the reaction, the solution was cooled to room temperature, and 500 ml of toluene and 2,000 ml of ethanol were added to the solution to lead to the aggregation of nanocrystals. The nanocrystals were precipitated with a centrifuge. The supernatant liquor was discarded. The precipitates were dissolved in chloroform again in such a manner that the concentration of the nanocrystals in the solution was 20% by mass, thereby providing a solution of InP/ZnS core-shell nanocrystals (red light emissive) in chloroform (QD dispersion 1).

A solution of InP/ZnS core-shell nanocrystals (green light emissive) in chloroform (QD dispersion 2) was prepared by the use of the green light-emitting nanocrystalline indium phosphide (InP) particles in place of the red light-emitting nanocrystalline indium phosphide (InP) particles.

### [Ligand Exchange of QD]

Triethylene glycol monomethyl ether ester of 3-mercaptopropionic acid (triethylene glycol monomethyl ether mercaptopropionate) (TEGMEMP) was synthesized and dried under reduced pressure with reference to Japanese Unexamined Patent Application Publication No. 2002-121549 (Mitsubishi Chemical Corporation).

In a container filled with nitrogen gas, QD dispersion 1 (containing the InP/ZnS core-shell nanocrystals (red light emissive)) was mixed with 80 g of a solution prepared by dissolving 8 g of TEGMEMP synthesized above in chloroform. The mixture was stirred at 80° C. for 2 hours to perform ligand exchange and then cooled to room temperature.

The mixture was concentrated until the liquid volume was 100 ml by evaporating toluene/chloroform with stirring at 40° C. under reduced pressure. Four-fold weight of n-hexane was added to this dispersion to aggregate QD. The supernatant liquor was removed by centrifugation and decantation. Then 50 g of toluene was added to the resulting precipitate. The mixture was subjected to redispersion using ultrasonic waves. This washing operation was performed a total of three times to remove the free ligand component remaining in the liquid. The precipitate after decantation was vacuum-dried at room temperature for 2 hours to provide 2 g of a TEGMEMP-modified QD (QD-TEGMEMP) powder.

### “Production of Ink Composition”

### [Preparation of Titanium Oxide Dispersion]

In a container filled with nitrogen gas, 6 g of titanium oxide, 1.01 g of a polymeric dispersant, and 1,4-butanediol diacetate were mixed in such a manner that the non-volatile content was 40%. Zirconia beads (diameter: 1.25 mm) was added to the mixture in the container filled with nitrogen gas. The mixture was subjected to dispersion treatment by shaking the closed container filled with nitrogen gas for 2 hours using a paint conditioner, thereby providing a light-scattering particle dispersion 1. Regarding all the above-described materials, dissolved oxygen was replaced with nitrogen gas by introducing nitrogen gas into the materials before use.

### [Preparation of Ink Composition 1]

In a container filled with nitrogen gas, (1), (2), and (3) described below were uniformly mixed. The mixture was filtered through a filter having a pore size of 5 μm in a glove box. Nitrogen gas was further introduced into the resulting ink to saturate the ink with nitrogen gas. Then nitrogen gas was removed by reducing the pressure to provide an ink composition. In this way, a substantially water-free final ink composition 1 that had been deoxidized was obtained.

The materials used are described below.

### [Light-Scattering Particles]

Titanium oxide: MPT141 (available from Ishihara Sangyo Kaisha Ltd.)

### [Thermosetting Resin]

Glycidyl group-containing solid acrylic resin:

### “FINEDIC” A-254”

(available from DIC Corporation, epoxy equivalent: 500)

### [Polymeric Dispersant]

Polymeric dispersant: BYK-2164

(trade name, available from BYK, “Disperbyk” is a registered trademark)

### [Organic Solvent]

1,4-butanediol diacetate (available from Daicel Chemical Industries, Ltd.)
   (1) A QD-TEGMEMP dispersion 1 (containing the InP/ZnS core-shell nanocrystals (red light emissive)) in which QD-TEGMEMP prepared above was mixed with 1,4-butanediol diacetate, which is an organic solvent, in such a manner that the non-volatile content was 30%: 22.5 g
   (2) A thermosetting resin solution in which a thermosetting resin (“FINEDIC A-254” (6.28 g), available from DIC Corporation), a curing agent (1-methylcyclohexane-4,5-dicarboxylic anhydride (1.05 g)), and a curing accelerator (dimethylbenzylamine (0.08 g)) were dissolved in an organic solvent (1,4-butanediol diacetate) in such a manner that the non-volatile content was 30%: 12.5 g
   (3) The light-scattering particle dispersion 1: 7.5 g

Titanium oxide was heated at 120° C. for 2 hours under a reduced pressure of 1 mmHg and allowed to cool in a nitrogen gas atmosphere before use.

### [Preparation of Ink Composition 2]

An ink composition 2 was prepared in the same manner as the ink composition 1, except that the QD dispersion 2 (containing the InP/ZnS core-shell nanocrystals (green light emissive)) was used in place of the QD dispersion 1.

### [Preparation of Ink Composition 3]

An ink composition 3 was prepared in the same manner as the ink composition 1, except that 1,4-butanediol diacetate was used as (1) in place of the QD-TEGMEMP dispersion 1 described in (1).

### [Preparation of Ink Composition 4]

First, 0.50 parts by mass of Y138 (available from BASF), 1.50 parts by mass of sodium chloride, and 0.75 parts by mass of diethylene glycol were ground. The resulting mixture was added to 600 parts by mass of hot water and stirred for 1 hour. The water-insoluble matter was separated by filtration, washed well with hot water, and dried by air blowing at 90° C., thereby providing a pigment. The particle system of the pigment was 100 nm or less. The average length/width ratio of the particles was less than 3.00. A dispersion test and a color filter evaluation test described below were performed using the resulting yellow pigment of a quinophthalone compound.

Next, 0.660 parts by mass of Y138 (available from BASF) that had been made into the pigment by the foregoing method was placed in a glass bottle. To the bottle, 6.42 parts by mass of propylene glycol monomethyl ether acetate, 0.467 parts by mass of Disperbyk (registered trademark) LPN-6919 (available from BYK Chemie), 0.700 parts by mass of an acrylic resin solution, Unidic (registered trademark) ZL-295 available from DIC Corporation, and 22.0 parts by mass of SEPR beads having a diameter of 0.3 to 0.4 mm were added. The mixture was dispersed for 4 hours with a paint conditioner (available from available from Toyo Seiki Seisaku-sho, Ltd.) to prepare a pigment dispersion. Then 2.00 parts by mass of the resulting pigment dispersion, 0.490 parts by mass of an acrylic resin solution, Unidic (registered trademark) ZL-295 available from DIC Corporation, and 0.110 parts by mass of propylene glycol monomethyl ether acetate were placed in a glass bottle to prepare an ink composition 4.

### “Production of Light Conversion Layer”

The ink compositions 1 and 2 obtained above were applied to respective glass substrates (supporting substrates) to a dry thickness of 3.5 μm with a spin coater in a glove box filled with nitrogen. The coating films were cured by heating to 180° C. in nitrogen to form layers (light conversion layers) composed of the cured products of the ink compositions, thereby providing a red light-emitting light conversion layer (1) and a green light-emitting light conversion layer (2).

### “Formation of Wavelength-Selective Transmission Layer”

### (Wavelength-Selective Transmission Layer Formed of Cholesteric Liquid Crystal Layer)

### [Preparation of Polymerizable Liquid Crystal Composition]

One or two or more compounds selected from the group consisting of polymerizable chiral compounds represented by formulae (C-1) to (C-3), one or two or more compounds selected from the group consisting of photopolymerization initiators represented by formulae (D-1) to (D-6), a polymerization inhibitor (E-1), a surfactant (F-1), a solvent selected from (I-1) to (I-3) or a solvent mixture thereof, and an alignment control agent (H-1) were appropriately mixed with 100 parts by mass of the total amount of one or two or more compounds selected from the group consisting of polymerizable liquid crystal compounds represented by formulae (A-1) to (A-4) and (B-1) to (B-9) to prepare polymerizable liquid crystal compositions for cholesteric liquid crystal layers.

Specifically, 4.6 parts by mass of the compound represented by formula (C-3), 6 parts by mass of (D-4), 0.1 parts by mass of (E-1), and the organic solvent (G-1) were added to 100 parts by mass of the total amount of 9 parts by mass of the compound represented by formula (A-1), 4 parts by mass of the compound represented by formula (A-2), 12 parts by mass of the compound represented by formula (B-3), and 75 parts by mass of the compound represented by formula (B-9) in such a manner that the solid content was 30%. The mixture was stirred for 15 minutes with a stirrer having a stirring propeller under conditions of a stirring speed of 500 rpm and a solution temperature of 60° C. and then filtered through a membrane filter with a pore size of 0.2 μm to provide a polymerizable liquid crystal composition (1).

Similarly, polymerizable liquid crystal compositions (2) to (17) were prepared in composition ratios described in Table 1-1 to Table 1-5. Separately, a composition (10) used for a λ/2 wave plate was also prepared in the same manner as described above.

Composition tables of the polymerizable liquid crystal compositions (1) to (17) used in examples are illustrated below.

TABLE 1-1

| | Formula number | Polymerizable | Polymerizable | Polymerizable | Polymerizable |
|---|---|---|---|---|---|
| | of additive | composition (1) | composition (2) | composition (3) | composition (4) |
| | compound | left-handed | left-handed | left-handed | right-handed |
| Polymerizable | A-1 | 9 | 9 | 40 | 40 |
| compound | A-2 | 4 | 4 | 40 | 40 |
| | A-3 | | | | |
| | B-2 | | 27 | 20 | 20 |
| | B-7 | | 30 | | |
| | B-8 | | 30 | | |
| | B-9 | 75 | | | |
| | B-3 | 12 | | | |
| Chiral | C-2 | | | | 3.9 |
| compound | C-1 | | | | |
| | C-3 | 4.6 | 4.5 | 4.2 | |
| Polymerization | D-4 | 6 | 5 | 5 | 5 |
| initiator | D-1 | | | | |
| Polymerization | E-1 | 0.1 | 0.1 | 0.1 | 0.1 |
| inhibitor | | | | | |
| Surfactant | F-1 | 0.1 | 0.1 | 0.1 | 0.1 |
| Alignment | H-1 | | | | |
| control agent | | | | | |
| Solvent | I-1 | toluene | cyclopentanone | cyclopentanone | toluene |
| Peak position | | 560 | 555 | 550 | 635 |
| of reflection | | | | | |
| wavelength | | | | | |
| (nm) | | | | | |

TABLE 1-2

| | Formula number | Polymerizable | Polymerizable | Polymerizable | Polymerizable |
|---|---|---|---|---|---|
| | of additive | composition (5) | composition (6) | composition (7) | composition (8) |
| | compound | right-handed | right-handed | right-handed | right-handed |
| Polymerizable | A-1 | 40 | 40 | 50 | 50 |
| compound | A-2 | 40 | 40 | 50 | 50 |
| | A-3 | | | | |
| | B-2 | 20 | 20 | | |
| | B-7 | | | | |
| | B-8 | | | | |
| | B-9 | | | | |
| | B-3 | | | | |
| Chiral | C-2 | 4.4 | 5.2 | | |
| compound | C-1 | | | 5.5 | 4.4 |
| | C-3 | | | | |
| Polymerization | D-4 | 5 | 5 | | |
| initiator | D-1 | | | 5 | 5 |
| Polymerization | E-1 | 0.1 | 0.1 | 0.1 | 0.1 |
| inhibitor | | | | | |
| Surfactant | F-1 | 0.1 | 0.1 | 0.1 | 0.1 |
| Alignment | H-1 | | | | |
| control agent | | | | | |
| Solvent | I-1 | toluene | toluene | toluene | toluene |
| Peak position | | 560 | 470 | 462 | 570 |
| of reflection | | | | | |
| wavelength | | | | | |
| (nm) | | | | | |

TABLE 1-3

| | Formula number | Polymerizable | Polymerizable | Polymerizable | Polymerizable |
|---|---|---|---|---|---|
| | of additive | composition (9) | composition (10) | composition (11) | composition (12) |
| | compound | right-handed | λ/2 layer | right-handed | right-handed |
| Polymerizable | A-1 | 50 | 45 | 41 | 41 |
| compound | A-2 | 50 | 45 | 36 | 36 |
| | A-3 | | 10 | | |
| | B-2 | | | 23 | 23 |
| | B-7 | | | | |
| | B-8 | | | | |
| | B-9 | | | | |
| | B-3 | | | | |
| Chiral | C-2 | | | | |
| compound | C-1 | 3.7 | | 5.3 | 4.3 |
| | C-3 | | | | |
| Polymerization | D-4 | | 5 | 5 | 5 |
| initiator | D-1 | 5 | | | |
| Polymerization | E-1 | 0.1 | 0.1 | 0.1 | 0.1 |
| inhibitor | | | | | |
| Surfactant | F-1 | 0.1 | | | |
| Alignment | H-1 | | 0.2 | 0.2 | 0.2 |
| control agent | | | | | |
| Solvent | I-1 | toluene | toluene | toluene/methyl | toluene/methyl |
| | | | | ethyl ketone | ethyl ketone |
| Peak position | | 685 | | 550 | 660 |
| of reflection | | | | | |
| wavelength | | | | | |
| (nm) | | | | | |

TABLE 1-4

| | Formula | | | | |
|---|---|---|---|---|---|
| | number of | Polymerizable | Polymerizable | Polymerizable | Polymerizable |
| | additive | composition (13) | composition (14) | composition (15) | composition (16) |
| | compound | right-handed | left-handed | right-handed | left-handed |
| Polymerizable | A-1 | 45 | 45 | 45 | 45 |
| compound | A-2 | 45 | 45 | 45 | 45 |
| | A-3 | 10 | 10 | 10 | 10 |
| | B-2 | | | | |
| | B-7 | | | | |
| | B-8 | | | | |
| | B-9 | | | | |
| | B-3 | | | | |
| Chiral | C-2 | | | | |
| compound | C-1 | 4.4 | | 3.9 | |
| | C-3 | | 4.6 | | 3.6 |
| Polymerization | D-4 | | 6 | | 5 |
| initiator | D-1 | 5 | | 5 | |
| Polymerization | E-1 | 0.1 | 0.1 | 0.1 | 0.1 |
| inhibitor | | | | | |
| Surfactant | F-1 | | 0.1 | | 0.1 |
| Alignment | H-1 | | | 0.2 | |
| control agent | | | | | |
| Solvent | I-1 | PGMEA/propylene | PGMEA/propylene | PGMEA/propylene | PGMEA/propylene |
| | | glycol diacetate | glycol diacetate | glycol diacetate | glycol diacetate |
| Peak position | | 565 | 565 | 660 | 660 |
| of refection | | | | | |
| wavelength | | | | | |
| (nm) | | | | | |

TABLE 1-5

| | | Polymerizable |
|---|---|---|
| | Formula number of | composition (17) |
| | additive compound | right-handed |
| Polymerizable compound | A-1 | 9 |
| | A-2 | 4 |
| | A-3 | |
| | B-2 | 27 |
| | B-7 | 30 |
| | B-8 | 30 |
| | B-9 | |
| | B-3 | |
| Chiral compound | C-2 | |
| | C-1 | 4.4 |
| | C-3 | |
| Polymerization initiator | D-4 | 5 |
| | D-1 | |
| Polymerization inhibitor | E-1 | 0.1 |
| Surfactant | F-1 | 0.1 |
| Alignment control agent | H-1 | |
| Solvent | I-1 | cyclopentanone |
| Peak position of | | 540-690 |
| reflection wavelength (nm) | | |

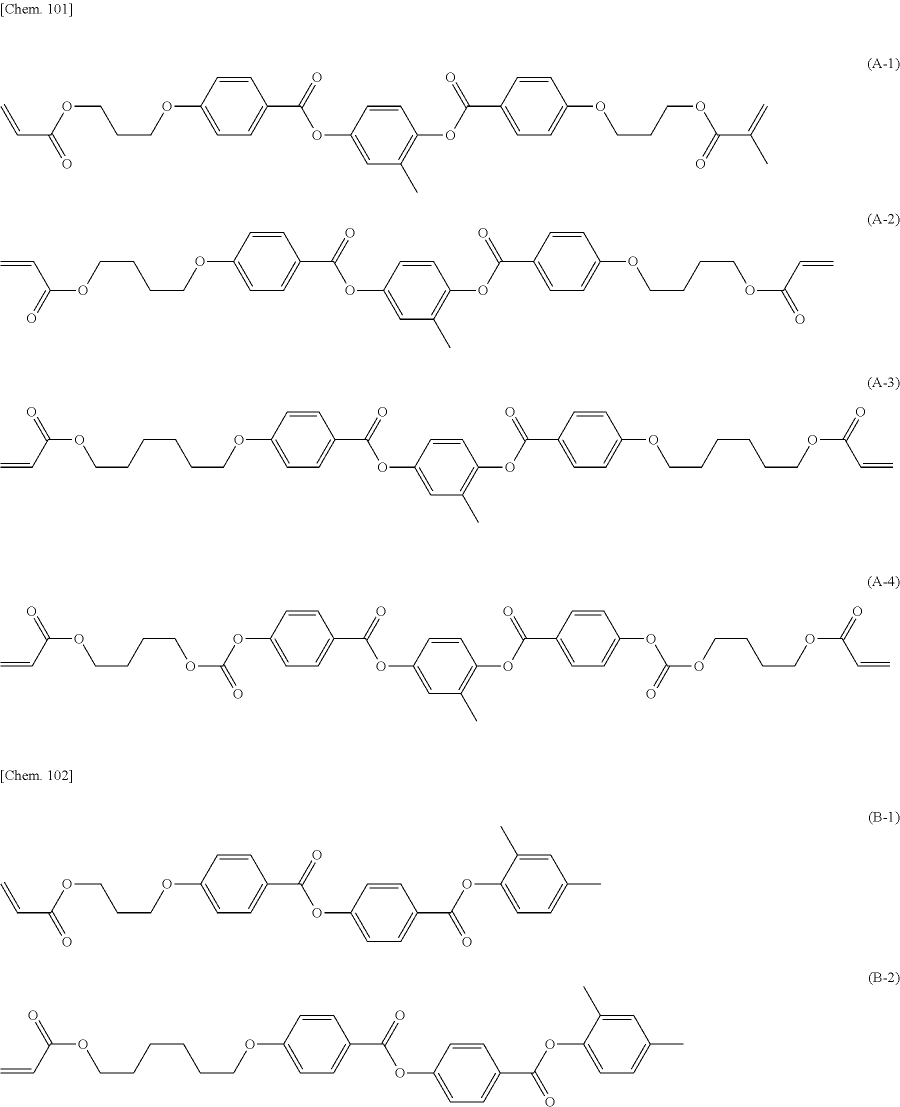

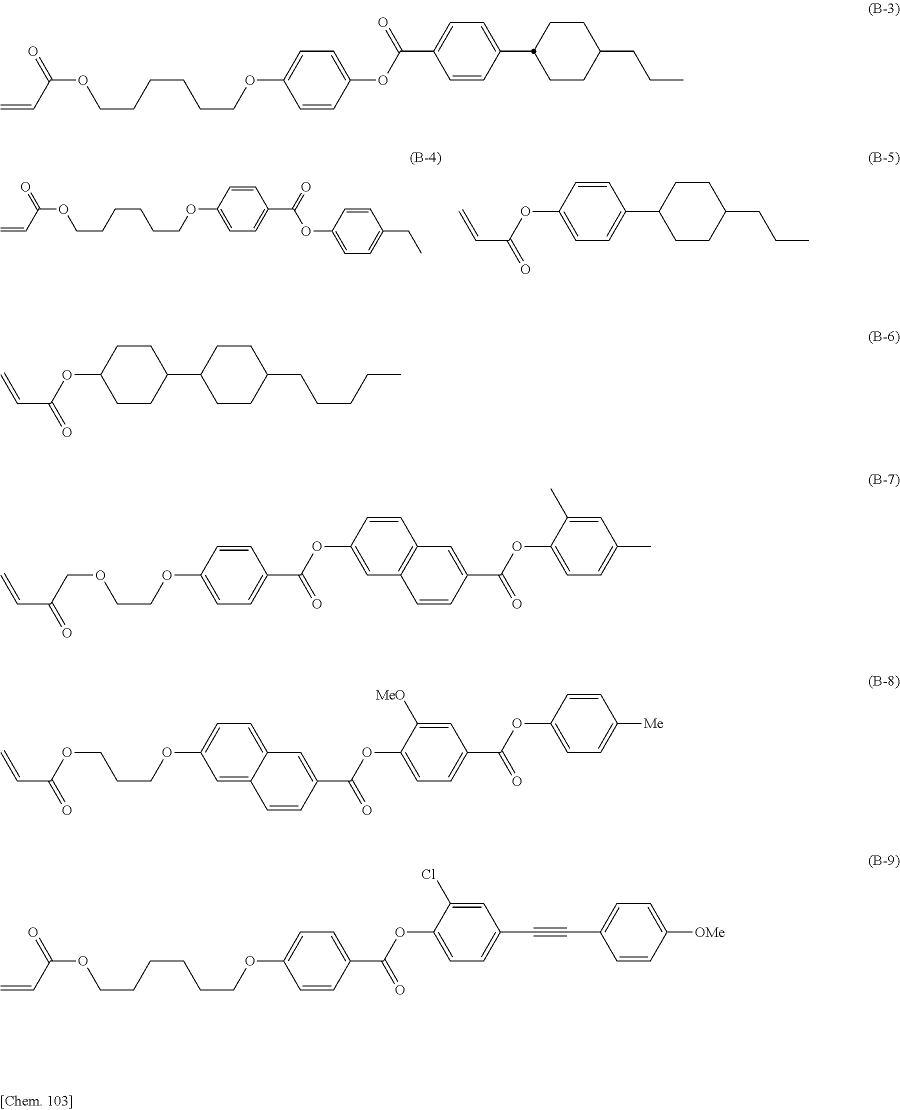

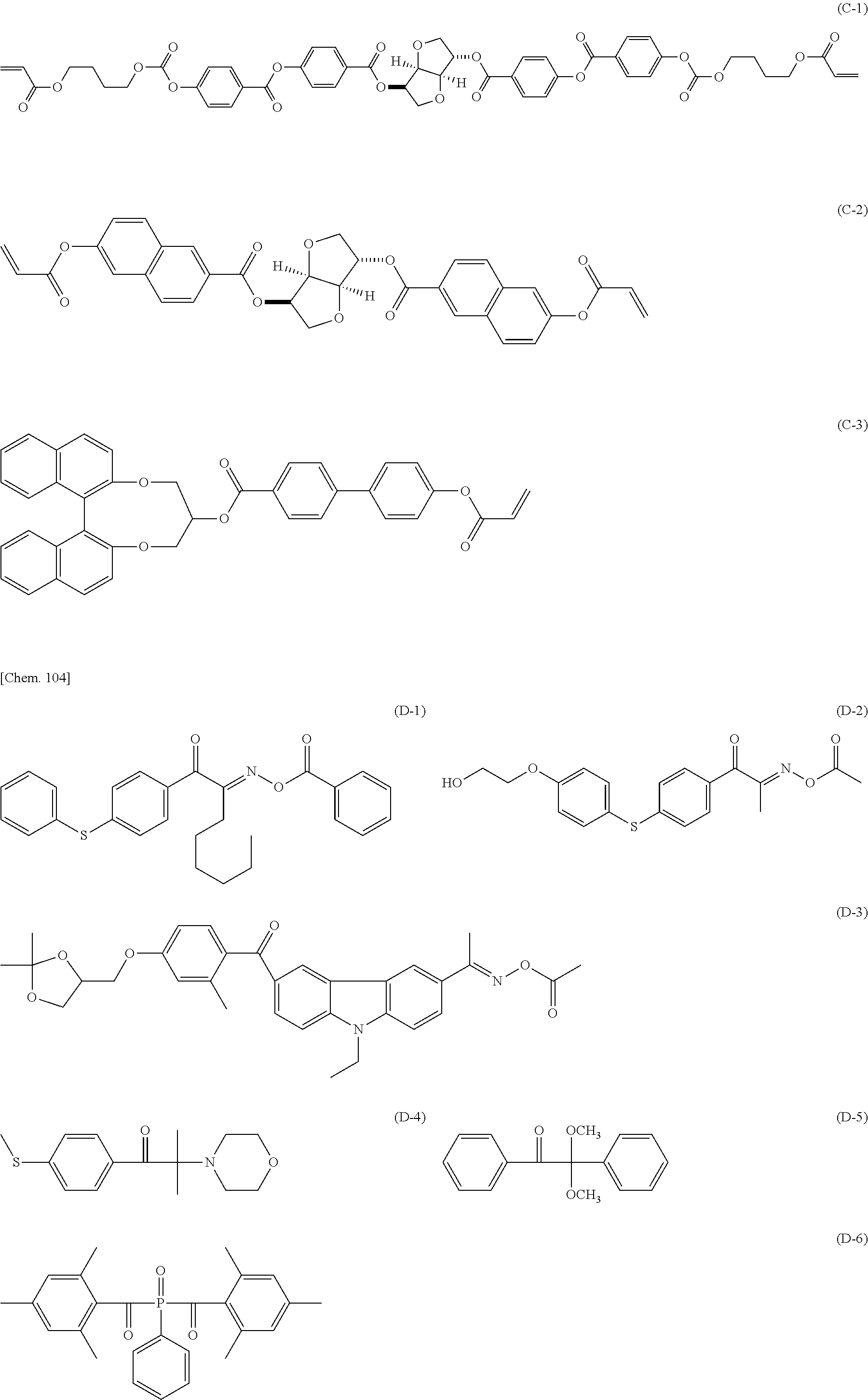

Polymerization inhibitor: 4-methoxyphenol (MEHQ) (E-1)

Surfactant: BYK-352 (available from BYK Chemie) (F-1)

Alignment control agent: polypropylene (H-1)

Solvent: toluene (I-1), methyl ethyl ketone (I-2), cyclopentanone (I-3)

### [Formation of Cholesteric Liquid Crystal Layer]

### Example 1

The prepared polymerizable liquid crystal composition (11) was applied to the rubbed green light-emitting light conversion layer (2) at room temperature (25° C.) by a spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using a high-pressure mercury lamp to form a right-handed cholesteric liquid crystal layer (11) on the green light-emitting light conversion layer (2). A surface of the right-handed cholesteric liquid crystal layer (11) was subjected to rubbing treatment. The prepared polymerizable liquid crystal composition (10) was applied thereto at room temperature (25° C.) by the spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a λ/2 layer on the right-handed cholesteric layer (11). The prepared polymerizable liquid crystal composition (11) was applied to the λ/2 layer in the same manner, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a right-handed cholesteric liquid crystal layer (11) on the λ/2 layer, thereby forming a light conversion film (1) formed of a stack of supporting substrate-green light-emitting light conversion layer (2)-right-handed cholesteric liquid crystal layer (11)-λ/2 layer-right-handed cholesteric liquid crystal layer (11). The center value (λ) of the selective reflection wavelength of the light conversion film (1) was 550 nm.

### Example 2

A light conversion film (2) formed of a stack of supporting substrate-green light-emitting light conversion layer (2)-right-handed cholesteric liquid crystal layer (8)-λ/2 layer-right-handed cholesteric liquid crystal layer (8) was formed as in Example 1, except that the polymerizable liquid crystal composition (8) was used in place of the polymerizable liquid crystal composition (11). The center value (λ) of the selective reflection wavelength of the light conversion film (2) was 570 nm.

### Example 3

The prepared polymerizable liquid crystal composition (4) was applied to the rubbed red light-emitting light conversion layer (1) at room temperature (25° C.) by a spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using a high-pressure mercury lamp to form a right-handed cholesteric liquid crystal layer (4) on the red light-emitting light conversion layer (1). A surface of the right-handed cholesteric liquid crystal layer (4) was subjected to rubbing treatment. Then the prepared polymerizable liquid crystal composition (10) was applied thereto at room temperature (25° C.) by the spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a λ/2 layer on the right-handed cholesteric layer (4). The prepared polymerizable liquid crystal composition (4) was applied to the λ/2 layer in the same manner, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a right-handed cholesteric liquid crystal layer (4) on the λ/2 layer, thereby forming a light conversion film (3) formed of a stack of supporting substrate-red light-emitting light conversion layer (1)-right-handed cholesteric liquid crystal layer (4)-λ/2 layer-right-handed cholesteric liquid crystal layer (4). The center value (λ) of the selective reflection wavelength of the light conversion film (3) was 630 nm.

### Example 4

A light conversion film (4) formed of a stack of supporting substrate-red light-emitting light conversion layer (1)-right-handed cholesteric liquid crystal layer (9)-λ/2 layer-right-handed cholesteric liquid crystal layer (9) was formed as in Example 3, except that the polymerizable liquid crystal composition (9) was used in place of the polymerizable liquid crystal composition (4). The center value (λ) of the selective reflection wavelength of the light conversion film (4) was 670 nm.

### Example 5

A light conversion film (5) formed of a stack of supporting substrate-red light-emitting light conversion layer (1)-right-handed cholesteric liquid crystal layer (12)-λ/2 layer-right-handed cholesteric liquid crystal layer (12) was formed as in Example 3, except that the polymerizable liquid crystal composition (12) was used in place of the polymerizable liquid crystal composition (4). The center value (λ) of the selective reflection wavelength of the light conversion film (5) was 660 nm. FIG. 5 illustrates an example of the transmission spectrum data of the wavelength-selective transmission layer of Example 5. FIG. 5 demonstrates that the wavelength-selective transmission layer having a layer structure of right-handed cholesteric liquid crystal layer (12)-λ/2 layer-right-handed cholesteric liquid crystal layer (12) transmits light having a wavelength of about 620 nm or less, reflects light in a wavelength range of about 620 nm to about 700 nm, and transmits light having a wavelength of about 700 nm or more.

### Example 6

The prepared polymerizable liquid crystal composition (5) was applied to the rubbed green light-emitting light conversion layer (2) at room temperature (25° C.) by a spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using a high-pressure mercury lamp to form a right-handed cholesteric liquid crystal layer (5) on the green light-emitting light conversion layer (2). A surface of the right-handed cholesteric liquid crystal layer (5) was subjected to rubbing treatment. Then the prepared polymerizable liquid crystal composition (1) was applied to the cholesteric liquid crystal layer (1) at room temperature (25° C.) by the spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a left-handed cholesteric liquid crystal layer (1) on the right-handed cholesteric layer (5), thereby forming a light conversion film (6) formed of a stack of supporting substrate-green light-emitting light conversion layer (2)-right-handed cholesteric liquid crystal layer (5)-left-handed cholesteric liquid crystal layer (1). The center value (λ) of the selective reflection wavelength of the light conversion film (6) was 560 nm.

### Example 7

A light conversion film (7) formed of a stack of supporting substrate-green light-emitting light conversion layer (2)-right-handed cholesteric liquid crystal layer (5)-left-handed cholesteric liquid crystal layer (2) was formed as in Example 6, except that the polymerizable liquid crystal composition (2) was used in place of the polymerizable liquid crystal composition (1). The center value (λ) of the selective reflection wavelength of the light conversion film (7) was 550 nm.

### Example 8

A light conversion film (8) formed of a stack of supporting substrate-green light-emitting light conversion layer (2)-right-handed cholesteric liquid crystal layer (5)-left-handed cholesteric liquid crystal layer (3) was formed as in Example 6, except that the polymerizable liquid crystal composition (3) was used in place of the polymerizable liquid crystal composition (1). The center value (λ) of the selective reflection wavelength of the light conversion film (3) was 550 nm.

### Example 9

A light conversion film (9) formed of a stack of supporting substrate-red light-emitting light conversion layer (1)-right-handed cholesteric liquid crystal layer (15)-left-handed cholesteric liquid crystal layer (16) was formed as in Example 6, except that the red light-emitting light conversion layer (1) was used in place of the green light-emitting light conversion layer (2), the polymerizable liquid crystal composition (15) was used in place of the polymerizable liquid crystal composition (5), and the polymerizable liquid crystal composition (16) was used in place of the polymerizable liquid crystal composition (1). The center value (λ) of the selective reflection wavelength of the light conversion film (9) was 660 nm.

### Example 10

The prepared polymerizable liquid crystal composition (6) was applied to the rubbed green light-emitting light conversion layer (2) at room temperature (25° C.) by a spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using a high-pressure mercury lamp to form a right-handed cholesteric liquid crystal layer (6) on the green light-emitting light conversion layer (2). A surface of the right-handed cholesteric liquid crystal layer (6) was subjected to rubbing treatment. Then the prepared polymerizable liquid crystal composition (10) was applied thereto at room temperature (25° C.) by the spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a λ/2 layer on the right-handed cholesteric liquid crystal layer (6). The prepared polymerizable liquid crystal composition (6) was applied to the λ/2 layer in the same manner, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a right-handed cholesteric liquid crystal layer (6) on the λ/2 layer, thereby forming a light conversion film (10) formed of a stack of supporting substrate-green light-emitting light conversion layer (2)-heat resistance cholesteric liquid crystal layer (6)-λ/2 layer-right-handed cholesteric liquid crystal layer (6). The center value (λ) of the selective reflection wavelength of the light conversion film (1) was 470 nm.

### Example 11

A light conversion film (11) formed of a stack of supporting substrate-red light-emitting light conversion layer (1)-right-handed cholesteric liquid crystal layer (6)-λ/2 layer-right-handed cholesteric liquid crystal layer (6) was formed as in Example 10, except that the red light-emitting light conversion layer (1) was used in place of the green light-emitting light conversion layer (2). The center value (λ) of the selective reflection wavelength of the light conversion film (9) was 470 nm.

### Example 12

A light conversion film (12) formed of a stack of supporting substrate-red light-emitting light conversion layer (1)-right-handed cholesteric liquid crystal layer (7)-λ/2 layer-right-handed cholesteric liquid crystal layer (7) was formed as in Example 11, except that the polymerizable liquid crystal composition (7) was used in place of the polymerizable liquid crystal composition (6). The center value (λ) of the selective reflection wavelength of the light conversion film (12) was 462 nm.

### Example 13

The prepared polymerizable liquid crystal composition (7) was applied to a glass substrate provided with a rubbed alignment film at room temperature (25° C.) by a spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using a high-pressure mercury lamp to form a right-handed cholesteric liquid crystal layer (7) on the rubbed alignment film. A surface of the right-handed cholesteric liquid crystal layer (7) was subjected to rubbing treatment. Then the prepared polymerizable liquid crystal composition (10) was applied thereto at room temperature (25° C.) by the spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a λ/2 layer on the right-handed cholesteric liquid crystal layer (7). The prepared polymerizable liquid crystal composition (7) was applied to the λ/2 layer in the same manner, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a right-handed cholesteric liquid crystal layer (7) on the λ/2 layer, thereby forming a stack of supporting substrate-rubbed alignment film-right-handed cholesteric liquid crystal layer (7)-λ/2 layer-right-handed cholesteric liquid crystal layer (7).

The ink composition 1 prepared above was applied to the right-handed cholesteric liquid crystal layer (7) of the surface to a dry thickness of 3.0 μm with a spin coater in a glove box filled with nitrogen. The coating film was cured by heating to 180° C. in nitrogen to form a red light-emitting light conversion layer (1) serving as a light conversion layer. A surface of the resulting red light-emitting light conversion layer (1) was subjected to rubbing treatment. A light conversion film (13) formed of a stack of supporting substrate-rubbed alignment film-right-handed cholesteric liquid crystal layer (7)-λ/2 layer-right-handed cholesteric liquid crystal layer (7)-red light-emitting light conversion layer (1)-right-handed cholesteric liquid crystal layer (4)-λ/2 layer-right-handed cholesteric liquid crystal layer (4) was formed in the same manner as in Example 3. The center values (λ) of the selective reflection wavelengths of the light conversion film (13) were 462 nm and 630 nm.

### Example 14

A light conversion film (14) formed of a stack of supporting substrate-rubbed alignment film-right-handed cholesteric liquid crystal layer (6)-λ/2 layer-right-handed cholesteric liquid crystal layer (6)-green light-emitting light conversion layer (2)-right-handed cholesteric liquid crystal layer (8)-λ/2 layer-right-handed cholesteric liquid crystal layer (8) was formed as in Example 13, except that the green light-emitting light conversion layer (2) was used in place of the red light-emitting light conversion layer (1), the polymerizable liquid crystal composition (6) was used in place of the polymerizable liquid crystal composition (7), and the polymerizable liquid crystal composition (8) was used in place of the polymerizable liquid crystal composition (4). The center values (X) of the selective reflection wavelengths of the light conversion film (14) were 470 nm and 570 nm.

### Comparative Example 1

The green light-emitting light conversion layer (2) formed on a glass substrate was used as a film of Comparative example 1.

### Comparative Example 2

The red light-emitting light conversion layer (1) formed on a glass substrate was used as a film of Comparative example 2.

### (Calculation of Selective Reflection Wavelength)

Each of the polymerizable composition (1) to (17) were applied to a glass substrate at room temperature (25° C.) by a spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using a high-pressure mercury lamp. The spectral transmittance of the resulting thin film was measured with a V-560 ultraviolet and visible spectrophotometer (available from JASCO Corporation), and the center value (λ) of the selective reflection wavelength was determined therefrom. For example, when the selective reflection wavelength of the cholesteric liquid crystal layer (12) formed from the polymerizable liquid crystal composition (12) was measured, the selective reflection wavelength as illustrated in FIG. 5 is obtained.

Evaluations were performed according to a procedure described using the light conversion films obtained above below.

An integrating sphere was connected to an emission spectrophotometer (trade name “MCPD-9800”), available from Otsuka Electronics Co., Ltd., using a blue LED (peak emission wavelength: 450 nm). The integrating sphere was arranged above the blue LED. Each of the light conversion films was inserted between the blue LED and the integrating sphere. The blue LED was turned on, and the spectrum and the illuminance observed at each wavelength were measured.

Specifically, for each of the light conversion films (1) to (9) produced in Examples 1 to 9 and the light conversion films (13) and (14), the cholesteric liquid crystal layer was arranged adjacent to the blue LED so as to be directly irradiated with light from the blue LED. In other words, the blue LED, the cholesteric liquid crystal layer, the light conversion layer, (the cholesteric liquid crystal layer), the supporting substrate, and the integrating sphere are arranged in this order, and the illuminance at each wavelength was measured.

For each of the light conversion films (10) to (12) produced in Examples 10 to 14, the supporting substrate (glass substrate) was arranged adjacent to the blue LED so as to be directly irradiated with light from the blue LED. In other words, the blue LED, the supporting substrate, the light conversion layer, the cholesteric liquid crystal layer, and the integrating sphere were arranged in this order, and the illuminance at each wavelength was measured.

From the spectrum measured by the above measuring apparatus, the total illuminance at 400 to 500 nm was defined as blue light illuminance, the total illuminance at 500 to 600 nm was defined as green light illuminance, and the total illuminance at 600 to 700 nm was defined as red light illuminance.

### [External Quantum Efficiency (EQE)]

The integrating sphere was connected to an emission spectrophotometer (trade name “MCPD-9800”), available from Otsuka Electronics Co., Ltd., using the blue LED (peak emission wavelength: 450 nm). The integrating sphere was arranged above the blue LED. A base material was inserted between the blue LED and the integrating sphere. The blue LED was turned on, and the spectrum and the illuminance observed at each wavelength were measured.

From the spectrum and illuminance measured with the above measuring apparatus, the external quantum efficiency was determined as described below. The value indicates what percentage of light (photons) that enters the light conversion layer is emitted as fluorescence toward the observer. A larger value indicates a better light conversion layer. The value is an important evaluation index.

External quantum efficiency of red light-emitting light conversion layer=P(Red)/E(Blue)×100(%)=(hereinafter, also referred to as an “R/B value”)

External quantum efficiency of green light-emitting light conversion layer=P(Gleen)/E(Blue)×100(%)=(hereinafter, also referred to as “G/B value”)

E(Blue), P(Red), and P(Gleen) used here are defined below.

### E(Blue):

E(Blue) represents the total value of “illuminance×wavelength/hc” in a wavelength range of 380 to 490 nm, wherein h represents the Planck constant, and c represents the speed of light (this is a value corresponding to the number of photons observed).

### P(Red):

P(Red) represents the total value of “illuminance×wavelength/hc” in a wavelength range of 490 to 590 nm (and corresponds to the number of photons observed).

### P(Gleen):

P(Gleen) represents the total value of “illuminance×wavelength/hc” in a wavelength range of 590 to 780 nm (and corresponds to the number of photons observed).

TABLE 2

| | Light | Light | | | | | |
|---|---|---|---|---|---|---|---|
| | conversion | conversion | | | | | |
| | layer 1 alone | layer 2 alone | | | | | |
| | (Comparative | (Comparative | | | | | |
| | example 1) | example 2) | Example 1 | Example 2 | Example 3 | Example 4 | Example 5 |
| Illuminance (at 500- | | 813.3 | 871.9 | 997.8 | | | |
| 600 nm (green | | | | | | | |
| region)) (μW/cm²) | | | | | | | |
| Illuminance (at 600- | 865.1 | | | | 1170 | 1184.7 | 1337.1 |
| 700 nm (red | | | | | | | |
| region)) (μW/cm²) | | | | | | | |
| G/B | 2.8 | 0.1 | 4 | 3.4 | 0.1 | 0.1 | 0.1 |
| R/B | 0.2 | 6.4 | 0.3 | 0.2 | 16.7 | 14.7 | 10.1 |

It was revealed from Table 2 that the illuminance of green light from the light conversion film (1) produced in Example 1 was higher than that in Comparative example 2 because of the presence of the cholesteric liquid crystal layer. The reason for this is that, of light components converted by the light conversion layer (2), some light components emitted toward the blue LED were reflected from the cholesteric liquid crystal layer toward the spectroradiometer owing to its selective reflection properties. This proves the effect of the present invention.

It was also revealed from Table 2 that the illuminance of red light from the light conversion film (3) produced in Example 3 was higher than that in Comparative example 1 because of the presence of the cholesteric liquid crystal layer. The same effect should be provided.

It was revealed that illuminances of red and green light from the light conversion films 6 to 9 produced in Examples 6 to 9 were higher than those in Comparative examples 1 and 2 because of the presence of the cholesteric liquid crystal layers. The experimental results of Examples 6 to 9 indicated that R/B and G/B were improved, i.e., the color purities of red and green were increased.

The experimental results of the blue light transmittance and the external quantum efficiency (EQE) in Examples 10 and 11 were described below.

TABLE 3

| | Comparative example 1 | Comparative example 2 | | |
|---|---|---|---|---|
| | (green light-emitting light | (red light-emitting light | | |
| | conversion layer 1 | conversion layer 2 | Example 10 | Example 11 |
| | alone) | alone) | (green emissive) | (red emissive) |
| Transmittance | 43.40% | 23% | 38.50% | 20.40% |
| EQE | 7.60% | 11.30% | 9.10% | 13.30% |

A comparison of Comparative example 1 and Example 10 revealed that the arrangement of the blue-blocking cholesteric liquid crystal layer on the green light-emitting light conversion layer (1) resulted in a reduction in blue transmittance by about 11% and an about 1.20-fold increase in EQE.

A comparison of Comparative example 2 and Example 11 revealed that the arrangement of the blue-blocking cholesteric liquid crystal layer on the red light-emitting light conversion layer (2) resulted in a reduction in blue transmittance by about 11% and an about 1.18-fold increase in EQE.

These results seemingly indicate that the blue-blocking cholesteric liquid crystal layer is effective in improving the optical properties of the light conversion layer.

### (Wavelength-Selective Transmission Layer of Dielectric Multilayer Film)

The ink composition 1 containing the red light-emitting nanocrystalline particles was applied to a glass substrate with a spin coater to a dry thickness of 3 μm. The coating film was dried and cured in a nitrogen gas atmosphere to form a red light-emitting light conversion layer (1).

Similarly, a green light-emitting light conversion layer (2) was formed from the ink composition 2 containing the green light-emitting nanocrystalline particles.

### Example 15

A planarization film composition (trade name: PIG-7424, available from JNC Corporation) was applied to the red light-emitting light conversion layer (1) by spin coating, dried, and post-baked to form a planarization film. A dielectric multilayer film (a dichroic filter (DFB-500 (available from Optical Solutions Corporation) that transmits light in a wavelength range of 500 nm or less and reflects light in a wavelength range of 510 nm or more) was bonded thereto using a carrier-free transparent double-sided adhesive sheet (MHM-FWV, available from Nichieikako Co., Ltd.) to produce a light conversion film substrate 15.

### Example 16

As with Example 16, a dielectric multilayer film (a dichroic filter (DFB-500 (available from Optical Solutions Corporation) that transmits light in a wavelength range of 500 nm or less and reflects light in a wavelength range of 510 nm or more) was bonded to the green light-emitting light conversion layer (2) to produce a light conversion film substrate 16.

### Comparative Example 1

As with Comparative example 1 described above, the red light-emitting light conversion layer (1) formed on a glass substrate was used as a film of Comparative example 1.

### Comparative Example 2

As with Comparative example 2 described above, the green light-emitting light conversion layer (2) formed on a glass substrate was used as a film of Comparative example 2.

The following evaluation was performed using the light conversion films 10 and 11 obtained above and the films of Comparative examples 1 and 2.

### [Evaluation of Fluorescence Intensity of Light Conversion Film]

As a flat panel light source, a blue LED (peak emission wavelength: 450 nm), available from CCS Inc., was used. Regarding a measuring apparatus, an integrating sphere was connected to a spectroradiometer (trade name “MCPD-9800”), available from Otsuka Electronics Co., Ltd. The integrating sphere was arranged above the blue LED. The blue LED was turned on, and the spectrum and the illuminance observed at each wavelength were measured. In this case, each sample presented in Table 1 was placed on the blue LED. The fluorescence intensity (illuminance) at a wavelength of 450 nm and the peak wavelength of the fluorescence observed was measured and designated as S(450) and S(PL), respectively. The fluorescence intensity S(PL) corresponds to the fluorescence intensity from the light conversion layer. Thus, a larger value indicates a better light conversion layer. The value is an important evaluation index.

Table 3-1 and Table 3-2 present the evaluation results using the dielectric multilayer film.

TABLE 3-1

| | | Comparative example 1 | Example 15 |
|---|---|---|---|
| Structure of light | Light conversion layer | (red emitting) light | (red emitting) light |
| conversion film | | conversion layer (1) | conversion layer (1) |
| | Wavelength-selective | no | DFB-500 (available |
| | transmission layer | | from Optical Solutions |
| | | | Corporation) |
| Fluorescence intensity at | | 100 | 122 |
| peak wavelength S (PL) | | | |
| External quantum | | 100 | 138 |
| efficiency*1 | | | |

(The relative evaluation of the fluorescence intensity was performed on the basis that the fluorescence intensity when no wavelength-selective transmission layer was used was set to 100).

TABLE 3-2

| | | Comparative example 2 | Example 16 |
|---|---|---|---|
| Structure of light | Light conversion layer | (green emitting) light | (green emitting) light |
| conversion film | | conversion layer (2) | conversion layer (2) |
| | Wavelength-selective | no | DFB-500 (available |
| | transmission layer | | from Optical Solutions |
| | | | Corporation) |
| Fluorescence intensity at | | 100 | 116 |
| peak wavelength S (PL) | | | |

(The relative evaluation of the fluorescence intensity was performed on the basis that the fluorescence intensity when no wavelength-selective transmission layer was used was set to 100).
Notes: Regarding the positional relationship of the measurement system of Examples 15 and 16, the blue LED, the wavelength-selective transmission layer (DFB-500), the light conversion layer (1) or (2), and the integrating sphere are arranged in this order from the bottom.

### *1: P(Blue) was 380 to 500 nm.

The experimental results presented in Table 3-1 and Table 3-2 indicated that when the dielectric multilayer film was interposed between the blue LED and the light conversion layer, the emission intensity was significantly increased. Similar results were obtained when DIF-50S-BLE, available from Sigmakoki Co., Ltd., was used in place of DIF-500.

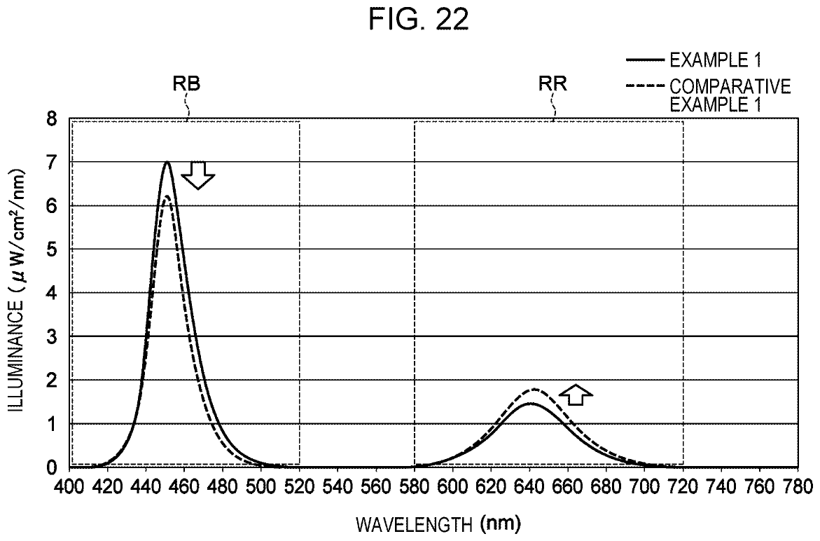

FIG. 22 illustrates a comparison of experimental data between the light conversion layer of Comparative example 1 and the light conversion film of Example 15. The experimental data illustrated in FIG. 22 illustrates the relationship between the wavelength range and the illuminance. For example, as illustrated in FIG. 22, the experimental results presented in Table 3-1 indicated that, based on the integral value (area) of illuminance, the use of the dichroic filter results in a 1.22-fold increase in the peak intensity of R light (642 nm), an increase in the ratio, i.e., R light/B light (area ratio), from 0.417 to 0.586 (1.40 times), an increase in the ratio, i.e., R light/(R light+B light) (area ratio), from 0.294 to 0.369 (1.25 times). The external quantum efficiency (EQE) calculated from the following formula was increased from 13.6% to 18.8%, which was a 1.38-fold increase.

(EQE=number of photons of R light/(number of photons of B light when measured with filter only)×100(%)

The B light (blue light) indicates light in the wavelength range RB of 400 to 520 nm. The R light (red light) indicates light in the wavelength range RR of 580 to 720 nm.

This demonstrated that the light conversion film substrate provided with the dielectric multilayer film had improved color purities of red and green.

### <Method for Producing Liquid Crystal Panel, Backlight Unit, and Liquid Crystal Display Device>

### [Production of Light Conversion Film]

First, a substrate (BM substrate) including a light-shielding portion called a black matrix (BM) was produced according to the following procedure. That is, a black resist (“CFPR-BK”, available from Tokyo Ohka Kogyo Co., Ltd.) was applied to a glass substrate composed of alkali-free glass (“OA-10G”, available from Nippon Electric Glass Co., Ltd.). Then pre-baking, pattern exposure, developing, and post-baking were performed to form a pattern of a light-shielding portion. The exposure was performed by irradiating the black resist with ultraviolet light at an exposure amount of 250 mJ/cm². The pattern of the light-shielding portion was a pattern having opening portions each corresponding to a subpixel with a size of 200 μm×600 μm. The pattern had a line width of 20 μm and a thickness of 2.6 μm.

The ink composition 1 (red light emissive), the ink composition 2 (green light emissive), and the ink composition 3 (transparent) were applied to the opening portions of the BM substrate by an inkjet printing, dried, irradiated with ultraviolet light, and heated at 150° C. for 30 minutes in a nitrogen atmosphere. The ink compositions were thus cured to form pixel portions composed of the ink compositions. This results in the formation of pixel portions that transmit and scatter blue light, pixel portions that convert blue light into red light, and pixel portions that convert blue light into green light on the BM substrate. A patterned light conversion layer (3) including multiple types of pixel portions was obtained through the operation described above.

### Example 17

Subsequently, a planarization film composition (trade name: PIG-7424, available from JNC Corporation) was applied to a surface of the light conversion layer (3) by spin coating, dried, and post-baked to form a planarization film. After the formation of the planarization film (passivation film), a light conversion film substrate (17) on which a wavelength-selective transmission layer (dielectric multilayer film) was stacked was produced.

The dielectric multilayer film used here was formed by forming a TiO₂ layer on a glass base material, alternately forming SiO₂ layers and TiO₂ layers in 14 layers by sputtering, forming a SiO₂ layer, alternately forming SiO₂ layers and TiO₂ layers in 12 layers, and forming SiO₂ layer. The optical thickness of each layer was determined in accordance with a multilayer optical interference film that transmits blue and that was described in Table 1 in Japanese Unexamined Patent Application Publication No. 10-31982. The dielectric multilayer film transmitted light with a wavelength of 500 nm or less and reflected light with a wavelength of 500 nm or more.

The planarization film was bonded to a surface of the dielectric multilayer film of the glass substrate including the dielectric multilayer film with a transparent double-sided adhesive sheet (MHM-FWV, available from Nichieikako Co., Ltd.) provided therebetween to form a light conversion film substrate (17).

In this way, the light conversion film substrate (17) formed of a stack of supporting substrate-patterned light conversion layer (3) including multiple pixel portions-planarization film-wavelength-selective transmission layer (dielectric multilayer film) was obtained.

### Example 18

The light conversion layer (3) including the pixel portions configured to transmit and scatter blue light, the pixel portions configured to convert blue light into red light, and the pixel portions configured to convert blue light into green light was subjected to rubbing treatment. Regarding the pixel portions configured to convert blue light into green light, the right-handed polymerizable composition (13) was applied by inkjet printing, dried, irradiated with ultraviolet light, and heated at 150° C. for 30 minutes in a nitrogen atmosphere to form a cholesteric liquid crystal layer (13), which was a coating film composed of the polymerizable composition (13). The polymerizable composition (14) was applied thereto by inkjet printing, dried, irradiated with ultraviolet light, and heated at 150° C. for 30 minutes in a nitrogen atmosphere to form a left-handed cholesteric liquid crystal layer (14). Regarding the pixel portions configured to convert blue light into red light, similarly, a light conversion layer (15) originating from the right-handed polymerizable composition (15) and a cholesteric liquid crystal layer (16) originating from the left-handed polymerizable composition (16) were formed. A planarization film composition (trade name: PIG-7424, available from JNC Corporation) was applied to a surface of the cholesteric liquid crystal layer by spin coating, dried, and post-baked to form a planarization film, thereby providing a light conversion film substrate (18) formed of a stack of patterned light conversion layer (3) including multiple pixel portions-cholesteric liquid crystal layer (cholesteric liquid crystal layer (13)-cholesteric liquid crystal layer (14) on green pixels, and cholesteric liquid crystal layer (15)-cholesteric liquid crystal layer (16) on red pixels)-planarization film.

### Example 19

The light conversion layer (3) including the pixel portions configured to transmit and scatter blue light, the pixel portions configured to convert blue light into red light, and the pixel portions configured to convert blue light into green light was subjected to rubbing treatment. The polymerizable liquid crystal composition (17) of the present invention was applied over the entire surface by a spin coating method and dried at 80° C. for 2 minutes. The resulting coating film was placed on a hot plate with a temperature of 60° C. and irradiated with UV light at an intensity of 15 mW/cm² for 10 seconds using a high-pressure mercury lamp adjusted to emit only ultraviolet light (UV light) having a wavelength of about 365 nm through a band-pass filter. The band-pass filter was removed. The coating film was irradiated with UV light at an intensity of 70 mW/cm² for 20 seconds to form a cholesteric liquid crystal layer (17). A surface of the right-handed cholesteric liquid crystal layer (17) was subjected to rubbing treatment. The prepared polymerizable liquid crystal composition (10) was applied thereto at room temperature (25° C.) by the spin coating method at a rotation speed of 800 rpm for 15 seconds, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a λ/2 layer. Subsequently, the prepared polymerizable liquid crystal composition (17) was applied to the λ/2 layer in the same manner, dried at 60° C. for 2 minutes, allowed to stand at 25° C. for 1 minute, and irradiated with 420 mJ/cm² of UV light having a maximum UVA illuminance of 300 mW/cm² using the high-pressure mercury lamp to form a right-handed cholesteric liquid crystal layer (17) on the λ/2 layer, thereby forming a light conversion film (19) formed of a stack of supporting substrate-patterned light conversion layer (3) including multiple pixel portions-right-handed cholesteric liquid crystal layer (17)-λ/2 layer-right-handed cholesteric liquid crystal layer (17). The reflection wavelength range (540 to 690 nm) of the cholesteric liquid crystals was observed.

### Example 20

The ink composition 4 was applied, with a spin coater, to the supporting substrate of the light conversion film substrate (17) of Example 17 obtained by the method described above, dried, and heated at 230° C. for 1 hour. A yellow color filter exhibiting each green chromaticity in the case of using illuminant C specified in color standards for high color reproduction was formed on the supporting substrate of the light conversion film (17), thereby providing a light conversion film (20) formed of a stack of yellow color filter-supporting substrate-light conversion layer (3)-planarization film-wavelength-selective transmission layer (dielectric multilayer film).

### Example 21

The ink composition 4 was applied, with a spin coater, to the supporting substrate of the light conversion film (18) of Example 18 obtained by the method described above, dried, and heated at 230° C. for 1 hour. A yellow color filter exhibiting each green chromaticity in the case of using illuminant C specified in color standards for high color reproduction was formed on the supporting substrate of the light conversion film (18), thereby providing a light conversion film (21) formed of a stack of yellow color filter-supporting substrate-light conversion layer (3)-planarization film-wavelength-selective transmission layer (cholesteric liquid crystal layer).

### Comparative Example 3

The light conversion layer (3) was used as Comparative example 3.

“Production of Electrode Substrate Including in-Cell Polarizing Layer”

### [Production of Opposite Substrate 1]

An aqueous solution of “Poval 103” (solid content concentration: 4% by mass), available from Kuraray Co., Ltd., was applied to the wavelength-selective transmission layer (dielectric multilayer film) of the light conversion film (17) produced above, dried, and subjected to rubbing treatment.

A polarizing layer coating solution containing 0.03 parts by mass Megafac F-554 (available from DIC Corporation), 1 part by mass of an azo pigment represented by formula (az-1) below, 1 part by mass of an azo pigment represented by formula (az-2) below:

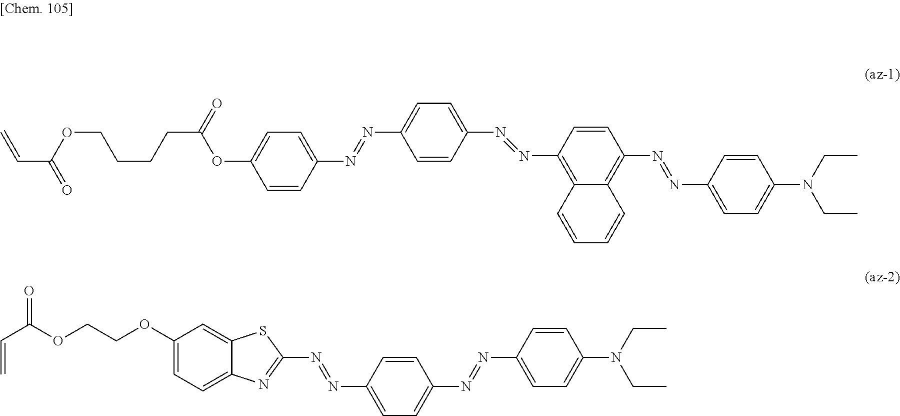 [SMILES: C=CC(=O)OCCCCC(=O)Oc1ccc(/N=N/c2ccc(/N=N/c3ccc(/N=N/c4ccc(N(CC)CC)cc4)c4ccccc34)cc2)cc1 ; C=CC(=O)OCCOc1ccc2nc(/N=N/c3ccc(/N=N/c4ccc(N(CC)CC)cc4)cc3)sc2c1]

98 parts by mass chloroform, 2 parts by mass ethylene oxide-modified trimethylolpropane triacrylate (V#360, available from Osaka Organic Chemical Industry Ltd.), 2 parts by mass dipentaerythrithol hexaacrylate (KAYARAD DPHA, available from Nippon Kayaku Co., Ltd.), 0.06 parts by mass Irgacure 907 (available from Ciba Specialty Chemicals), and Kayacure DETX (available from Nippon Kayaku Co., Ltd.) was applied to a surface that had been subjected to rubbing treatment, and dried to form a substrate 1 including the polarizing layer and the light conversion film (17). Then ITO was deposited by a sputtering method to produce an opposite substrate 1 (=second (electrode) substrate).

### [Production of Opposite Substrate 2]

A polarizing layer was formed on the wavelength-selective transmission layer (cholesteric liquid crystal layer) of the light conversion film (18) in the same manner as the substrate 1 including the light conversion film (17). Then ITO was deposited by a sputtering method to produce an opposite substrate 2 (=second (electrode) substrate).

### [Production of Opposite Substrate 3]

A polarizing layer was formed on the wavelength-selective transmission layer (dielectric multilayer film) of the light conversion film (20) in the same manner as the substrate 1 including the light conversion film (17), thereby producing an opposite substrate 3 (=second (electrode) substrate).

### [Production of Opposite Substrate 4]

A polarizing layer was formed on the wavelength-selective transmission layer (cholesteric liquid crystal layer) of the light conversion film (19) in the same manner as the substrate 1 including the light conversion film (17). Then ITO was deposited by a sputtering method to produce an opposite substrate 4 (=second (electrode) substrate).

### [Production of Opposite Substrate 5]

Aluminum was deposited by sputtering (about 100 nm, available from Shibaura Mechatronics Corporation) on a glass surface of a glass substrate on which the wavelength-selective transmission layer (dielectric multilayer film) used for the light conversion film (17) produced above was formed, the glass surface being opposite to the dielectric multilayer film. A silicon oxide film and a silicon film were formed thereon by sputtering. A photocurable resist was uniformly applied to a surface of the film by a spin coating method to a thickness of 100 nm. The resist layer was dried in an oven at 70° C. for 5 minutes. The resist was photocured by irradiation with ultraviolet light including a wavelength of 365 nm at an amount of light of 1,000 mJ/cm² while a resin mold (pattern mold: a line and space pattern having a pitch of 130 nm, a duty of 0.4, and a pattern height of 180 nm) was uniformly pressed on the dry resist layer. Then the resin mold was removed. The recessed portion of the resist pattern was selectively etched in an oxygen gas plasma with a reactive ion etching system (RIE system) to leave a protruding portion alone, thereby providing a resist mask.

After the formation of the resist mask, the silicon layer and the silicon oxide layer were anisotropically etched in CHF₃ gas plasma with the RIE system in a direction perpendicular to the substrate. The layer composed of aluminum was anisotropically etched in a Cl gas plasma with the RIE system in the thickness direction of the substrate (direction perpendicular to the substrate). The resist mask left on the top of the silicon layer was removed by etching in an oxygen gas plasma, thereby producing a substrate including the light conversion film (17) having a wire grid polarizing layer on its surface. Then ITO was deposited by a sputtering method to produce an opposite substrate 5 (=second (electrode) substrate).

### [Production of Opposite Substrate 6]

A planarization film composition (trade name: PIG-7424, available from JNC Corporation) was applied by spin coating to the cholesteric liquid crystal layer of the light conversion film (19) produced above, dried, and post-baked to form a planarization film. A wire grid polarizing layer was formed on the cholesteric liquid crystal layer of the light conversion film (19) under the same conditions as those in the method for producing the opposite substrate 5. Then ITO was deposited by a sputtering method to produce an opposite substrate 6 (=second (electrode) substrate).

### (Production of Opposite Substrate 7)

A planarization film composition (trade name: PIG-7424, available from JNC Corporation) was applied by spin coating to the dielectric multilayer film of the light conversion film (21) produced above dried, and post-baked to form a planarization film. A wire grid polarizing layer was formed on the planarization film of the light conversion film (21) under the same conditions as those in the method for producing the opposite substrate 5. Then ITO was deposited by a sputtering method to produce an opposite substrate 7 (=second (electrode) substrate).

### (Production of Opposite Substrate 8)

A planarization film composition (trade name: PIG-7424, available from JNC Corporation) was applied by spin coating to the cholesteric liquid crystal layer of the light conversion film (18) produced above, dried, and post-baked to form a planarization film. A wire grid polarizing layer was formed on the planarization film of the light conversion film (18) under the same conditions as those in the method for producing the opposite substrate 5. Then ITO was deposited by a sputtering method to produce an opposite substrate 8 (=second (electrode) substrate).

### (Production of Opposite Substrate 9)

As Comparative example 3, A planarization film composition (trade name: PIG-7424, available from JNC Corporation) was applied by spin coating to the light conversion layer (3) produced above, dried, and post-baked to form a planarization film. A wire grid polarizing layer was formed on the light conversion layer (3) under the same conditions as those in the method for producing the opposite substrate 3. Then ITO was deposited by a sputtering method to produce an opposite substrate 9 (=second (electrode) substrate).

### (Production of Opposite Substrate 10)

A planarization film composition (trade name: PIG-7424, available from JNC Corporation) was applied by spin coating to the cholesteric liquid crystal layer of the light conversion film (18) produced above, dried, and post-baked to form a planarization film. A wire grid polarizing layer was formed on the planarization film of the light conversion film (18) under the same conditions as those in the method for producing the opposite substrate 5, thereby producing an opposite substrate 10 (=second (electrode) substrate) (without ITO).

### “VA-Mode Liquid Crystal Panel”

### Example 22

A homeotropic alignment layer was formed on each of the ITO of the second (electrode) substrate (opposite substrate 8) and the transparent electrode of a first (electrode) substrate including TFTs. The first substrate including the transparent electrode and the homeotropic alignment layer and the second (electrode) substrate (opposite substrate 8) including the homeotropic alignment layer were arranged in such a manner that the alignment layers faced each other and the alignment directions of the alignment layers were antiparallel directions (180°). The peripheral portions thereof were bonded to each other with a sealing agent while a certain gap (4 μm) was maintained between the two substrates, thereby producing a VA-mode liquid crystal cell. Liquid crystal compositions (exemplified compositions 1 to 4) described in Table 4 below were each charged by a vacuum injection method into the cell gap defined by the surfaces of the alignment layers and the sealing agent. A polarizing plate was bonded to the first substrate. Thereby, VA-mode liquid crystal panels 1 to 4 were produced (a VA-mode liquid crystal cell containing the exemplified composition 3 is referred to as a “VA-mode liquid crystal panel 3”). The resulting liquid crystal panels 1 to 4 were used as evaluation devices, and VHR measurement and fluorescence intensity measurement in the same manner as above were performed.

### Comparative Example 4

As a comparative example, a comparative liquid crystal panel 5 was produced in the same manner as the method for producing the liquid crystal panels 1 to 4, except that an opposite substrate 9 not including the wavelength-selective transmission layer was used in place of the opposite substrate 8 and the exemplified composition 1 was charged as a liquid crystal composition. The fluorescence intensity was measured.

TABLE 4

| | Exemplified | Exemplified | Exemplified | Exemplified |
|---|---|---|---|---|
| Sample No. | composition 1 | composition 2 | composition 3 | composition 4 |
| 3-Cy-Cy-2 | 18 | 21 | | |
| 3-Cy-Cy-4 | | 5 | | |
| 3-Cy-Cy-V | | | 35 | 30 |
| 3-Cy-Cy-V1 | | | | 8 |
| 3-Ph—Ph5—O2 | 11 | 15 | 13 | 11 |
| 3-Ph—Ph-1 | 6 | | | |
| 3-Cy-Cy-Ph-1 | 6 | | | |
| 3-Cy-Ph—Ph-2 | 6 | | | 7 |
| V-Cy-Cy-Ph-1 | | 6 | 6 | |
| V-Cy-Ph-3 | 6 | 6 | 6 | |
| 3-Cy-Ph5—O2 | 12 | 12 | 7 | 7 |
| 5-Cy-Ph5—O2 | 7 | | | |
| 2-Cy-Cy-Ph5—O2 | | 7 | | 8 |
| 3-Cy-Cy-Ph5—O2 | | 7 | | 8 |
| 3-Cy-Cy-1O—Ph5—O2 | 7 | | 12 | |
| 2-Cy-Ph—Ph5—O2 | 7 | 7 | 7 | 7 |
| 3-Cy-Ph—Ph5—O2 | 7 | 7 | 7 | 7 |
| 3-Cy-Ph—Ph5—O3 | 7 | 7 | 7 | 7 |
| Total [%] | 100 | 100 | 100 | 100 |
| T_{NI} | 71.1 | 73.2 | 78.5 | 78.8 |
| Δn | 0.121 | 0.109 | 0.109 | 0.096 |
| Δε | −3.3 | −3.5 | −3.0 | −2.8 |
| γ1 | 121 | 122 | 98 | 97 |

Even when each of the liquid crystal panels 1 to 4 was irradiated with light having a main emission peak at 450 nm for one week, VHR was 98% or more. Accordingly, they were seemingly stable to light having a main emission peak at 450 nm. Comparisons of the fluorescence intensity evaluations of the VA-mode liquid crystal panels 1 to 4 and the liquid crystal panel 5 revealed that the presence of the cholesteric liquid crystal layer significantly increased the emission intensity. The same tendency as the fluorescence intensity measurement results of Examples 1 to 5 was observed.

### Example 23

A VA-mode liquid crystal panel 6 was produced in the same manner as the method for producing the liquid crystal panels 1 to 4, except that the opposite substrate 5 was used in place of the opposite substrate 8 of Example 22 and the exemplified composition 1 was charged as a liquid crystal composition. The fluorescence intensity was measured. The results indicated that the presence of the wavelength-selective transmission layer (dielectric multilayer film) significantly increased the emission intensity. The same tendency as the fluorescence intensity measurement results of Examples 15 and 16 was observed.

### Example 24

A VA-mode liquid crystal panel 7 was produced in the same manner as the method for producing the liquid crystal panels 1 to 4, except that the opposite substrate 4 was used in place of the opposite substrate 8 and the exemplified composition 1 was charged as a liquid crystal composition. The fluorescence intensity was measured. The results indicated that the presence of the cholesteric liquid crystal layer significantly increased the emission intensity and improved the R/B ratio or G/B ratio.

### “PSVA-Mode Liquid Crystal Panel”

### Example 25

A polyimide alignment layer to induce homeotropic alignment was formed on each of the ITO of the second (electrode) substrate (opposite substrate 2) and a transparent electrode of the first substrate including TFTs. The first substrate including the transparent electrode and the homeotropic alignment layer and the second (electrode) substrate (opposite substrate 2) including the homeotropic alignment layer were arranged in such a manner that the alignment layers faced each other and the alignment directions of the alignment layers were antiparallel directions (180°). The peripheral portions thereof were bonded to each other with a sealing agent while a certain gap (4 μm) was maintained between the two substrates. A polymerizable compound-containing liquid crystal composition 1 containing 0.3 parts by mass of a polymerizable compound below:

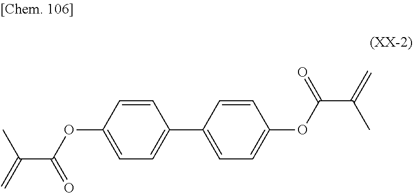 [SMILES: C=C(C)C(=O)Oc1ccc(-c2ccc(OC(=O)C(=C)C)cc2)cc1]

and 99.7 parts by mass of the exemplified composition 1 mixed was injected by a vacuum injection method into the cell gap defined by the surfaces of the alignment layers and the sealing agent. As a material for the formation of the homeotropic alignment layer, JALS2096 available from JSR Corporation was used. As the first substrate, a substrate having a fishbone structure and including ITO was used.

The liquid crystal panel into which the polymerizable compound-containing liquid crystal composition had been injected was irradiated with ultraviolet light from a high-pressure mercury lamp through a filter that cut off ultraviolet light having a wavelength of 325 nm or less while a voltage of 10 V was applied thereto at a frequency of 100 Hz. At this time, the illuminance measured at a center wavelength of 365 nm was adjusted to 100 mW/cm², and ultraviolet irradiation was performed at an integrated quantity of light of 10 J/cm². Next, the illuminance measured at a center wavelength of 313 nm with a fluorescent UV lamp was adjusted to 3 mW/cm², and ultraviolet irradiation was further performed at an integrated quantity of light of 10 J/cm², thereby producing a PSVA-mode liquid crystal panel 1. As with the exemplified composition 1, the panel was evaluated using a light resistance test with light having a main emission peak at 450 nm and a light resistance test with light having a main emission peak at 385 nm. The results indicated that in each case of light having a main emission peak at 450 nm and a main emission peak at 385 nm, substantially the same results as those of the VA-mode liquid crystal panels 1 to 4 were obtained. The results also indicated that the presence of the wavelength-selective transmission layer (cholesteric liquid crystal layer) significantly increased the emission intensity. The same tendency as the fluorescence intensity measurement results of Examples 1 to 5 was observed.

### Example 26

A polyimide alignment layer to induce homeotropic alignment was formed on each of the ITO of the second (electrode) substrate (opposite substrate 1) and a transparent electrode of the first substrate including TFTs. The first substrate including the transparent electrode and the homeotropic alignment layer and the second (electrode) substrate (opposite substrate 2) including the homeotropic alignment layer were arranged in such a manner that the alignment layers faced each other and the alignment directions of the alignment layers were antiparallel directions (180°). The peripheral portions thereof were bonded to each other with a sealing agent while a certain gap (4 μm) was maintained between the two substrates. A polymerizable compound-containing liquid crystal composition 2 containing a polymerizable compound (XX-5) below:

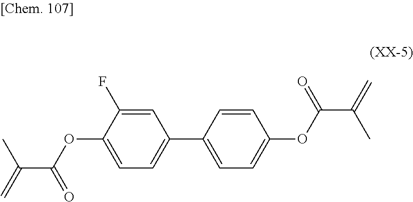 [SMILES: C=C(C)C(=O)Oc1ccc(-c2ccc(OC(=O)C(=C)C)c(F)c2)cc1]

and 99.7 parts by mass of the exemplified composition 2 mixed was injected by a vacuum injection method into the cell gap defined by the surfaces of the alignment layers and the sealing agent. As a material for the formation of the homeotropic alignment layer, JALS2096 available from JSR Corporation was used. As the first substrate, a substrate having a fishbone structure and including ITO was used.

The liquid crystal panel into which the polymerizable compound-containing liquid crystal composition had been injected was irradiated with ultraviolet light from a high-pressure mercury lamp through a filter that cut off ultraviolet light having a wavelength of 325 nm or less while a voltage of 10 V was applied thereto at a frequency of 100 Hz. At this time, the illuminance measured at a center wavelength of 365 nm was adjusted to 100 mW/cm², and ultraviolet irradiation was performed at an integrated quantity of light of 10 J/cm². Next, the illuminance measured at a center wavelength of 313 nm with a fluorescent UV lamp was adjusted to 3 mW/cm², and ultraviolet irradiation was further performed at an integrated quantity of light of 10 J/cm², thereby producing a PSVA-mode liquid crystal panel 2. As with the exemplified composition 1, the panel was evaluated using a light resistance test with light having a main emission peak at 450 nm and a light resistance test with light having a main emission peak at 385 nm. The results indicated that in each case of light having a main emission peak at 450 nm and a main emission peak at 385 nm, substantially the same results as those of the VA-mode liquid crystal panels 1 to 4 were obtained. The results also indicated that the presence of the wavelength-selective transmission layer (dielectric multilayer film) significantly increased the emission intensity. The same tendency as the fluorescence intensity measurement results of Examples 15 and 16 was observed.

### “Spontaneous Alignment-Type VA-Mode Liquid Crystal Panel”

### Example 27

A first substrate including TFTs and a transparent electrode and the second substrate (opposite substrate 2) were arranged in such a manner that these electrodes face each other. The peripheral portions thereof were bonded to each other with a sealing agent while a certain gap (4 μm) was maintained between the two substrates (no alignment layers were formed). A liquid crystal composition prepared by adding 2 parts by mass of a spontaneous alignment agent (formula (al-1) below):

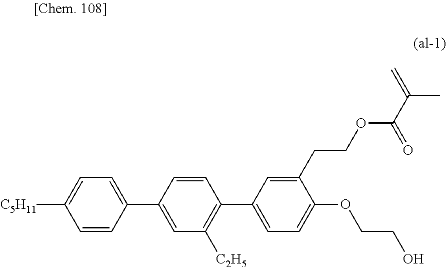

and 0.5 parts by mass of the polymerizable compound (XX-2) to the liquid crystal composition 1 (100 parts by mass) was injected by a vacuum injection method into the cell gap defined by the sealing agent. A polarizing plate was bonded to the first substrate. Ultraviolet irradiation was performed under the same conditions as in Example 25, thereby producing a VA-mode liquid crystal panel 8.

### Example 28

### (VA-Mode Liquid Crystal Panel 8)

A VA-mode liquid crystal panel 9 was produced as in the same manner, except that the opposite substrate 7 was used in place of the second substrate (opposite substrate 2).

### Example 29

A first substrate including TFTs and a transparent electrode and the second transparent electrode substrate (the opposite substrate 1) were arranged in such a manner that these electrodes face each other. The peripheral portions thereof were bonded to each other with a sealing agent while a certain gap (4 μm) was maintained between the two substrates (no alignment layers were formed). A liquid crystal composition prepared by adding 2 parts by mass of a spontaneous alignment agent (formula (P-1-2) below):

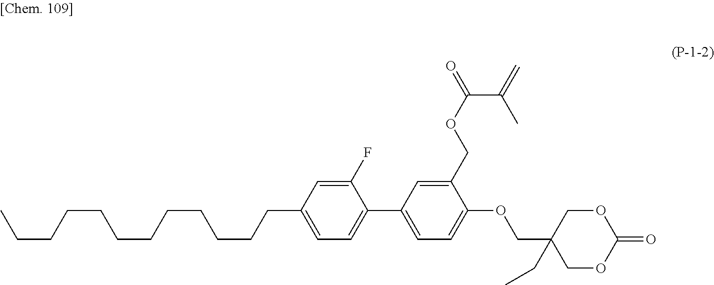 [SMILES: C=C(C)C(=O)OCc1cc(-c2ccc(CCCCCCCCCCCC)cc2F)ccc1OCC1(CC)COC(=O)OC1]

and the polymerizable compound (XX-5) to the liquid crystal composition 1 (100 parts by mass) was injected by a vacuum injection method into the cell gap defined by the surfaces of the alignment layers and the sealing agent. A polarizing plate was bonded to the first substrate. Ultraviolet irradiation was performed under the same conditions as in Example 20, thereby producing a VA-mode liquid crystal panel 10.

The fluorescence intensity of each of the spontaneous alignment-type VA-mode liquid crystal panels 8 to 10 produced in Examples 27 to 29 was evaluated. The results indicated that the emission intensity thereof was significantly higher than those of the panels including no wavelength-selective transmission layer and that the R/B value and the G/B value were increased.

### Example 30

A homeotropic alignment layer solution used in Example 22 described in International Publication No. 2013/002260 was used to form an alignment layer having a dry thickness of 0.1 μm by a spin coating method on a first substrate including TFTs and a transparent electrode. Similarly, a photoalignment layer was formed on a surface of the second transparent electrode substrate (opposite substrate 2). The first substrate including the transparent electrode and the photoalignment layer and the second (electrode) substrate (opposite substrate 2) were arranged in such a manner that the alignment layers face each other and the alignment directions of the alignment layers were antiparallel directions (180°). The peripheral portions thereof were bonded to each other with a sealing agent while a certain gap (4 μm) was maintained between the two substrates. The liquid crystal composition 1 was injected by a vacuum injection method into the cell gap defined by the surfaces of the alignment layers and the sealing agent. A polarizing plate was bonded to the first substrate, thereby producing a VA-mode liquid crystal panel 11.

### Example 31

A VA-mode liquid crystal panel 12 was produced in the same manner as the method for producing the VA-mode liquid crystal panel 10, except that the opposite substrate 2 in the method for producing the VA-mode liquid crystal panel 11 was changed to the opposite substrate 1.

The fluorescence intensity of each of the VA-mode liquid crystal panels 10 and 11 produced in Examples 30 and 31 was evaluated. The results indicated that the emission intensity thereof was significantly higher than those of the panels including no wavelength-selective transmission layer and that the R/B value and the G/B value were increased.

### “IPS-Mode Liquid Crystal Panel”

### Example 32

A homogeneous alignment layer solution was used to form an alignment layer by a spin coating method on a pair of a comb-shaped electrodes disposed on a transparent substrate, thereby producing a first substrate including the comb-shaped transparent electrodes and the alignment layer. The homogeneous alignment layer solution was used to form an alignment layer by a spin coating method on the opposite substrate 3 (second (electrode) substrate). The two substrates were arranged in such a manner that the alignment layers face each other and that the directions of irradiation with linearly polarized light or the directions of rubbing in the horizontal direction were antiparallel directions (180°). The peripheral portions thereof were bonded to each other with a sealing agent while a certain gap (4 μm) was maintained between the two substrates. The liquid crystal composition (exemplified composition 3) was injected by a vacuum injection method into the cell gap defined by the surfaces of the alignment layers and the sealing agent. A pair of polarizing plates was bonded to the first substrate and the second substrate to produce an IPS-mode liquid crystal panel.

The fluorescence intensity of the IPS-mode liquid crystal panel produced in Example 32 was evaluated. The results indicated that the emission intensity thereof was significantly higher than those of the panels including no wavelength-selective transmission layer and that the R/B value and the G/B value were increased.

### “FFS-Mode Liquid Crystal Panel”

### Example 33

A flat plate-shaped common electrode was formed on a first transparent substrate. An insulating layer was formed thereon. A transparent comb-shaped electrode was formed on the insulating layer. An alignment layer solution was applied onto the transparent comb-shaped electrode by a spin coating method, thereby producing a first electrode substrate. A homogeneous alignment layer solution was used to form an alignment layer by a spin coating method on the opposite substrate 10 (second (electrode) substrate). The first substrate including the comb-shaped transparent electrode and the alignment layer and the second substrate including the alignment layer, a polarizing layer, and a light conversion film were arranged in such a manner that the alignment layers face each other and that the directions of irradiation with linearly polarized light or the directions of rubbing were antiparallel directions (180°). The peripheral portions thereof were bonded to each other with a sealing agent while a certain gap (4 μm) was maintained between the two substrates. The liquid crystal composition (exemplified composition 2) was injected by a dispenser method into the cell gap defined by the surfaces of the alignment layers and the sealing agent, thereby producing an FFS-mode liquid crystal panel.

The fluorescence intensity of the FFS-mode liquid crystal panel produced in Example 33 was evaluated. The results indicated that the emission intensity thereof was significantly higher than those of the panels including no wavelength-selective transmission layer and that the R/B value and the G/B value were increased.

### <Liquid Crystal Display Device>

### (Production of Backlight Unit 1)

A backlight unit 1 was produced by placing a blue LED light source on an end portion of a side of a light guide plate, covering portions of the plate excluding an irradiation surface with a reflection sheet, and placing a diffusion sheet on the irradiation surface.

### (Production of Backlight Unit 2)

A backlight unit 2 was produced by arranging blue LEDs in grid form on a lower reflector plate configured to scatter and reflect light, placing a diffusion plate directly on the irradiation side thereof, and arranging a diffusion sheet on the irradiation side thereof.

### (3) Production of Liquid Crystal Display Device and Measurement of Color Gamut

Each of the backlight units 1 and 2 was attached to the individual VA-mode liquid crystal panels 1 to 11 and the PSVA-mode liquid crystal panel produced above. The color gamuts and the fluorescence intensities thereof were measured. Comparisons of the liquid crystal display devices including the light conversion films and conventional liquid crystal display devices not including such a light conversion film revealed that the former devices had broader color gamuts and higher color purities.

Similarly, each of the backlight units 1 and 2 was attached to the IPS-mode liquid crystal panel produced above. The color gamuts and the fluorescence intensities thereof were measured. Comparisons of the liquid crystal display devices including the light conversion films and conventional liquid crystal display devices not including such a light conversion film revealed that the former devices had broader color gamuts and higher color purities.

Each of the backlight units 1 and 2 was attached to the FFS-mode liquid crystal panel produced above. The color gamuts and the fluorescence intensities thereof were measured. Comparisons of the liquid crystal display devices including the light conversion films and conventional liquid crystal display devices not including such a light conversion film revealed that the former devices had broader color gamuts and higher color purities.

### <Light-Emitting Device or Organic Electroluminescent Image Display Device>

### Example 34

An ITO electrode was vapor-deposited on a wavelength-selective transmission layer (dielectric multilayer film) on a surface of a glass substrate including TFTs and the light conversion film (17) stacked. A light-emitting device 1 including an electroluminescent layer configured to emit blue light was formed on the ITO electrode by a method described in “Appl. Mater. Interfaces 2013, 5, 7341-7351”. The ITO electrode and the TFT layer were electrically connected through a contact hole. Thereby, an image display device 1 corresponding to the light conversion layer (17) was produced.

### Example 35

An ITO electrode was vapor-deposited on a wavelength-selective transmission layer (cholesteric liquid crystal layer) on a surface of a glass substrate including TFTs and the light conversion film (18) stacked. An image display device 2 corresponding to the light conversion film (18) was produced in the same manner as in Example 34.

### Comparative Example 5

An ITO electrode was vapor-deposited on the light conversion layer (3) on a surface of a glass substrate including TFTs and the light conversion layer (3) stacked. An image display device 3 corresponding to the light conversion layer (3) was produced in the same manner as in Example 34.

The light-emitting device 1 including the electroluminescent layer configured to emit blue light has a specific structure described below.

As the hole transport layer of the light-emitting device 1, TAPC illustrated below was used.

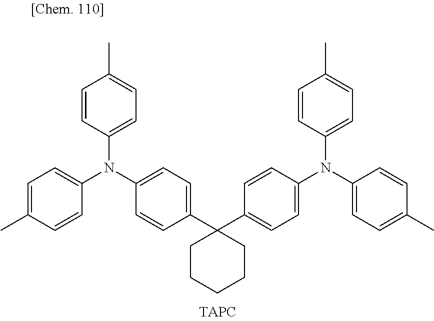

As the electron-blocking layer of the light-emitting device 1, mCP illustrated below was used.

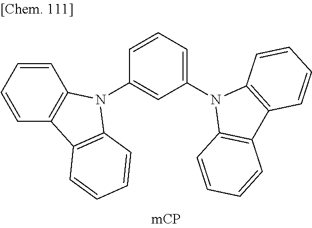 [SMILES: c1cc(-n2c3ccccc3c3ccccc32)cc(-n2c3ccccc3c3ccccc32)c1]

A compound illustrated below was used as a light-emitting material (dopant) of a first light-emitting layer of the light-emitting device 1.

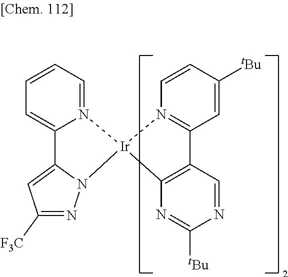

As the host material of the first light-emitting layer of the light-emitting device 1, mCP illustrated below was used.

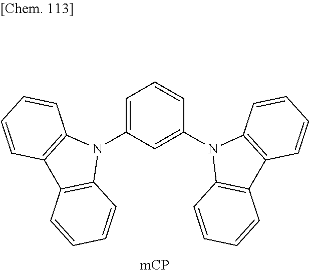 [SMILES: c1cc(-n2c3ccccc3c3ccccc32)cc(-n2c3ccccc3c3ccccc32)c1]

A compound illustrated below was used as a light-emitting material (dopant) of a second light-emitting layer of the light-emitting device 1.

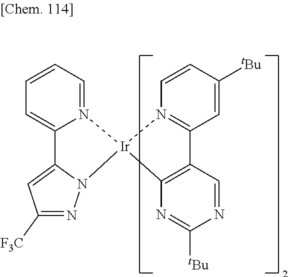

As the host material of the second light-emitting layer of the light-emitting device 1, UGH2 illustrated below was used.

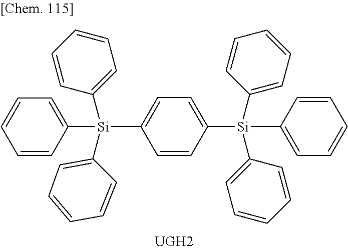 [SMILES: c1ccc([Si](c2ccccc2)(c2ccccc2)c2ccc([Si](c3ccccc3)(c3ccccc3)c3ccccc3)cc2)cc1]

As the hole-blocking layer of the light-emitting device 1, UGH2 illustrated above was used.

As the electron transport layer of the light-emitting device 1, a compound illustrated below was used.

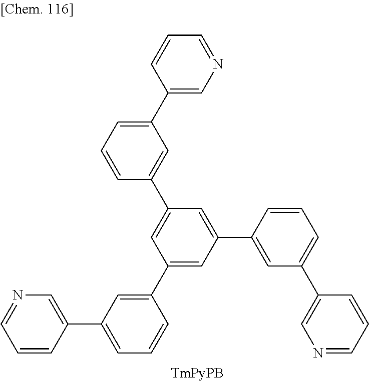 [SMILES: c1cncc(-c2cccc(-c3cc(-c4cccc(-c5cccnc5)c4)cc(-c4cccc(-c5cccnc5)c4)c3)c2)c1]

The hole transport layer, the electron-blocking layer, the first light-emitting layer, the second light-emitting layer, the hole-blocking layer, and the electron transport layer were formed, in this order, by patterning on the ITO electrode. A blue-light-emitting layer was formed by a method described in “Appl. Mater. Interfaces 2013, 5, 7341-7351. A solid (LiF/Al) electrode serving as a cathode and a solid protective layer were formed and stacked in this order. Thereby, the image display device 1 and 2 including the light-emitting devices configured to emit blue light were produced.

The color gamuts and the fluorescence intensities of the image display devices 1 and 2 produced above were measured. Comparisons of the liquid crystal display devices including the light conversion films and conventional liquid crystal display devices not including such a light conversion film revealed that the former devices had broader color gamuts and higher color purities.

### REFERENCE SIGNS LIST

1000A, 1000B: liquid crystal display device, 100A, 100B: backlight unit, 101A, 101B: light source section, 102: light guide section, 200A, 200B: liquid crystal panel, L: light-emitting device, NC: light-emitting nanocrystalline particle (compound semiconductor), 1: first polarizing layer, 2: first substrate, 3: electrode layer, 3a: first electrode layer (pixel electrode), 3b: second electrode layer (common electrode), 4: first alignment layer, 5: liquid crystal layer, 6: second alignment layer, 7: second polarizing layer, 8, 11: wavelength-selective transmission layer, 9: light conversion layer, 10: second substrate, 12: supporting substrate, 13: gate insulating layer, 14: gate electrode, 16: drain electrode, 17: source electrode, 18: passivation film, 19: semiconductor layer, 20: protective film, 21: pixel electrode, 22: common electrode, 23, 25: insulating layer, 1000C: image display device (LED panel), 51: substrate, 52: first electrode, 53: hole injection layer, 54: hole transport layer, 55: light-emitting layer, 56: electron transport layer, 57: electron injection layer, 58: second electrode, 59: overcoat layer, 60: substrate, 500: electroluminescent layer

1. A light conversion film, comprising:
a light conversion layer containing light-emitting nanocrystalline particles configured to convert light having a predetermined wavelength into light of any of red, green, and blue and to emit the light; and
a wavelength-selective transmission layer disposed on at least one side of the light conversion layer and configured to transmit light in one or more specific wavelength ranges.

2. The light conversion film according to claim 1, wherein the wavelength-selective transmission layer is configured to transmit the light having the one or more predetermined wavelengths and to reflect light emitted from the light conversion layer.

3. The light conversion film according to claim 1, wherein the light having the one or more predetermined wavelengths is blue light, and
the light conversion layer includes a red pixel portion containing red light-emitting nanocrystalline particles configured to absorb the light having the one or more predetermined wavelengths and to emit red light, a green pixel portion containing green light-emitting nanocrystalline particles configured to absorb the light having the one or more predetermined wavelengths and to emit green light, and a blue pixel portion configured to transmit the light having the one or more predetermined wavelengths.

4. The light conversion film according to claim 1, wherein the light conversion film comprises the wavelength-selective transmission layer, the light conversion layer, and a second wavelength-selective transmission layer.

5. An image display device, comprising:
a light source section;
a light conversion layer containing light-emitting nanocrystalline particles configured to convert light having one or more predetermined wavelengths into light of any of red, green, and blue and to emit the light; and
a wavelength-selective transmission layer disposed on at least one side of the light conversion layer and configured to transmit light in a specific wavelength range.

6. The image display device according to claim 5, wherein the wavelength-selective transmission layer is disposed in such a manner that light from the light source section is incident on the wavelength-selective transmission layer, the wavelength-selective transmission layer being configured to transmit light from the light source and to reflect light from the light conversion layer, and
wherein the light conversion layer is disposed on an opposite side of the wavelength-selective transmission layer from the light source section and contains light-emitting nanocrystalline particles configured to convert transmitted light transmitted through the wavelength-selective transmission layer into light of any of red, green, and blue and to emit light.

7. The image display device according to claim 6, wherein light from the light source section is blue light, and
wherein the light conversion layer includes a red pixel portion containing red light-emitting nanocrystalline particles configured to absorb the transmitted light and to emit red light, a green pixel portion containing green light-emitting nanocrystalline particles configured to absorb the transmitted light and to emit green light, and a blue pixel portion configured to transmit the transmitted light.

8. The image display device according to claim 6, further comprising a second wavelength-selective transmission layer on an opposite side of the light conversion layer from the wavelength-selective transmission layer.

9. The image display device according to claim 6, further comprising a liquid crystal layer on an opposite side of the wavelength-selective transmission layer from the light conversion layer.

10. The image display device according to claim 6, further comprising a liquid crystal layer on an opposite side of the light conversion layer from the wavelength-selective transmission layer.

11. The image display device according to claim 5, wherein light from the light source section is electroluminescent light.
